(19) United States
(12) Patent Application Publication
(10) Pub. No.: US 2020/0319549 A1
(43) Pub. Date: Oct. 8, 2020

(54) PHOTOSENSITIVE RESIN COMPOSITION, CURED FILM, ELEMENT HAVING CURED FILM, ORGANIC EL DISPLAY, AND METHOD FOR MANUFACTURING ORGANIC EL DISPLAY

(71) Applicant: TORAY INDUSTRIES, INC., Tokyo (JP)

(72) Inventors: Yugo TANIGAKI, Shiga (JP); Kazuto MIYOSHI, Shiga (JP)

(73) Assignee: TORAY INDUSTRIES, INC., Tokyo (JP)

(21) Appl. No.: 16/650,700

(22) PCT Filed: Sep. 27, 2018
(86) PCT No.: PCT/JP2018/036083

§ 371 Date: Mar. 25, 2020

(30) Foreign Application Priority Data
Sep. 29, 2017 (JP) 2017-191946

(51) Int. Cl. G03F 7/004; G03F 7/075; G03F 7/16; G03F 7/20; G03F 7/32; G03F 7/40; C08G 73/10; C08G 73/22; C08G 77/26; G03F 7/038; H01L 27/32; H01L 51/52; G02F 1/1339; G02F 1/1335; G02F 1/1362

(52) U.S. Cl. CPC G03F 7/0045; G02F 2001/13398; G03F 7/168; G03F 7/2004; G03F 7/162; G03F 7/322; G03F 7/40; C08G 73/1071; C08G 73/22; C08G 77/26; G03F 7/0387; H01L 27/3246; H01L 27/3258; H01L 51/5284; G02F 1/13394; G02F 1/133512; G02F 1/136209; G03F 7/0757

(57) ABSTRACT

An object of the invention is to provide a cured film which is high in sensitivity, capable of forming a pattern in a low-taper shape, capable of the change in pattern opening width between before and after thermal curing, an excellent in light-blocking property, and a photosensitive resin composition that forms the film. The photosensitive resin composition contains an (A) alkali-soluble resin, a (C) photosensitive agent, a (Da) black colorant, and a (F) a cross-linking agent, where the (A) alkali-soluble resin contains a (A1) first resin including one or more selected from the group consisting of: a specific (A1-1) polyimide; a (A1-2) polyimide precursor; a (A1-3) polybenzoxazole; and a (A1-4) polybenzoxazole precursor, and contains a structural unit having a fluorine atom at a specific ratio, the content ratio of the (Da) black colorant is a specific ratio, and the (F) cross-linking agent contains an epoxy compound that has a specific structure, and/or an epoxy resin that has a specific structural unit.

### TECHNICAL FIELD

The present invention relates to a photosensitive resin composition, a cured film, an element including a cured film, an organic EL display, and a method for manufacturing an organic EL display.

### BACKGROUND ART

In recent years, many products that use organic electroluminescence (Electroluminescence: EL) display devices have been developed in display devices including thin displays, such as smartphones, tablet PCs, and televisions.

In general, an organic EL display has a transparent electrode such as an indium tin oxide (hereinafter referred to as an “ITO”) on the light-extraction side of a light-emitting element, and a metal electrode such as an alloy of magnesium and silver on the side of the light-emitting element, from which no light is extracted. In addition, in order to define the pixels of the light-emitting element, an insulation layer referred to as a pixel defining layer is provided between the transparent electrode and the metal electrode. After the pixel defining layer is formed, a light-emitting material is deposited by evaporation through an evaporation mask in a region corresponding to the pixel region, where the pixel defining layer has an opening to expose the underlying transparent electrode or metal electrode, thereby forming a light-emitting layer. The transparent electrode and metal electrode are commonly formed by sputtering, but the pixel defining layer requires a low-taper pattern shape in order to prevent disconnection of the formed transparent electrode or metal electrode.

Furthermore, the organic EL display has thin-film-transistors (hereinafter, “TFTs”) for controlling the light-emitting element, which include a driving TFT, a switching TFT, and the like. In general, these TFTs are formed as laminated structures located further below the transparent electrode or the metal electrode, which serves as a base for the pixel defining layer mentioned above. The level differences due to the TFTs and a TFT array with a metal wiring or the like formed for connecting the TFTs to each other deteriorate uniformity in the subsequent formation of transparent electrodes, metal electrodes, pixel defining layers, and light-emitting layers, thereby causing the display characteristics and reliability of the organic EL display to be deteriorated. For that reason, after forming the TFT array, it is common to form a TFT planarization layer and/or a TFT protective layer for reducing or smoothing the level difference due to the TFT array.

Organic EL displays have a self-light-emitting element that emits light with the use of energy generated by recombination of electrons injected from a cathode and holes injected from an anode. Thus, the presence of a substance which inhibits the movement of electrons or holes, a substance that forms an energy level which inhibits recombination of electrons and holes, or the like, makes influences such as the decreased light emission efficiency of the light-emitting element or the deactivation of the light-emitting material, thus leading to the decreased lifetime of the light-emitting element. Since the pixel defining layer is formed at a position adjacent to the light-emitting element, degassing and ionic component outflow from the pixel defining layer can contribute to the decreased lifetime of the organic EL display. For that reason, high heat resistance is required for the pixel defining layer. As photosensitive resin compositions with high heat resistance, negative photosensitive resin compositions including resins such as high heat-resistance polyimide are known (for example, see Patent Document 1). The use of such a photosensitive resin composition allows for the formation of a high heat-resistance pixel dividing layer that has a pattern in a low-taper pattern.

In addition, since the organic EL display has the self-light-emitting element, incident external light such as sunlight outdoors decreases the visibility and contrast due to reflection of the external light. Thus, a technique for reducing external light reflection is required.

As a technique for blocking external light and then reducing external light reflection, a photosensitive resin composition containing an alkali-soluble polyimide and a colorant is known (for example, see Patent Document 2). More specifically, there is a method of reducing external light reflection by forming a pixel dividing layer with high heat resistance and light-blocking property with the use of a photosensitive resin composition containing a polyimide and a colorant such as a pigment.

### PRIOR ART DOCUMENTS

### Patent Documents

Patent Document 1: International Publication No. 2017/057281

Patent Document 2: International Publication No. 2016/158672

### SUMMARY OF THE INVENTION

### Problems to be Solved by the Invention

From the viewpoint of improving the reliability of organic EL displays, in addition to the requirement of high heat resistance for the pixel defining layer adjacent to the light-emitting element, high heat resistance is also required for the TFT planarization layer and the TFT protective layer, because the layers are also formed at positions close to the light-emitting layer with the pixel defining layer interposed therebetween. In the case of containing a colorant such as a pigment in order to impart a light-blocking property to the photosensitive resin composition, however, ultraviolet rays and the like during pattern exposure are also blocked as the content of the colorant is increased, thus decreasing sensitivity for the exposure. Accordingly, conventionally known photosensitive resin compositions containing a colorant all have insufficient characteristics for use as a material for forming pixel defining layers, TFT planarization layers, or TFT protective layers of organic EL displays. Specifically, any of the sensitivity, light-blocking property, or patternability for low-taper shapes has been insufficient.

For example, in the case of improving the light-blocking property of the photosensitive resin composition, the deep part of the film is insufficiently cured during pattern exposure, and the deep part of the film is side-etched during development. For that reason, an inverse tapered shape is obtained after the development, which becomes an obstructive factor against the pattern formation in a low-taper shape. On the other hand, sufficient curing down to the deep part of the film, it is necessary to increase the exposure energy for pattern exposure, thereby promoting ultraviolet curing (UV curing). The increased exposure energy makes, however, the film excessively crosslinked during the UV curing, thereby decreasing the reflow property for thermal curing, and thus forming a pattern in a high-taper shape. Accordingly, for example, the photosensitive resin composition containing an alkali-soluble polyimide and a colorant such as a pigment, described in Patent Document 2, has difficulty in combining characteristics such as sensitivity, light-blocking property, and pattern formation in a low-taper shape.

Furthermore, in the case of forming a pattern in a high-taper shape after development and forming a pattern in a low-taper shape by reflow during thermal curing, pattern skirt reflow also caused during the thermal curing. For that reason, the pattern opening width after the thermal curing is smaller as compared with the pattern opening width after development, thus causing an error in the pixel design or the like for a display device such as an organic EL display. In addition, the variation in pattern opening width due to reflow during the thermal curing causes a decrease in panel manufacturing yield. Accordingly, for example, the photosensitive resin composition containing a resin such as a high heat-resistance polyimide, and a colorant such as a pigment, described in Patent Document 1, has difficulty in achieving a balance between the pattern formation in a low-taper shape and the suppression of the change in pattern opening width between before and after thermal curing.

The present invention has been achieved in view of the foregoing, and an object of the invention is to provide a photosensitive resin composition capable of achieving a cured film which is high in sensitivity, capable of forming a pattern in a low-taper shape after thermal curing, capable of the change in pattern opening width between before and after thermal curing, and excellent in light-blocking property.

### Solutions to the Problems

The photosensitive resin composition according to an aspect of the present invention is a photosensitive resin composition containing an (A) alkali-soluble resin, a (C) photosensitive agent, a (Da) black colorant, and a (F) cross-linking agent, the (A) alkali-soluble resin contains a (A1) first resin including one or more selected from the group consisting of a (A1-1) polyimide, a (A1-2) polyimide precursor, a (A1-3) polybenzoxazole, and a (A1-4) polybenzoxazole precursor, the one or more selected from the group consisting of the (A1-1) polyimide, the (A1-2) polyimide precursor, the (A1-3) polybenzoxazole, and the (A1-4) polybenzoxazole precursor contains a structural unit having a fluorine atom at 10 to 100 mol % to all of structural units, the content ratio of the (Da) black colorant is 5 to 70% by mass to the total solid content, and the (F) cross-linking agent contains one or more selected from the group consisting of: an (F1) epoxy compound having a fluorene skeleton and two or more epoxy groups in the molecule; an (F2) epoxy compound having an indane skeleton and two or more epoxy groups in the molecule; an (F3) epoxy resin having a structural unit including an aromatic structure, an alicyclic structure, and an epoxy group; an (F4) epoxy resin having a structural unit including one or more selected from the group consisting of a biphenyl structure, a terphenyl structure, a naphthalene structure, an anthracene structure, and a fluorene structure, and including two or more epoxy groups; an (F5) epoxy compound having two or more fluorene skeletons or two or more indane skeletons, and two or more epoxy groups in the molecule; an (F6) epoxy compound having two or more condensed polycyclic skeletons linked by a spiro skeleton, and two or more epoxy groups in the molecule; an (F7) epoxy compound having an indolinone skeleton or an isoindolinone skeleton, and two or more epoxy groups in the molecule; and an (F8) epoxy compound having two or more naphthalene skeletons and two or more epoxy groups in the molecule.

### Effects of the Invention

The photosensitive resin composition according to the present invention makes it possible to achieve a cured film which is high in sensitivity, capable of forming a pattern in a low-taper shape, capable of the change in pattern opening width between before and after thermal curing, an excellent in light-blocking property.

### BRIEF DESCRIPTION OF THE DRAWINGS

FIG. 1 is a schematic cross-sectional view illustrating a manufacturing process of Step 1 to Step 7 in an organic EL display that uses a cured film of a photosensitive resin composition according to the present invention.

FIG. 2 is a schematic cross-sectional view illustrating a manufacturing process of Step 1 to Step 13 in a liquid crystal display that uses a cured film of a photosensitive resin composition according to the present invention.

FIG. 3 is a cross-sectional view illustrating a cross section example of a cured pattern with a step shape.

FIG. 4 is a schematic view illustrating, in plan views, a manufacturing process of Step 1 to Step 4 for a substrate of an organic EL display for use in the evaluation of light-emitting characteristics.

FIG. 5 is a schematic cross-sectional view illustrating an organic EL display without any polarizing layer.

FIG. 6 is a schematic view illustrating a method for evaluating the bendability of a cured film.

FIG. 7A is a schematic view illustrating a residue evaluation method during thermal curing.

FIG. 7B is a schematic view illustrating a residue evaluation method during thermal curing.

FIG. 8 is a schematic cross-sectional view illustrating a flexible organic EL display without any polarizing layer.

### EMBODIMENTS OF THE INVENTION

Preferred embodiments of a photosensitive resin composition, a cured film, an element including a cured film, an organic EL display, and a method for manufacturing an organic EL display according to the present invention will be described in detail below, but the present invention is not to be construed as being limited to the embodiments including the following examples, and various modifications can be made without departing from the scope of the invention, as long as the object of the invention can be achieved.

The photosensitive resin composition according to the present invention is a photosensitive resin composition containing an (A) alkali-soluble resin, a (C) photosensitive agent, a (Da) black colorant, and a (F) cross-linking agent,

the (A) alkali-soluble resin contains a (A1) first resin including one or more selected from the group consisting of a (A1-1) polyimide, a (A1-2) polyimide precursor, a (A1-3) polybenzoxazole, and a (A1-4) polybenzoxazole precursor,

the one or more selected from the group consisting of the (A1-1) polyimide, the (A1-2) polyimide precursor, the (A1-3) polybenzoxazole, and the (A1-4) polybenzoxazole precursor contains a structural unit having a fluorine atom at 10 to 100 mol % to all of structural units,

the content ratio of the (Da) black colorant is 5 to 70% by mass to the total solid content, and

the (F) cross-linking agent contains one or more selected from the group consisting of:

an (F1) epoxy compound having a fluorene skeleton and two or more epoxy groups in the molecule;

an (F2) epoxy compound having an indane skeleton and two or more epoxy groups in the molecule;

an (F3) epoxy resin having a structural unit including an aromatic structure, an alicyclic structure, and an epoxy group;

an (F4) epoxy resin having a structural unit including one or more selected from the group consisting of a biphenyl structure, a terphenyl structure, a naphthalene structure, an anthracene structure, and a fluorene structure, and including two or more epoxy groups;

an (F5) epoxy compound having two or more fluorene skeletons or two or more indane skeletons, and two or more epoxy groups in the molecule;

an (F6) epoxy compound having two or more condensed polycyclic skeletons linked by a spiro skeleton, and two or more epoxy groups in the molecule;

an (F7) epoxy compound having an indolinone skeleton or an isoindolinone skeleton, and two or more epoxy groups in the molecule; and

an (F8) epoxy compound having two or more naphthalene skeletons and two or more epoxy groups in the molecule.

### <(A1) First Resin>

The photosensitive resin composition according to the present invention contains at least the (A1) first resin as the (A) alkali-soluble resin.

The composition contains, as the (A1) first resin, one or more selected from a (A1-1) polyimide, a (A1-2) polyimide precursor, a (A1-3) polybenzoxazole, and a (A1-4) polybenzoxazole precursor.

According to the present invention, the (A1-1) polyimide, the (A1-2) polyimide precursor, the (A1-3) polybenzoxazole, and the (A1-4) polybenzoxazole precursor may be any single resin or copolymer thereof.

### <(A1-1) Polyimide and (A1-2) Polyimide Precursor>

Examples of the (A1-2) polyimide precursor include products obtained by reacting a tetracarboxylic acid, a corresponding tetracarboxylic dianhydride or tetracarboxylic diester dichloride, or the like, with a diamine, a corresponding diisocyanate compound or trimethylsilylated diamine, or the like, which have a tetracarboxylic acid residue and/or a derivative residue thereof, and a diamine residue and/or a derivative residue thereof. Examples of the (A1-2) polyimide precursor include a polyamide acid, a polyamide acid ester, polyamide acid amide, and a polyisoimide.

Examples of the (A1-1) polyimide include products obtained by dehydration and cyclization of the above-described polyamide acid, polyamide acid ester, polyamide acid amide, or polyisoimide through heating or through a reaction with the use of an acid, a base, or the like, which have a tetracarboxylic acid residue and/or a derivative residue thereof, and a diamine residue and/or a derivative residue thereof.

The (A1-2) polyimide precursor, which is a thermosetting resin, is thermally cured at high temperature for dehydration and cyclization to form a highly heat-resistance imide bond, thereby providing the (A1-1) polyimide. Accordingly, the photosensitive resin composition contains therein the (A1-1) polyimide having the highly heat-resistance imide bond, thereby making it possible to remarkably improve the heat resistance of the cured film obtained. For that reason, the cured film is suitable in such a case of using the cured film for applications which require high heat resistance. In addition, the (A1-2) polyimide precursor, which is a resin with heat resistance improved after dehydration and cyclization, is suitable in such a case of using the precursor for applications which have a desire to achieve a balance between characteristics of the precursor structure before dehydration and cyclization and the heat resistance of the cured film.

Furthermore, the (A1-1) polyimide and the (A1-2) polyimide precursor have an imide bond and/or an amide bond as a bond with polarity. For that reason, in the case of containing, in particular, a (D1) pigment as a (D) colorant described later, the bond interacts strongly with the (D1) pigment, thus allowing the dispersion stability of the (D1) pigment to be improved.

The (A1-1) polyimide for use in the present invention preferably contains a structural unit represented by the following general formula (1), from the viewpoint of improving the heat resistance of the cured film.

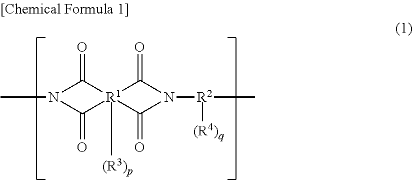

In the general formula (1), R¹ represents a tetravalent to decavalent organic group, and R² represents a divalent to decavalent organic group. R³ and R⁴ each independently represent a phenolic hydroxyl group, a sulfonic acid group, a mercapto group, or a substituent represented by general formula (5) or the general formula (6). p represents an integer of 0 to 6, and q represents an integer of 0 to 8.

R¹ of the general formula (1) represents a tetracarboxylic acid residue and/or a derivative residue thereof, and R² represents a diamine residue and/or a derivative residue thereof. Examples of the tetracarboxylic acid derivative include a tetracarboxylic dianhydride, a tetracarboxylic acid dichloride, or a tetracarboxylic acid active diester. Examples of the diamine derivative include a diisocyanate compound or a trimethylsilylated diamine.

In the general formula (1), R¹ is preferably a tetravalent to decavalent organic group having one or more selected from an aliphatic structure having 2 to 20 carbon atoms, an alicyclic structure having 4 to 20 carbon atoms, and an aromatic structure having 6 to 30 carbon atoms. Furthermore, R² is preferably a divalent to decavalent organic group having one or more selected from an aliphatic structure having 2 to 20 carbon atoms, an alicyclic structure having 4 to 20 carbon atoms, and an aromatic structure having 6 to 30 carbon atoms. q is preferably 1 to 8. The above-described aliphatic structure, alicyclic structure, and aromatic structure may have a hetero atom, and may be either unsubstituted or substituted.

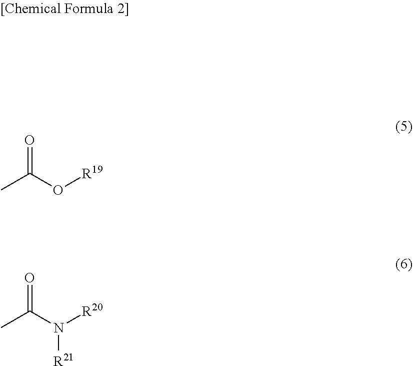

In the general formulas (5) and (6), R¹⁹ to R²¹ each independently represent hydrogen, an alkyl group having 1 to 10 carbon atoms, an acyl group having 2 to 6 carbon atoms, or an aryl group having 6 to 15 carbon atoms. In the general formulas (5) and (6), R¹⁹ to R²¹ each independently preferably represent hydrogen, an alkyl group having 1 to 6 carbon atoms, an acyl group having 2 to 4 carbon atoms, or an aryl group having 6 to 10 carbon atoms. The above-described alkyl group, acyl group, and aryl group may be either unsubstituted or substituted.

The (A1-1) polyimide preferably contains the structural unit represented by general formula (1) as a main component, and the content ratio of the structural unit represented by general formula (1) to all of structural units in the (A1-1) polyimide is preferably 50 to 100 mol %, more preferably 60 to 100 mol %, still more preferably 70 to 100 mol %. When the content ratio is 50 to 100 mol %, the heat resistance of the cured film can be improved.

The (A1-2) polyimide precursor for use in the present invention preferably contains a structural unit represented by general formula (3) from the viewpoint of improving the heat resistance of the cured film and improving the resolution after development.

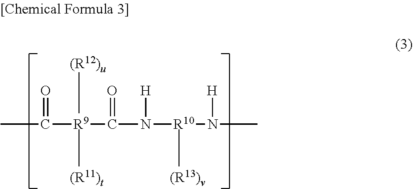

In the general formula (3), R⁹ represents a tetravalent to decavalent organic group, and R¹⁰ represents a divalent to decavalent organic group. R¹¹ represents a substituent represented by the above-described general formula (5) or general formula (6), R¹² represents a phenolic hydroxyl group, a sulfonic acid group, or a mercapto group, and R¹³ represents a phenolic hydroxyl group, a sulfonic acid group, a mercapto group, or a substituent represented by the above-described general formula (5) or general formula (6). t represents an integer of 2 to 8, u represents an integer of 0 to 6, and v represents an integer of 0 to 8, and 2≤t+u≤8.

R⁹ of the general formula (3) represents a tetracarboxylic acid residue and/or a derivative residue thereof, and R¹⁰ represents a diamine residue and/or a derivative residue thereof. Examples of the tetracarboxylic acid derivative include a tetracarboxylic dianhydride, a tetracarboxylic acid dichloride, or a tetracarboxylic acid active diester. Examples of the diamine derivative include a diisocyanate compound or a trimethylsilylated diamine.

In the general formula (3), R⁹ is preferably a tetravalent to decavalent organic group having one or more selected from an aliphatic structure having 2 to 20 carbon atoms, an alicyclic structure having 4 to 20 carbon atoms, and an aromatic structure having 6 to 30 carbon atoms. Furthermore, R¹⁰ preferably represents a divalent to decavalent organic group having one or more selected from an aliphatic structure having 2 to 20 carbon atoms, an alicyclic structure having 4 to 20 carbon atoms, and an aromatic structure having 6 to 30 carbon atoms. v is preferably 1 to 8. The above-described aliphatic structure, alicyclic structure, and aromatic structure may have a hetero atom, and may be either unsubstituted or substituted.

The (A1-2) polyimide precursor preferably contains the structural unit represented by general formula (3) as a main component, and the content ratio of the structural unit represented by general formula (3) to all of structural units in the (A1-2) polyimide precursor is preferably 50 to 100 mol %, more preferably 60 to 100 mol %, still more preferably 70 to 100 mol %. When the content ratio is 50 to 100 mol %, the resolution can be improved.

As the (A1-2) polyimide precursor, in a case where R¹¹ in the structural unit represented by general formula (3) represents a substituent represented by general formula (5), the structural unit where R¹⁹ represents hydrogen is referred to as an amide acid structural unit. The amide acid structural unit in the (A1-2) polyimide precursor has a carboxy group as a tetracarboxylic acid residue and/or a derivative residue thereof. It is to be noted that the (A1-2) polyimide precursor where R¹¹ in the structural unit represented by general formula (3) is composed of only a substituent represented by general formula (5), and R¹⁹ represents hydrogen is referred to as a (A1-2a) polyamide acid.

As the (A1-2) polyimide precursor, in a case where Ril in the structural unit represented by general formula (3) represents a substituent represented by general formula (5), the structural unit where R¹⁹ represents an alkyl group having 1 to 10 carbon atoms, an acyl group having 2 to 6 carbon atoms, or an aryl group having 6 to 15 carbon atoms is referred to as an amide acid ester unit. The amide acid ester structural unit in the (A1-2) polyimide precursor has a carboxylic acid ester group as a tetracarboxylic acid residue and/or an esterified derivative residue thereof. It is to be noted that the (A1-2) polyimide precursor where R¹¹ in the structural unit represented by general formula (3) is composed of only a substituent represented by general formula (5), and R¹⁹ represents an alkyl group having 1 to 10 carbon atoms, an acyl group having 2 to 6 carbon atoms, or an aryl group having 6 to 15 carbon atoms is referred to as a (A1-2b) polyamide acid ester.

As the (A1-2) polyimide precursor, in a case where R¹¹ in the structural unit represented by general formula (3) represents a substituent represented by general formula (6), the structural unit is referred to as an amide acid amide structural unit. The amide acid amide structural unit in the (A1-2) polyimide precursor has a carboxylic acid amide group as a tetracarboxylic acid residue and/or an amidated derivative residue thereof. It is to be noted that the (A1-2) polyimide precursor where R¹¹ in the structural unit represented by general formula (3) is composed of only a substituent represented by general formula (6) is referred to as a (A1-2c) polyamide acid amide.

From the viewpoint of improving the resolution after development and forming a pattern in a low taper shape after development, the (A1-2) polyimide precursor preferably contains the amide acid structural unit, and the amide acid ester structural unit and/or the amide acid amide structural unit. It is to be noted that the (A1-2) polyimide precursor containing the amide acid structural unit and the amide acid ester structural unit is referred to as a (A1-2-1) polyamide acid partial ester. On the other hand, the (A1-2) polyimide precursor containing the amide acid structural unit and the amide acid amide structural unit is referred to as a (A1-2-2) polyamide acid partial amide. Furthermore, the (A1-2) polyimide precursor containing the amide acid structural unit, the amide acid ester structural unit, and the amide acid amide structural unit is referred to as a (A1-2-3) polyamide acid partial ester amide. These polyimide precursors containing the amide acid structural unit and the amide acid ester structural unit and/or the amide acid amide structural unit can be synthesized by esterifying a part of the carboxy group and/or amidating a part of the carboxy group from the (A1-2a) polyamide acid having a tetracarboxylic acid residue and/or a carboxy group as a derivative residue thereof.

The content ratio of the polyamide acid unit to all the structural units in the (A1-2) polyimide precursor is preferably 10 mol % or higher, more preferably 20 mol % or higher, still more preferably 30 mol % or higher. When the content ratio is 10 mol % or higher, the resolution after development can be improved. On the other hand, the content ratio of the polyamide acid unit is preferably 60 mol % or lower, more preferably 50 mol % or lower, still more preferably 40 mol % or lower. When the content ratio is 60 mol % or lower, a pattern in a low taper shape can be formed after development.

The total content ratio of the polyamide acid ester unit and the polyamide acid amide unit to all of structural units in the (A1-2) polyimide precursor is preferably 40 mol % or higher, more preferably 50 mol % or higher, still more preferably 60 mol % or higher. When the total content ratio is 40 mol % or higher, a pattern in a low taper shape can be formed after development. On the other hand, the total content ratio of the polyamide acid ester unit and the polyamide acid amide unit is preferably 90 mol % or lower, more preferably 80 mol % or lower, still more preferably 70 mol %. When the total content ratio is 90 mol % or lower, the resolution after development can be improved.

### <(A1-3) Polybenzoxazole and (A1-4) Polybenzoxazole Precursor>

Examples of the (A1-4) polybenzoxazole precursor include products obtained by reacting a dicarboxylic acid, a corresponding dicarboxylic acid dichloride dicarboxylic acid active diester, or the like with a bisaminophenol compound as a diamine, and which have a dicarboxylic acid residue and/or a derivative residue thereof, and a bisaminophenol compound residue and/or a derivative residue thereof. Examples of the (A1-4) polybenzoxazole precursor include a polyhydroxyamide.

Examples of the (A1-3) polybenzoxazole include products obtained by dehydration and cyclization of a dicarboxylic acid and a bisaminophenol compound as a diamine through a reaction with the use of a polyphosphoric acid, and products obtained by dehydration and cyclization of the polyhydroxyamide described above through heating or reaction with the use of a phosphoric anhydride, a base or a carbodiimide compound, or the like, which have a dicarboxylic acid residue and/or a derivative residue thereof, a bisaminophenol compound residues and/or a derivative residue thereof.

The (A1-4) polybenzoxazole precursor, which is a thermosetting resin, is thermally cured at high temperature for dehydration and cyclization to form a highly heat-resistance and rigid benzoxazole ring, thereby providing the (A1-3) polybenzoxazole. Accordingly, the photosensitive resin composition contains therein the (A1-3) polybenzoxazole having the highly heat-resistance and rigid benzoxazole ring, thereby making it possible to remarkably improve the heat resistance of the cured film obtained. For that reason, the cured film is suitable in such a case of using the cured film for applications which require high heat resistance. In addition, the (A1-4) polybenzoxazole precursor, which is a resin with heat resistance improved after dehydration and cyclization, is suitable in such a case of using the precursor for applications which have a desire to achieve a balance between characteristics of the precursor structure before dehydration and cyclization and the heat resistance of the cured film.

Furthermore, the (A1-3) polybenzoxazole and the (A1-4) polybenzoxazole precursor have an imide bond and/or an oxazole bond as a bond with polarity. For that reason, in the case of containing, in particular, a (D1) pigment as a (D) colorant described later, the bond interacts strongly with the (D1) pigment, thus allowing the dispersion stability of the (D1) pigment to be improved.

The (A1-3) polybenzoxazole for use in the present invention preferably contains a structural unit represented by general formula (2), from the viewpoint of improving the heat resistance of the cured film.

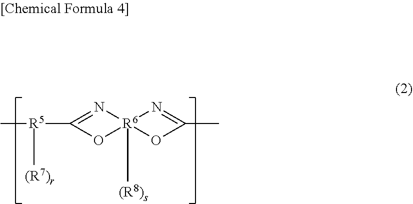

In the general formula (2), R⁵ represents a divalent to decavalent organic group, and R⁶ represents a tetravalent to decavalent organic group that has an aromatic structure. R⁷ and R⁸ each independently represent a phenolic hydroxyl group, a sulfonic acid group, a mercapto group, or a substituent represented by general formula (5) or general formula (6) described above. r represents an integer of 0 to 8, and s represents an integer of 0 to 6.

R⁵ of the general formula (2) represents a dicarboxylic acid residue and/or a derivative residue thereof, and R⁶ represents a bisaminophenol compound residue and/or a derivative residue thereof. Examples of the dicarboxylic acid derivative include a dicarboxylic anhydride, a dicarboxylic acid chloride, a dicarboxylic acid active ester, a tricarboxylic anhydride, a tricarboxylic acid chloride, a tricarboxylic acid active ester, and a diformyl compound.

In the general formula (2), R⁵ is preferably a divalent to decavalent organic group having one or more selected from an aliphatic structure having 2 to 20 carbon atoms, an alicyclic structure having 4 to 20 carbon atoms, and an aromatic structure having 6 to 30 carbon atoms. Furthermore, R⁶ is preferably a tetravalent to decavalent organic group that has an aromatic structure having 6 to 30 carbon atoms. s preferably represents 1 to 8. The above-described aliphatic structure, alicyclic structure, and aromatic structure may have a hetero atom, and may be either unsubstituted or substituted.

The (A1-3) polybenzoxazole preferably contains the structural unit represented by general formula (2) as a main component, and the content ratio of the structural unit represented by general formula (2) to all of structural units in the (A1-3) polybenzoxazole is preferably 50 to 100 mol %, more preferably 60 to 100 mol %, still more preferably 70 to 100 mol %. When the content ratio is 50 to 100 mol %, the heat resistance of the cured film can be improved.

The (A1-4) polybenzoxazole precursor for use in the present invention preferably contains a structural unit represented by general formula (4), from the viewpoint of improving the heat resistance of the cured film and improving the resolution after development.

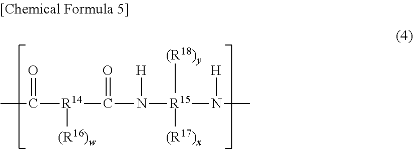

In the general formula (4), R¹⁴ represents a divalent to decavalent organic group, and R¹⁵ represents a tetravalent to decavalent organic group that has an aromatic structure. R¹⁶ represents a phenolic hydroxyl group, a sulfonic acid group, a mercapto group, or a substituent represented by general formula (5) or general formula (6) described above, R¹⁷ represents a phenolic hydroxyl group, and RI' represents a sulfonic acid, a mercapto group, or a substituent represented by general formula (5) or general formula (6) described above. w represents an integer of 0 to 8, x represents an integer of 2 to 8, y represents an integer of 0 to 6, and 2≤x+y≤8.

R¹⁴ of the general formula (4) represents a dicarboxylic acid residue and/or a derivative residue thereof, and R¹⁵ represents a bisaminophenol compound residue and/or a derivative residue thereof. Examples of the dicarboxylic acid derivative include a dicarboxylic anhydride, a dicarboxylic acid chloride, a dicarboxylic acid active ester, a tricarboxylic anhydride, a tricarboxylic acid chloride, a tricarboxylic acid active ester, and a diformyl compound.

In the general formula (4), R¹⁴ preferably represents a divalent to decavalent organic group having one or more selected from an aliphatic structure having 2 to 20 carbon atoms, an alicyclic structure having 4 to 20 carbon atoms, and an aromatic structure having 6 to 30 carbon atoms. Furthermore, R¹⁵ is preferably a tetravalent to decavalent organic group that has an aromatic structure having 6 to 30 carbon atoms. The above-described aliphatic structure, alicyclic structure, and aromatic structure may have a hetero atom, and may be either unsubstituted or substituted.

The (A1-4) polybenzoxazole precursor preferably contains the structural unit represented by general formula (4) as a main component, and the content ratio of the structural unit represented by general formula (4) to all of structural units in the (A1-4) polybenzoxazole precursor is preferably 50 to 100 mol %, more preferably 60 to 100 mol %, still more preferably 70 to 100 mol %. When the content ratio is 50 to 100 mol %, the resolution can be improved.

<Tetracarboxylic Acid and Dicarboxylic Acid and Derivatives thereof>

Examples of the tetracarboxylic acid include an aromatic tetracarboxylic acid, an alicyclic tetracarboxylic acid, and an aliphatic tetracarboxylic acid. These tetracarboxylic acids may have a hetero atom in addition to the oxygen atoms of the carboxy groups.

Examples of the aromatic tetracarboxylic acid and derivatives thereof include 1,2,4,5-benzenetetracarboxylic acid (pyromellitic acid), 3,3′,4,4′-biphenyltetracarboxylic acid, 1,2,5,6-naphthalenetetracarboxylic acid, 3,3′,4,4′-benzophenonetetracarboxylic acid, 2,2-bis(3,4-dicarboxyphenyl)propane, 2,2-bis(3,4-dicarboxyphenyl)hexafluoropropane, bis(3,4-dicarboxyphenyl)sulfone, bis(3,4-dicarboxyphenyl)ether, 2,3,5,6-pyridinetetracarboxylic acid, or 3,4,9,10-perylenetetracarboxylic acid, N,N′-bis[5,5′-hexafluoropropane-2,2-diyl-bis(2-hydroxyphenyl)bis(3,4-dicarboxybenzoic acid amide), or tetracarboxylic dianhydrides, tetracarboxylic dichlorides, or tetracarboxylic acid active diesters thereof.

Examples of the alicyclic tetracarboxylic acid and derivatives thereof include bicyclo[2.2.2]octane-7-ene-2,3,5,6-tetracarboxylic acid and 1,2,4,5-cyclohexanetetracarboxylic acid. 1,2,3,4-cyclobutanetetracarboxylic acid, or 2,3,4,5-tetrahydrofurantetracarboxylic acid, or tetrcarboxylic dianhydrides, tetracarboxylic dichlorides, or tetracarboxylic acid active diesters thereof.

Examples of the aliphatic tetracarboxylic acid and derivatives thereof include butane-1,2,3,4-tetracarboxylic acid, or tetrcarboxylic dianhydrides, tetracarboxylic dichlorides, or tetracarboxylic acid active diesters thereof.

As the dicarboxylic acid and derivative thereof in the (A1-3) polybenzoxazole and the (A1-4) polybenzoxazole precursor, a tricarboxylic acid and/or a derivative thereof may be used.

Examples of the dicarboxylic acid and tricarboxylic acid include an aromatic dicarboxylic acid, an aromatic tricarboxylic acid, an alicyclic dicarboxylic acid, an alicyclic tricarboxylic acid, an aliphatic dicarboxylic acid, and an aliphatic tricarboxylic acid. These dicarboxylic acid and tricarboxylic acid may have a hetero atom other than oxygen atoms, in addition to the oxygen atoms of the carboxy groups.

Examples of the aromatic dicarboxylic acids and derivatives thereof include 4,4′-dicarboxybiphenyl, 2,2′-bis(trifluoromethyl)-4,4′-dicarboxybiphenyl, and 4,4′-benzophenone dicarboxylic acid. 2,2-bis(4-carboxyphenyl) hexafluoropropane, 2,2-bis(3-carboxyphenyl) hexafluoropropane, or 4,4′-dicarboxydiphenyl ether, or dicarboxylic anhydrides, dicarboxylic acid chlorides, dicarboxylic acid active esters, or diformyl compounds thereof.

Examples of the aromatic tricarboxylic acid and derivatives thereof include 1,2,4-benzenetricarboxylic acid, 1,3,5-benzenetricarboxylic acid, 2,4,5-benzophenone tricarboxylic acid, and 2,4,4′-biphenyl, or 3,3′,4′-tricarboxydiphenyl ether, or tricarboxylic anhydrides, tricarboxylic acid chlorides, tricarboxylic acid active esters, or diformyl monocarboxylic acids thereof.

Examples of the alicyclic dicarboxylic acid and derivatives thereof include tetrahydrophthalic acid, 3-methyltetrahydrophthalic acid, 4-methylhexahydrophthalic acid, 1,4-cyclohexanedicarboxylic acid, or 1,2-cyclohexanedicarboxylic acid, or dicarboxylic anhydrides, dicarboxylic acid chlorides, dicarboxylic acid active esters, or diformyl compounds thereof.

Examples of the alicyclic tricarboxylic acid and derivatives thereof include 1,2,4-cyclohexanetricarboxylic acid or 1,3,5-cyclohexanetricarboxylic acid, or tricarboxylic anhydrides, tricarboxylic acid chlorides, and tricarboxylic acid active esters, or diformyl monocarboxylic acids thereof.

Examples of the aliphatic dicarboxylic acid and derivatives thereof include, for example, an itaconic acid, a maleic acid, a fumaric acid, a malonic acid, a succinic acid, or hexane-1,6-dicarboxylic acid, or dicarboxylic anhydrides, dicarboxylic acid chlorides, dicarboxylic acid active esters, or diformyl compounds thereof.

Examples of the aliphatic tricarboxylic acid and derivatives thereof include hexane-1,3,6-tricarboxylic acid or propane-1,2,3-tricarboxylic acid, or tricarboxylic anhydrides, tricarboxylic acid chlorides, tricarboxylic acid active esters, or diformyl monocarboxylic acids thereof.

<Diamine and Derivatives thereof>

Examples of the diamine and derivatives thereof include aromatic diamines, bisaminophenol compounds, alicyclic diamines, alicyclic dihydroxydiamines, aliphatic diamines, and aliphatic dihydroxydiamines. These diamines and derivatives thereof may have a hetero atom in addition to the nitrogen atoms and oxygen atoms of the amino group and derivatives thereof.

Examples of the aromatic diamines and bisaminophenol compounds and derivatives thereof include p-phenylenediamine, 1,4-bis(4-aminophenoxy)benzene, 2,2′-dimethyl-4,4′-diaminobiphenyl, 2,2′-bis(trifluoromethyl)-4,4′-diaminobiphenyl, 3,3′-diamino-4,4′-biphenol, 1,5-naphthalenediamine, 9,9-bis(3-amino -4-hydroxyphenyl)fluorene, 2,2-bis(3-amino-4-hydroxyphenyl)propane, 2,2-bis(3-amino-4-hydroxyphenyl)hexafluoropropane, bis(3-amino-4-hydroxyphenyl)sulfone, 4,4′-diaminodiphenyl sulfide, bis(3-amino-4-hydroxyphenyl)ether, 3-sulfonic acid-4,4′-diaminodiphenyl ether, dimercaptophenylenediamine, or N,NY-bis[5,5′-hexafluoropropane-2,2-diyl-bis(2-hydroxyphenyl)]bis(3-aminobenzoic acid amide), or diisocyanate compounds or trimethylsilylated diamines thereof.

Examples of the alicyclic diamines and alicyclic dihydroxydiamines, and derivatives thereof include 1,4-cyclohexanediamine, bis(4-aminocyclohexyl)methane, 3,6-dihydroxy-1,2-cyclohexanediamine, or bis(3-hydroxy-4-aminocyclohexyl)methane, or diisocyanate compounds or trimethylsilylated diamines thereof.

Examples of the aliphatic diamines and aliphatic dihydroxydiamines, and derivatives thereof include 1,6-hexamethylenediamine or 2,5-dihydroxy-1,6-hexamethylenediamine, or diisocyanated compounds or trimethylsilylated diamines thereof.

<Structural Unit having Fluorine Atom>

One or more selected from a (A1-1) polyimide, a (A1-2) polyimide precursor, a (A1-3) polybenzoxazole, and a (A1-4) polybenzoxazole precursor contains a structural unit having a fluorine atom at 10 to 100 mol % of all of the structural units.

One or more selected from a (A1-1) polyimide, a (A1-2) polyimide precursor, a (A1-3) polybenzoxazole, and a (A1-4) polybenzoxazole precursor contains a structural unit having a fluorine atom, thereby improving the transparency, and allowing the sensitivity for exposure to be improved. Furthermore, water repellency can be imparted to the film surface, and soaking from the film surface during alkali development can be suppressed. In this regard, the exposure refers to irradiation with active actinic rays (radiation), and examples thereof include irradiation with visible light, ultraviolet rays, electron beams, X-rays or the like. From the viewpoint of a light source commonly used, for example, an ultra-high pressure mercury lamp light source capable of irradiation with visible light or ultraviolet rays is preferred, and more preferred is irradiation with j-rays (wavelength: 313 nm), i-rays (wavelength: 365 nm), h-rays (wavelength: 405 nm), or g-rays (wavelength: 436 nm). Hereinafter, the exposure refers to irradiation with active actinic rays (radiation).

In addition, in general, in the case of using the (A1-1) polyimide, the (A1-2) polyimide precursor, the (A1-3) polybenzoxazole, and/or the (A1-4) polybenzoxazole precursor, it is necessary to use, as an after-mentioned solvent that is used for dissolution of the foregoing resins, a highly polar solvent such as N-methyl-2-pyrrolidone, dimethyl sulfoxide, N,N-dimethylformamide, or γ-butyrolactone. In a case where, in particular, the (D1) pigment is contained as the (D) colorant described later, however, these highly polar solvents interact strongly with the (D1) pigment, and the effect of improving the dispersion stability with the (A1) first resin, the (A2) second resin described layer, or the (E) dispersant described later may be thus insufficient.

One or more selected from a (A1-1) polyimide, a (A1-2) polyimide precursor, a (A1-3) polybenzoxazole, and a (A1-4) polybenzoxazole precursor contain a structural unit having a fluorine atom, thereby allowing the solubility in the solvent to be improved. Thus, it is possible to reduce the content of the highly polar solvent described above or dissolve the foregoing resins without using the highly polar solvent, thereby allowing the dispersion stability of the (D1) pigment to be improved.

Examples of the structural unit having a fluorine atom, which is contained in the (A1-1) polyimide and/or the (A1-2) polyimide precursor, include a structural unit derived from a tetracarboxylic acid having a fluorine atom and/or a structural unit derived from a derivative of the tetracarboxylic acid, or a structural unit derived from a diamine having a fluorine atom and/or a structural unit derived from a derivative of the diamine.

Examples of the structural unit having a fluorine atom, which is contained in the (A1-3) polybenzoxazole and/or the (A1-4) polybenzoxazole precursor, include a structural unit derived from a dicarboxylic acid having a fluorine atom and/or a structural unit derived from a derivative of the dicarboxylic acid, or a structural unit derived from a bisaminophenol compound having a fluorine atom and/or a structural unit derived from a derivative of the bisaminophenol compound.

The content ratio of the structural unit having a fluorine atom to all of structural units is preferably 30 to 100 mol % in one or more resins selected from the (A1-1) polyimide, the (A1-2) polyimide precursor, the (A1-3) polybenzoxazole, and the (A1-4) polybenzoxazole precursor. The content ratio of the structural unit having a fluorine atom is more preferably 50 mol % or higher, still more preferably 70 mol % or higher. When the content ratio is 30 to 100 mol %, the sensitivity for exposure can be improved.

The content ratio of structural units derived from one or more selected from a tetracarboxylic acid having a fluorine atom, a tetracarboxylic acid derivative having a fluorine atom, a dicarboxylic acid having a fluorine atom, and a dicarboxylic acid derivative having a fluorine atom to the total of structural units derived from all of carboxylic acids and structural units derived from derivatives of the acids is preferably 30 to 100 mol % in one or more resins selected from the (A1-1) polyimide, the (A1-2) polyimide precursor, the (A1-3) polybenzoxazole, and the (A1-4) polybenzoxazole precursor. The content ratio of the structural unit having a fluorine atom is more preferably 50 mol % or higher, still more preferably 70 mol % or higher. When the content ratio is 30 to 100 mol %, the sensitivity for exposure can be improved.

The content ratio of structural units derived from one or more selected from a diamine having a fluorine atom, a diamine derivative having a fluorine atom, a bisaminophenol compound having a fluorine atom, and a bisaminophenol compound derivative having a fluorine atom to the total of structural units derived from all of amines and structural units derived from derivatives of the amines is preferably 30 to 100 mol % in one or more resins selected from the (A1-1) polyimide, the (A1-2) polyimide precursor, the (A1-3) polybenzoxazole, and the (A1-4) polybenzoxazole precursor. The content ratio of the structural unit having a fluorine atom is more preferably 50 mol % or higher, still more preferably 70 mol % or higher. When the content ratio is 30 to 100 mol %, the sensitivity for exposure can be improved.

<Structural Units Derived from Aromatic Carboxylic Acid and Derivative thereof>

The (A1-1) polyimide and/or the (A1-2) polyimide precursor preferably contains a structural unit derived from an aromatic carboxylic acid and/or a structural unit derived from a derivative of the acid. The (A1-1) polyimide and/or the (A1-2) polyimide precursor contains a structural unit derived from an aromatic carboxylic acid and/or a structural unit derived from a derivative of the acid, thereby allowing the heat resistance of the aromatic group to improve the heat resistance of the cured film. As the aromatic carboxylic acid and the derivative thereof, an aromatic tetracarboxylic acid and/or a derivative thereof are preferred.

The content ratio of the structural unit derived from an aromatic carboxylic acid and/or the structural unit derived from a derivative of the acid to the total of structural units derived from all of carboxylic acids and structural units derived from derivatives of the acids is preferably 50 to 100 mol %, more preferably 60 to 100 mol %, still more preferably 70 to 100 mol % in (A1-1) polyimide and/or (A1-2) polyimide precursor. When the content ratio is 50 to 100 mol %, the heat resistance of the cured film can be improved.

The (A1-3) polybenzoxazole and/or the (A1-4) polybenzoxazole precursor preferably contains a structural unit derived from an aromatic carboxylic acid and/or a structural unit derived from a derivative of the acid. The (A1-3) polybenzoxazole and/or the (A1-4) polybenzoxazole precursor contains a structural unit derived from an aromatic carboxylic acid and/or a structural unit derived from a derivative of the acid, thereby allowing the heat resistance of the aromatic group to improve the heat resistance of the cured film. As the aromatic carboxylic acid and the derivative thereof, an aromatic dicarboxylic acid or an aromatic tricarboxylic acids and/or derivatives thereof are preferred, and an aromatic dicarboxylic acid and/or a derivative thereof are more preferred.

The content ratio of the structural unit derived from an aromatic carboxylic acid and/or the structural unit derived from a derivative of the acid to the total of structural units derived from all of carboxylic acids and structural units derived from derivatives of the acids is preferably 50 to 100 mol %, more preferably 60 to 100 mol %, still more preferably 70 to 100 mol % in the (A1-3) polybenzoxazole and/or the (A1-4) polybenzoxazole precursor. When the content ratio is 50 to 100 mol %, the heat resistance of the cured film can be improved.

<Structural Units Derived from Aromatic Amine and Derivative>

One or more selected from the (A1-1) polyimide, the (A1-2) polyimide precursor, the (A1-3) polybenzoxazole, and the (A1-4) polybenzoxazole precursor preferably contain a structural unit derived from an aromatic amine and/or a structural unit derived from a derivative of the amine. One or more selected from the (A1-1) polyimide, the (A1-2) polyimide precursor, the (A1-3) polybenzoxazole, and the (A1-4) polybenzoxazole precursor contain a structural unit derived from an aromatic amine and/or a structural unit derived from a derivative of the amine, thereby allowing the heat resistance of the aromatic group to improve the heat resistance of the cured film. As the aromatic amine and the derivative thereof, an aromatic diamine, a bisaminophenol compound, an aromatic triamine, or a trisaminophenol compound, and/or a derivative thereof are preferred, and an aromatic diamine or a bisaminophenol compound, and/or a derivatives thereof are more preferred.

The content ratio of the structural unit derived from an aromatic amine and/or the structural unit derived from a derivative of the amine to the total of structural units derived from all of amines and structural units derived from derivatives of the amines is preferably 50 to 100 mol %, more preferably 60 to 100 mol %, still more preferably 70 to 100 mol % in one or more resins selected from the (A1-1) polyimide, the (A1-2) polyimide precursor, the (A1-3) polybenzoxazole, and the (A1-4) polybenzoxazole precursor. When the content ratio is 50 to 100 mol %, the heat resistance of the cured film can be improved.

<Structural Units Derived from Diamine having Silyl Group or Siloxane Bond and Derivatives thereof>

One or more selected from the (A1-1) polyimide, the (A1-2) polyimide precursor, the (A1-3) polybenzoxazole, and the (A1-4) polybenzoxazole precursor preferably contain a structural unit derived from a diamine having a silyl group or a siloxane bond and/or a structural unit derived from a derivative of the diamine. One or more selected from the (A1-1) polyimide, the (A1-2) polyimide precursor, the (A1-3) polybenzoxazole, and the (A1-4) polybenzoxazole precursor contain a structural unit derived from a diamine having a silyl group or a siloxane bond and/or a structural unit derived from a derivative of the diamine, thereby increasing the interaction between the cured film of the photosensitive resin composition and the underlying substrate interface, and then allowing the adhesion property to the underlying substrate and the chemical resistance of the cured film to be improved.

<Structural Units Derived from Amine having Oxyalkylene Structure and Derivative thereof>

One or more selected from the (A1-1) polyimide, the (A1-2) polyimide precursor, the (A1-3) polybenzoxazole, and the (A1-4) polybenzoxazole precursor preferably contain a structural unit derived from an amine that has an oxyalkylene structure and/or a structural unit derived from a derivative of the amine. One or more selected from the (A1-1) polyimide, the (A1-2) polyimide precursor, the (A1-3) polybenzoxazole, and the (A1-4) polybenzoxazole precursor contain a structural unit derived from an amine that has an oxyalkylene structure and/or a structural unit derived from a derivative of the amine, thereby allowing a cured film in a pattern in a low-taper shape to be obtained, and allowing the mechanical characteristic of the cured film and the patternability thereof with an alkaline developer to be improved.

### <End-Capping Agent>

For one or more selected from the (A1-1) polyimide, the (A1-2) polyimide precursor, the (A1-3) polybenzoxazole, and the (A1-4) polybenzoxazole precursor, the terminals of the resins may be sealed with an end-capping agent such as a monoamine, a dicarboxylic anhydride, a monocarboxylic acid, a monocarboxylic acid chloride, or monocarboxylic acid active ester. The terminals of the resins are sealed with the end-capping agent, thereby making it possible to improve the storage stability of a coating liquid with the resin composition containing one or more selected from the (A1-1) polyimide, the (A1-2) polyimide precursor, the (A1-3) polybenzoxazole, and the (A1-4) polybenzoxazole precursor.

The content ratio of the structural units derived from various types of carboxylic acids or amines and derivatives thereof to the (A1-1) polyimide, the (A1-2) polyimide precursor, the (A1-3) polybenzoxazole, and/or the (A1-4) polybenzoxazole precursor can be determined by combining ¹H-NMR, ¹³C-NMR, ¹⁵N-NMR, IR, TOF-MS, elemental analysis, ash measurement, and the like.

<Physical Properties of (A1-1) Polyimide, (A1-2) Polyimide Precursor, (A1-3) Polybenzoxazole and/or (A1-4) Polybenzoxazole Precursor>

The repetition number n of structural units in one or more resins selected from the (A1-1) polyimide, the (A1-2) polyimide precursor, the (A1-3) polybenzoxazole, and the (A1-4) polybenzoxazole precursor is preferably 5 or more, more preferably 10 or more, still more preferably 15 or more. When the repetition number n is 5 or more, the resolution after development can be improved. On the other hand, the repetition number n is preferably 1,000 or less, more preferably 500 or less, still more preferably 100 or less. When the repetition number n is 1,000 or less, the leveling property in the case of coating and the patternability with an alkaline developer can be improved.

The weight average molecular weight (hereinafter, “Mw”) of one or more selected from the (A1-1) polyimide, the (A1-2) polyimide precursor, the (A1-3) polybenzoxazole, and the (A1-4) polybenzoxazole precursor is preferably 1,000 or more, more preferably 3,000 or more, still more preferably 5,000 or more in terms of polystyrene measured by gel permeation chromatography (hereinafter, “GPC”). When the Mw is 1,000 or more, the resolution after development can be improved. On the other hand, the Mw is preferably 500,000 or less, more preferably 300,000 or less, still more preferably 100,000 or less. When the Mw is 500,000 or less, the leveling property in the case of coating and the patternability with an alkaline developer can be improved.

Furthermore, the number average molecular weight (hereinafter, “Mn”) is preferably 1,000 or more, more preferably 3,000 or more, still more preferably 5,000 or more in terms of polystyrene measured by GPC. When the Mn is 1,000 or more, the resolution after development can be improved. On the other hand, the Mn is preferably 500,000 or less, more preferably 300,000 or less, still more preferably 100,000 or less. When the Mn is 500,000 or less, the leveling property in the case of coating and the patternability with an alkaline developer can be improved.

The Mw and Mn of the (A1-1) polyimide, (A1-2) polyimide precursor, (A1-3) polybenzoxazole, and (A1-4) polybenzoxazole precursor can be easily measured as a value in terms of polystyrene by GPC, a light scattering method, an X-ray small angle scattering method, or the like. The repetition number n of structural units in the (A1-1) polyimide, the (A1-2) polyimide precursor, the (A1-3) polybenzoxazole, and the (A1-4) polybenzoxazole precursor can be derived from n=Mw/M where M represents the molecular weight of the structural unit, and Mw represents the weight average molecular weight of the resins.

The alkali dissolution rate of one or more selected from the (A1-1) polyimide, the (A1-2) polyimide precursor, the (A1-3) polybenzoxazole, and the (A1-4) polybenzoxazole precursor is preferably 50 nm/min or more, more preferably 70 nm/min or more, still more preferably 100 nm/min or more. When the alkali dissolution rate is 50 nm/min or more, the resolution after development can be improved. On the other hand, the alkali dissolution rate is preferably 12,000 nm/min or less, more preferably 10,000 nm/min or less, still more preferably 8,000 nm/min or less. When the alkali dissolution rate is 12,000 nm/min or less, the film loss during alkaline development can be reduced.

The alkali dissolution rate herein refers to the value of a reduction in film thickness after applying a solution of the resin dissolved in γ-butyrolactone onto a Si wafer, and then prebaking the solution at 120° C. for 4 minutes to form a prebaked film of 10 μm±0.5 μm in film thickness, developing the prebaked film with a 2.38% by mass of tetramethylammonium hydroxide aqueous solution at 23° C.±1° C. for 60 seconds, and rinsing the film with water for 30 seconds.

The (A1-1) polyimide and the (A1-2) polyimide precursor can be synthesized by known methods. The methods include a method of reacting a tetracarboxylic dianhydride and a diamine (partially substituted with a monoamine as an end-capping agent) at 80° C. to 200° C. in a polar solvent such as N-methyl-2-pyrrolidone, or a method of reacting a tetracarboxylic dianhydride (partially substituted with a dicarboxylic anhydride, a monocarboxylic acid, a monocarboxylic acid chloride, or a monocarboxylic acid active ester as an end-capping agent) and a diamine at 80° C. to 200° C.

The (A1-3) polybenzoxazole and the (A1-4) polybenzoxazole precursor can be synthesized by known methods. The methods include a method of reacting a dicarboxylic acid active diester and a bisaminophenol compound (partially substituted with a monoamine as an end-capping agent) at 80° C. to 250° C. in a polar solvent such as N-methyl-2-pyrrolidone, or a method of reacting a dicarboxylic acid active diester (partially substituted with a dicarboxylic anhydride, a monocarboxylic acid, a monocarboxylic acid chloride, or a monocarboxylic acid active ester as an end-capping agent) and a bisaminophenol compound at 80° C. to 250° C.

The imide ring closing ratio (imidization ratio) of the (A1-1) polyimide or (A1-2) polyimide precursor can be determined, for example, by the following method. First, the infrared absorption spectrum of the resin is measured to confirm the presence of absorption peaks (around 1780 cm⁻¹ and around 1377 cm⁻¹) of imide bonds derived from the polyimide structure. Next, the resin is thermally cured at 350° C. for 1 hour, and the infrared absorption spectrum of the resin is measured. The peak intensity around 1780 cm⁻¹ or around 1377 cm⁻¹ is compared between before and after the thermal curing, thereby calculating the content of imide bonds in the resin before the thermal curing, and then allowing the imidization ratio to be determined.

The oxazole ring closing ratio (oxazolation ratio) of the (A1-3) polybenzoxazole or (A1-4) polybenzoxazole precursor can be determined, for example, by the following method. First, the infrared absorption spectrum of the resin is measured to confirm the presence of absorption peaks (around 1574 cm⁻¹ and around 1557 cm⁻¹) of oxazole bonds derived from the polybenzoxazole structure. Next, the resin is thermally cured at 350° C. for 1 hour, and the infrared absorption spectrum of the resin is measured. The peak intensity around 1574 cm⁻¹ or around 1557 cm⁻¹ is compared between before and after the thermal curing, thereby calculating the content of oxazole bonds in the resin before the thermal curing, and then allowing the oxazolation ratio to be determined.

### <(A2) Second Resin>

The photosensitive resin composition according to the present invention preferably contains the (A2) second resin as the (A) alkali-soluble resin.

It is preferable to contain, as the (A2) second resin, one or more selected from a (A2-1) polysiloxane, a (A2-2) polycyclic side chain-containing resin, an (A2-3) acid-modified epoxy resin, and an (A2-4) acrylic resin.

According to the present invention, the (A2-1) polysiloxane, the (A2-2) polycyclic side chain-containing resin, the (A2-3) acid-modified epoxy resin, and the (A2-4) acrylic resin may be any of single resins or copolymers thereof.

### <(A2-1) Polysiloxane>

Examples of the (A2-1) polysiloxane for use in the present invention include a polysiloxane obtained by hydrolyzing, and then dehydrating condensing one or more selected from a trifunctional organosilane, a tetrafunctional organosilane, a bifunctional organosilane, and a monofunctional organosilane.

The (A2-1) polysiloxane, which is a thermosetting resin, is thermally cured at high temperature for dehydration and condensation to form a high heat-resistance siloxane bond (Si-0). Accordingly, the photosensitive resin composition contains therein the (A2-1) polysiloxane having the highly heat-resistance siloxane bond, thereby making it possible improve the heat resistance of the cured film obtained. In addition, the (A2-1) polysiloxane, which is a resin with heat resistance improved after dehydration and condensation, is suitable in such a case of using the resin for applications which have a desire to achieve a balance between characteristics before dehydration and condensation and the heat resistance of the cured film.

Furthermore, the (A2-1) polysiloxane has a silanol group as a reactive group. Thus, in the case of containing, in particular, the (D1) pigment is as the (D) colorant described later, the silanol group is capable of interacting with and/or binding to the surface of the (D1) pigment, and capable of interacting with and/or binding to the surface modifying group of the (D1) pigment. Accordingly, the dispersion stability of the (D1) pigment can be improved.

### <Trifunctional Organosilane Unit, Tetrafunctional Organosilane Unit, Bifunctional Organosilane Unit, and Monofunctional Organosilane Unit>

The (A2-1) polysiloxane for use in the present invention preferably contains a trifunctional organosilane unit and/or a tetrafunctional organosilane unit, from the viewpoint of improving the heat resistance of the cured film and improving the resolution after development. The trifunctional organosilane is preferably an organosilane unit represented by general formula (7). The tetrafunctional organosilane unit is preferably an organosilane unit represented by general formula (8).

The (A2-1) polysiloxane for use in the present invention may contain a bifunctional organosilane unit from the viewpoint of reducing the taper of the pattern shape and improving the mechanical characteristic of the cured film. The bifunctional organosilane is preferably an organosilane unit represented by general formula (9).

The (A2-1) polysiloxane for use in the present invention may contain a monofunctional organosilane unit from the viewpoint of improving the storage stability of the coating liquid with the resin composition. The monofunctional organosilane unit is preferably an organosilane unit represented by general formula (10).

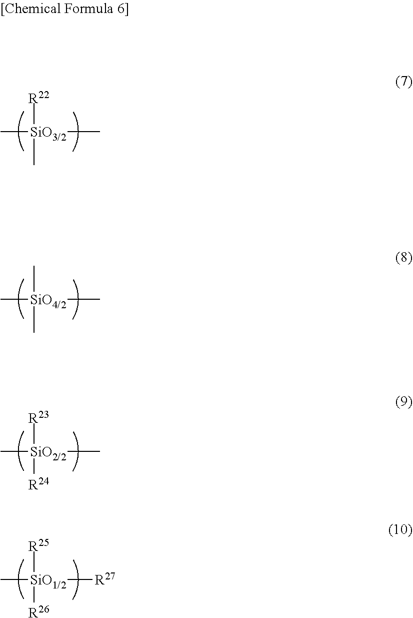

In the general formulas (7) to (10), R²² to R²⁷ each independently represent hydrogen, an alkyl group, a cycloalkyl group, an alkenyl group, or an aryl group. In the general formulas (7) to (10), R²² to R²⁷ each independently preferably represents hydrogen, an alkyl group having 1 to 10 carbon atoms, a cycloalkyl group having 4 to 10 carbon atoms, an alkenyl group having 2 to 10 carbon atoms, or an aryl group having 6 to 15 carbon atoms. The alkyl group, cycloalkyl group, alkenyl group, and aryl group described above may have a hetero atom, and may be either unsubstituted or substituted.

Examples of the organosilane having an organosilane unit represented by general formula (7) include trifunctional organosilanes such as methyltrimethoxysilane, methyltriethoxysilane, n-propyltrimethoxysilane, cyclohexyltrimethoxysilane 3-glycidoxypropyltrimethoxysilane, 2-(3,4-epoxycyclohexyl)ethyltrimethoxysilane, 3-[(3-ethyl-3-oxetanyl)methoxy]propyltrimethoxysilane, 3-aminopropyltrimethoxysilane, N-phenyl-3-aminopropyltrimethoxysilane, 3-(4-aminophenyl)propyltrimethoxysilane, 1-(3-trimethoxysilylpropyl)urea, 3-triethoxysilyl-N-(1,3-dimethylbutylidene)propylamine, 3-mercaptopropyltrimethoxysilane, 3-isocyanatopropyltriethoxysilane, 1,3,5-tris(3-trimethoxysilylpropyl) isocyanurate, N-t-butyl-2-(3-trimethoxysilylpropyl) succinimide, or N-t-butyl-2-(3-triethoxysilylpropyl)succinimide.

The content ratio of the organosilane unit represented by general formula (7) to the (A2-1) polysiloxane is preferably 50 to 100 mol %, more preferably 60 to 100 mol %, still more preferably 70 to 100 mol % in terms of Si atom mol ratio. When the content ratio is 50 to 100 mol %, the heat resistance of the cured film can be improved.

Examples of the organosilane having an organosilane unit represented by general formula (8) include tetrafunctional organosilanes such as tetramethoxysilane, tetraethoxysilane, or tetra-n-propoxysilane, or silicate compounds such as methyl silicate 51 (manufactured by FUSO CHEMICAL CO., LTD.), M silicate 51 (manufactured by TAMA CHEMICALS CO., LTD.), or methyl silicate 51 (manufactured by COLCOAT CO.,LTD.).

The content ratio of the organosilane unit represented by general formula (8) to the (A2-1) polysiloxane is preferably 0 to 40 mol %, more preferably 0 to 30 mol %, still more preferably 0 to 20 mol % in terms of Si atom mol ratio. When the content ratio is 0 to 40 mol %, the heat resistance of the cured film and the resolution after development can be improved.

Examples of the organosilane having an organosilane unit represented by general formula (9) include bifunctional organosilanes such as dimethyldimethoxysilane, dimethyldiethoxysilane, diethyldimethoxysilane, diphenyldimethoxysilane, 1,1,3,3-tetramethyl-1,3-dimethoxydisiloxane, or 1,1,3,3-tetraethyl-1,3-dimethoxydisiloxane.

The content ratio of the organosilane unit represented by general formula (9) to the (A2-1) polysiloxane is preferably 0 to 60 mol %, more preferably 0 to 50 mol %, still more preferably 0 to 40 mol % in terms of Si atom mol ratio. When the content ratio is 0 to 60 mol %, the heat resistance of the cured film and the resolution after development can be improved. [0123]

Examples of the organosilane having an organosilane unit represented by general formula (10) include monofunctional organosilanes such as trimethylmethoxysilane, trimethylethoxysilane, tri-n-propylmethoxysilane, (3-glycidoxypropyl) dimethylmethoxysilane, or (3-glycidoxypropyl) dimethylethoxysilane.

The content ratio of the organosilane unit represented by general formula (10) to the (A2-1) polysiloxane is preferably 0 to 20 mol %, more preferably 0 to 10 mol %, still more preferably 0 to 5 mol % in terms of Si atom mol ratio. When the content ratio is 0 to 20 mol %, the heat resistance of the cured film can be improved.

The polysiloxane (A2-1) for use in the present invention is preferably the polysiloxane (A2-1) obtained by hydrolyzing, and then dehydrating and condensing one or more selected from an organosilane represented by general formula (7a), an organosilane represented by general formula (8a), and an organosilane represented by general formula (9a), and an organosilane represented by general formula (10a).

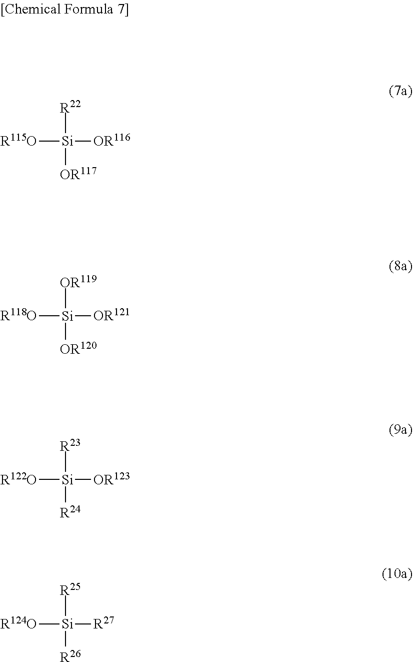

In the general formulas (7a) to (10a), R²² to R²⁷ each independently represent hydrogen, an alkyl group, a cycloalkyl group, an alkenyl group, or an aryl group, and R¹¹⁵ to R¹²⁴ each independently represent hydrogen, an alkyl group, an acyl group, or an aryl group. In the general formulas (7a) to (10a), R²² to R²⁷ each independently preferably represent hydrogen, an alkyl group having 1 to 10 carbon atoms, a cycloalkyl group having 4 to 10 carbon atoms, an alkenyl group having 2 to 10 carbon atoms, or an aryl group having 6 to 15 carbon atoms. R¹¹⁵ to R¹²⁴ each independently preferably represent hydrogen, an alkyl group having 1 to 6 carbon atoms, an acyl group having 2 to 6 carbon atoms, or an aryl group having 6 to 15 carbon atoms. The alkyl group, cycloalkyl group, alkenyl group, aryl group, and acyl group described above may have a hetero atom, and may be either unsubstituted or substituted.

In the (A2-1) polysiloxane, the organosilane unit represented by general formula (7), the organosilane unit represented by general formula (8), the organosilane unit represented by general formula (9), and the organosilane unit represented by general formula (10) may have a regular arrangement or an irregular arrangement. Examples of the regular arrangement include alternating copolymerization, periodic copolymerization, block copolymerization, or graft copolymerization. Examples of the irregular arrangement include random copolymerization.

In addition, in the (A2-1) polysiloxane, the organosilane unit represented by general formula (7), the organosilane unit represented by general formula (8), the organosilane unit represented by general formula (9), and the organosilane unit represented by general formula (10) may have a two-dimensional arrangement or a three-dimensional arrangement. Examples of the two-dimensional arrangement include a linear shape. Examples of the three-dimensional arrangement include a ladder shape, a basket shape, and a mesh shape.

<Organosilane Unit having Aromatic Group>

The (A2-1) polysiloxane for use in the present invention preferably contains an organosilane unit having an aromatic group. Such a (A2-1) polysiloxane is preferably obtained with the use of an organosilane having an aromatic group as the organosilane having an organosilane unit represented by general formula (7), the general formula (9), or the general formula (10). The (A2-1) polysiloxane contains the organosilane unit having an aromatic group, thereby allowing the heat resistance of the aromatic group to improve the heat resistance of the cured film.

In addition, in the case of containing, in particular, the (D1) pigment as the (D) colorant described later, the (A2-1) polysiloxane contains the organosilane unit having an aromatic group, thereby allowing the steric hindrance of the aromatic group to improve the dispersion stability of the (D1) pigment. Furthermore, in a case where the (D1) pigment is an (D1-1) organic pigment, the aromatic group in the (A2-1) polysiloxane interacts with an aromatic group of the (D1-1) organic pigment, thus allowing the dispersion stability of the (D1-1) organic pigment to be improved.

The content ratio of the organosilane unit having an aromatic group to the polysiloxane (A2-1) is preferably 5 mol % or higher, more preferably 10 mol % or higher, still more preferably 15 mol % or higher in terms of Si atom mol ratio. When the content ratio is 5 mol % or higher, the heat resistance of the cured film can be improved. On the other hand, the content ratio is preferably 80 mol % or lower, more preferably 75 mol % or lower, still more preferably 70 mol % or lower. When the content ratio is 80 mol % or lower, the patternability with an alkaline developer can be improved. In particular, the Si atom mol ratio derived from the organosilane unit represented by general formula (7), the general formula (9), or the general formula (10) and having an aromatic group is 5 mol % or higher and 80 mol % or lower.

<Organosilane Unit having Ethylenically Unsaturated Double Bond Group>

The (A2-1) polysiloxane for use in the present invention preferably contains an organosilane unit having an ethylenically unsaturated double bond group. Such a (A2-1) polysiloxane is preferably obtained with the use of an organosilane having a ethylenically unsaturated double bond group as the organosilane having the organosilane unit represented by general formula (7), the general formula (9), or the general formula (10). The (A2-1) polysiloxane contains the organosilane unit having an ethylenically unsaturated double bond group, thereby promoting UV curing during exposure, and then allowing the sensitivity to be improved.

In the case of using an organosilane having an organosilane unit represented by general formula (7), the general formula (9), or the general formula (10) and having an ethylenically unsaturated double bond group, the double bond equivalent of the (A2-1) polysiloxane is preferably 150 g/mol or more, more preferably 200 g/mol or more, still more preferably 250 g/mol or more. When the double bond equivalent is 150 g/mol or more, the adhesion property to the underlying substrate can be improved. On the other hand, the double bond equivalent is preferably 10,000 g/mol or less, more preferably 5,000 g/mol or less, still more preferably 2,000 g/mol or less. When the double bond equivalent is 10,000 g/mol or less, the sensitivity for exposure can be improved. In particular, the double bond equivalent derived from an organosilane unit represented by general formula (7), the general formula (9), or the general formula (10) and having an ethylenically unsaturated double bond group in the polysiloxane (A2-1) is preferably 150 g/mol or more and 10,000 g/mol or less.

In this regard, the double bond equivalent refers to the resin weight per 1 mol of the ethylenically unsaturated double bond group, and the unit is g/mol. From the value of the double bond equivalent, the number of ethylenically unsaturated double bond groups in the resin can be determined. The double bond equivalent can be calculated from the iodine value.

It is to be noted that the iodine value refers to the value obtained by converting the amount of halogen that reacts with 100 g of the resin to the weight of iodine, and the unit is g1/100 g. The value can be determined by reacting 100 g of the resin with iodine monochloride, then capturing the unreacted iodine with an aqueous solution of potassium iodide, and titrating the unreacted iodine with an aqueous solution of sodium thiosulfate.

<Organosilane Unit having Acidic Group>

The (A2-1) polysiloxane for use in the present invention preferably contains an organosilane unit having an acidic group. Such a (A2-1) polysiloxane is preferably obtained with the use of an organosilane having an acidic group as the organosilane having an organosilane unit represented by general formula (7), the general formula (9), or the general formula (10). The (A2-1) polysiloxane contains the organosilane unit having an acidic group, thereby allowing the patternability with an alkaline developer and the resolution after development to be improved.

As the acidic group, a group that exhibits an acidity of less than pH 6 is preferred. Examples of the group that exhibits an acidity of less than pH 6 include a carboxy group, a carboxylic anhydride group, a sulfonic acid group, a phenolic hydroxyl group, a hydroxyimide group, and a silanol group. From the viewpoint of improving the patternability with an alkaline developer and improving the resolution after development, a carboxy group, a carboxylic anhydride group, a phenolic hydroxyl group, or a hydroxyimide group is preferred, and a carboxy group or a carboxylic anhydride group is more preferred.

In the case of using an organosilane having an organosilane unit represented by general formula (7), the general formula (9), or the general formula (10) and having an acidic group, the acid equivalent of the (A2-1) polysiloxane is preferably 280 g/mol or more, more preferably 300 g/mol or more, still more preferably 400 g/mol or more. When the acid equivalent is 280 g/mol or more, the film loss during alkaline development can be reduced. On the other hand, the acid equivalent is preferably 1,400 g/mol or less, more preferably 1,100 g/mol or less, still more preferably 950 g/mol or less. When the acid equivalent is 1,400 g/mol or less, the patternability with an alkaline developer and the resolution after development can be improved. In particular, the acid equivalent derived from the organosilane unit represented by general formula (7), the general formula (9), or the general formula (10) and having an acidic group in the (A2-1) polysiloxane is preferably 280 g/mol or more and 1,400 g/mol or less. In addition, the acid equivalent is more preferably a carboxylic acid equivalent from the viewpoint of improving the patternability with an alkaline developer and improving the resolution after development.

In this regard, the acid equivalent refers to the resin weight per 1 mol of the acidic group, and the unit is g/mol. The number of acidic groups in the resin can be determined from the value of the acid equivalent. The acid equivalent can be calculated from the acid value. It is to be noted that the acid value refers to the weight of potassium hydroxide that reacts with 1 g of the resin, and the unit is mgKOH/g. The acid value can be determined by titrating 1 g of the resin with an aqueous solution of potassium hydroxide.

The content ratio of various types of organosilane units in the (A2-1) polysiloxane can be determined by combining ¹H-NMR, ¹³C-NMR, ²⁹Si-NMR, IR, TOF-MS, elemental analysis, ash measurement, and the like.

### <Physical Properties of (A2-1) Polysiloxane>

The Mw of the (A2-1) polysiloxane for use in the present invention is preferably 500 or more, more preferably 700 or more, still more preferably 1,000 or more in terms of polystyrene measured by GPC. When the Mw is 500 or more, the resolution after development can be improved. On the other hand, the Mw is preferably 100,000 or less, more preferably 50,000 or less, still more preferably 20,000 or less. When the Mw is 100,000 or less, the leveling property in the case of coating and the patternability with an alkaline developer can be improved.

The (A2-1) polysiloxane can be synthesized by known methods. The methods include a method in which an organosilane is hydrolyzed in a reaction solvent and subjected to dehydration and condensation. Examples of the method for hydrolyzing and dehydrating, and condensing the organosilane include a method of further adding a reaction solvent and water, and if necessary, a catalyst, to the mixture containing the organosilane, and heating and stirring the mixture for about 0.5 to 100 hours at a temperature of 50 to 150° C., preferably 90 to 130° C. Further, during the heating and stirring, if necessary, hydrolysis by-products (alcohols such as methanol) and condensation by-products (water) may be distilled away by distillation.

### <(A2-2) Polycyclic Side Chain-containing Resin>

Examples of the (A2-2) polycyclic side chain-containing resin for use in the present invention include the following (I) to (IV) polycyclic side chain-containing resins:

(I) The polycyclic side chain-containing resin obtained by reacting an epoxy compound with the compound obtained by reacting a polyfunctional phenol compound and a polyfunctional carboxylic anhydride.

(II) The polycyclic side chain-containing resin obtained by reacting a polyfunctional carboxylic anhydride with the compound obtained by reacting a polyfunctional phenol compound and an epoxy compound.

(III) The polycyclic side chain-containing resin obtained by reacting an epoxy compound with the compound obtained by reacting a polyfunctional epoxy compound with a polyfunctional carboxylic acid compound.

(IV) The polycyclic side chain-containing resin obtained by reacting a polyfunctional carboxylic anhydride with the compound obtained by reacting a polyfunctional epoxy compound with a carboxylic acid compound.

It is to be noted that examples of the phenol compound, epoxy compound, carboxylic anhydride, and carboxylic acid compound include the compounds described in International Publication No. 2017/057281.

The (A2-2) polycyclic side chain-containing resin, which is a thermosetting resin, has a structure with a main chain and a bulky side chain connected by one atom, and has, as the bulky side chain, a ring structure such as a high heat-resistance and rigid fluorene ring. Accordingly, the photosensitive resin composition contains therein the (A2-2) polycyclic side chain-containing resin that has a ring structure such as a high heat-resistance and rigid fluorene ring, thereby making it possible to improve the heat resistance of the cured film obtained. For that reason, the cured film is suitable in such a case of using the cured film for applications which require heat resistance.

The (A2-2) polycyclic side chain-containing resin for use in the present invention preferably has an ethylenically unsaturated double bond group. The photosensitive resin composition contains therein the (A2-2) polycyclic side chain-containing resin having an ethylenically unsaturated double bond group, thereby making it possible to improve the sensitivity for exposure. In addition, the three-dimensional crosslinked structure to be formed has, as its main component, an alicyclic structure or an aliphatic structure, thus keeping the softening point of the resin from being increased, making it possible to obtain a pattern in a low-taper shape, and making it possible to improve the mechanical characteristic of the cured film obtained. For that reason, the cured film is suitable in such a case of using the cured film for applications which require a mechanical characteristic.

The (A2-2) polycyclic side chain-containing resin for use in the present invention, from the viewpoint of improving the heat resistance of the cured film, preferably contains one or more selected from a structural unit represented by general formula (47), a structural unit represented by general formula (48), a structural unit represented by general formula (49), and a structural unit represented by general formula (50). In addition, the (A2-2) polycyclic side chain-containing resin for use in the present invention preferably contains an ethylenically unsaturated double bond group for any one or more of the main chain, the side chain, and the terminal, from the viewpoint of improving the sensitivity for exposure and improving the mechanical characteristic of the cured film.

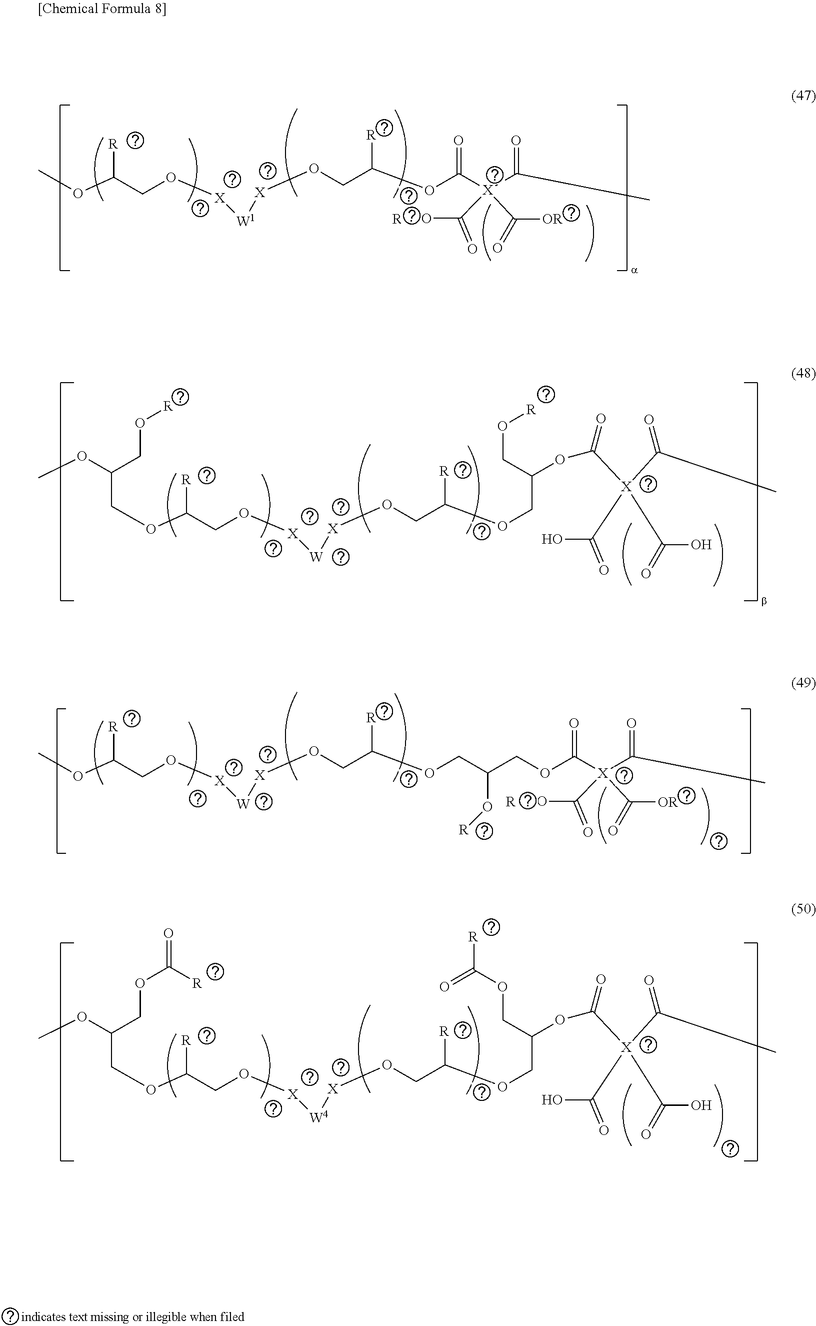

In the general formulas (47) to (50), X⁶⁹, X⁷⁰, X⁷², X⁷³, X⁷⁵, X⁷⁶, X⁷⁸, and X⁷⁹ each independently represent a monocyclic or condensed polycyclic hydrocarbon ring. X⁷¹, X⁷⁴, X⁷⁷, and X⁸⁰ each independently represent a divalent to decavalent organic group of a carboxylic acid and/or a derivative residue thereof. W¹ to W⁴ each independently represents an organic group having two or more aromatic groups. R¹⁶⁰ to R¹⁶⁷ each independently represent hydrogen or an alkyl group having 1 to 6 carbon atoms, and R¹⁷⁰ to R¹⁷⁵, R¹⁷⁷, and R¹⁷⁸ each independently represent hydrogen or an organic group having an ethylenically unsaturated double bond group. R¹⁷⁶ represents hydrogen or an alkyl group having 1 to 10 carbon atoms. a, b, c, d, e, f, g, and h each independently represent an integer of 0 to 10, and α, β, γ, and δ each independently represent 0 or 1.

In the general formulas (47) to (50), X⁶⁹, X⁷⁰, X⁷², X⁷³, X⁷⁵, X⁷⁶, X^{78,} and X⁷⁹ each independently preferably represent a divalent to decavalent monocyclic or condensed polycyclic hydrocarbon ring having 6 to 15 carbon atoms. Furthermore, X⁷¹, X⁷⁴, X⁷⁷, and X⁸⁰ each independently preferably represent a divalent to decavalent organic group having one or more selected from an aliphatic structure having 2 to 20 carbon atoms, an alicyclic structure having 4 to 20 carbon atoms, and an aromatic structure having 6 to 30 carbon atoms. Furthermore, W¹ to W⁴ each independently preferably represent a substituent represented by any of the general formulas (51) to (56). Furthermore, R¹⁷⁰ to R¹⁷⁵, R¹⁷⁷ and R¹⁷⁸ each independently preferably represent a substituent represented by general formula (57). The organic groups having an alkyl group, an aliphatic structure, alicyclic structure, an aromatic structure, a monocyclic or condensed polycyclic aromatic hydrocarbon ring, and an ethylenically unsaturated double bond group as described above may have a hetero atom, and may be either unsubstituted or substituted.

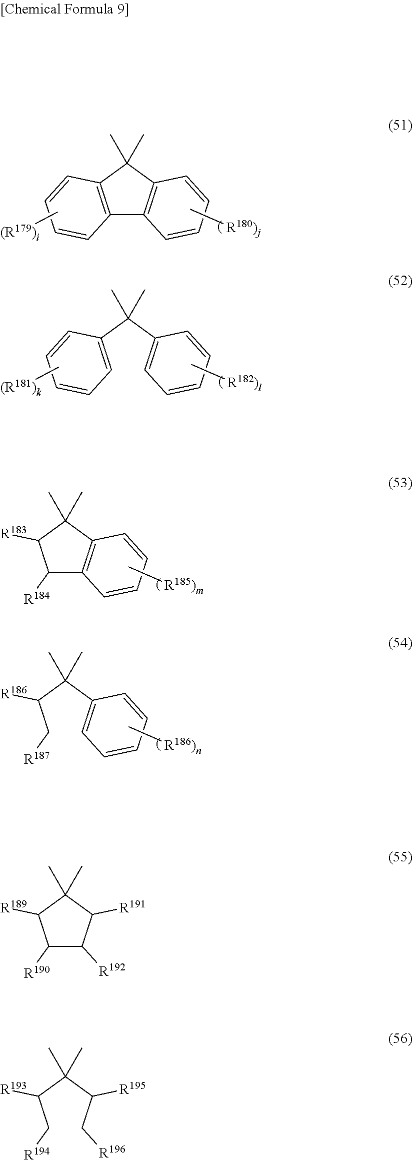

In the general formulas (51) to (56), R¹⁷⁹ to R¹⁸², R¹⁸⁵, and R¹⁸⁸ each independently represents an alkyl group having 1 to 10 carbon atoms. R¹⁸³, R¹⁸⁴, R¹⁸⁶, R¹⁸⁷, R¹⁸⁹, R¹⁹¹, and R¹⁹³ to R¹⁹⁶ each independently represent hydrogen, an alkyl group having 1 to 10 carbon atoms, a cycloalkyl group having 4 to 10 carbon atoms, or an aryl having 6 to 15 carbon atoms. R¹⁹⁰ and R¹⁹² each independently represent hydrogen, an alkyl group having 1 to 10 carbon atoms, a cycloalkyl group having 4 to 10 carbon atoms, or an aryl group having 6 to 15 carbon atoms, and R¹⁹⁰ and R¹⁹² may form a ring. Examples of the ring formed by R¹⁹⁰ and R¹⁹² include a benzene ring or a cyclohexane ring. At least one of R¹⁸³ and R¹⁸⁴ represents an aryl group having 6 to 15 carbon atoms. At least one of R¹⁸⁶ and R¹⁸⁷ represents an aryl group having 6 to 15 carbon atoms. At least one of R¹⁸⁹ and R¹⁹⁰ represents an aryl group having 6 to 15 carbon atoms, and at least one of R¹⁹¹ and R¹⁹² represents an aryl group having 6 to 15 carbon atoms, and R¹⁹⁰ and R¹⁹² may form a ring. At least one of R¹⁹³ and R¹⁹⁴ represents an aryl group having 6 to 15 carbon atoms, and at least one of R¹⁹⁵ and R¹⁹⁶ represents an aryl group having 6 to 15 carbon atoms. i, j, k, 1, m, and n each independently represent an integer of 0 to 4. In the general formulas (51) to (56), the ring formed by R¹⁹⁰ and R¹⁹² is preferably a benzene ring. The alkyl group, cycloalkyl group and aryl group described above may be either unsubstituted or substituted.

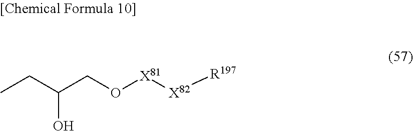

In the general formula (57), X⁸¹ represents a direct bond, an alkylene chain having 1 to 10 carbon atoms, a cycloalkylene chain having 4 to 10 carbon atoms, or an arylene chain having 6 to 15 carbon atoms, and X⁸² represents a direct bond or an arylene chain having 6 to 15 carbon atoms. R¹⁹⁷ represents a vinyl group, an aryl group, or a (meth)acrylic group. In the general formula (57), X⁸¹ preferably represents a direct bond, an alkylene chain having 1 to 6 carbon atoms, a cycloalkylene chain having 4 to 7 carbon atoms, or an arylene chain having 6 to 10 carbon atoms. Furthermore, X⁸² preferably represents a direct bond or an arylene chain having 6 to 10 carbon atoms. The alkylene chain, cycloalkylene chain, arylene chain, vinyl group, aryl group, and (meth)acrylic group described above may be either unsubstituted or substituted.

### <Method for Synthesis of (A2-2) Polycyclic Side Chain-Containing Resin>

As the (A2-2) polycyclic side chain-containing resin for use in the present invention, the (A2-2) polycyclic side chain-containing resins obtained by any one or more of the synthesis methods described in the following (I) to (IV) are preferred.

Examples of the (A2-2) polycyclic side chain-containing resin obtained by (I) include the (A2-2) polycyclic side chain-containing resin obtained by the ring-opening addition reaction of the resin obtained by reacting a compound having two or more aromatic groups in the molecule and a hydroxy group and a polyfunctional active carboxylic acid derivative (one or more selected from a tetracarboxylic dianhydride, a dicarboxylic acid dichloride, and a dicarboxylic acid active diester), with an unsaturated compound having an ethylenically unsaturated double bond group and an epoxy group. As the polyfunctional active carboxylic acid derivative, a tetracarboxylic dianhydride is preferred. In addition to the polyfunctional active carboxylic acid derivative, a tricarboxylic anhydride, a dicarboxylic anhydride, a monocarboxylic acid chloride, or a monocarboxylic acid active ester may be used as an end-capping agent for a reaction constituent.

Examples of the (A2-2) polycyclic side chain-containing resin obtained by (II) include the (A2-2) polycyclic side chain-containing resin obtained by reacting the resin obtained by the ring-opening addition reaction of a compound having two or more aromatic groups in the molecule and a hydroxy group with an unsaturated compound having an ethylenically unsaturated double bond group and an epoxy group, with a polyfunctional active carboxylic acid derivative (one or more selected from a tetracarboxylic dianhydride, a dicarboxylic acid dichloride, and a dicarboxylic acid active diester). As the polyfunctional active carboxylic acid derivative, a tetracarboxylic dianhydride is preferred. In addition to the polyfunctional active carboxylic acid derivative, a tricarboxylic anhydride, a dicarboxylic anhydride, a monocarboxylic acid chloride, or a monocarboxylic acid active ester may be used as an end-capping agent for a reaction constituent.

Examples of the (A2-2) polycyclic side chain-containing resin obtained by (III) include the (A2-2) polycyclic side chain-containing resin obtained by the ring-opening addition reaction of the resin obtained by the ring-opening addition reaction of a compound having two or more aromatic groups in the molecule and an epoxy group with a polyfunctional carboxylic acid (one or more selected from a tetracarboxylic acid, a tricarboxylic acid, and a dicarboxylic acid), with an unsaturated compound having an ethylenically unsaturated double bond group and an epoxy group. As the polyfunctional carboxylic acid, a tetracarboxylic acid or a tricarboxylic acid is preferred. In addition to the polyfunctional carboxylic acid, a monocarboxylic acid may be used as an end-capping agent for a reaction constituent.

Examples of the (A2-2) polycyclic side chain-containing resin obtained by (IV) include the (A2-2) polycyclic side chain-containing resin obtained by reacting the resin obtained by the ring-opening addition reaction of a compound having two or more aromatic groups in the molecule and an epoxy group with an unsaturated carboxylic acid having an ethylenically unsaturated double bond group, with a polyfunctional active carboxylic acid derivative (one or more selected from a tetracarboxylic dianhydride, a dicarboxylic acid dichloride, and a dicarboxylic acid active diester). As the polyfunctional active carboxylic acid derivative, a tetracarboxylic dianhydride is preferred. In addition to the polyfunctional active carboxylic acid derivative, a tricarboxylic anhydride, a dicarboxylic anhydride, a monocarboxylic acid chloride, or a monocarboxylic acid active ester may be used as an end-capping agent for a reaction constituent.

<Structural Units Derived from Aromatic Carboxylic Acid and Derivative thereof>

The (A2-2) polycyclic side chain-containing resin for use in the present invention preferably contains a structural unit derived from an aromatic carboxylic acid and a derivative thereof. The (A2-2) polycyclic side chain-containing resin contains a structural unit derived from an aromatic carboxylic acid and a derivative thereof, thereby allowing the heat resistance of the aromatic group to improve the heat resistance of the cured film. As the aromatic carboxylic acid an derivative thereof, one or more selected from a tetracarboxylic acid having an aromatic group, a tetracarboxylic dianhydride having an aromatic group, a tricarboxylic acid having an aromatic group, and a dicarboxylic acid having an aromatic group are preferred.

In addition, in the case of containing, in particular, the (D1) pigment as the (D) colorant described later, the (A2-2) polycyclic side chain-containing resin contains a structural unit derived from an aromatic carboxylic acid and a derivative thereof, thereby allowing the steric hindrance of the aromatic group to improve the dispersion stability of the (D1) pigment. Furthermore, in a case where the (D1) pigment is an (D1-1) organic pigment, the aromatic group in the (A2-2) polycyclic side chain-containing resin interacts with an aromatic group of the (D1-1) organic pigment, thus allowing the dispersion stability of the (D1-1) organic pigment to be improved.

Examples of the aromatic carboxylic acid and derivative thereof include the above-mentioned compounds included in the aromatic tetracarboxylic acid and/or derivative thereof, aromatic tricarboxylic acid and/or derivative thereof, or aromatic dicarboxylic acid and/or derivative thereof.

The content ratio of the structural units derived from aromatic carboxylic acids and/or derivatives thereof to structural units derived from all tetracarboxylic acids and all dicarboxylic acids and derivatives thereof in the (A2-2) polycyclic side chain-containing resin is preferably 10 to 100 mol %, more preferably 20 to 100 mol %, still more preferably 30 to 100 mol %. When the content ratio is 10 to 100 mol %, the heat resistance of the cured film can be improved.

<Acid Group derived from Carboxylic Acid and Derivative thereof>

The (A2-2) polycyclic side chain-containing resin for use in the present invention contains a structural unit derived from a carboxylic acid and a derivative thereof, and the (A2-2) polycyclic side chain-containing resin preferably has an acidic group. The (A2-2) polycyclic side chain-containing resin has an acidic group, thereby allowing the patternability with an alkaline developer and the resolution after development to be improved.

As the acidic group, a group that exhibits an acidity of less than pH 6 is preferred. Examples of the group that exhibits an acidity of less than pH 6 include a carboxy group, a carboxylic anhydride group, a sulfonic acid group, a phenolic hydroxyl group, and a hydroxyimide group. From the viewpoint of improving the patternability with an alkaline developer and improving the resolution after development, a carboxy group, a carboxylic anhydride group, or a phenolic hydroxyl group is preferred, and a carboxy group or a carboxylic anhydride group is more preferred.

The acid equivalent of the (A2-2) polycyclic side chain-containing resin for use in the present invention is preferably 280 g/mol or more, more preferably 300 g/mol or more, still more preferably 400 g/mol or more. When the acid equivalent is 280 g/mol or more, the film loss during alkaline development can be reduced. On the other hand, the acid equivalent is preferably 1,400 g/mol or less, more preferably 1,100 g/mol or less, still more preferably 950 g/mol or less. When the acid equivalent is 1,400 g/mol or less, the patternability with an alkaline developer and the resolution after development can be improved. Moreover, the acid equivalent is preferably a carboxylic acid equivalent from a viewpoint of the patternability improvement with an alkaline developer and the resolution improvement after development.

The content ratio of structural units derived from various types of monomer components in the (A2-2) polycyclic side chain-containing resin can be determined by combining ¹H-NMR, ¹³C-NMR, ²⁹Si-NMR, IR, TOF-MS, elemental analysis, ash measurement, and the like.

### <Specific Examples of (A2-2) Polycyclic Side Chain-Containing Resin>

Examples of the (A2-2) polycyclic side chain-containing resin for use in the present invention include “ADEKA ARKLS” (registered trademark) WR-101 or WR-301 (all manufactured by ADEKA Corporation), OGSOL (registered) trademark) CR-1030, CR-TR1, CR-TR^{2,} CR-TR3, CR-TR4, CR-TR5, CR-TR6, CR-TR7, CR-TR8, CR-TR9, or CR-TR10 (all manufactured by Osaka Gas Chemicals Co., Ltd.), and TR-B201 or TR-B202 (all manufactured by TRONLY).

### <Physical Properties of (A2-2) Polycyclic Side Chain-Containing Resin>

The double bond equivalent of the (A2-2) polycyclic side chain-containing resin for use in the present invention is preferably 150 g/mol or more, more preferably 200 g/mol or more, still more preferably 250 g/mol or more. When the double bond equivalent is 150 g/mol or more, the adhesion property to the underlying substrate can be improved. On the other hand, the double bond equivalent is preferably 10,000 g/mol or less, more preferably 5,000 g/mol or less, still more preferably 2,000 g/mol or less. When the double bond equivalent is 10,000 g/mol or less, the sensitivity for exposure can be improved.

The Mw of the (A2-2) polycyclic side chain-containing resin for use in the present invention is preferably 500 or more, more preferably 1,000 or more, still more preferably 1,500 or more in terms of polystyrene measured by GPC. When the Mw is 500 or more, the resolution after development can be improved. On the other hand, the Mw is preferably 100,000 or less, more preferably 50,000 or less, still more preferably 20,000 or less. When the Mw is 100,000 or less, the leveling property in the case of coating and the patternability with an alkaline developer can be improved.

### <(A2-3) Acid-Modified Epoxy Resin>

Examples of the (A2-3) acid-modified epoxy resin for use in the present invention include the following acid-modified epoxy resins (I) to (VI).

(I) The acid-modified epoxy resin obtained by reacting an epoxy compound with the compound obtained by reacting a polyfunctional phenol compound and a polyfunctional carboxylic anhydride.

(II) The acid-modified epoxy resin obtained by reacting a polyfunctional carboxylic anhydride with the compound obtained by reacting a polyfunctional phenol compound and an epoxy compound.

(III) The acid-modified epoxy resin obtained by reacting an epoxy compound with the compound obtained by reacting a polyfunctional alcohol compound and a polyfunctional carboxylic anhydride.

(IV) The acid-modified epoxy resin obtained by reacting a polyfunctional carboxylic anhydride with the compound obtained by reacting a polyfunctional alcohol compound and an epoxy compound.

(V) The acid-modified epoxy resin obtained by reacting an epoxy compound with the compound obtained by reacting a polyfunctional epoxy compound with a polyfunctional carboxylic acid compound.

(VI) The acid-modified epoxy resin obtained by reacting a polyfunctional carboxylic anhydride with the compound obtained by reacting a polyfunctional epoxy compound and a carboxylic acid compound.

It is to be noted that examples of the phenol compound, alcohol compound, epoxy compound, carboxylic anhydride, and carboxylic acid compound include the compounds described in International Publication No. 2017/057281.

The (A2-3) acid-modified epoxy resin, which is a thermosetting resin, has a highly heat-resistance aromatic ring structure in the epoxy resin skeleton of the main chain. Accordingly, the resin composition contains therein the (A2-3) acid-modified epoxy resin, thereby making it possible improve the heat resistance of the cured film obtained. For that reason, the cured film is suitable in such a case of using the cured film for applications which require heat resistance.

The (A2-3) acid-modified epoxy resin for use in the present invention preferably has an ethylenically unsaturated double bond group. The resin composition contains therein the (A2-3) acid-modified epoxy resin having an ethylenically unsaturated double bond group, thereby making it possible to improve the sensitivity for exposure. In addition, the three-dimensional crosslinked structure to be formed has, as its main component, an alicyclic structure or an aliphatic structure, thus keeping the softening point of the resin from being increased, making it possible to obtain a pattern in a low-taper shape, and making it possible to improve the mechanical characteristic of the cured film obtained. For that reason, the cured film is suitable in such a case of using the cured film for applications which require a mechanical characteristic.

The (A2-3) acid-modified epoxy resin for use in the present invention has a carboxy group and/or a carboxylic anhydride group as an alkali-soluble group. The resin has a carboxy group and/or a carboxylic anhydride group, allowing the resolution after development to be improved.

The (A2-3) acid-modified epoxy resin for use in the present invention preferably contains, from the viewpoint of improving the heat resistance of the cured film, one or more selected from a structural unit represented by general formula (35), a structural unit represented by general formula (36), a structural unit represented by general formula (37), a structural unit represented by general formula (38), a structural unit represented by general formula (41), a structural unit represented by general formula (42), and a structural unit represented by general formula (43). In addition, the (A2-3) acid-modified epoxy resin for use in the present invention preferably has an ethylenically unsaturated double bond group for any one or more of the main chain, the side chain, and the terminal, from the viewpoint of improving the sensitivity for exposure and improving the mechanical characteristic of the cured film.

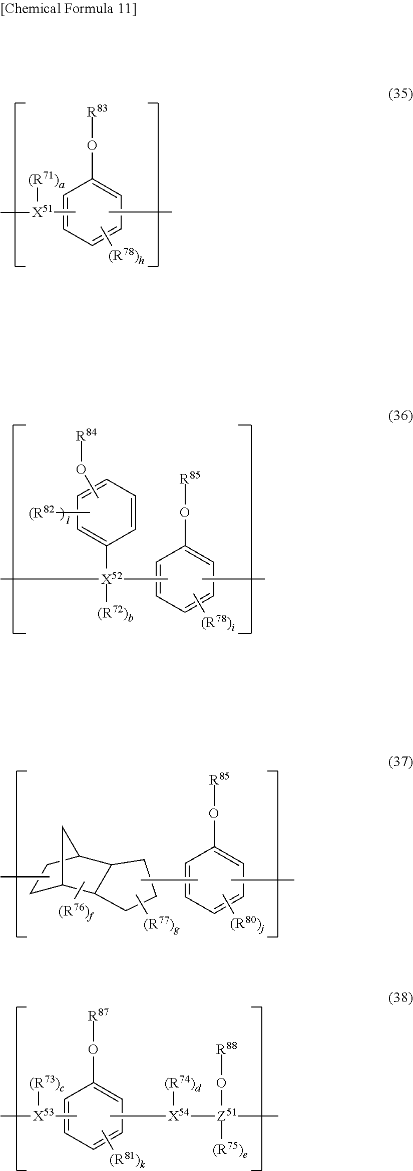

In the general formulas (35) to (38), X⁵¹ to X⁵⁴ each independently represent an aliphatic structure having 1 to 6 carbon atoms. Z⁵¹ represents a trivalent to 16-valent aromatic structure having 10 to 25 carbon atoms. R⁷¹ to R⁷⁵ each independently represent an alkyl group having 1 to 10 carbon atoms, a cycloalkyl group having 4 to 10 carbon atoms, or an aryl group having 6 to 15 carbon atoms, and R⁷⁶ and R⁷⁷ each independently represent an alkyl group having 1 to 10 carbon atoms, R⁷⁸ to R⁸² each independently represent halogen, an alkyl group having 1 to 10 carbon atoms, a cycloalkyl group having 4 to 10 carbon atoms, or an aryl group having 6 to 15 carbon atoms, and R⁸³ to R88 each independently represent a substituent represented by general formula (39). a, b, c, d, and e each independently represent an integer of 0 to 10, f represents an integer of 0 to 8, g represents an integer of 0 to 6, h, i, j, and k each independently represent an integer of 0 to 3, and 1 represents an integer of 0 to 4. The above-described alkyl group, cycloalkyl group, aryl group, aliphatic structure, and aromatic structure may have a hetero atom, and may be either unsubstituted or substituted.

The aromatic structure of Z⁵¹ in the general formula (38) contains one or more selected from the group consisting of a terphenyl structure, a naphthalene structure, an anthracene structure, and a fluorene structure. In addition, examples of other aromatic structures for Z⁵¹ in the general formula (38) include a 1,2,3,4-tetrahydronaphthalene structure, a 2,2-diphenylpropane structure, a diphenyl ether structure, a diphenyl ketone structure, and a diphenyl sulfone structure.

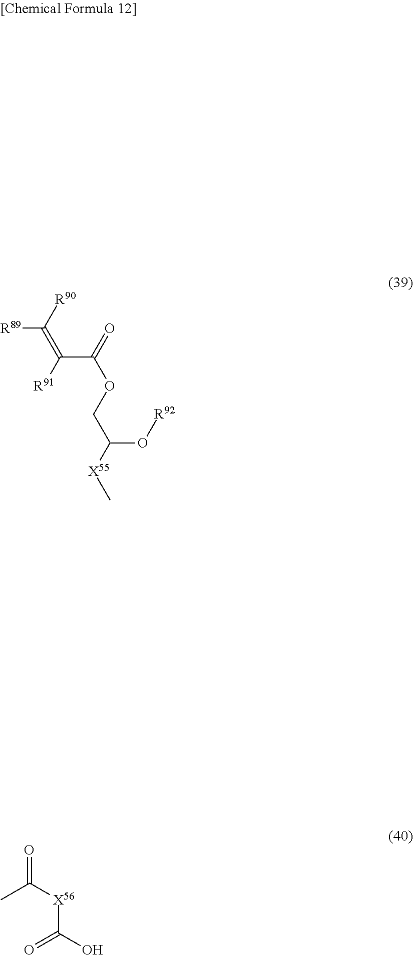

In the general formula (39), X⁵⁵ represents an alkylene chain having 1 to 6 carbon atoms or a cycloalkylene chain having 4 to 10 carbon atoms. R⁸⁹ to R⁹¹ each independently represent hydrogen, an alkyl group having 1 to 10 carbon atoms, or an aryl group having 6 to 15 carbon atoms. R⁹² represents hydrogen or a substituent represented by general formula (40). In the general formula (39), R⁸⁹ and R″ each independently preferably represent hydrogen or an alkyl group having 1 to 4 carbon atoms, more preferably hydrogen. R⁹¹ preferably represents hydrogen or an alkyl group having 1 to 4 carbon atoms, more preferably hydrogen or a methyl group. In the general formula (40), X⁵⁶ represents an alkylene chain having 1 to 6 carbon atoms or a cycloalkylene chain having 4 to 10 carbon atoms. In the general formula (40), X⁵⁶ preferably represents an alkylene chain having 1 to 4 carbon atoms or a cycloalkylene chain having 4 to 7 carbon atoms. The alkylene chain, cycloalkylene chain, alkyl group, and aryl group described above may be either unsubstituted or substituted.

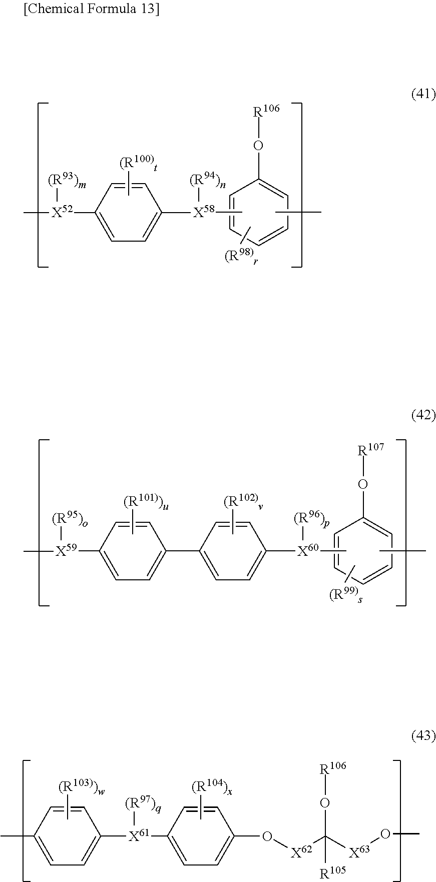

In the general formulas (41) to (43), X⁵⁷ to X⁶¹ each independently represent an aliphatic structure having 1 to 6 carbon atoms, and X⁶² and X⁶³ each independently represent an alkylene chain having 1 to 6 carbon atoms, or a cycloalkylene chain having 4 to 10 carbon atoms. R⁹³ to R⁹⁷ each independently represent an alkyl group having 1 to 10 carbon atoms, a cycloalkyl group having 4 to 10 carbon atoms, or an aryl group having 6 to 15 carbon atoms, and R⁹⁸ to R¹° ⁴ each independently represent halogen, an alkyl group having 1 to 10 carbon atoms, a cycloalkyl group having 4 to 10 carbon atoms, or an aryl group having 6 to 15 carbon atoms, R¹° ⁵ represents hydrogen or an alkyl group having 1 to 6 carbon atoms, R¹° ⁶ and R¹° ⁷ each independently represent a substituent represented by general formula (39), and R¹⁰⁸ represents hydrogen, a substituent represented by general formula (39), or a substituent represented by general formula (40). m, n, o, p, and q each independently represent an integer of 0 to 10, r and s each independently represent an integer of 0 to 3, and t, u, v, w, and x each independently represent an integer of 0 to 4. The above-mentioned alkylene chain, cycloalkylene chain, alkyl group, cycloalkyl group, aryl group, and aliphatic structure may have a hetero atom, and may be either unsubstituted or substituted.

Among the (A2-3) acid-modified epoxy resins for use in the present invention, as the (A2-3) acid-modified epoxy resin having a structural unit represented by general formula (43), the terminal preferably has a substituent represented by general formula (44) and/or a substituent represented by general formula (45).

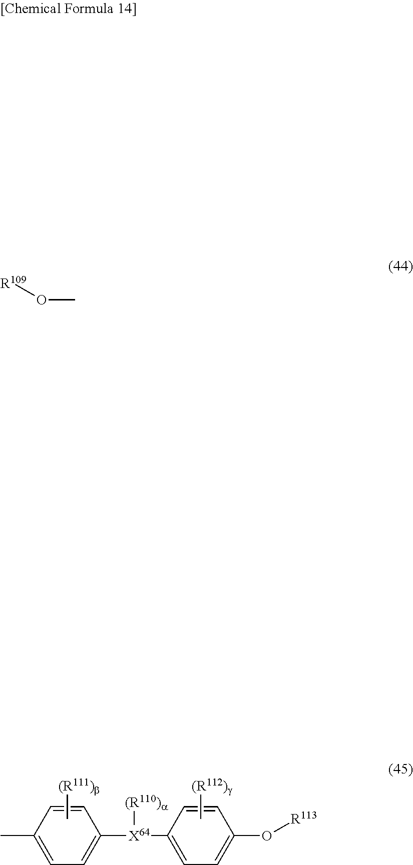

In the general formula (44), R¹⁰⁹ represents a substituent represented by general formula (39). In the general formula (45), X⁶⁴ represents an aliphatic structure having 1 to 6 carbon atoms. R¹¹⁰ represents an alkyl group having 1 to 10 carbon atoms, a cycloalkyl group having 4 to 10 carbon atoms, or an aryl group having 6 to 15 carbon atoms, and R¹¹¹ and R¹¹² each independently represent halogen, an alkyl group having 1 to 10 carbon atoms, a cycloalkyl group having 4 to 10 carbon atoms, or an aryl group having 6 to 15 carbon atoms. R¹¹³ represents a substituent represented by general formula (39). a represents an integer of 0 to β and γ represent integers of 0 to 4. In the general formula (45), X⁶⁴ preferably represents an aliphatic structure having 1 to 4 carbon atoms. ^{Rico} preferably represents an alkyl group having 1 to 6 carbon atoms, a cycloalkyl group having 4 to 7 carbon atoms, or an aryl group having 6 to 10 carbon atoms, and R¹¹¹ and R¹¹² each independently represent halogen, an alkyl group having 1 to 6 carbon atoms, a cycloalkyl group having 4 to 7 carbon atoms, or an aryl group having 6 to 10 carbon atoms.

<Structural Units Derived from Aromatic Carboxylic Acid and Derivative thereof>

The (A2-3) acid-modified epoxy resin for use in the present invention preferably contains a structural unit derived from an aromatic carboxylic acid and a derivative thereof. The (A2-3) acid-modified epoxy resin contains a structural unit derived from an aromatic carboxylic acid and a derivative thereof, thereby allowing the heat resistance of the aromatic group to improve the heat resistance of the cured film. As the aromatic carboxylic acid and derivative thereof, one or more selected from a tetracarboxylic acid having an aromatic group, a tricarboxylic acid having an aromatic group, a tricarboxylic anhydride having an aromatic group, a dicarboxylic acid having an aromatic group, and a dicarboxylic anhydride having an aromatic group are preferred.

In addition, in the case of containing, in particular, the (D1) pigment as the (D) colorant described later, the (A2-3) acid-modified epoxy resin contains a structural unit derived from an aromatic carboxylic acid and a derivative thereof, thereby allowing the steric hindrance of the aromatic group to improve the dispersion stability of the (D1) pigment. Furthermore, in a case where the (D1) pigment is an (D1-1) organic pigment, the aromatic group in the (A2-3) acid-modified epoxy resin interacts with an aromatic group of the (D1-1) organic pigment, thus allowing the dispersion stability of the (D1-1) organic pigment to be improved.

Examples of the aromatic carboxylic acid and derivative thereof include the above-described compounds included in the aromatic tetracarboxylic acid and/or derivative thereof, the aromatic tricarboxylic acid and/or derivative thereof, or the aromatic dicarboxylic acid and/or derivative thereof.

The content ratio of the structural units derived from aromatic carboxylic acids and/or derivatives thereof to structural units derived from all carboxylic acids and derivatives thereof in the (A2-3) acid-modified epoxy resin is preferably 10 to 100 mol %, more preferably 20 to 100 mol %, still more preferably 30 to 100 mol %. When the content ratio is 10 to 100 mol %, the heat resistance of the cured film can be improved.

<Acid Group derived from Carboxylic Acid and Derivative thereof>

The (A2-3) acid-modified epoxy resin for use in the present invention preferably contains a structural unit derived from a carboxylic acid and a derivative thereof, and the (A2-3) acid-modified epoxy resin preferably has an acidic group. The (A2-3) acid-modified epoxy resin has an acidic group, thereby allowing the patternability with an alkaline developer and the resolution after development to be improved.

As the acidic group, a group that exhibits an acidity of less than pH 6 is preferred. Examples of the group that exhibits an acidity of less than pH 6 include a carboxy group, a carboxylic anhydride group, a sulfonic acid group, a phenolic hydroxyl group, and a hydroxyimide group. From the viewpoint of improving the patternability with an alkaline developer and improving the resolution after development, a carboxy group, a carboxylic anhydride group, or a phenolic hydroxyl group is preferred, and a carboxy group or a carboxylic anhydride group is more preferred.

The acid equivalent of the (A2-3) acid-modified epoxy resin for use in the present invention is preferably 280 g/mol or more, more preferably 300 g/mol or more, still more preferably 400 g/mol or more. When the acid equivalent is 280 g/mol or more, the film loss during alkaline development can be reduced. On the other hand, the acid equivalent is preferably 1,400 g/mol or less, more preferably 1,100 g/mol or less, still more preferably 950 g/mol or less. When the acid equivalent is 1,400 g/mol or less, the patternability with an alkaline developer and the resolution after development can be improved. Moreover, the acid equivalent is preferably a carboxylic acid equivalent from a viewpoint of the patternability improvement with an alkaline developer and the resolution improvement after development.

The content ratio of structural units derived from various types of monomer components in the (A2-3) acid-modified epoxy resin can be determined by combining ¹H-NMR, ¹³C-NMR, ²⁹Si-NMR, IR, TOF-MS, elemental analysis, ash measurement, and the like.

### <Specific Examples of (A2-3) Acid-Modified Epoxy Resin>

Examples of the (A2-3) acid-modified epoxy resin for use in the present invention include “KAYARAD” (registered trademark) PCR-1222H, CCR-1171H, TCR-1348H, ZAR-1494H, ZFR-1401H, ZCR-1798H, ZXR-1807H, ZCR-6002H, or ZCR-8001H (all manufactured by Nippon Kayaku Co., Ltd.) or “NK OLIGO” (registered trademark) EA-6340, EA-7140, or EA-7340 (all manufactured by Shin Nakamura Chemical Co., Ltd.).

### <Physical Properties of (A2-3) Acid-Modified Epoxy Resin>

The Mw of the (A2-3) acid-modified epoxy resin for use in the present invention is preferably 500 or more, more preferably 1,000 or more, still more preferably 1,500 or more in terms of polystyrene measured by GPC. When the Mw falls within the range mentioned above, the resolution after development can be improved. On the other hand, the Mw is preferably 100,000 or less, more preferably 50,000 or less, still more preferably 20,000 or less. When the Mw falls within the range mentioned above, the leveling property in the case of coating and the patternability with an alkaline developer can be improved.

### <(A2-4) Acrylic Resin>

Examples of the (A2-4) acrylic resin for use in the present invention include the acrylic resin obtained by radical copolymerization of one or more selected from a copolymerization component having an acidic group, a copolymerization component derived from a (meth)acrylic ester, and other copolymerization components.

The (A2-4) acrylic resin for use in the present invention preferably has an ethylenically unsaturated double bond group. The photosensitive resin composition contains therein the (A2-4) acrylic resin having an ethylenically unsaturated double bond group, thereby making it possible to improve the sensitivity for exposure. In addition, the three-dimensional crosslinked structure to be formed has, as its main component, an alicyclic structure or an aliphatic structure, thus keeping the softening point of the resin from being increased, making it possible to obtain a pattern in a low-taper shape, and making it possible to improve the mechanical characteristic of the cured film obtained. For that reason, the cured film is suitable in such a case of using the cured film for applications which require a mechanical characteristic.

The (A2-4) acrylic resin for use in the present invention preferably contains a structural unit represented by general formula (61) and/or a structural unit represented by general formula (62), from the viewpoint of improving the sensitivity for exposure and improving the mechanical characteristic of the cured film.

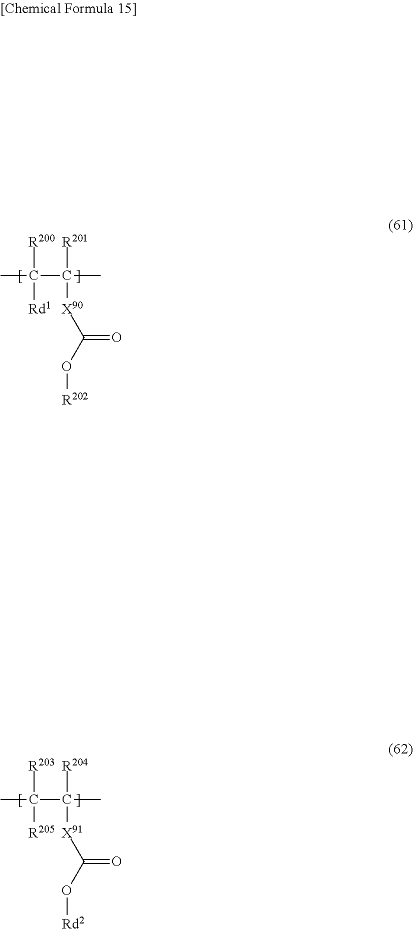

In the general formulas (61) and (62), Rd¹ and Rd² each independently represent an alkyl group having 1 to 10 carbon atoms, a cycloalkyl group having 4 to 15 carbon atoms, or an aryl group having 6 to 15 carbon atoms, which has an ethylenically unsaturated double bond group. R²⁰⁰ to R²⁰⁵ each independently represent hydrogen, an alkyl group having 1 to 10 carbon atoms, a cycloalkyl group having 4 to 10 carbon atoms, or an aryl group having 6 to 15 carbon atoms. X⁹⁰ and X⁹¹ each independently represent a direct bond, an alkylene chain having 1 to 10 carbon atoms, a cycloalkylene chain having 4 to 10 carbon atoms, or an arylene chain having 6 to 15 carbon atoms.

In the general formulas (61) and (62), Rd¹ and Rd² each independently preferably represent an alkyl group having 1 to 6 carbon atoms, a cycloalkyl group having 4 to 10 carbon atoms, or an aryl group having 6 to 10 carbon atoms, which has an ethylenically unsaturated double bond group. In addition, R²⁰⁰ to R²⁰⁵ each independently represent preferably hydrogen, an alkyl group having 1 to 6 carbon atoms, a cycloalkyl group having 4 to 7 carbon atoms, or an aryl group having 6 to 10 carbon atoms. In addition, X⁹⁰ and X⁹¹ each independently preferably represent a direct bond, an alkylene chain having 1 to 6 carbon atoms, a cycloalkylene chain having 4 to 7 carbon atoms, or an arylene chain having 6 to 10 carbon atoms. The alkyl group, cycloalkyl group, aryl group, alkylene chain, cycloalkylene chain, and arylene chain described above may have a hetero atom, and may be either unsubstituted or substituted.

The (A2-4) acrylic resin for use in the present invention is preferably an (A2-4) acrylic resin obtained by radical copolymerization of copolymerization components having acidic groups or other copolymerization components. As the other copolymer components, copolymerization components having aromatic groups or copolymerization components having alicyclic groups are preferred.

<Structural Unit Derived from Copolymerization Component having Acidic Group>

The (A2-4) acrylic resin for use in the present invention preferably contains a structural unit derived from a copolymerization component having an acidic group, and the (A2-4) acrylic resin preferably has an acidic group. The (A2-4) acrylic resin has an acidic group, thereby allowing the patternability with an alkaline developer and the resolution after development to be improved.

As the acidic group, a group that exhibits an acidity of less than pH 6 is preferred. Examples of the group that exhibits an acidity of less than pH 6 include a carboxy group, a carboxylic anhydride group, a sulfonic acid group, a phenolic hydroxyl group, and a hydroxyimide group. From the viewpoint of improving the patternability with an alkaline developer and improving the resolution after development, a carboxy group, a carboxylic anhydride group, or a phenolic hydroxyl group is preferred, and a carboxy group or a carboxylic anhydride group is more preferred.

The acid equivalent of the (A2-4) acrylic resin for use in the present invention is preferably 280 g/mol or more, more preferably 300 g/mol or more, still more preferably 400 g/mol or more. When the acid equivalent is 280 g/mol or more, the film loss during alkaline development can be reduced. On the other hand, the acid equivalent is preferably 1,400 g/mol or less, more preferably 1,100 g/mol or less, still more preferably 950 g/mol or less. When the acid equivalent is 1,400 g/mol or less, the patternability with an alkaline developer and the resolution after development can be improved. Moreover, the acid equivalent is preferably a carboxylic acid equivalent from a viewpoint of the patternability improvement with an alkaline developer and the resolution improvement after development.

As the (A2-4) acrylic resin for use in the present invention, an (A2-4) acrylic resin having no epoxy group is preferred in a case where the (A2-4) acrylic resin has a carboxy group. If the (A2-4) acrylic resin has both a carboxy group and an epoxy group, there is a possibility that the carboxy group and the epoxy group may react during the storage of a coating liquid with the photosensitive resin composition. Thus, the reaction causes the storage stability of the coating liquid with the resin composition to be decreased. As the (A2-4) acrylic resin having no epoxy group, an (A2-4) acrylic resin obtained by radical copolymerization of a copolymerization component having a carboxy group or a carboxylic anhydride group and another copolymerization component having no epoxy group is preferred.

<Structural Unit Derived from Copolymerization Component having Aromatic Group>

The (A2-4) acrylic resin for use in the present invention preferably contains a structural unit derived from a copolymerization component having an aromatic group. The (A2-4) acrylic resin contains a structural unit derived from a copolymerization component having an aromatic group, thereby allowing the heat resistance of the aromatic group to improve the heat resistance of the cured film.

In addition, in the case of containing, in particular, the (D1) pigment as the (D) colorant described later, the (A2-4) acrylic resin contains the structural unit derived from a copolymerization component having an aromatic group, thereby allowing the steric hindrance of the aromatic group to improve the dispersion stability of the (D1) pigment. Furthermore, in a case where the (D1) pigment is an (D1-1) organic pigment, the aromatic group in the (A2-4) acrylic resin interacts with an aromatic group of the (D1-1) organic pigment, thus allowing the dispersion stability of the (D1-1) organic pigment to be improved.

The content ratio of the structural unit derived from the copolymerization component having an aromatic group to structural units derived from all of the copolymerization components in the (A2-4) acrylic resin is preferably 10 mol % or higher, more preferably 20 mol % or higher, still more preferably 30 mol % or higher. When the content ratio is 10 mol % or higher, the heat resistance of the cured film can be improved. On the other hand, the content ratio is preferably 80 mol % or lower, more preferably 75 mol % or lower, still more preferably 70 mol % or lower. When the content ratio is 80 mol % or lower, the sensitivity for exposure can be improved.

<Structural Unit Derived from Copolymerization Component having Alicyclic Group>

The (A2-4) acrylic resin for use in the present invention preferably contains a structural unit derived from a copolymerization component having an alicyclic group. The (A2-4) acrylic resin contains a structural unit derived from a copolymerization component having an alicyclic group, thereby allowing the heat resistance and transparency of the alicyclic group to improve the heat resistance and transparency of the cured film.

The content ratio of the structural unit derived from the copolymerization component having an alicyclic group to structural units derived from all of the copolymerization components in the (A2-4) acrylic resin is preferably 5 mol % or higher, more preferably 10 mol % or higher, still more preferably 15 mol % or higher. When the content ratio is 5 mol % or higher, the heat resistance and transparency of the cured film can be improved. On the other hand, the content ratio is preferably 90 mol % or lower, more preferably 85 mol % or lower, still more preferably 75 mol % or lower. When the content ratio is 90 mol % or lower, the mechanical characteristic of the cured film can be improved.

As the (A2-4) acrylic resin for use in the present invention, a resin obtained further by the ring-opening addition reaction of an unsaturated compound having an ethylenically unsaturated double bond group and an epoxy group with a resin obtained by radical copolymerization of copolymerization components having an acidic groups or other copolymerization components is preferred. The ring-opening addition reaction of the unsaturated compound having an ethylenically unsaturated double bond group and an epoxy group allows an ethylenically unsaturated double bond group to be introduced into the side chain of the (A2-4) acrylic resin.

The content ratio of structural units derived from various types of copolymerization components in the (A2-4) acrylic resin can be determined by combining ¹H-NMR, ¹³C-NMR, ²⁹Si-NMR, IR, TOF-MS, elemental analysis, ash measurement, and the like.

### <Physical Properties of (A2-4) Acrylic Resin>

The double bond equivalent of the (A2-4) acrylic resin for use in the present invention is preferably 150 g/mol or more, more preferably 200 g/mol or more, still more preferably 250 g/mol or more. When the double bond equivalent is 150 g/mol or more, the adhesion property to the underlying substrate can be improved. On the other hand, the double bond equivalent is preferably 10,000 g/mol or less, more preferably 5,000 g/mol or less, still more preferably 2,000 g/mol or less. When the double bond equivalent is 10,000 g/mol or less, the sensitivity for exposure can be improved.

The Mw of the (A2-4) acrylic resin for use in the present invention is preferably 1,000 or more, more preferably 3,000 or more, still more preferably 5,000 or more in terms of polystyrene measured by GPC. When the Mw is 1,000 or more, the resolution after development can be improved. On the other hand, the Mw is preferably 100,000 or less, more preferably 70,000 or less, still more preferably 50,000 or less. When the Mw is 100,000 or less, the leveling property in the case of coating and the patternability with an alkaline developer can be improved.

The (A2-4) acrylic resin can be synthesized by known methods. Examples thereof include a method for radical copolymerization of a copolymerization component in the presence of a radical polymerization initiator in air or nitrogen. Examples of the method for radical copolymerization include a method of sufficiently purging the inside of a reaction container with nitrogen in air or by bubbling or degassing under reduced pressure, adding, into a reaction solvent therein, copolymerization components and a radical polymerization initiator, reacting the components at 60 to 110° C. for 30 to 500 minutes. Furthermore, a chain transfer agent such as a thiol compound and/or a polymerization terminator such as a phenol compound may be used, if necessary.

In the photosensitive resin composition according to the present invention, the content ratio of the (A1) first resin to 100% by mass of the (A1) first resin and (A2) second resin in total is preferably 25% by mass or higher, more preferably 50% by mass or higher, still more preferably 60% by mass or higher, even more preferably 70% by mass or higher, particularly preferably 80% by mass or higher. When the content ratio is 25% by mass or higher, the heat resistance of the cured film can be improved. On the other hand, the content ratio of the (A1) first resin is preferably 99% by mass or lower, more preferably 98% by mass or lower, still more preferably 97% by mass or lower, even more preferably 95% by mass or lower, particularly preferably 90% by mass or lower. When the content ratio is 99% by mass or lower, a cured film in a pattern in a low-taper shape can be obtained.

The content ratio of the (A1) first resin and (A2) second resin in the photosensitive resin composition according to the present invention falls within the above-described preferred range, thereby allowing the heat resistance of the cured film to be improved, and allowing a pattern in a low-taper shape to be obtained. Accordingly, the cured film obtained from the photosensitive resin composition according to the present invention is suitable for applications which require high heat resistance and a pattern in a low-taper shape, e.g., an insulation layer such as a pixel dividing layer of an organic EL display, a TFT planarization layer, or a TFT protective layer. In particular, in applications in which problems due to heat resistance and pattern shapes are expected, such as element failures or characteristic degradation due to degassing by thermal decomposition, or electrode wiring disconnection due to high-taper pattern shapes, the use of a cured film of the photosensitive resin composition according to the present invention makes it possible to manufacture a highly reliable element where the above-described problems are kept from being caused. In addition, the photosensitive resin composition according to the present invention contains the (D) colorant described later, thus allowing electrode wiring to be prevented from becoming visible or allowing external light reflection to be reduced, and the contrast in image display can be thus improved.

### <(B) Radical Polymerizable Compound>

The photosensitive resin composition according to the present invention preferably further contains a (B) radical polymerizable compound.

The (B) radical polymerizable compound refers to a compound having a plurality of ethylenically unsaturated double bond groups in the molecule. During exposure, radicals generated from a photo initiator (C1) to be described later causes radical polymerization of the (B) radical polymerizable compound to proceed, thereby making the exposed part of the film of the resin composition insoluble in an alkaline developer, and then allowing a negative pattern to be formed.

Containing the (B) radical polymerizable compound accelerates UV curing during the exposure, thereby allowing the sensitivity for the exposure to be improved. In addition, the crosslink density after thermal curing is improved, thereby allowing the hardness of the cured film to be improved.

As the (B) radical polymerizable compound, a compound having a (meth)acrylic group is preferred, which facilitates radical polymerization. From the viewpoint of improving the sensitivity for exposure and improving the hardness of the cured film, a compound having two or more (meth)acrylic groups in the molecule is more preferred. The double bond equivalent of the (B) radical polymerizable compound is preferably from 80 to 800 g/mol from the viewpoint of improving the sensitivity for exposure and forming a pattern in a low-taper shape.

Examples of the (B) radical polymerizable compound include, in addition to a (B1) fluorene skeleton-containing radical polymerizable compound and an (B2) indane skeleton-containing radical polymerizable compound to be described later, diethylene glycol di(meth)acrylate, triethylene glycol di(meth)acrylate, tetraethylene glycol di(meth)acrylate, propylene glycol di(meth)acrylate, trimethylolpropane di(meth)acrylate, trimethylolpropane tri(meth)acrylate, ditrimethylolpropane tri(meth)acrylate, ditrimethylolpropane tetra(meth)acrylate, 1,3-butanediol di(meth)acrylate, neopentyl glycol di(meth)acrylate, 1,4-butanediol di(meth)acrylate, 1,6-hexanediol di(meth)acrylate, 1,9-nonane di(meth)acrylate, 1,10-decanediol di(meth)acrylate, dimethylol-tricyclodecane di(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, tetrapentaerythritol nona(meth)acrylate, tetrapentaerythritol deca(meth)acrylate, pentapentaerythritol undeca(meth)acrylate, pentapentaerythritol dodeca(meth)acrylate, ethoxylated bisphenol A di(meth)acrylate, 2,2-bis[4-(3-(meth)acryloxy-2-hydroxypropoxy) phenyl]propane, 1,3,5-tris((meth)acryloxyethyl) isocyanuric acid, or 1,3-bis((meth)acryloxyethyl) isocyanuric acid, or acid modified products. Furthermore, from the viewpoint of improving the resolution after development, the compound obtained by reacting a compound obtained by the ring-opening addition reaction of a compound having two or more glycidoxy groups in the molecule and an unsaturated carboxylic acid having an ethylenically unsaturated double bond group, with a polybasic carboxylic acid or polybasic carboxylic anhydride is also preferred.

The content of the (B) radical polymerizable compound in the photosensitive resin composition according to the present invention is, in a case where the (A) alkali-soluble resin and the (B) radical polymerizable compound are regarded as 100 parts by mass in total, preferably 15 parts by mass or more, more preferably 20 parts by mass or more, still more preferably 25 parts by mass or more, particularly preferably 30 parts by mass or more. When the content is 15 parts by mass or more, the sensitivity for exposure can be improved, and a cured film in pattern in a low-taper shape can be obtained. On the other hand, the content of the (B) radical polymerizable compound is preferably 65 parts by mass or less, more preferably 60 parts by mass or less, still more preferably 55 parts by mass or less, particularly preferably 50 parts by mass or less. When the content is 65 parts by mass or less, the heat resistance of the cured film can be improved, and a low taper pattern shape can be obtained.

### <(B1) Fluorene Skeleton-Containing Radical Polymerizable Compound and (B2) Indane Skeleton-Containing Radical Polymerizable Compound>

The photosensitive resin composition according to the present invention preferably contains, as the (B) radical polymerizable compound, one or more selected from the group consisting of a (B1) fluorene skeleton-containing radical polymerizable compound and an (B2) indane skeleton-containing radical polymerizable compound.

The (B1) fluorene skeleton-containing radical polymerizable compound refers to a compound having a plurality of ethylenically unsaturated double bond groups and a fluorene skeleton in the molecule. The (B2) indane skeleton-containing radical polymerizable compound refers to a compound having a plurality of ethylenically unsaturated double bond groups and an indane skeleton in the molecule.

Containing the (B1) fluorene skeleton-containing radical polymerizable compound or the (B2) indane skeleton-containing radical polymerizable compound makes it possible to improve the sensitivity for exposure and control the pattern shape after development, and makes it possible to form a pattern in a low-taper shape after thermal curing. In addition, controlling the pattern shape after development makes it possible to form a forward tapered pattern, and the halftone characteristics can be thud improved. Furthermore, the change in pattern opening width between before and after thermal curing can be suppressed.

Furthermore, in the case of containing, in particular, a (D1a-1a) benzofuranone-based black pigment as the (Da) black colorant described later, a development residue derived from the pigment described above may be generated due to the insufficient alkali resistance of the above-described pigment. In this case, containing a (B3) flexible chain-containing aliphatic radical polymerizable compound to be described later, and the (B1) fluorene skeleton-containing radical polymerizable compound or (B2) indane skeleton-containing radical polymerizable compound is capable of keeping the development residue generation derived from the pigment described above from being generated.

As the (B1) fluorene skeleton-containing radical polymerizable compound, a compound represented by general formula (31) is preferred. As the (B2) indane skeleton-containing radical polymerizable compound, a compound represented by general formula (32) and a compound represented by general formula (33) are preferred.

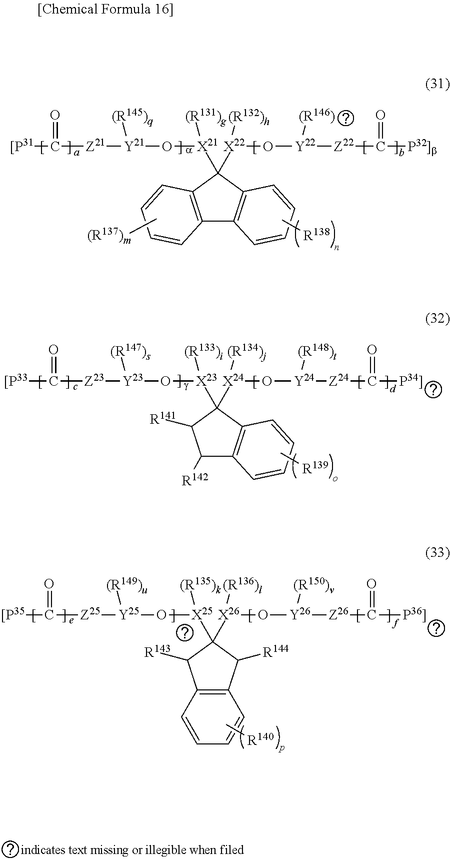

In the general formulas (31), (32), and (33), X²¹ to X²⁶ each independently represent a divalent to decavalent monocyclic or condensed polycyclic aromatic hydrocarbon ring having 6 to 15 carbon atoms, or a divalent to octavalent monocyclic or condensed polycyclic aliphatic hydrocarbon ring having 4 to 10 carbon atoms. Y²¹ to Y²⁶ each independently represent a direct bond, an alkylene group having 1 to 10 carbon atoms, a cycloalkylene group having 4 to 10 carbon atoms, or an arylene group having 6 to 15 carbon atoms. In a case where Y²¹ to Y²⁶ represent direct bonds, Z²¹ to Z²⁶ represent direct bonds, and q, r, s, t, u, and v represent 0. In a case where Y²¹ to Y²⁶ represent no direct bond, Z²¹ to Z²⁶ each represent an oxygen atom, and q, r, s, t, u, and v each independently represent an integer of 0 to 8. R¹³¹ to R¹⁴⁰ each independently represent halogen, an alkyl group having 1 to 10 carbon atoms, a cycloalkyl group having 4 to 10 carbon atoms, or an aryl group having 6 to 15 carbon atoms, R¹⁴¹ to R¹⁴⁴ each independently represent hydrogen, an alkyl group having 1 to 10 carbon atoms, a cycloalkyl group having 4 to 10 carbon atoms, or an aryl group having 6 to 15 carbon atoms, and R¹⁴⁵ to R¹⁵⁰ each independently represent an alkyl group or a hydroxy group having 1 to 10 carbon atoms. P³¹ to P³⁶ each independently represent a group represented by general formula (34). a, b, c, d, e, and f each independently represent 0 or 1. In a case where a, b, c, d, e, and f represent 0, Z²¹ to Z²⁶ represent an oxygen atom. g, h, i, j, k, and 1 each independently represent an integer of 0 to 8, and m, n, o, and p each independently represent an integer of 0 to 4. α, β, γ, δ, ε, and ζ each independently represent an integer of 1 to 4. The monocyclic or condensed polycyclic aromatic hydrocarbon ring, monocyclic or condensed polycyclic aliphatic hydrocarbon ring, alkylene group, cycloalkylene group, arylene group, alkyl group, cycloalkyl group, and aryl group described above may have a hetero atom, and may be either unsubstituted or substituted.

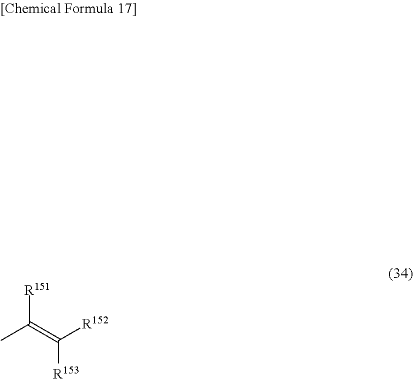

In the general formula (34), R¹⁵¹ to R¹⁵³ each independently represent hydrogen, an alkyl group having 1 to 10 carbon atoms, or an aryl group having 6 to 15 carbon atoms. In the general formula (34), R¹⁵¹ preferably represents hydrogen or an alkyl group having 1 to 4 carbon atoms, more preferably hydrogen or a methyl group. R¹⁵² and R¹⁵³ each independently preferably represent hydrogen or an alkyl group having 1 to 4 carbon atoms, more preferably hydrogen.

As the (B1) fluorene skeleton-containing radical polymerizable compound and the (B2) indane skeleton-containing radical polymerizable compound, a compound having a (meth)acrylic group is preferred, which facilitates radical polymerization. From the viewpoint of improving the sensitivity for exposure and reducing the residue after development, compounds having two or more (meth)acrylic groups in the molecule are more preferred.

The double bond equivalent of the (B1) fluorene skeleton-containing radical polymerizable compound and (B2) indane skeleton-containing radical polymerizable compound is preferably 150 g/mol or more, more preferably 170 g/mol or more, even more preferably 190 g/mol or more, particularly preferably 210 g/mol or more. When the double bond equivalent is 150 g/mol or more, a pattern in a low-taper shape can be formed after thermal curing, and the change in pattern opening width between before and after thermal curing can be suppressed. On the other hand, the double bond equivalent of the (B1) fluorene skeleton-containing radical polymerizable compound and (B2) indane skeleton-containing radical polymerizable compound is preferably 800 g/mol or less, more preferably 600 g/mol or less, still more preferably 500 g/mol or less, particularly preferably 400 g/mol or less. When the double bond equivalent is 800 g/mol or less, the sensitivity for exposure can be improved.

Examples of the (B1) fluorene skeleton-containing radical polymerizable compounds include 9,9-bis[4-(2-(meth)acryloxyethoxy) phenyl]fluorene, 9,9-bis[4-(3-(meta)acryloxypropoxy) phenyl]fluorene, 9,9-bis(4-(meth)acryloxyphenyl)fluorene, 9,9-bis[4-(2-hydroxy-3-(meth)acryloxypropoxy) phenyl]fluorene, or 9,9-bis[3,4-bis(2-(meth)acryloxyethoxy)phenyl]fluorene, and OGSOL (registered trademark) EA-50P, EA-0200, EA-0250P, EA-0300, EA-500, EA-1000, EA-F5510, or GA-5000 (all manufactured by Osaka Gas Chemicals Co., Ltd.).

Examples of the (B2) indane skeleton-containing radical polymerizable compound include 1,1-bis[4-(2-(meth)acryloxyethoxy)phenyl]indane, 1,1-bis(4-(meth)acryloxyphenyl)indane, 1,1-bis[4-(2-hydroxy-3-(meth)acryloxypropoxy) phenyl]indane, 1,1-bis[3,4-bis(2-(meth) acryloxyethoxy)phenyl]indane, 2,2-bis[4-(2-(meth)acryloxyethoxy)phenyl]indane, or 2,2-bis(4-(meth) acryloxyphenyl)indane.

The (B1) fluorene skeleton-containing radical polymerizable compound and the (B2) indane skeleton-containing radical polymerizable compound can be synthesized by known methods. For example, the synthesis method described in International Publication No. 2008/139924 can be mentioned.

The total content of the (B1) fluorene skeleton-containing radical polymerizable compound and (B2) indane skeleton-containing radical polymerizable compound in the photosensitive resin composition according to the present invention is, in a case where the (A) alkali-soluble resin and the (B) radical polymerizable compound are regarded as 100 parts by mass in total, preferably 0.5 parts by mass or more, more preferably 1 part by mass or more, still more preferably 2 parts by mass or more, even more preferably 3 parts by mass or more, particularly preferably 5 parts by mass or more. When the content is 0.5 parts by mass or more, the sensitivity for exposure can be improved, and a pattern in a low-taper shape can be formed after thermal curing. In addition, the change in pattern opening width between before and after thermal curing can be suppressed. On the other hand, the total content of the (B1) fluorene skeleton-containing radical polymerizable compound and (B2) indane skeleton-containing radical polymerizable compound is preferably 25 parts by mass or less, more preferably 22 parts by mass or less, still more preferably 20 parts by mass or less, even more preferably 18 parts by mass or less, particularly preferably 15 parts by mass or less. When the content is 25 parts by mass or less, the change in pattern opening width between before and after thermal curing can be suppressed, and residues after development can be kept from being generated.

### <(B3) Flexible Chain-Containing Aliphatic Radical Polymerizable Compound>

The photosensitive resin composition according to the present invention preferably contains the (B3) flexible chain-containing aliphatic radical polymerizable compound as the (B) radical polymerizable compound.

The (B3) flexible chain-containing aliphatic radical polymerizable compound refers to a compound having a plurality of ethylenically unsaturated double bond groups and a flexible skeleton such as an aliphatic chain or an oxyalkylene chain in the molecule.

Containing the (B3) flexible chain-containing aliphatic radical polymerizable compound causes UV curing during the exposure to proceed efficiently, thereby allowing the sensitivity for the exposure to be improved. In addition, in the case of containing, in particular, the (D1) pigment as (D) colorant described later, the (D1) pigment is immobilized to the cured part by crosslinking during UV curing of the (B3) flexible chain-containing aliphatic radical polymerizable compound, thus making it possible to inhibit the residue generation after development, which is derived from the (D1) pigment. Furthermore, the change in pattern opening width between before and after thermal curing can be suppressed. In addition, the bendability of the cured film can be improved. This is presumed to be because having a flexible skeleton such as an aliphatic chain accelerates UV curing to increase the molecular weight of the cured film, and in addition, because the introduction of a flexible skeleton into the cured film improves mechanical properties.

Furthermore, in the case of containing, in particular, a (D1a-1a) benzofuranone-based black pigment as the (Da) black colorant described later, a development residue derived from the pigment described above may be generated due to the insufficient alkali resistance of the above-described pigment. Even in such a case, the generation of the development residue derived from the pigment described above can be inhibited by containing the (B3) flexible chain-containing aliphatic radical polymerizable compound.

As the (B3) flexible chain-containing aliphatic radical polymerizable compound, a compound having a group represented by general formula (24) and three or more groups represented by general formula (25) in the molecule is preferred.

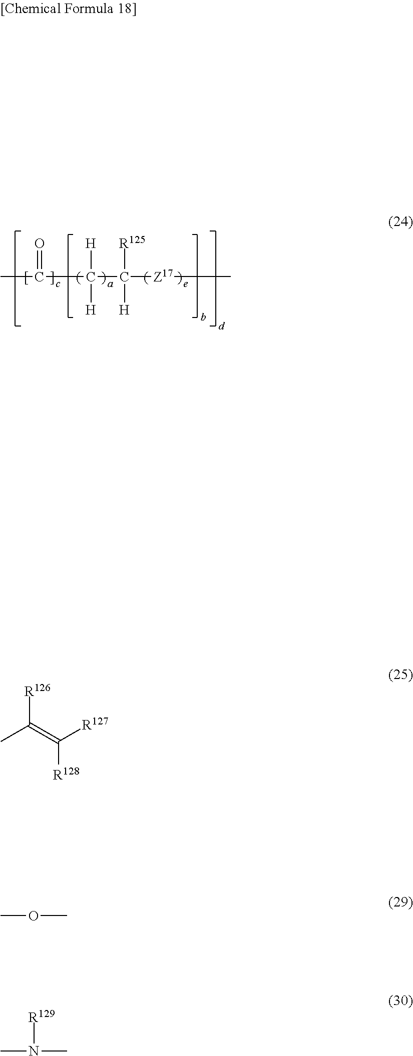

In the general formula (24), R¹²⁵ represents hydrogen or an alkyl group having 1 to 10 carbon atoms. Z¹⁷ represents a group represented by general formula (29) or a group represented by general formula (30). a represents an integer of 1 to 10, b represents an integer of 1 to 4, c represents 0 or 1, d represents an integer of 1 to 4, and e represents 0 or 1. In a case where c is 0, d represents 1. In the general formula (25), R¹²⁶ to R¹²⁸ each independently represent hydrogen, an alkyl group having 1 to 10 carbon atoms, or an aryl group having 6 to 15 carbon atoms. In the general formula (30), R¹²⁹ represents hydrogen or an alkyl group having 1 to 10 carbon atoms. In the general formula (24), c preferably represents 1, and e preferably represents 1. In the general formula (25), R¹²⁶ preferably represents hydrogen or an alkyl group having 1 to 4 carbon atoms, more preferably hydrogen or a methyl group. R¹²⁷ and R¹²⁸ each independently preferably represent hydrogen or an alkyl group having 1 to 4 carbon atoms, more preferably hydrogen. In the general formula (30), R¹²⁹ preferably represents hydrogen or an alkyl group having 1 to 4 carbon atoms, more preferably hydrogen or a methyl group. In the general formula (24), in a case where c represents 1, the residue generation after development can be inhibited. In addition, the bendability of the cured film can be improved.

As the (B3) flexible chain-containing aliphatic radical polymerizable compound, a compound represented by general formula (27) and a compound represented by general formula (28) are preferred.

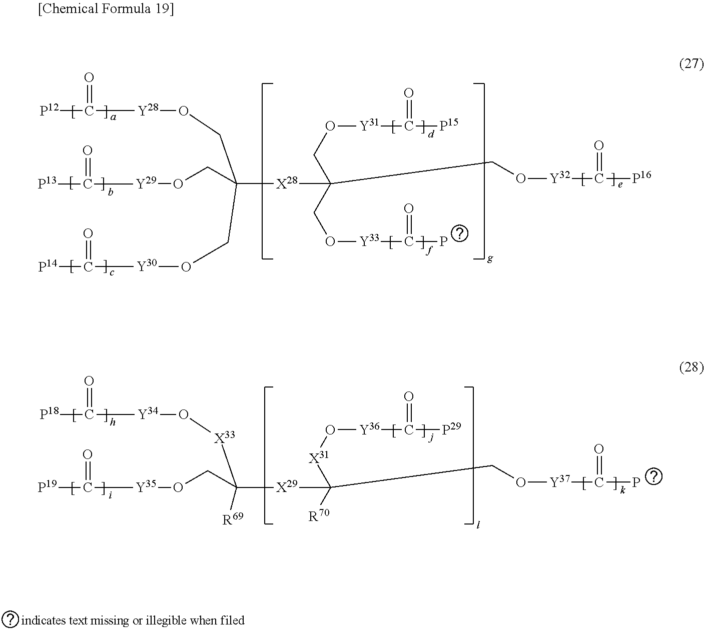

In the general formula (27), X²⁸ represents a divalent organic group. Y²⁸ to Y³³ each independently represent a direct bond or a group represented by the above-described general formula (24), and at least one of Y²⁸ to Y³³ represents a group represented by general formula (24). p¹² to p¹⁷ each independently represent hydrogen or a group represented by the above-described general formula (25), and at least three of p¹² to p¹⁷ represent groups represented by general formula (25). a, b, c, d, e, and f each independently represent 0 or 1, and g represents an integer of 0 to 10.

In the general formula (27), X²⁸ preferably represents a divalent organic group having one or more selected from an aliphatic structure having 1 to 10 carbon atoms, an alicyclic structure having 4 to 20 carbon atoms, and an aromatic structure having 6 to 30 carbon atoms. a b, c, d, e, and f each independently preferably represent 1, and g preferably represents 0 to 5. The above-described aliphatic structure, alicyclic structure, and aromatic structure may have a hetero atom, and may be either unsubstituted or substituted. In the general formula (27), among Y²⁸ to Y³³, the number of the groups represented by general formula (24) described above is preferably 2 or more, more preferably 3 or more, even more preferably 4 or more. When the number of the groups represented by general formula (24) described above is 2 or more among Y²⁸ to Y³³, the sensitivity for exposure can be improved, and the residue generation after development can be inhibited. In addition, the bendability of the cured film can be improved.

In the general formula (28), X²⁹ represents a divalent organic group. X³⁰ and X³¹ each independently represent a direct bond or an alkylene chain having 1 to 10 carbon atoms. Y³⁴ to Y³⁷ each independently represent a direct bond or a group represented by the above-described general formula (24), and at least one of Y³⁴ to Y³⁷ represents a group represented by general formula (24). R⁶⁹ and R⁷° each independently represent hydrogen or an alkyl group having 1 to 10 carbon atoms. p¹⁸ to p²¹ each independently represent hydrogen or a group represented by the above-described general formula (25), and at least three of p¹⁸ to p²¹ represent groups represented by general formula (25). h, i, j, and k each independently represent 0 or 1, and 1 represents an integer of 0 to 10.

In the general formula (28), X²⁹ preferably represents a divalent organic group having one or more selected from an aliphatic structure having 1 to 10 carbon atoms, an alicyclic structure having 4 to 20 carbon atoms, and an aromatic structure having 6 to 30 carbon atoms. h, i, j, and k each independently preferably represent 1, and 1 preferably represents 0 to 5. The above-described alkyl group, alkylene chain, aliphatic structure, alicyclic structure, and aromatic structure may have a hetero atom, and may be either unsubstituted or substituted. In the general formula (28), among Y³⁴ to Y³⁷, the number of the groups represented by general formula (24) described above is preferably 2 or more, more preferably 3 or more, even more preferably 4 or more. When the number of the groups represented by general formula (24) described above is 2 or more among Y³⁴ to Y³⁷, the sensitivity for exposure can be improved, and the residue generation after development can be inhibited. In addition, the bendability of the cured film can be improved.

The (B3) flexible chain-containing aliphatic radical polymerizable compound preferably has at least one lactone-modified chain and/or at least one lactam-modified chain. The (B3) flexible chain-containing aliphatic radical polymerizable compound has at least one lactone-modified chain and/or at least one lactam-modified chain, thereby allowing the residue generation after development to be inhibited. In addition, the bendability of the cured film can be improved. This is believed to be because having a lactone-modified chain and/or a lactam-modified chain remarkably accelerates UV curing to increase the molecular weight of the cured film. Furthermore, it is presumed to be because the introduction of a flexible skeleton such as a lactone-modified chain and/or a lactam-modified chain into the cured film improves mechanical properties.

The (B3) flexible chain-containing aliphatic radical polymerizable compound has at least one lactone-modified chain and/or at least one lactam-modified chain, when c and e respectively represent 1 and 1 in the general formula (24).

The number of ethylenically unsaturated double bond groups in the molecule of the (B3) flexible chain-containing aliphatic radical polymerizable compound is preferably 3 or more, more preferably 4 or more. When the number of ethylenically unsaturated double bond groups is 3 or more, the sensitivity for exposure can be improved. On the other hand, the number of ethylenically unsaturated double bond groups in the molecule of the (B3) flexible chain-containing aliphatic radical polymerizable compound is preferably 12 or less, more preferably 10 or less, still more preferably 8 or less, particularly preferably 6 or less. When the number of ethylenically unsaturated double bond groups is 12 or less, a pattern in a low-taper shape can be formed after thermal curing, and the change in pattern opening width between before and after thermal curing can be suppressed.

The double bond equivalent of the (B3) flexible chain-containing aliphatic radical polymerizable compound is preferably 100 g/mol or more, more preferably 120 g/mol or more, still more preferably 150 g/mol or more, and even more preferably 170 g/mol or more, particularly preferably 200 g/mol or more. When the double bond equivalent is 100 g/mol or more, the sensitivity for exposure can be improved, and the residue generation after development can be inhibited. In addition, the change in pattern opening width between before and after thermal curing can be suppressed. On the other hand, the double bond equivalent of the (B3) flexible chain-containing aliphatic radical polymerizable compound is preferably 800 g/mol or less, more preferably 600 g/mol or less, still more preferably 500 g/mol or less, particularly preferably 450 g/mol or less. When the double bond equivalent is 800 g/mol or less, the sensitivity for exposure can be improved, and the residue generation after development can be inhibited. In addition, the change in pattern opening width between before and after thermal curing can be suppressed.

Examples of the (B3) flexible chain-containing aliphatic radical polymerizable compound include, as compounds having three or more ethylenically unsaturated double bond groups in the molecules, for example, ethoxylated dipentaerythritol hexa(meth)acrylate, propoxylated dipentaerythritol hexa(meth)acrylate, ε-caprolactone modified dipentaerythritol hexa(meth)acrylate, δ-valerolactone modified dipentaerythritol hexa(meth)acrylate, γ-butyrolactone modified dipentaerythritol hexa(meth)acrylate, β-propiolactone modified dipentaerythritol hexa(meth)acrylate, ε-caprolactam modified dipentaerythritol hexa(meth)acrylate, ε-caprolactone modified dipentaerythritol penta(meth)acrylate, ε-caprolactone modified trimethylolpropane tri(meth)acrylate, ε-caprolactone modified ditrimethylolpropane tetra(meth)acrylate, ε-caprolactone modified glycerin tri(meth)acrylate, ε-caprolactone modified pentaerythritol tri(meth)acrylate, ε-caprolactone modified pentaerythritol tetra(meth)acrylate, or ε-caprolactone modified 1,3,5-tris((meth)acryloxyethyl) isocyanurate, and “KAYARAD” (registered trademark) DPEA-12, DPCA-20, DPCA-30, DPCA-60, or DPCA-120 (all manufactured by Nippon Kayaku Co., Ltd.), or “NK ESTER” (registered trademark) A-DPH-6E, A-DPH-6P, M-DPH-6E, A-9300-1CL, or A-9300-3CL (all manufactured by Shin Nakamura Chemical Co., Ltd.).

The (B3) flexible chain-containing aliphatic radical polymerizable compound can be synthesized by known methods.

The content of the (B3) flexible chain-containing aliphatic radical polymerizable compound in the photosensitive resin composition according to the present invention is, in a case where the (A) alkali-soluble resin and the (B) radical polymerizable compound are regarded as 100 parts by mass in total, preferably 5 parts by mass or more, more preferably 10 parts by mass or more, still more preferably 15 parts by mass or more, particularly preferably 20 parts by mass or more. When the content is 5 parts by mass or more, the sensitivity for exposure can be improved, and the residue generation after development can be inhibited. In addition, the change in pattern opening width between before and after thermal curing can be suppressed. In addition, the bendability of the cured film can be improved. On the other hand, the content of the (B3) flexible chain-containing aliphatic radical polymerizable compound is preferably 45 parts by mass or less, more preferably 40 parts by mass or less, still more preferably 35 parts by mass or less, particularly preferably 30 parts by mass or less. When the content is 45 parts by mass or less, a cured film in a pattern in a low-taper shape can be obtained.

The photosensitive resin composition according to the present invention preferably contains the above-mentioned (B3) flexible chain-containing aliphatic radical polymerizable compound and a (B4) flexible chain-containing bifunctional radical polymerizable compound. The above-mentioned (B3) flexible chain-containing aliphatic radical polymerizable compound and (B4) flexible chain-containing bifunctional radical polymerizable compound are used in combination, thereby making it possible to suppress the change in pattern opening width between before and after thermal curing, and making it possible to improve the bendability of the cured film. In the photosensitive resin composition according to the present invention, the content ratio of the (B4) flexible chain-containing bifunctional radical polymerizable compound to 100% by mass of the (B3) flexible chain-containing aliphatic radical polymerizable compound and (B4) flexible chain-containing bifunctional radical polymerizable compound in total is preferably 20% by mass or higher, more preferably 25% by mass or higher, still more preferably 30% by mass or higher, even more preferably 35% by mass or higher, particularly preferably 40% by mass or higher. When the content ratio is 20% by mass or higher, the change in pattern opening width between before and after thermal curing can be suppressed, and the bendability of the cured film can be improved. On the other hand, the content ratio of the (B4) flexible chain-containing bifunctional radical polymerizable compound is preferably 80% by mass or lower, more preferably 75% by mass or lower, still more preferably 70% by mass or lower, and even more preferably 65% by mass or lower, particularly preferably 60 mass% or less. When the content ratio is 80% by mass or lower, the sensitivity for exposure can be improved, the residue generation after development can be inhibited, and the change in pattern opening width between before and after thermal curing can be suppressed.

### <(B4) Flexible Chain-Containing Bifunctional Radical Polymerizable Compound>

The photosensitive resin composition according to the present invention preferably contains the (B4) flexible chain-containing bifunctional radical polymerizable compound as the (B) radical polymerizable compound. The (B4) flexible chain-containing bifunctional radical polymerizable compound refers to a compound having two ethylenically unsaturated double bond groups and a flexible skeleton such as an aliphatic chain or an oxyalkylene chain in the molecule.

Containing the (B4) flexible chain-containing bifunctional radical polymerizable compound causes UV curing during the exposure to proceed efficiently, thereby allowing the sensitivity for the exposure to be improved. In addition, in the case of containing, in particular, the (D1) pigment as (D) colorant described later, the (D1) pigment is immobilized to the cured part by crosslinking during UV curing of the (B4) flexible chain-containing bifunctional radical polymerizable compound, thus making it possible to inhibit the residue generation after development, which is derived from the (D1) pigment, and making it possible to form a pattern in a low-taper shape after thermal curing. This is presumed to be because having a flexible skeleton such as an aliphatic chain accelerates UV curing to improve the crosslink density, and in addition, because the bifunctionality inhibits excessive curing, thereby allowing reflow property during thermal curing to be maintained. Furthermore, the change in pattern opening width between before and after thermal curing can be suppressed. This is presumed to be because controlling the degree of UV curing during the exposure allows a pattern in a low-taper shape to be formed after development, thereby suppressing reflow of the pattern skirt during the thermal curing.

Furthermore, the bendability of the cured film can be improved. This is presumed to be because having a flexible skeleton such as an aliphatic chain accelerates UV curing to increase the molecular weight of the cured film, and in addition, because the introduction of a flexible skeleton into the cured film improves mechanical properties. Moreover, it is believed to be because the bifunctionality inhibits excessive curing, thereby allowing the flexibility of the cured film to be improved.

Furthermore, in the case of containing, in particular, a (D1a-1a) benzofuranone-based black pigment as the (Da) black colorant described later, a development residue derived from the pigment described above may be generated due to the insufficient alkali resistance of the pigment as described previously. Even in such a case, the generation of the development residue derived from the pigment can be inhibited by containing the (B4) flexible chain-containing bifunctional radical polymerizable compound. This is presumed to be because, as mentioned above, UV curing accelerated improves the crosslink density, thereby immobilizing the (D1a-1a) benzofuranone-based black pigment to the cured part, and then inhibiting decomposition or dissolution by an alkaline developer.

The (B4) flexible chain-containing bifunctional radical polymerizable compound preferably has a compound having at least one group represented by general formula (21) and two groups represented by general formula (25) in the molecule.

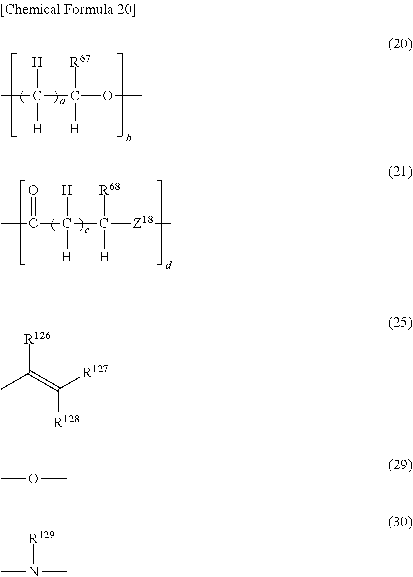

In the general formula (20), R⁶⁷ represents hydrogen or an alkyl group having 1 to 10 carbon atoms. a represents an integer of 1 to 10, and b represents an integer of 1 to 4. In the general formula (21), R⁶⁸ represents hydrogen or an alkyl group having 1 to 10 carbon atoms. Z¹⁸ represents a group represented by general formula (29) or a group represented by general formula (30). c represents an integer of 1 to 10, and d represents an integer of 1 to 4. In the general formula (25), R¹²⁶ to R¹²⁸ each independently represents hydrogen, an alkyl group having 1 to 10 carbon atoms, or an aryl group having 6 to 15 carbon atoms. In the general formula (30), R¹²⁹ represents hydrogen or an alkyl group having 1 to 10 carbon atoms. In the general formula (20), R⁶⁷ preferably represents hydrogen or an alkyl group having 1 to 4 carbon atoms. a preferably represents an integer of 1 to 6, and b preferably represents 1 or 2. In the general formula (21), R⁶⁸ preferably represents hydrogen or an alkyl group having 1 to 4 carbon atoms. c preferably represents an integer of 1 to 6, and d preferably represents 1 or 2. In the general formula (25), R126 preferably represents hydrogen or an alkyl group having 1 to 4 carbon atoms, more preferably hydrogen or a methyl group. R¹²⁷ and R¹²⁸ each independently preferably represent hydrogen or an alkyl group having 1 to 4 carbon atoms, more preferably hydrogen. In the general formula (30), R¹²⁹ preferably represents hydrogen or an alkyl group having 1 to 4 carbon atoms, more preferably hydrogen or a methyl group.

The (B4) flexible chain-containing bifunctional radical polymerizable compound is preferably a compound represented by general formula (22) and a compound represented by general formula (23).

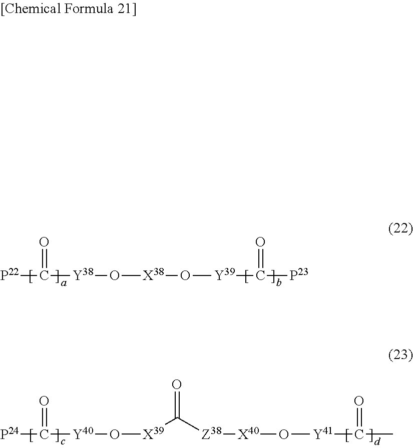

In the general formula (22), X³⁸ represents a divalent organic group. Y³⁸ and Y³⁹ each independently represent a direct bond, a group represented by general formula (20), or a group represented by general formula (21), and at least one of Y³⁸ and Y³⁹ represent a group represented by general formula (21). P²² and P²³ represent groups represented by general formula (25). a and b each independently represent 0 or 1. In the general formula (22), X³⁸ preferably represents a divalent organic group having one or more selected from an aliphatic structure having 1 to 10 carbon atoms, an alicyclic structure having 4 to 20 carbon atoms, and an aromatic structure having 6 to 30 carbon atoms, more preferably, a divalent organic group having one or more selected from an aliphatic structure having 1 to 6 carbon atoms, an alicyclic structure having 4 to 15 carbon atoms, and an aromatic structure having 6 to 25 carbon atoms. a and b each independently preferably represent 1. The above-mentioned aliphatic structure, alicyclic structure, and aromatic structure may have a hetero atom, and may be either unsubstituted or substituted.

In the general formula (23), X³⁹ and X⁴⁰ each independently represent a divalent organic group. Y⁴⁰ and Y⁴¹ each independently represent a direct bond, a group represented by general formula (20), or a group represented by general formula (21), and at least one of V° and Y⁴¹ represent a group represented by general formula (21). Z³⁸ represents a direct bond or oxygen. P²⁴ and P²⁵ represent a group represented by general formula (25). c and d each independently represent 0 or 1. In the general formula (23), X³⁹ and X⁴⁰ preferably represent divalent organic groups having one or more selected from an aliphatic structure having 1 to 10 carbon atoms, an alicyclic structure having 4 to 20 carbon atoms, and an aromatic structure having 6 to 30 carbon atoms, more preferably, divalent organic groups having one or more selected from an aliphatic structure having 1 to 6 carbon atoms, an alicyclic structure having 4 to 15 carbon atoms, and an aromatic structure having 6 to 25 carbon atoms. c and d each independently preferably represent 1. The above-mentioned aliphatic structure, alicyclic structure, and aromatic structure may have a hetero atom, and may be either unsubstituted or substituted.

The (B4) flexible chain-containing bifunctional radical polymerizable compound has at least one lactone-modified chain and/or at least one lactam-modified chain. The (B4) flexible chain-containing bifunctional radical polymerizable compound has at least one lactone-modified chain and/or at least one lactam-modified chain, thereby allowing the residue generation after development to be inhibited. In addition, the bendability of the cured film can be improved. This is believed to be because having a lactone-modified chain and/or a lactam-modified chain remarkably accelerates UV curing to increase the molecular weight of the cured film. Furthermore, it is presumed to be because the introduction of a flexible skeleton such as a lactone-modified chain and/or a lactam-modified chain into the cured film improves mechanical properties.

When the (B4) flexible chain-containing bifunctional radical polymerizable compound has the group represented by general formula (34), the compound has at least one lactone-modified chain and/or at least one lactam-modified chain.

As the lactone-modified chain, a structure derived from a lactone compound is preferred. Examples of the lactone compound include β-propiolactone, γ-butyrolactone, δ-valerolactone, and ε-caprolactone. As the lactam-modified chain, a structure derived from a lactam compound is preferred. Examples of the lactam compound include β-propiolactam, γ-butyrolactam, δ-valerolactam, and ε-caprolactam.

The double bond equivalent of the (B4) flexible chain-containing bifunctional radical polymerizable compound is preferably 100 g/mol or more, more preferably 120 g/mol or more, still more preferably 150 g/mol or more, and even more preferably 170 g/mol or more, particularly preferably 200 g/mol or more. When the double bond equivalent is 100 g/mol or more, the sensitivity for exposure can be improved, and the residue generation after development can be inhibited. On the other hand, the double bond equivalent of the (B4) flexible chain-containing bifunctional radical polymerizable compound is preferably 800 g/mol or less, more preferably 600 g/mol or less, still more preferably 500 g/mol or less, particularly preferably 450 g/mol or less. When the double bond equivalent is 800 g/mol or less, the sensitivity for exposure can be improved, and the residue generation after development can be inhibited.

The molecular weight of the (B4) flexible chain-containing bifunctional radical polymerizable compound is preferably 200 or more, more preferably 250 or more, still more preferably 300 or more, even more preferably 350 or more, particularly preferably 400 or more. When the molecular weight is 200 or more, the sensitivity for exposure can be improved, and the residue generation after development can be inhibited. On the other hand, the molecular weight of the (B4) flexible chain-containing bifunctional radical polymerizable compound is preferably 1,000 or less, more preferably 900 or less, still more preferably 800 or less, particularly preferably 700 or less. When the molecular weight is 1,000 or less, the sensitivity for exposure can be improved, and the residue generation after development can be inhibited.

Examples of the (B4) flexible chain-containing bifunctional radical polymerizable compound include, as compounds having two ethylenically unsaturated double bond groups in the molecule, for example, ε-caprolactone-modified hydroxypivalate neopentyl glycol di(meth)acrylate, ε-caprolactone modified trimethylolpropane di(meth)acrylate, ε-caprolactone modified ditrimethylolpropane di(meth)acrylate, ε-caprolactone modified glycerin di(meth)acrylate, ε-caprolactone modified pentaerythritol di(meth)acrylate, ε-caprolactone modified dimethylol-tricyclodecane di(meth)acrylate, ε-caprolactone modified 1,3-bis((meth)acryloxyethyl) isocyanuric acid, or ε-caprolactone modified 1,3-bis((meth)acryloxyethyl) isocyanuric acid, or “KAYARAD” (registered trademark) HX-220 or HX-620 (all manufactured by Nippon Kayaku Co., Ltd.).

The content of the (B4) flexible chain-containing bifunctional radical polymerizable compound in the photosensitive resin composition according to the present invention is, in a case where the (A) alkali-soluble resin and the (B) radical polymerizable compound are regarded as 100 parts by mass in total, preferably 3 parts by mass or more, more preferably 5 parts by mass or more, still more preferably 10 parts by mass or more, even more preferably 15 parts by mass or more, particularly preferably 20 parts by mass or more. When the content is 3 parts by mass or more, the sensitivity for exposure can be improved, and a pattern in a low-taper shape can be formed. In addition, the bendability of the cured film can be improved. On the other hand, the content of the (B4) flexible chain-containing bifunctional radical polymerizable compound is preferably 40 parts by mass or less, more preferably 35 parts by mass or less, still more preferably 30 parts by mass or less, particularly preferably 25 parts by mass or less. When the content is 40 parts by mass or less, the sensitivity for exposure can be improved, and the residue generation after development can be inhibited.

The photosensitive resin composition according to the present invention preferably contains the above-mentioned (B3) flexible chain-containing aliphatic radical polymerizable compound and a (B4) flexible chain-containing bifunctional radical polymerizable compound. The above-mentioned (B3) flexible chain-containing aliphatic radical polymerizable compound and (B4) flexible chain-containing bifunctional radical polymerizable compound are used in combination, thereby making it possible to suppress the change in pattern opening width between before and after thermal curing, and making it possible to improve the bendability of the cured film. In the photosensitive resin composition according to the present invention, the content ratio of the (B4) flexible chain-containing bifunctional radical polymerizable compound to 100% by mass of the (B3) flexible chain-containing aliphatic radical polymerizable compound and (B4) flexible chain-containing bifunctional radical polymerizable compound in total is preferably 20% by mass or higher, more preferably 25% by mass or higher, still more preferably 30% by mass or higher, even more preferably 35% by mass or higher, particularly preferably 40% by mass or higher. When the content ratio is 20% by mass or higher, the change in pattern opening width between before and after thermal curing can be suppressed, and the bendability of the cured film can be improved. On the other hand, the content ratio of the (B4) flexible chain-containing bifunctional radical polymerizable compound is preferably 80% by mass or lower, more preferably 75% by mass or lower, still more preferably 70% by mass or lower, and even more preferably 65% by mass or lower, particularly preferably 60 mass% or less. When the content ratio is 80% by mass or lower, the sensitivity for exposure can be improved, the residue generation after development can be inhibited, and the change in pattern opening width between before and after thermal curing can be suppressed.

### <Negative Photosensitivity>

The photosensitive resin composition according to the present invention further contains the (C) photosensitive agent. The (C) photosensitive agent is preferably a (C1) photo initiator and/or (C2) a photo acid generator.

### <(C1) Photo Initiator>

The (C1) photo initiator refers to a compound that generates radicals through bond cleavage and/or reaction upon exposure.

Containing the (C1) photo initiator causes radical polymerization of the above-described (B) radical polymerizable compound to proceed, thereby making the exposed part of the film of the resin composition insoluble in an alkaline developer, and then allowing a negative pattern to be formed. In addition, UV curing during the exposure is accelerated, thereby allowing the sensitivity to be improved.

Further, containing a specific amount of (C1) photo initiator or more allows the change in pattern opening width between before and after thermal curing to be suppressed. This is believed to be due to an increase in radical generation, derived from the (C1) photo initiator during the exposure. More specifically, increasing the radical generation during the exposure is presumed to increase the probability of collision between the generated radicals and the ethylenically unsaturated double bond group in the above-described (B) radical polymerizable compound, thereby accelerating UV curing and then improving the crosslink density, thus suppressing reflow of a pattern taper and a pattern skirt during thermal curing, and thus making it possible to suppress the change in pattern opening width between before and after thermal curing.

As the (C1) photo initiator, for example, a benzyl ketal-based photo initiator, an a-hydroxy ketone-based photo initiator, an a-amino ketone-based photo initiator, an acylphosphine oxide-based photo initiator, an oxime ester-based photo initiator, an acridine-based photo initiator, a titanocene-based photo initiator, a benzophenone-based photo initiator, an acetophenone-based photo initiator, an aromatic ketoester-based photo initiator, or a benzoic acid ester-based photo initiator is preferred, and from the viewpoint of improvement in sensitivity at the time of exposure, an a-hydroxy ketone-based photo initiator, an a-amino ketone-based photo initiator, an acylphosphine oxide-based photo initiator, an oxime ester-based photo initiator, an acridine-based photo initiator, or a benzophenone-based photo initiator is more preferred, and an a-amino ketone-based photo initiator, an acylphosphine-based photo initiator, or an oxime ester-based photo initiator is further preferred.

Examples of the benzyl ketal-based photo initiator include 2,2-dimethoxy-1,2-diphenylethane-1-one.

Examples of the a-hydroxy ketone-based photo initiators include 1-(4-isopropylphenyl)-2-hydroxy-2-methylpropan-1-one, 2-hydroxy-2-methyl-1-phenylpropane-1-one, 1-hydroxycyclohexyl phenyl ketone, 1-[4-(2-hydroxyethoxy)phenyl]-2-hydroxy-2-methylpropane-1-one, or 2-hydroxy-1-[4-[4-(2-hydroxy-2-methylpropionyl)benzyl]phenyl]-2-methylpropan-1-one.

Examples of the a-amino ketone-based photo initiator include 2-methyl-1-[4-(methylthio)phenyl]-2-morpholinopropan-1-one, 2-benzyl-2-dimethylamino-1-(4-morpholinophenyl)-butane-1-one, 2-dimethylamino-2-(4-methylbenzyl)-1-(4-morpholinophenyl)-butane-1-one, or 3,6-bis(2-methyl-2-morpholinopropionyl)-9-octyl-9H-carbazole.

Examples of the acyl phosphine oxide-based photo initiator include 2,4,6-trimethyl benzoyl-diphenyl phosphine oxide, bis(2,4,6-trimethyl benzoyl)-phenyl phosphine oxide, or bis(2,6-dimethoxy benzoyl)-(2,4,4-trimethylpentyl) phosphine oxide.

Examples of the oxime ester photo initiator include 1-phenylpropane-1,2-dione-2-(O-ethoxycarbonyl)oxime, 1-phenylbutane-1,2-dione-2-(O-methoxycarbonyl)oxime, 1,3-diphenylpropane-1,2,3-trione-2-(O-ethoxycarbonyl)oxime, 1-[4-(phenylthio)phenyl]octane-1,2-dione-2-(O-benzoyl)oxime, 1-[4-[4-carboxyphenylthio]phenyl]propane-1,2-dione-2-(O-acetyl)oxime, 1-[4-[4-(2-hydroxyethoxy)phenylthio]phenyl]propane-1,2-dione-2-(O-acetyl)oxime, 1-[4-(phenylthio)phenyl]-3-cyclopentylpropane-1,2-dione-2-(O-benzoyl)oxime, 1-[4-(phenylthio)phenyl]-2-cyclopentylethane-1,2-dione-2-(O-acetyl)oxime, 1-[9,9-diethylfluorene-2-yl]propane-1,2-dion-2-(O-acetyl)oxime, 1-[9,9-di-n-propyl-7-(2-methylbenzoyl)-fluoren-2-yl]ethanone-1-(O-acetyl)oxime, 1-[9-ethyl-6-(2-methylbenzoyl)-9H-carbazol-3-yl]ethanone-1-(O-acetyl)oxime, 1-[9-ethyl-6-[2-methyl-4-[1-(2,2-dimethyl-1,3-dioxolan-4-yl)methyloxy]benzoyl]-9H-carbazol-3-yl]ethanone-1-(O-acetyl)oxime, 1-[9-ethyl-6-(2-methylbenzoyl)-9H-carbazol-3-yl]-3-cyclopentylpropan-1-one-1-(O-acetyl)oxime, and 1-(9-ethyl-6-nitro-9H-carbazol-3-yl)-1-[2-methyl-4-(1-methoxypropan-2-yloxy)phenyl]methanone-1-(O-acetyl)oxime.

Examples of the acridine-based photo initiator include 1,7-bis(acridin-9-yl)-n-heptane.

Examples of the titanocene-based photo initiator include bis(ₕ⁵-2,4-cyclopentadien-1-yl)-bis[2,6-difluoro-3-(1H-pyrrol-1-yl)phenyl]titanium (IV) or bis(ₕ⁵-3-methyl-2,4-cyclopentadien-1-yl)-bis(2,6-difluorophenyl) titanium (IV).

Examples of the benzophenone-based photo initiator include benzophenone, 4,4′-bis(dimethylamino)benzophenone, 4,4′-bis(diethylamino)benzophenone, 4-phenylbenzophenone, 4,4-dichlorobenzophenone, 4-hydroxybenzophenone, alkylated benzophenone, 3,3′,4,4′-tetrakis(t-butylperoxycarbonyl)benzophenone, 4-methylbenzophenone, dibenzyl ketone, or fluorenone.

Examples of the acetophenone-based photo initiator include 2,2-diethoxyacetophenone, 2,3-diethoxyacetophenone, 4-t-butyldichloroacetophenone, benzalacetophenone, or 4-azidobenzalacetophenone.

Examples of the aromatic ketoester-based photo initiator include methyl 2-phenyl-2-oxyacetate.

Examples of the benzoate-based photo initiator include ethyl 4-dimethylaminobenzoate, (2-ethyl)hexyl 4-dimethylaminobenzoate, ethyl 4-diethylaminobenzoate, or methyl 2-benzoylbenzoate.

The content of the (C1) photo initiator in the photosensitive resin composition according to the present invention is, in a case where the (A) alkali-soluble resin and the (B) radical polymerizable compound are regarded as 100 parts by mass in total, preferably 10 parts by mass or more, more preferably 12 parts by mass or more, still more preferably 14 parts by mass or more, particularly preferably 15 parts by mass or more. When the content is 10 parts by mass or more, the change in pattern opening width between before and after thermal curing can be suppressed. On the other hand, the content of the (C1) photo initiator is preferably 30 parts by mass or less, more preferably 25 parts by mass or less, still more preferably 22 parts by mass or less, particularly preferably 20 parts by mass or less. When the content is 30 parts by mass or less, the resolution after development can be improved, and a cured film in a pattern in a low-taper shape can be obtained.

### <(C2) Photo Acid Generator>

The photosensitive resin composition according to the present invention may further contain a (C2) photo acid generator as the (C) photosensitive agent.

The (C2) photo acid generator refers to a compound that causes bond cleavage upon exposure to generate an acid. Containing the (C2) photo acid generator accelerates UV curing during the exposure, allowing the sensitivity to be improved. Furthermore, the crosslink density after thermal curing of the resin composition is improved, thereby allowing the chemical resistance of the cured film to be improved. Examples of the (C2) photo acid generator include ionic compounds and non-ionic compounds.

As the (C2) photo acid generator of an ionic compound, compounds containing no heavy metal or halogen ion are preferred, and triorganosulfonium salt-based compounds are more preferred. Examples of the triorganosulfonium salt-based compound include methanesulfonate, trifluoromethanesulfonate, camphorsulfonate, or 4-toluenesulfonate of triphenylsulfonium; methanesulfonate, trifluoromethanesulfonate, camphorsulfonate, or 4-toluenesulfonate of dimethyl-1-naphthylsulfonium; methanesulfonate, trifluoromethanesulfonate, camphorsulfonate, or 4-toluenesulfonate of dimethyl(4-hydroxy-1-naphthyl) sulfonium; methanesulfonate, trifluoromethanesulfonate, camphorsulfonate, or 4-toluenesulfonate of dimethyl(4,7-dihydroxy-1-naphthyl) sulfonium; methanesulfonate, trifluoromethanesulfonate, camphorsulfonate, or 4-toluenesulfonate of diphenyliodonium.

Examples of the (C2) photo acid generator of a non-ionic compound include halogen-containing compounds, diazomethane compounds, sulfone compounds, sulfonate ester compounds, carboxylic acid ester compounds, sulfonimide compounds, phosphate ester compounds, and sulfone benzotriazoles compounds.

Among these (C2) photo acid generators, the non-ionic compounds are more preferred than the ionic compounds from the viewpoints of the solubility and the insulation properties of the cured film. From the viewpoint of the strength of the acid generated, those that generate benzenesulfonic acid, 4-toluenesulfonic acid, perfluoroalkylsulfonic acid, or phosphoric acid are more preferred. From the viewpoints of the high sensitivity due to the high quantum yield for j-rays (wavelength: 313 nm), i-rays (wavelength: 365 nm), h-rays (wavelength: 405 nm), or g-rays (wavelength: 436 nm), and the transparency of the cured film, a sulfonic acid ester compound, a sulfonimide compound, or an imino sulfonic acid ester compound is still more preferred.

The content of the (C2) photo acid generator in the photosensitive resin composition according to the present invention is, in a case where the (A) alkali-soluble resin and the (B) radical polymerizable compound are regarded as 100 parts by mass in total, preferably 0.1 parts by mass or more, more preferably 0.5 parts by mass or more, still more preferably 0.7 parts by mass or more, particularly preferably 1 part by mass or more. When the content is 0.1 parts by mass or more, the sensitivity for exposure can be improved. On the other hand, the content of the (C2) photo acid generator is preferably 25 parts by mass or less, more preferably 20 parts by mass or less, still more preferably 17 parts by mass or less, particularly preferably 15 parts by mass or less. When the content is 25 parts by mass or less, the resolution after development can be improved, and a pattern in a low-taper shape can be obtained.

### <(D) Colorant, (Da) Black Colorant, and (Db) Non-black Colorant>

The photosensitive resin composition according to the present invention further contains the (D) colorant. The colorant (D) refers to a compound that absorbs light of a specific wavelength, in particular, a compound which is colored by absorbing light with a wavelength of visible light (380 to 780 nm).

Containing the (D) colorant makes it possible to color a film obtained from the photosensitive resin composition, and makes it possible to impart colorability of coloring the light transmitted through the resin composition film or the light reflected from the resin composition film into a desired color. Furthermore, it is possible to impart a light-blocking property of blocking light with a wavelength absorbed by the (D) colorant, from light transmitted through the resin composition film or light reflected from the resin composition film.

Examples of the colorant (D) include compounds that absorb light with a wavelength of visible light and are colored in red, orange, yellow, green, blue, or purple. Two or more of these colorants are combined, thereby making it possible to improve the toning property of toning light transmitted through the resin composition film or reflected from the resin composition film to desired color coordinates.

The photosensitive resin composition according to the present invention contains, as the (D) colorant, the (Da) black colorant as an essential component. The (Da) black colorant refers to a compound which is colored in black by absorbing light with a wavelength of visible light. Containing the (Da) black colorant makes it possible to improve the light blocking property of blocking the light transmitted through the resin composition film or the light reflected from the resin composition film, because the resin composition film is blackened. Thus, the composition is suitable for applications such as a pixel defining layer, an electrode insulation layer, a wiring insulation layer, an interlayer insulation layer, a TFT planarization layer, an electrode planarization layer, a wiring planarization layer, a TFT protective layer, an electrode protective layer, a wiring protective layer, a gate insulation layer, a color filter, a black matrix, or a black column spacer. The composition is preferred as in particular, a light-blocking pixel defining layer, electrode insulation layer, wiring insulation layer, interlayer insulation layer, TFT planarization layer, electrode planarization layer, wiring planarization layer, TFT protective layer, electrode protective layer, wiring protective layer, or gate insulating layer of an organic EL display protective layer, and suitable for applications which require contrast increased by suppression of external light reflection, such as a light-blocking pixel defining layer, interlayer insulation layer, TFT planarization layer, or TFT protective layer.

The black color in the colorant refers to a color with Color Index Generic Number (hereinafter a “C.I. number”) including “BLACK” therein. The color assigned with no C.I. number refers to a black color in the case of the composition as a cured film. The black color in a mixture of (D) colorants of two or more colors with non-black C.I. numbers, and a mixture of (D) colorants of two or more colors, including at least one (D) colorant assigned with no C.I. number refers to a black color in the case of the composition as a cured film. The black color in the case of the composition a cured film means that in the transmission spectrum of the cured film of the resin composition containing the (D) colorant, based on the Lambert Beer formula, the transmittance per 1.0 μm of the film thickness at a wavelength of 550 nm is converted with the film thickness within the range of 0.1 to 1.5 μm such that the transmittance at a wavelength of 550 nm is 10%, the transmittance at a wavelength of 450 to 650 nm in the converted transmission spectrum is 25% or less.

The transmission spectrum of the cured film can be obtained by the following method. A resin composition containing at least an arbitrary binder resin and the (D) colorant is prepared such that the content ratio of the (D) colorant in the total solid content of the resin composition is 35% by mass. After a film of the resin composition is applied onto a Tempax glass substrate (manufactured by AGC TECHNO GLASS CO., LTD.), the film is prebaked at 110° C. for 2 minutes to form a film, thereby providing a prebaked film. Next, with the use of a high-temperature inert gas oven (INH-9CD-S; manufactured by Koyo Thermo Systems Co., Ltd.), the film is subjected to thermal curing at 250° C. for 60 minutes under a nitrogen atmosphere, thereby preparing a cured film of 1.0 μm in film thickness from the resin composition containing the (D) colorant (hereinafter, “colorant-containing cured film”). In addition, a resin composition containing the binder resin and containing no (D) colorant is prepared, and applied onto a Tempax glass substrate, and prebaked and subjected to thermal curing by the same manner as mentioned above, thereby preparing a cured film of 1.0 μm in film thickness from the resin composition containing no (D) colorant (hereinafter, a “blank cured film”. With the use of a ultraviolet-visible spectrophotometer (MultiSpec-1500; manufactured by Shimadzu Corporation), first, the Tempax glass substrate with the blank cured film formed to have the thickness of 1.0 μm is measured, and the ultraviolet-visible absorption spectrum is regarded as a blank. Next, the Tempax glass substrate with the prepared colorant-containing cured film formed is measured with a single beam, thereby measuring the transmittance per 1.0 μm of the film thickness at a wavelength of 450 to 650 nm, and calculating the transmittance of the colorant-containing cured film from the difference from the blank.

As the (Da) black colorant, a compound which is colored in black by absorbing light of all wavelengths of visible light is preferred from the viewpoint of the light-blocking property. Also preferred is a mixture of two or more (D) colorants selected from red, orange, yellow, green, blue, or purple colorants. Two or more of these (D) colorants are combined, thereby allowing pseudo-coloring in black, and allowing the light-blocking property to be improved.

As the photosensitive resin composition according to the present invention, the (Da) black colorant described above preferably contains one or more selected from a (D1a) black pigment, a (D2a-1) black dye, and a (D2a-2) dye mixture of two or more colors to be described later, and from the viewpoint of light-blocking property, more preferably contains the black pigment (D1a) described later.

The (Db) non-black colorant refers to a compound which is colored by absorbing light with a wavelength of visible light. More specifically, the (Db) non-black colorant is the above-described colorant which is colored in red, orange, yellow, green, blue, or purple, excluding black. Containing the (Da) black colorant and the (Db) non-black colorant makes it possible to impart a light-blocking property as well as colorability and/or a toning property to the resin composition film.

As the photosensitive resin composition according to the present invention, the above-described (Db) non-black colorant preferably contains a (D1b) non-black pigment and/or a (D2b) non-black dye, which will be described later, and from the viewpoints of the light-blocking property, and heat resistance or weather resistance, preferably contains the (D1b) non-black pigment, which will be described later.

In the photosensitive resin composition according to the present invention, the content ratio of the (D) colorant to 100% by mass in total of the (A) alkali-soluble resin, (D) colorant, and (E) dispersant described later is preferably 15% by mass or higher, more preferably 20% by mass or higher, still more preferably 25% by mass or higher, particularly preferably 30% by mass or higher. When the content ratio is 15% by mass or higher, the light-blocking property, the colorability, or the toning property can be improved. On the other hand, the content ratio of the (D) colorant is preferably 80% by mass or lower, more preferably 75% by mass or lower, still more preferably 70% by mass or lower, particularly preferably 65% by mass or lower. When the content ratio is 80% by mass or lower, the sensitivity during the exposure can be improved.

Furthermore, the content ratio of the (D) colorant to the total solid content of the photosensitive resin composition according to the present invention, excluding the solvent, is preferably 5% by mass or higher, more preferably 10% by mass or higher, still more preferably 15% by mass or higher, particularly preferably 20% by mass or higher. When the content ratio is 5% by mass or higher, the light-blocking property, the colorability, or the toning property can be improved. On the other hand, the content ratio of the (D) colorant is preferably 70% by mass or lower, more preferably 65% by mass or lower, still more preferably 60% by mass or lower, even more preferably 55% by mass or lower, particularly preferably 50% by mass or lower. When the content ratio is 70% by mass or lower, the sensitivity for exposure can be improved.

In the photosensitive resin composition according to the present invention, the content ratio of the (Da) black colorant is 5 to 70% by mass in the total solid content. Furthermore, the preferred content ratio of the (Da) black colorant is the same as the preferred content ratio of the (D) colorant described above.

### <(D1) Pigment, (D1-1) Organic Pigment, and (D1-2) Inorganic Pigment>

In the photosensitive resin composition according to the present invention, the above-mentioned (D) colorant preferably contains the (D1) pigment. As an aspect in which the above-described (D) colorant contains the (D1) pigment, the above-described (Da) black colorant is necessarily contained, and the (Db) non-black colorant can be optionally contained.

The (D1) pigment refers to a compound that colors an object with the (D1) pigment physically adsorbed on the surface of the object, or with the interaction between the (D1) pigment and the surface of the object, and typically, the (D1) pigment is insoluble in solvents. In addition, coloring with (D1) pigment has high hiding power, and fading due to ultraviolet rays or the like is less likely to be caused. Containing the (D1) pigment allows coloring in a color with excellent hiding power, and then allows the light-blocking property and weather resistance of the resin composition film to be improved.

The number average particle size of the (D1) pigment is preferably 1 to 1,000 nm, more preferably 5 to 500 nm, still more preferably 10 to 200 nm. When the number average particle size of the (D1) pigment is 1 to 1,000 nm, the light-blocking property of the resin composition film and the dispersion stability of the (D1) pigment can be improved.

In this regard, the number average particle size of the (D1) pigment can be determined by measuring laser scattering (dynamic light scattering method) due to the Brownian motion of the (D1) pigment in the solution, with the use of a submicron particle size distribution measurement device (N4-PLUS; manufactured by Beckman Coulter) or a zeta potential/particle size/molecular weight measurement device (Zeta Sizer Nano ZS; Sysmex Corporation). Furthermore, the number average particle size of the (D1) pigment in the cured film obtained from the resin composition can be determined by measurement with the use of a scanning electron microscope (hereinafter “SEM”) and a transmission electron microscope (hereinafter “TEM”). At the magnification of 50,000 to 200,000 times in SEM and TEM, the number average particle size of the (D1) pigment is directly measured. When the (D1) pigment has a true sphere, the diameter of the true sphere is measured and then regarded as the number average particle size. When the (D1) pigment is not a true sphere, the longest diameter (hereinafter, referred to as a “long axis diameter”) and the longest diameter (hereinafter, referred to as a “short axis diameter”) in a direction perpendicular to the long axis diameter are measured, and the biaxial average diameter obtained by averaging the long axis diameter and the short axis diameter is regarded as the number average particle size.

Examples of the (D1) pigment include the (D1-1) organic pigment and the (Dl-2) inorganic pigment. Examples of the (D1-1) organic pigment include phthalocyanine based pigments, anthraquinone based pigments, quinacridone based pigments, dioxazine based pigments, thioindigo based pigments, diketopyrrolopyrrole based pigments, selenium based pigments, indoline based pigments, benzofuranone based pigments. perylene based pigments, aniline based pigments, azo based pigments, condensed azo based pigments, and carbon black. Examples of the (D1-2) inorganic pigment include graphite or silver-tin alloys, or fine particles of metals such as titanium, copper, iron, manganese, cobalt, chromium, nickel, zinc, calcium, or silver, or oxides, composite oxides, sulfides, sulfates, nitrates, carbonates, nitrides, carbides, or oxynitrides of the metals.

The preferred content ratio of the (D1) pigment, (D1-1) organic pigment, and (D1-2) inorganic pigment to the total solid content of the photosensitive resin composition according to the present invention, excluding the solvent, is the same as the preferred content ratio of the (D) colorant.

### <(D1a) Black Pigment and (D1b) Non-black Pigment>

In the photosensitive resin composition according to the present invention, the (D1) pigment described above preferably contains the (D1a) black pigment, or contains the (D1a) black pigment and the (D1b) non-black pigment.

The (D1a) black pigment refers to a pigment which is colored in black by absorbing light with a wavelength of visible light. Containing the (D1a) black pigment makes the resin composition film blackened, and provides excellent hiding power, thus allowing the light-blocking property of the resin composition film to be improved.

As the photosensitive resin composition according to the present invention, the above-described (Da) black colorant is preferably the (D1a) black pigment, and the (D1a) black pigment is preferably one or more selected from a (D1a-1) black organic pigment, a (D1a-2) black inorganic pigment, and a (D1a-3) coloring pigment mixture of two or more colors which will be described later.

The (D1b) non-black pigment refers to a pigment which is colored in purple, blue, green, yellow, orange, or red, excluding black, by absorbing light with a wavelength of visible light. Containing the (D1b) non-black pigment allows the resin composition film to be colored, and thereby allowing colorability or a toning property to be imparted. Two or more (D1b) non-black pigments are combined, thereby allowing the resin composition film to be toned to desired color coordinates, and then allows the toning property to be improved. Examples of the (D1b) non-black pigment include pigments that are colored in red, orange, yellow, green, blue, or purple, excluding black, which will be described later.

As the photosensitive resin composition according to the present invention, the (D1b) non-black pigment described above is preferably a (D1b-1) non-black organic pigment and/or a (D1b-2) non-black inorganic pigment, which will be described later.

### <(D1a-1) Black Organic Pigment, (D1a-2) Black Inorganic Pigment, and (D1a-3) Coloring Pigment Mixture of Two or More Colors>

As the photosensitive resin composition according to the present invention, the above-described (D1a) black pigment is preferably one or more selected from the (D1a-1) black organic pigment, the (D1a-2) black inorganic pigment, and the (D1a-3) coloring pigment mixture of two or more colors.

The (D1a-1) black organic pigment refers to an organic pigment which is colored in black by absorbing light with a wavelength of visible light. Containing the (D1a-1) black organic pigment makes the resin composition film blackened, and provides excellent hiding power, thus allowing the light-blocking property of the resin composition film to be improved. Furthermore, since the pigment is an organic substance, the chemical structure change or functionality transformation adjusts the transmission spectrum or absorption spectrum of the resin composition film, such as transmitting or blocking light with a desired specific wavelength, thereby making it possible to improve the toning property. In addition, since the (D1a-1) black organic pigment is superior in insulation properties and low dielectric properties, as compared with common inorganic pigments, containing the (D1a-1) black organic pigment is capable of improving the resistance value of the film. In particular, in the case of use as an insulation layer such as a pixel defining layer of an organic EL display, a TFT planarization layer, or a TFT protective layer, defective light emissions can be suppressed, thereby improving reliability.

Examples of the (D1a-1) black organic pigment include anthraquinone-based black pigments, benzofuranone-based black pigments, perylene-based black pigments, aniline-based black pigments, azo-based black pigments, azomethine-based black pigments, and carbon black. Examples of the carbon black include channel black, furnace black, thermal black, acetylene black, and lamp black. From the viewpoint of light-blocking properties, channel black is preferred.

The (D1a-2) black inorganic pigment refers to an inorganic pigment which is colored in black by absorbing light with a wavelength of visible light. Containing the (D1a-2) black inorganic pigment makes the resin composition film blackened, and provides excellent hiding power, thus allowing the light-blocking property of the resin composition film to be improved. Furthermore, since the pigment, which is an inorganic substance, is superior in heat resistance and weather resistance, the heat resistance and weather resistance of the resin composition film can be improved.

Examples of the (D1a-2) black inorganic pigment include graphite, or fine particles, oxides, composite oxides, sulfides, sulfates, nitrates, carbonates, nitrides, carbides, or oxynitrides of metals such as titanium, copper, iron, manganese, cobalt, chromium, nickel, zinc, calcium, or silver. From the viewpoint of improving the light-blocking property, fine particles, oxides, composite oxides, sulfides, nitrides, carbides, or oxynitrides of titanium or silver are preferred, and titanium nitrides or titanium oxynitrides are more preferred.

The (D1a-3) coloring pigment mixture of two or more colors refers to a pigment mixture which is colored in pseudo black by combining two or more pigments selected from red, orange, yellow, green, blue, or purple pigments. Containing the (D1a-3) coloring pigment mixture of two or more colors makes the resin composition film blackened, and provides excellent hiding power, thus allowing the light-blocking property of the resin composition film to be improved. Furthermore, since the two or more color pigments are mixed, the chemical structure change or functionality transformation adjusts the transmission spectrum or absorption spectrum of the resin composition film, such as transmitting or blocking light with a desired specific wavelength, thereby making it possible to improve the toning property.

As the black organic pigment, the black inorganic pigment, the red pigment, the orange pigment, the yellow pigment, the green pigment, the blue pigment, and the purple pigment, known pigments can be used.

### <(D1b-1) Non-Black Organic Pigment, (D1b-2) Non-Black Inorganic Pigment>

As the photosensitive resin composition according to the present invention, the non-black pigment (D1b) described above is preferably the (D1b-1) non-black organic pigment and/or the (D1b-2) non-black inorganic pigment.

The (D1b-1) non-black organic pigment refers to an organic pigment which is colored in red, orange, yellow, green, blue, or purple, excluding black, by absorbing light with a wavelength of visible light. Containing the (D1b-1) non-black organic pigment allows the resin composition film to be colored, thereby allowing colorability or a toning property to be imparted. Furthermore, since the pigment is an organic substance, the chemical structure change or functionality transformation adjusts the transmission spectrum or absorption spectrum of the resin composition film, such as transmitting or blocking light with a desired specific wavelength, thereby making it possible to improve the toning property. Two or more (D1b-1) non-black organic pigments are combined, thereby allowing the resin composition film to be toned to desired color coordinates, and then allows the toning property to be improved. Examples of the (D1b-1) non-black organic pigment include organic pigments that are colored in red, orange, yellow, green, blue, or purple, excluding black.

The (D1b-2) non-black inorganic pigment refers to an inorganic pigment which is colored in red, orange, yellow, green, blue, or purple, excluding black, by absorbing light with a wavelength of visible light. Containing the (D1b-2) non-black inorganic pigment allows the resin composition film to be colored, and thereby allowing colorability or a toning property to be imparted. Furthermore, since the pigment, which is an inorganic substance, is superior in heat resistance and weather resistance, the heat resistance and weather resistance of the resin composition film can be improved. Two or more (D1b-2) non-black inorganic pigments are combined, thereby allowing the resin composition film to be toned to desired color coordinates, and then allows the toning property to be improved. Two or more (D1b-2) non-black inorganic pigments are combined, thereby allowing the resin composition film to be toned to desired color coordinates, and then allows the toning property to be improved. Examples of the (D1b-2) non-black inorganic pigment include inorganic pigments that are colored in red, orange, yellow, green, blue, or purple, excluding black.

### <(D1a-1a) Benzofuranone-Based Black Pigment, (D1a-1b) Perylene-Based Black Pigment, and (D1a-1c) Azo-based Black Pigment>

As the photosensitive resin composition according to the present invention, the above-described (D1a-1) black organic pigment preferably has one or more selected from the group consisting of a (D1a-1a) benzofuranone-based black pigment, a (D1a-1b) perylene-based black pigment, and an (D1a-1c) azo-based black pigment.

Containing one or more selected from the group consisting of the (D1a-1a) benzofuranone-based black pigment, the (D1a-1b) perylene-based black pigment, and the (D1a-1c) azo-based black pigment makes the resin composition film blackened, and provides excellent hiding power, thus allowing the light-blocking property of the resin composition film to be improved. In particular, as compared with common organic pigments, the light-blocking property per unit content ratio of the pigment in the resin composition is excellent, thus allowing the same light-blocking property to be imparted with a low content ratio.

Accordingly, the light-blocking property of the film can be improved, and the sensitivity for exposure can be improved. Furthermore, since the pigment is an organic substance, the chemical structure change or functionality transformation adjusts the transmission spectrum or absorption spectrum of the resin composition film, such as transmitting or blocking light with a desired specific wavelength, thereby making it possible to improve the toning property. In particular, since the transmittance of wavelengths in the near-infrared area (for example, 700 nm or more) can be improved, the composition has a light-blocking property, and the composition is suitable for applications which use light with wavelengths in the near-infrared area. Moreover, as compared with common organic pigments and inorganic pigments, the pigment is excellent in insulation properties and low dielectric properties, the resistance value of a film can be improved. In particular, in the case of use as an insulation layer such as a pixel defining layer of an organic EL display, a TFT planarization layer, or a TFT protective layer, defective light emissions can be suppressed, thereby improving reliability.

In addition, the (D1a-1a) benzofuranone-based black pigment absorbs light with a wavelength of visible light, and at the same time, has a high transmittance for wavelengths in the ultraviolet area (for example, 400 nm or less), and thus, containing the (D1a-1a) benzofuranone-based black pigment allows the sensitivity for exposure to be improved.

The (D1a-1a) benzofuranone-based black pigment refers to a compound with a benzofuran-2(3H)-one structure or a benzofuran-3(2H)-one structure in the molecule, which is colored in black by absorbing light with a wavelength of visible light.

On the other hand, in the case of containing a (D1a-1a) benzofuranone-based black pigment, a development residue derived from the pigment described above may be generated due to the insufficient alkali resistance of the above-described pigment as described above. More specifically, when the surface of the (D1a-1a) benzofuranone-based black pigment described above is exposed to an alkaline developer during development, a part of the surface may be decomposed or dissolved, thereby remaining on the substrate as a development residue derived from the pigment described above. In such a case, as described above, containing the (B3) flexible chain-containing aliphatic radical polymerizable compound and the (B1) fluorene skeleton-containing radical polymerizable compound or (B2) indane skeleton-containing radical polymerizable compound makes it possible to inhibit the development residue generation derived from the pigment described above.

The (D1a-1a) benzofuranone-based black pigment is preferably a benzofuranone compound represented by any of the general formulas (63) to (68), a geometric isomer thereof, a salt thereof, or a salt of the geometric isomer.

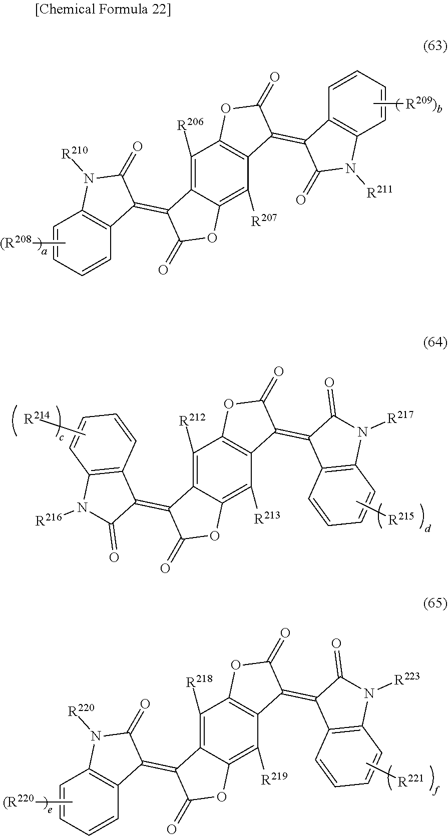

In general formulas (63) to (65), R²⁰⁶, R²⁰⁷, R²¹², R²¹³, R²¹⁸, and R²¹⁹ each independently represent hydrogen, a halogen atom, an alkyl group having 1 to 10 carbon atoms, or an alkyl group having 1 to 10 carbon atoms with 1 to 20 fluorine atoms. R²⁰⁸, R²⁰⁹, R²¹⁴, R²¹⁵, R²²⁰, and R²²¹ each independently represent hydrogen, a halogen atom, R²⁵¹, COOH, COOR^{251,} COO⁻, CONH₂, CONHR²⁵¹, CONR²⁵¹, R²⁵², CN, OH, OR²⁵¹, OCOR²⁵¹, OCONH₂, OCONHR²⁵¹, OCONR²⁵¹, R²⁵², NO₂, NH₂, NHR²⁵¹, NR²⁵¹R²⁵², NHCOR²⁵¹, NR²⁵¹COR²⁵², N═CH₂, N═CHR²⁵¹, N═CR²⁵¹R²⁵², SH, SR²⁵¹, SOR²⁵¹, SO₂R²⁵¹, SO₃R²⁵¹, SO₃H, SO₃⁻, SO₂NH₂, SO₂NHR²⁵¹, or SO₂NR²⁵¹R²⁵², and R²⁵¹ and R²⁵² each independently represent an alkyl group having 1 to 10 carbon atoms, a cycloalkyl group having 4 to 10 carbon atoms, an alkenyl group having 2 to 10 carbon atoms, a cycloalkenyl group having 4 to 10 carbon atoms, or an alkynyl group of 2 to 10 carbon atoms. More than one R²⁰⁸, R²⁰⁹, R²¹⁴, R²¹⁵, R²²⁰, or R²²¹ may form a ring with a direct bond, or an oxygen atom bridge, a sulfur atom bridge, an NH bridge, or an NR²⁵¹ bridge, R²¹⁰, R²¹¹, R²¹⁶, R²¹⁷, R²²², and R²²³ each independently represent hydrogen, an alkyl group having 1 to 10 carbon atoms, or an aryl group having 6 to 15 carbon atoms. a, b, c, d, e, and f each independently represent an integer of 0 to 4. The alkyl group, cycloalkyl group, alkenyl group, cycloalkenyl group, alkynyl group, and aryl group described above may have a hetero atom, and may be either unsubstituted or substituted.

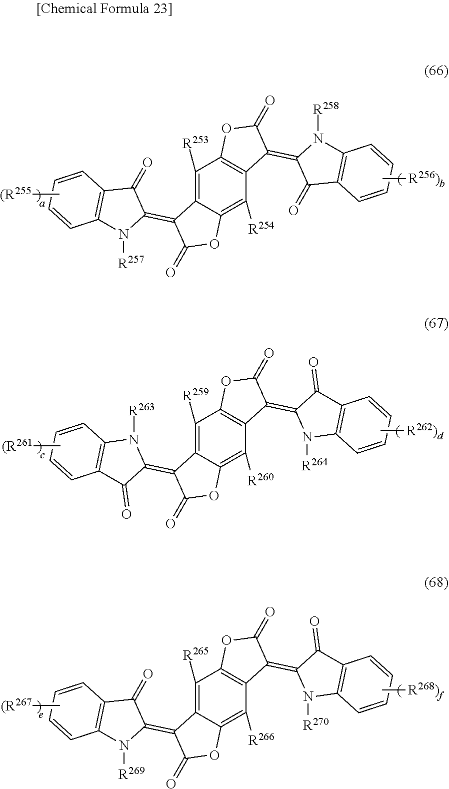

In general formulas (66) to (68), R²⁵³, R²⁵⁴, R²⁵⁹, R²⁶⁰, R²⁶⁵, and R²⁶⁶ each independently represent hydrogen, a halogen atom, an alkyl group having 1 to 10 carbon atoms, or an alkyl group having 1 to 10 carbon atoms with 1 to 20 fluorine atoms. R²⁵⁵, R²⁵⁶, R²⁶¹, R²⁶², R²⁶⁷, and R²⁶⁸ each independently represent hydrogen, a halogen atom, R²⁷¹, COOH, COOR^{271,} COO⁻, CONH₂, CONHR²⁷¹, CONR²⁷¹, R²⁷², CN, OH, OR²⁷¹, OCOR²⁷¹, OCONH₂, OCONHR²⁷¹, OCONR²⁷¹, R²⁷², NO₂, NH₂, NHR²⁷¹, NR²⁷¹R²⁷², NHCOR²⁷¹, NR²⁷¹COR²⁷², N═CH₂, N═CHR²⁷¹, N═CR²⁷¹R²⁷², SH, SR²⁷¹, SOR²⁷¹, SO₂R²⁷¹, SO₃R²⁷¹, SO₃H, SO₃⁻, SO₂NH₂, SO₂NHR²⁷¹, or SO₂NR²⁷¹R²⁷², and R²⁷¹ and R²⁷² each independently represent an alkyl group having 1 to 10 carbon atoms, a cycloalkyl group having 4 to 10 carbon atoms, an alkenyl group having 2 to 10 carbon atoms, a cycloalkenyl group having 4 to 10 carbon atoms, or an alkynyl group of 2 to 10 carbon atoms. More than one R²⁵⁵, R²⁵⁶, R²⁶¹, R²⁶², R^{267,} or R²⁶⁸ may form a ring with a direct bond, or an oxygen atom bridge, a sulfur atom bridge, an NH bridge, or an NR²⁷¹ bridge. R²⁵⁷, R²⁵⁸, R²⁶³, R²⁶⁴, R²⁶⁹, and R²⁷⁰ each independently represent hydrogen, an alkyl group having 1 to 10 carbon atoms, or an aryl group having 6 to 15 carbon atoms. a, b, c, d, e, and f each independently represent an integer of 0 to 4. The alkyl group, cycloalkyl group, alkenyl group, cycloalkenyl group, alkynyl group, and aryl group described above may have a hetero atom, and may be either unsubstituted or substituted.

Examples of the (D1a-1a) benzofuranone-based black pigment include “IRGAPHOR” (registered trademark) BLACK S0100CF (manufactured by BASF), the black pigment described in International Publication No. 2010/081624, or the black pigment described in International Publication No. 2010/081756.

The (D1a-1b) perylene-based black pigment refers to a compound with a perylene structure in the molecule, which is colored in black by absorbing light with a wavelength of visible light.

The (D1a-1b) perylene-based black pigment is preferably a perylene compound represented by any of the general formulas (69) to (71), a geometric isomer thereof, a salt thereof, or a salt of the geometric isomer.

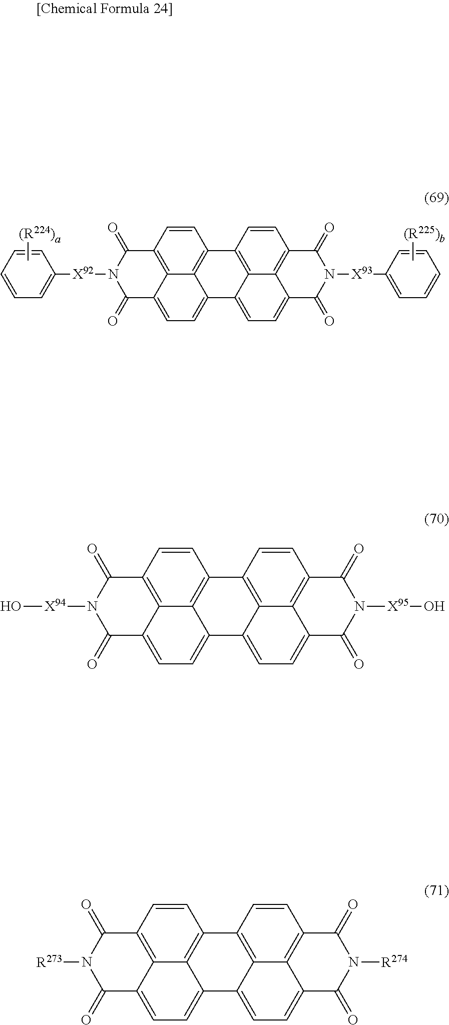

In the general formulas (69) to (71), X⁹², X⁹³, X⁹⁴, and X⁹⁵ each independently represent an alkylene chain having 1 to 10 carbon atoms. R²²⁴ and R²²⁵ each independently represent hydrogen, a hydroxy group, an alkoxy group having 1 to 6 carbon atoms, or an acyl group having 2 to 6 carbon atoms. R²⁷³ and R²⁷⁴ each independently represent hydrogen or an alkyl group having 1 to 10 carbon atoms. a and b each independently represent an integer of 0 to 5. The alkylene chain, alkoxy group, acyl group, and alkyl group described above may have a hetero atom, and may be either unsubstituted or substituted.

Examples of the (D1a-1b) perylene-based black pigment include pigment black 31 or 32 (the numerical values are both C.I. numbers). [0353]

The examples include, besides the pigments described above, “PALIOGEN” (registered trademark) BLACK 50084, K0084, L0086, K0086, EH0788, or FK4281 (all manufactured by BASF).

The (D1a-1c) azo-based black pigment refers to a compound with an azo group in the molecule, which is colored in black by absorbing light with a wavelength of visible light. The (D1a-1c) azo-based black pigment is preferably an azo compound represented by general formula (72).

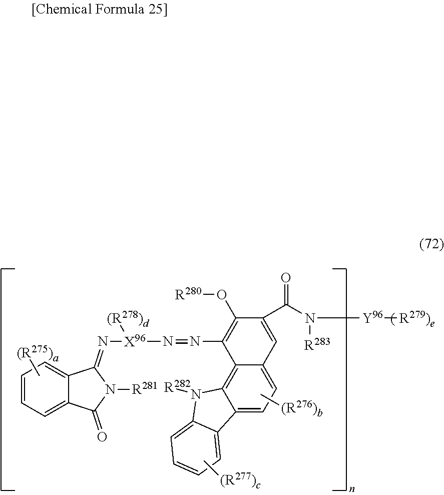

In the general formula (72), X⁹⁶ represents an arylene chain having 6 to 15 carbon atoms. Y⁹⁶ represents an arylene chain having 6 to 15 carbon atoms. R^{275,} R^{276,} and R²⁷⁷ each independently represent a halogen or an alkyl group having 1 to 10 carbon atoms. R²⁷⁸ represents halogen, an alkyl group having 1 to 10 carbon atoms, an alkoxy group having 1 to 6 carbon atoms, or a nitro group. R²⁷⁹ represents halogen, an alkyl group having 1 to 10 carbon atoms, an alkoxy group having 1 to 6 carbon atoms, an acylamino group having 2 to 10 carbon atoms, or a nitro group. R²⁸⁰, R²⁸¹, R^{282,} and R²⁸³ each independently represent hydrogen or an alkyl group having 1 to 10 carbon atoms. a represents an integer of 0 to 4, b represents an integer of 0 to 2, c represents an integer of 0 to 4, d and e each independently represent an integer of 0 to 8, and n represents an integer of 1 to 4. The above-mentioned arylene chain, alkyl group, alkoxy group, and acylamino group may have a hetero atom, and may be either unsubstituted or substituted.

Examples of the (D1a-1c) azo-based black pigment include “CHROMOFINE” (registered trademark) BLACK A1103 (manufactured by Dainichiseika Color & Chemicals Mfg. Co., Ltd.), the black pigment described in JP 01-170601 A, or the black pigment described in JP 02-034664 A.

The content ratio of one or more selected from the group consisting of the (D1a-1a) benzofuranone-based black pigment, the (D1a-1b) perylene-based black pigment, and the (D1a-1c) azo-based black pigment in the total solid content of the photosensitive resin composition according to the present invention, excluding the solvent, is preferably 5% by mass or higher, more preferably 10% by mass or higher, still more preferably 15% by mass or higher, particularly preferably 20% by mass or higher. When the content ratio is 5% by mass or higher, the light-blocking property and the toning property can be improved. On the other hand, content ratio of one or more selected from the group consisting of the (D1a-1a) benzofuranone-based black pigment, the (D1a-1b) perylene-based black pigment, and the (D1a-1c) azo-based black pigment is preferably 70% by mass or lower, more preferably 65% by mass or lower, still more preferably 60% by mass or lower, even more preferably 55% by mass or lower, particularly preferably 50% by mass or lower. When the content ratio is 70% by mass or lower, the sensitivity for exposure can be improved.

### <(DC) Covering Layer>

As the photosensitive resin composition according to the present invention, the (D1a-1) black organic pigment preferably further contains a (DC) covering layer. The (DC) covering layer refers to a layer covering a pigment surface, which is formed by a treatment such as a surface treatment with a silane coupling agent, a surface treatment with a silicate, a surface treatment with a metal alkoxide, or a covering treatment with a resin, for example.

Containing the (DC) covering layer makes it possible to modify the surface condition of the particles, such as acidifying or basifying the particle surfaces of the (D1a-1) black organic pigment or making the particle surfaces hydrophilic or hydrophobic, and then makes it possible to improve the acid resistance, the alkali resistance, the solvent resistance, the dispersion stability, the heat resistance, and the like. Thus, the development residue generation derived from a pigment can be inhibited. In addition, side etching during development is suppressed, a pattern in a low-taper shape can be formed after development, and reflow of the pattern skirt during thermal curing is suppressed, and thus, the change in pattern opening width between before and after thermal curing can be suppressed. In addition, since it is possible to form a pattern in a low-taper shape by controlling the pattern shape after development, the halftone characteristics can be improved. In addition, an insulating covering layer is formed on the particle surfaces to improve the insulation properties of the cured film for reduction in leakage current and the like, thereby allowing display reliability and the like to be improved.

In the case of containing, in particular, the (D1a-1a) benzofuranone-based black pigment as the (D1a-1) black organic pigment, the (D1a-1a) benzofuranone-based black pigment contains therein the (DC) covering layer, thereby allowing the alkali resistance of the pigment to be improved, and then allowing the development residue generation derived from the pigment to be inhibited.

The average coverage of the (DC) covering layer with respect to the (D1a-1) black organic pigment is preferably 50% or higher, preferably 70% or higher, more preferably 80% or higher, still more preferably 90% or higher. When the average coverage of the (DC) covering layer is 80% or higher, the residue generation during development can be inhibited.

For the average coverage of the (DC) covering layer with respect to the (D1a-1) black organic pigment, a cross section is observed at a magnification of 50,000 to 200,000 times under the condition of an acceleration voltage of 300 kV with the use of a transmission electron microscope (H9500; manufactured by Hitachi High-Technologies Corporation), and for 100 black pigment particles randomly selected, the average coverage N (%) can be determined by determining the coverage M (%) for each black pigment from the following formula, and calculating the number average value.

Coverage M (%)={(L1/(L1+L2)}×100

L1: the total length (nm) of a site of the outer periphery of a particle, covered with the covering layer

L2: the total length (nm) of a site of the outer periphery of the particle, covered with no covering layer (the site with the interface and the embedded resin in direct contact)

L1+L2: the outer peripheral length (nm) of a particle

### <(DC-1) Silica Covering Layer, (DC-2) Metal Oxide Covering Layer, and (DC-3) Metal Hydroxide Covering Layer>

The (DC) covering layer preferably contains one selected from the group consisting of a (DC-1) silica covering layer, a (DC-2) metal oxide covering layer, and a (DC-3) metal hydroxide covering layer. The silica, the metal oxide, and the metal hydroxide have the function of imparting alkali resistance to the pigment, thus the development residue generation derived from the pigment to be inhibited.

The silica included in the (DC-1) silica covering layer refers to a general term for silicon dioxide and hydrates thereof. The metal oxide included in the (DC-2) metal oxide covering layer refers to a general term for metal oxides and hydrates thereof. Examples of the metal oxide include alumina as an example, and include alumina (Al₂O₃) or an alumina hydrate (Al₂O₃·nH₂O), for example. Examples of the metal hydroxide contained in the (DC-3) metal hydroxide covering layer include an aluminum hydroxide (Al(OH)₃). Because silica has a low dielectric constant, the dielectric constant of the pixel defining layer, TFT planarization layer, or TFT protective layer can be kept from being increased, even in a case where the content of the (DC) covering layer of the (D1a-1) black organic pigment is high.

The (DC-1) silica covering layer, (DC-2) metal oxide covering layer, and (DC-3) metal hydroxide covering layer of the (DC) covering layer can be analyzed by, for example, an X-ray diffraction method. Examples of the X-ray diffractometer include a powder X-ray diffractometer (manufactured by Mac Science). The mass of the silicon atoms or metal atoms contained in the (DC-1) silica covering layer, (DC-2) metal oxide covering layer, and (DC-3) metal hydroxide covering layer is rounded to one decimal place to calculate the value down to the first decimal place. In addition, the mass of the pigment particles, excluding the (DC) covering layer, contained in the (D1a-1) black organic pigment including the (DC) covering layer can be determined by the following method, for example. After the operation of putting the pigment with the mass measured in a mortar, grinding the pigment with a pestle for the removal of the (DC) covering layer, then dissolving only the pigment particles by immersion in an amide-based solvent such as N,N-dimethylformamide, and removing the particles as filtrate, is repeated until the filter cake completely loses the blackness, the mass of the filter cake is measured, and the mass of the pigment particles is calculated from the difference from the pigment mass.

The metal oxide or metal hydroxide contained in the (DC-2) metal oxide covering layer or (DC-3) metal hydroxide covering layer preferably has both chemical durability such as alkali resistance, heat resistance and light resistance, and physical durability such as Vickers hardness that can withstand mechanical energy input appropriately optimized in the dispersion step, and wear resistance. Examples of the metal oxide and metal hydroxide include alumina, zirconia, zinc oxides, titanium oxides, and ferric oxides. Alumina or zirconia is preferred from the viewpoint of insulation properties, and ultraviolet transmittance and near-infrared transmittance, and alumina is more preferred from the viewpoint of dispersibility in alkali-soluble resins and solvents. The metal oxide and the metal hydroxide may be surface-modified with a group including an organic group.

In a case where the (DC) covering layer contains the (DC-1) silica covering layer, an alumina covering layer is formed as the (DC-2) metal oxide covering layer on the surface of the (DC-1) silica covering layer, thereby a decrease in pattern linearity to be suppressed. Since alumina is effective for dispersibility improvement in an aqueous pigment suspension even in the pigment granulation step performed after the pigment surface treatment step, the secondary aggregation particle diameter can be adjusted to a desired range, and furthermore, the productivity and quality stability can be improved. As the (DC-2) metal oxide covering layer contained in the (DC) covering layer, the covering amount of the alumina covering layer is preferably 10 parts by mess or more, more preferably 20 parts by weight or more, in a case where the silica contained in the (DC-1) silica covering layer is regarded as 100 parts by mass.

In the case of the (DC) covering layer containing the (DC-1) silica covering layer, the silica content is preferably 1 part by mass or more, more preferably 2 parts by mass or more, still more preferably 5 parts by mass or more, in a case where the pigment particles are regarded as 100 parts by mass. The content is adjusted to 1 part by mass or more, thereby making it possible to increase the coverage on the pigment particle surface and inhibit the development residue generation derived from the pigment. On the other hand, the content of the silica is preferably 20 parts by mass or less, more preferably 10 parts by mass or less. The content is adjusted to 20 parts by mass or less, thereby allowing the pattern linearity of the pixel defining layer, TFT planarization layer, or TFT protective layer to be improved.

In the case of the (DC) covering layer containing the (DC-2) metal oxide covering layer and/or the (DC-3) metal hydroxide covering layer, the total content of metal oxide and metal hydroxide is preferably 0.1 parts by mass or more, more preferably 0.5 parts by mass or more, in a case where the pigment particles are regarded as 100 parts by mass. The total content is adjusted to 0.1 parts by mass or more, the dispersibility and the pattern linearity can be improved. On the other hand, the total content of the metal oxide and metal hydroxide is preferably 15 parts by mass or less, more preferably 10 parts by mass or less. The total content is adjusted to 15 parts by mass or less, thereby making it possible to keep the concentration gradient of the pigment from being generated, and improve the storage stability of the coating liquid, in the photosensitive composition according to the present invention, which is designed to make the viscosity lower, preferably, provide a viscosity of 15 mPa·s or lower.

It is to be noted that the content of the silica refers to the silicon dioxide equivalent value calculated from the content of silicon atoms, which refers to a SiO₂ equivalent value, including cases where there is not only a single component in the (DC) covering layer and at the surface layer, and cases where the amount of dehydration varies due to thermal history. The contents of the metal oxide and metal hydroxide refer to the metal oxide and metal hydroxide equivalent values calculated from the metal atom content. More specifically, in the case of alumina, zirconia, and titanium oxide, the contents respectively refer to an Al₂O₃equivalent value, a ZrO₂ equivalent value, and a TiO₂ equivalent value. In addition, the total content of the metal oxide and metal hydroxide refers to the content in the case of containing either the metal oxide or the metal hydroxide, or refers to the total content in the case of containing the both.

The (DC) covering layer may be surface-modified with an organic group by using a silane coupling agent, with, as a reactive site, hydroxy at the surface of the silica, metal oxide, or metal hydroxide contained in the (DC-1) silica covering layer, (DC-2) metal oxide covering layer, or (DC-3) metal hydroxide covering layer. As the organic group, an ethylenically unsaturated double bond group is preferred. The surface modification with a silane coupling agent having an ethylenically unsaturated double bond group is capable of imparting radical polymerizability to the (D1a-1) black organic pigment, and suppressing film peeling at the cured part, thereby inhibiting the development residue generation derived from the pigment at the unexposed part.

As the (D1a-1) black organic pigment including the (DC) covering layer, the outermost layer may be further subjected to a surface treatment with an organic surface treatment agent. The outermost layer is subjected to the surface treatment, thereby allowing the wettability to the resin or the solvent to be improved. The (DC) covering layer may further contain a resin covering layer formed by a covering treatment with a resin. Containing the resin covering layer provides particle surfaces coated with an insulating resin with low conductivity, thereby allowing the particle surface condition to be modified, and allowing the light-blocking and insulating properties of the cured film to be improved.

### <(D2) Dye>

In the photosensitive resin composition according to the present invention, the above-mentioned (D) colorant preferably contains a (D2) pigment. As an aspect in which the (D) colorant described above contains the (D2) dye, it is preferable to contain the (D2) dye as the colorant other than the (Da) black colorant and/or (Db) non-black colorant described above.

The (D2) dye refers to a compound that colors an object by chemical adsorption or strong interaction of a substituent such as an ionic group or a hydroxy group in the (D2) dye on or with the surface structure of the object, and the compound is typically soluble in solvents and the like. In addition, coloring with the (D2) dye is high in coloring power and high in coloring efficiency, because each molecule is adsorbed to an object.

Containing the (D2) dye allows coloring in a color which is excellent in coloring power, and then allows the colorability and toning property of the resin composition film to be improved. Examples of the (D2) dye include direct dyes, reactive dyes, sulfur dyes, vat dyes, acid dyes, metal-containing dyes, metal-containing acid dyes, basic dyes, mordant dyes, acid mordant dyes, dispersive dyes, and cationic dyes, and fluorescent whitening dyes.

In this regard, the dispersive dye refers to a dye that is insoluble or poorly soluble in water, without having an anionic ionization group such as a sulfonic acid group or a carboxy group.

Examples of the (D2) dye include anthraquinone-based dyes, azo-based dyes, azine-based dyes, phthalocyanine-based dyes, methine-based dyes, oxazine-based dyes, quinoline-based dyes, indigo-based dyes, indigoid-based dyes, carbonium-based dyes, selenium-based dyes, perinone-based dyes, perylene-based dyes, triarylmethane-based dyes, and xanthene-based dyes. Anthraquinone-based dyes, azo-based dyes, azine-based dyes, methine-based dyes, triarylmethane-based dyes, and xanthene-based dyes are preferred from the viewpoints of solubility in solvents to be described later and heat resistance.

As the photosensitive resin composition according to the present invention, the above-described (D2) dye preferably contains one or more selected from the (D2a-1) black dye, the (D2a-2) dye mixture of two or more colors, and the (D2b) non-black dye, which will be described later.

The content ratio of the (D2) dye to the total solid content of the photosensitive resin composition according to the present invention, excluding the solvent, is preferably 0.01% by mass or higher, more preferably 0.05% by mass or higher, still more preferably 0.1% by mass or higher. When the content ratio is 0.01% by mass or higher, the colorability or the toning property can be improved. On the other hand, the content ratio of the (D2) dye is preferably 50% by mass or lower, more preferably 45% by mass or lower, still more preferably 40% by mass or lower. When the content ratio is 50% by mass or lower, the heat resistance of the cured film can be improved.

### <(D2a-1) Black Dye, (D2a-2) Dye Mixture of Two or More Colors, and (D2b) Non-Black Dye>

As the photosensitive resin composition according to the present invention, the (D2) dye described above preferably contains one or more selected from the (D2a-1) black dye, the (D2a-2) dye mixture of two or more colors, and the (D2b) non-black dye.

The (D2a-1) black dye refers to a dye which is colored in black by absorbing light with a wavelength of visible light. Containing the (D2a-1) black dye makes the resin composition film blackened, and provides excellent colorability, thus allowing the light-blocking property of the resin composition film to be improved.

The (D2a-2) dye mixture of two or more colors refers to a dye mixture which is colored in pseudo black by combining two or more dyes selected from white, red, orange, yellow, green, blue, or purple dyes. Containing the (D2a-2) dye mixture of two or more colors makes the resin composition film blackened, and provides excellent colorability, thus allowing the light-blocking property of the resin composition film to be improved. Furthermore, since the two o more dyes are mixed, the adjustment of the transmission spectrum or absorption spectrum of the resin composition film, such as transmitting or blocking light with a desired specific wavelength, makes it possible to improve the toning property. As the black dye, the red dye, the orange dye, the yellow dye, the green dye, the blue dye, and the purple dye, known dyes can be used.

The (D2b) non-black dye refers to a dye that is colored in white, red, orange, yellow, green, blue, or purple, excluding black, by absorbing light with a wavelength of visible light. Containing the (D2b) non-black dye allows the resin composition film to be colored, and thereby allowing colorability or a toning property to be imparted. Two or more (D2b) non-black dyes are combined, thereby allowing the resin composition film to be toned to desired color coordinates, and then allows the toning property to be improved. Examples of the (D2b) non-black dye include dyes that are colored in white, red, orange, yellow, green, blue, or purple, excluding black, which are described above.

The cured film obtained by curing the photosensitive resin composition according to the present invention preferably has an optical density of 0.3 or more, more preferably 0.5 or more, even more preferably 0.7 or more, particularly preferably 1.0 or more, per film thickness of 1 μm. When the optical density per film thickness of 1 μm is 0.3 or more, the cured film allows the light-blocking property to be improved, thus making it possible to prevent electrode wirings form being made visible or reduce external light reflection, and then allowing the contrast in image display to be improved, in display devices such as an organic EL display or a liquid crystal display. For this reason, the composition is suitable for applications such as a pixel defining layer, an electrode insulation layer, a wiring insulation layer, an interlayer insulation layer, a TFT planarization layer, an electrode planarization layer, a wiring planarization layer, a TFT protective layer, an electrode protective layer, a wiring protective layer, a gate insulation layer, a color filter, a black matrix, or a black column spacer. The composition is preferred as in particular, a light-blocking pixel defining layer, electrode insulation layer, wiring insulation layer, interlayer insulation layer, TFT planarization layer, electrode planarization layer, wiring planarization layer, TFT protective layer, electrode protective layer, wiring protective layer, or gate insulating layer of an organic EL display protective layer, and suitable for applications which require contrast increased by suppression of external light reflection, such as a light-blocking pixel defining layer, interlayer insulation layer, TFT planarization layer, or TFT protective layer. On the other hand, the optical density per film thickness of 1 μm is preferably 5.0 or less, more preferably 4.0 or less, still more preferably 3.0 or less. When the optical density per film thickness of 1 μm is 5.0 or less, the sensitivity for exposure can be improved, and a cured film in a pattern in a low-taper shape can be obtained. The optical density of the cured film per film thickness of 1 μm can be adjusted depending on the composition and content ratio of the colorant (D) described above.

### <(E) Dispersant>

The photosensitive resin composition according to the present invention preferably further contains the (E) dispersant. The (E) dispersant refers to a compound having a surface affinity group that interacts with the surface of a dispersive dye or the like as the (D1) pigment and/or the (D2) dye described above, and a dispersion-stabilization structure that improves the dispersion stability of a dispersive dye as the (D1) pigment and/or the (D2) dye. Examples of the dispersion stabilization structure of the (E) dispersant include a polymer chain and/or a substituent with an electrostatic charge.

Containing the (E) dispersant allows, in a case where the photosensitive resin composition contains a dispersive dye as the (D1) pigment and/or the (D2) dye, the dispersion stability to be improved, and then allows the resolution after development to be improved. In particular, for example, in a case where the (D1) pigment has particles crushed to a number average particle size of 1 μm or less, the particle surface area of the (D1) pigment is increased, thus making particle aggregation of the (D1) pigment more likely to be caused. On the other hand, in the case of containing the (E) dispersant, the interaction between the surface of the crushed (D1) pigment and the surface affinity group of the (E) dispersant, and the steric hindrance and/or electrostatic repulsion due to the dispersion-stabilization structure of the (E) dispersant make it possible to inhibit the particle aggregation of the (D1) pigment, thereby improving the dispersion stability.

Examples of the (E) dispersant having a surface affinity group include a (E) dispersant having only a basic group, a (E) dispersant having a basic group and an acidic group, and a (E) dispersant having only an acidic group, and a (E) dispersant having neither a basic group nor an acidic group. From the viewpoint of improving the dispersion stability of the particles of the (D1) pigment, the (E) dispersant having only a basic group and the (E) dispersant having a basic group and an acidic group are preferred. In addition, the basic group and/or the acidic group which serve as surface affinity group(s) also preferably have a structure that forms a salt with an acid and/or base.

Examples of the basic group of the (E) dispersant or the structure thereof that forms a salt include a tertiary amino group or a quaternary ammonium salt structure, or nitrogen-containing ring skeletons such as a pyrrolidine skeleton, a pyrrole skeleton, an imidazole skeleton, a pyrazole skeleton, a triazole skeleton, a tetrazole skeleton, an imidazoline skeleton, an oxazole skeleton, an isoxazole skeleton, an oxazoline skeleton, an isoxazoline skeleton, a thiazole skeleton, an isothiazole skeleton, a thiazoline skeleton, an isothiazoline skeleton, a triazine skeleton, a piperidine skeleton, a piperazine skeleton, a morpholine skeleton, a pyridine skeleton, a pyridazine skeleton, a pyrimidine skeleton, a pyrazine skeleton, a triazine skeleton, an isocyanuric acid skeleton, an imidazolidinone skeleton, a propylene urea skeleton, a butylene urea skeleton, a hydantoin skeleton, a barbituric acid skeleton, an alloxan skeleton, or a glycoluril skeleton.

From the viewpoint of improving the dispersion stability and the resolution after development, a tertiary amino group or a quaternary ammonium salt structure, or a nitrogen ring-containing skeleton such as or a pyrrole skeleton, an imidazole skeleton, a pyrazole skeleton, a pyridine skeleton, a pyridazine skeleton, a pyrimidine skeleton, a pyrazine skeleton, a triazine skeleton, an isocyanuric acid skeleton, an imidazolidinone skeleton, a propylene urea skeleton, a butylene urea skeleton, a hydantoin skeleton, a barbituric acid skeleton, an alloxan skeleton, or a glycoluril skeleton is preferred as the basic group or the structure thereof that forms a salt.

Examples of the (E) dispersant having only a basic group include “DISPERBYK” (registered trademark) −108, −160, −167, −182, −2000, or −2164 and “BYK” (registered trademark) −9075, -LP-N6919, or -LP-N21116 (all manufactured by BYK-Chemie Japan), “EFKA” (registered trademark) 4015, 4050, 4080, 4300, 4400, or 4800 (all manufactured by BASF), “Ajisper” (registered trademark) PB711 (manufactured by Ajinomoto Fine-Techno Co., Inc.), and “SOLSPERSE” (registered trademark) 13240, 20000 or 71000 (all manufactured by Lubrizol).

Examples of the (E) dispersant having a basic group and an acidic group include “ANTI-TERRA” (registered trademark) -U100 or -204, “DISPERBYK” (registered trademark) −106, −140, −145, −180, −191, −2001, or −2020, and “BYK” (registered trademark) −9076 (manufactured by BYK-Chemie Japan), “Ajisper” (registered trademark) PB821 or PB881 (all manufactured by Ajinomoto Fine-Techno Co., Inc.), and “SOLSPERSE” (registered trademark) 9000, 13650, 24000, 33000, 37500, 39000, 39000, 56000, or 76500 (all manufactured by Lubrizol).

Examples of the (E) dispersant having only an acidic group include “DISPERBYK” (registered trademark) −102, −118, −170 or −2096, “BYK” (registered trademark) −P104 or −220S. (all manufactured by BYK-Chemie Japan), and “SOLSPERSE” (registered trademark) 3000, 16000, 21000, 36000, or 55000 (all manufactured by Lubrizol).

Examples of the dispersant (E) having neither a basic group nor an acidic group include “DISPERBYK” (registered trademark) −103, −192, −2152, or −2200 (all manufactured by BYK-Chemie Japan), and “SOLSPERSE” (registered trademark) 27000, 54000, or X300 (all manufactured by Lubrizol).

The amine value of the (E) dispersant is preferably 5 mgKOH/g or more, more preferably 8 mgKOH/g or more, and still more preferably 10 mgKOH/g or more. When the amine value is 5 mgKOH/g or more, the dispersion stability of the (D1) pigment can be improved. On the other hand, the amine value is preferably 150 mgKOH/g or less, more preferably 120 mgKOH/g or less, still more preferably 100 mgKOH/g or less. When the amine value is 150 mgKOH/g or less, the storage stability of the resin composition can be improved.

The amine value herein refers to the weight of potassium hydroxide that is equivalent to an acid that reacts with per 1 g of the (E) dispersant, and the unit is mgKOH/g. The amine value can be determined by neutralization of 1 g of the (E) dispersant with an acid, and then titration with an aqueous potassium hydroxide solution. From the amine value, the amine equivalent (unit: g/mol), which refers to the resin weight per 1 mol of basic groups such as amino groups, can be calculated, and the number of basic groups such as amino groups in the (E) dispersant can be determined.

The acid value of the (E) dispersant is preferably 5 mgKOH/g or more, more preferably 8 mgKOH/g or more, and still more preferably 10 mgKOH/g or more. When the acid value is 5 mgKOH/g or more, the dispersion stability of the (D1) pigment can be improved. On the other hand, the acid value is preferably 200 mgKOH/g or less, more preferably 170 mgKOH/g or less, still more preferably 150 mgKOH/g or less. When the acid value is 200 mgKOH/g or less, the storage stability of the resin composition can be improved.

The acid value herein refers to the weight of potassium hydroxide that reacts with 1 g of the (E) dispersant, and the unit is mgKOH/g. The acid value can be determined by titrating 1 g of the (E) dispersant with an aqueous potassium hydroxide solution. From the acid value, the acid equivalent (unit: g/mol), which refers to the resin weight per 1 mol of acidic groups, can be calculated, and the number of acidic groups in the (E) dispersant can be determined.

Examples of the (E) dispersant having a polymer chain, acrylic resin-based dispersants, polyoxyalkylene ether-based dispersants, polyester-based dispersants, polyurethane-based dispersants, polyol-based dispersants, polyethyleneimine-based dispersants, and polyallylamine-based dispersants. From the viewpoint of patternability with an alkaline developer, acrylic resin-based dispersants, polyoxyalkylene ether-based dispersants, polyester-based dispersants, polyurethane-based dispersants, and polyol-based dispersants are preferred.

In a case where the photosensitive resin composition according to the present invention contains a dispersive dye as the (D1) pigment and/or the (D2) dye, the content ratio of the (E) dispersant in the photosensitive resin composition according to the present invention is, in a case where the total of the (D1) pigment and/or dispersive dye and the (E) dispersant is regarded as 100% by mass, preferably 1% by mass or higher, more preferably 5% by mass or higher, still more preferably 10% by mass or higher. When the content ratio is 1% by mass or higher, the dispersion stability of the (D1) pigment and/or dispersive dye can be improved, and the resolution after development can be improved. On the other hand, the content ratio of the (E) dispersant is preferably 60% by mass or lower, more preferably 55% by mass or lower, still more preferably 50% by mass or lower. When the content ratio is 60% by mass or lower, the heat resistance of the cured film can be improved.

### <(F) Cross-Linking Agent>

The photosensitive resin composition according to the present invention further contains the (F) cross-linking agent. The (F) cross-linking agent refers to a compound having a cross-linkable group capable of binding to the (A) alkali-soluble resin or the like.

Containing the (F) cross-linking agent allows the hardness and chemical resistance of the cured film to be improved. This is presumed to be because the (F) cross-linking agent is capable of introducing a new cross-linked structure into the cured film of the resin composition, thus improving the crosslink density.

In addition, containing the (F) cross-linking agent makes it possible to form a pattern in a low-taper shape after thermal curing. This is believed to be because the (F) cross-linking agent forms a cross-linked structure between the polymers, thereby inhibiting the tight orientation of the polymer chains, and then making it possible to maintain the reflow property of the pattern during thermal curing, and thus allowing a pattern in a low-taper shape to be formed.

As the (F) cross-linking agent, a compound having two or more thermal crosslinkable properties in the molecule, is preferred, such as an alkoxymethyl group, a methylol group, an epoxy group, or an oxetanyl group.

Examples of the compound having two or more alkoxymethyl groups or methylol groups in the molecule include DML-PC, DML-OC, DML-PTBP, DML-PCHP, DML-MBPC, DML-MTrisPC, DMOM-PC, DMOM-PTBP, TriML-P, TriML-35XL, TML-HQ, TML-BPA, TML-BPAF, TML-BPAP, TMOM-BPA, TMOM-BPAF, TMOM-BPAP, HML-TPHAP, or HMOM-TPHAP (all manufactured by Honshu Chemical Industry Co., Ltd.), and “NIKALAC” (registered trademark) MX-290, MX-280, MX-270, MX-279, MW-100LM, MW-30HM, MW-390, or MX-750LM (manufactured by SANWA CHEMICAL CO., LTD.)

Examples of the compound having two or more epoxy groups in the molecule include “Epolite” (registered trademark) 40E, 100E, 400E, 70P, 1500NP, 80MF, 3002, or 4000 (all manufactured by Kyoeisha Chemical Co., Ltd.), “Denacol” (registered trademark) EX-212L, EX-216L, EX-321L, or EX-850L (all manufactured by Nagase ChemteX Corporation), “jER” (registered trademark) 828, 1002, 1750, YX8100-BH30, E1256, or E4275 (all manufactured by Mitsubishi Chemical Corporation), GAN, GOT, EPPN-502H, NC-3000, or NC-6000 (all manufactured by Nippon Kayaku Co., Ltd.), “EPICLON” (registered trademark) EXA-9583, HP4032, N695, or HP7200 (all manufactured by Dainippon Ink and Chemicals Inc.), “TECHMORE” (registered trademark) VG-3101L (PRINTEC, INC.), and “Epototo” (registered trademark) YH-434L (manufactured by Tohto Kasei Co., Ltd.).

Examples of the compound having two or more oxetanyl groups in the molecule include “ETERNACOLL” (registered trademark) EHO, OXBP, OXTP, or OXMA (all manufactured by Ube Industries, Ltd.), and oxetanized phenol novolac.

The content of the (F) cross-linking agent in the photosensitive resin composition according to the present invention is, in a case where the total of the (A) alkali-soluble resin and (B) radical polymerizable compound is regarded as 100 parts by mass, preferably 0.5 parts by mass or more, more preferably 1 part by mass or more, still more preferably 2 parts by mass or more, even more preferably 3 parts by mass or more, particularly preferably 5 parts by mass or more. When the content is 0.5 parts by mass or more, the hardness and chemical resistance of the cured film can be improved, and a pattern in a low-taper shape can be formed after thermal curing. On the other hand, the content of the (F) cross-linking agent is preferably 50 parts by mass or less, more preferably 40 parts by mass or less, still more preferably 30 parts by mass or less, even more preferably 25 parts by mass or less, particularly preferably 20 parts by mass or less. When the content is 50 parts by mass or less, the hardness and chemical resistance of the cured film can be improved, and a pattern in a low-taper shape can be formed after thermal curing.

### <Specific (F) Cross-Linking Agent>

The photosensitive resin composition according to the present invention contains, as the (F) cross-linking agent, one or more (hereinafter referred to as a “specific (F) cross-linking agent”) selected from the group consisting of an (F1) epoxy compound having a fluorene skeleton and two or more epoxy groups in the molecule, an (F2) epoxy compound having an indane skeleton and two or more epoxy groups in the molecule, an (F3) epoxy resin having a structural unit including an aromatic structure, an alicyclic structure, and an epoxy group, an (F4) epoxy resin having a structural unit including one or more selected from the group consisting of a biphenyl structure, a terphenyl structure, a naphthalene structure, an anthracene structure, and a fluorene structure, and including two or more epoxy groups, an (F5) epoxy compound having two or more fluorene skeletons or two or more indane skeletons, and two or more epoxy groups in the molecule, an (F6) epoxy compound having two or more condensed polycyclic skeletons linked by a spiro skeleton, and two or more epoxy groups in the molecule, an (F7) epoxy compound having an indolinone skeleton or an isoindolinone skeleton, and two or more epoxy groups in the molecule, and an (F8) epoxy compound having two or more naphthalene skeletons and two or more epoxy groups in the molecule.

<(F1) Epoxy Compound having Fluorene Skeleton and Two or More Epoxy Groups in Molecule and (F2) Epoxy Compound having Indane Skeleton and Two or More Epoxy Groups in Molecule>

Containing the (F1) epoxy compound having a fluorene skeleton and two or more epoxy groups in the molecule or the (F2) an epoxy compound having an indane skeleton and two or more epoxy groups in the molecule makes it possible to improve the sensitivity for exposure and control the pattern shape after development, and makes it possible to form a pattern in a low-taper shape after thermal curing. This is presumed to be because in the UV-cured film upon exposure, the above-described epoxy compound is incorporated into the cured film due to the formation of an interpenetrating polymer network (hereinafter referred to as an “IPN”) structure. More specifically, with the introduction of the fluorene skeleton or indane skeleton derived from the epoxy compound described above, the molecular weight of the film is dramatically improved even in UV curing with low exposure energy, thereby making the composition insoluble in an alkaline developer, and the sensitivity for exposure is thus presumed to be improved. In addition, it is believed that, since the fluorene skeleton and the indane skeleton are hydrophobic, the hydrophobicity of the UV-cured film is improved, thereby suppressing the penetration of the alkaline developer, and making it possible to suppress, in particular, side etching in the deep part of the film, which is likely to be subjected to insufficient UV curing. Thus, the taper inversed after development is inhibited, thereby making it possible to control the pattern shape after development, such as, making it possible to form a pattern in a forward tapered shape after development. In addition to the inhibition of the taper inversed after development, the steric hindrance of the fluorene skeleton or indane skeleton is presumed to inhibit excessive curing during UV curing, thereby making it possible to maintain the reflow property of the tapered part of the pattern during thermal curing, and thus allowing a pattern in a low-taper shape to be formed.

In addition, containing the (F1) epoxy compound having a fluorene skeleton and two or more epoxy groups in the molecule or the (F2) epoxy compound having an indane skeleton and two or more epoxy groups in the molecule allows a pattern in a forward tapered shape to be formed by controlling the pattern shape after development, thus making it possible to improve the halftone characteristics. This is believed to be because, due to the hydrophobicity of the fluorene skeleton or indane skeleton, during alkali development, it is possible to suppress side etching of the halftone exposed part cured incompletely, and control the solubility of the halftone exposed part in alkali.

Furthermore, containing the (F1) epoxy compound having a fluorene skeleton and two or more epoxy groups in the molecule or the (F2) epoxy compound having an indane skeleton and two or more epoxy groups in the molecule allows the change in pattern opening width between before and after thermal curing to be suppressed. This is believed to be due to the fact that the fluorene skeleton and the indane skeleton are hydrophobic as mentioned above. More specifically, it is presumed that because side etching during development at the depth part of the film, which is likely to be subjected to insufficient UV curing, is suppressed, thereby allowing a pattern in a forward tapered shape to be formed after development, the suppressed reflow of the pattern skirt during thermal curing allows the change in pattern opening width between before and after thermal curing to be suppressed. In addition, the fact that the molecular weight of the film is drastically improved with the fluorene skeleton or indane skeleton is introduced into the UV-cured film during exposure, thereby suppressing reflow of the pattern skirt during thermal curing is also considered as a factor.

As the (F1) epoxy compound having a fluorene skeleton and two or more epoxy groups in the molecule, a compound represented by general formula (11) is preferred. As the (F2) epoxy compound having an indane skeleton and two or more epoxy groups in the molecule, a compound represented by general formula (12) and a compound represented by general formula (13) are preferred.

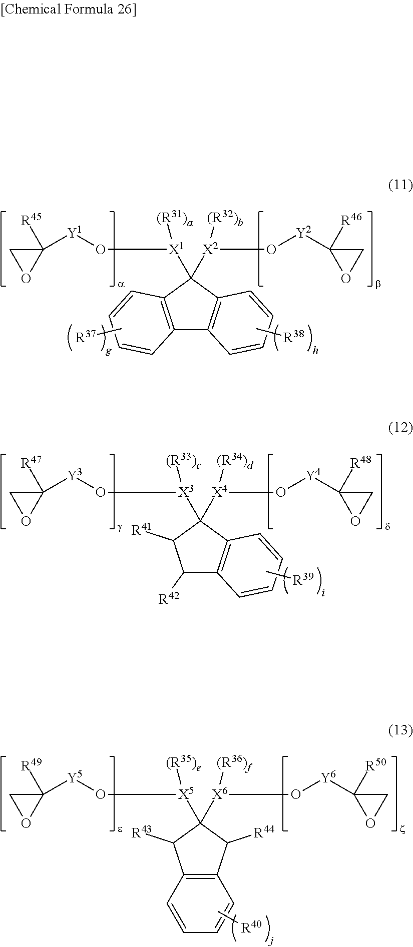

In the general formulas (11), (12), and (13), X¹ to X⁶ each independently represent a divalent to decavalent monocyclic or condensed polycyclic aromatic hydrocarbon ring having 6 to 15 carbon atoms, or a divalent to octavalent monocyclic or condensed polycyclic aliphatic hydrocarbon ring having 4 to 10 carbon atoms. Y¹ to Y⁶ each independently represent a direct bond, an alkylene group having 1 to 10 carbon atoms, a cycloalkylene group having 4 to 10 carbon atoms, or an arylene group having 6 to 15 carbon atoms. R³¹ to R⁴° each independently represent halogen, an alkyl group having 1 to 10 carbon atoms, a cycloalkyl group having 4 to 10 carbon atoms, an aryl group having 6 to 15 carbon atoms, a fluoroalkyl group having 1 to 10 carbon atoms, a fluorocycloalkyl group having 4 to 10 carbon atoms, or a fluoroaryl group having 6 to 15 carbon atoms, R⁴¹ to R⁴⁴ each independently represent hydrogen, an alkyl group having 1 to 10 carbon atoms, or a cycloalkyl group having 4 to 10 carbon atoms, or an aryl group having 6 to 15 carbon atoms, and R⁴⁵ to R⁵⁰ each independently represent hydrogen, an alkyl group having 1 to 10 carbon atoms, or a hydroxy group. a, b, c, d, e, and f each independently represent an integer of 0 to 8, and g, h, i, and j each independently represent an integer of 0 to 4. α, β, γ, δ, ε, and each independently represent an integer of 1 to 4. In the general formulas (11), (12) and (13), X¹ to X⁶ each independently preferably represent a divalent to decavalent monocyclic or condensed polycyclic aromatic hydrocarbon ring having 6 to 10 carbon atoms. The monocyclic or condensed polycyclic aromatic hydrocarbon ring, monocyclic or condensed polycyclic aliphatic hydrocarbon ring, alkylene group, cycloalkylene group, arylene group, alkyl group, cycloalkyl group, and aryl group, fluoroalkyl group, fluorocycloalkyl group, and fluoroaryl group described above may have a hetero atom, and may be either unsubstituted or substituted.

The epoxy equivalent of the (F1) epoxy compound having a fluorene skeleton and two or more epoxy groups in the molecule and (F2) epoxy compound having an indane skeleton and two or more epoxy groups in the molecule is preferably 150 g/mol or more, more preferably 170 g/mol or more, still more preferably 190 g/mol or more, particularly preferably 210 g/mol or more. When the epoxy equivalent is 150 g/mol or more, a pattern in a low-taper shape can be formed after thermal curing. On the other hand, the epoxy equivalent of the (F1) epoxy compound having a fluorene skeleton and two or more epoxy groups in the molecule and (F2) epoxy compound having an indane skeleton and two or more epoxy groups in the molecule is preferably 800 g/mol or less, more preferably 600 g/mol or less, still more preferably 500 g/mol or less, particularly preferably 400 g/mol or less. When the epoxy equivalent is 800 g/mol or less, the change in pattern opening width between before and after thermal curing can be suppressed.

Examples of the (F1) epoxy compound having a fluorene skeleton and two or more epoxy groups in the molecule include 9,9-bis[4-(2-glycidoxyethoxy)phenyl]fluorene, 9,9-bis[4-(3-glycidoxypropoxy)phenyl]fluorene, 9,9-bis[4-((3-glycidoxy)hexyloxy)phenyl]fluorene, 9,9-bis[4-(2-glycidoxyethoxy))-3-methylphenyl]fluorene, 9,9-bis[4-(2-glycidoxyethoxy)-3,5-dimethylphenyl]fluorene, 9,9-bis(4-glycidoxyphenyl)fluorene, 9,9-bis[4-(2-hydroxy-3-glycidoxypropoxy)phenyl]fluorene, 9,9-bis[4-(2-hydroxy-3-glycidoxypropoxy)-3-methylphenyl]fluorene, 9,9-bis[4-(2-hydroxy-3-glycidoxypropoxy)-3,5-dimethylphenyl]fluorene, 9,9-bis[3-phenyl-4-(2-glycidoxyethoxy)phenyl]fluorene, 9,9-bis[4-(2-glycidoxyethoxy)-1-naphthyl]fluorene, 9,9-bis[4′-(2-glycidoxyethoxy)-(1,1′-biphenyl)-4-yl]fluorene, 9,9-bis[3,4-bis(2-glycidoxyethoxy)phenyl]fluorene, or 9-[3,4-bis(2-glycidoxyethoxy)phenyl]-9-[4-(2-glycidoxyethoxy)phenyl]fluorene, OGSOL (registered trademark) PG, PG-100, EG, EG-200, EG-210, EG-280, CG-400,or CG-500 (all manufactured by Osaka Gas Chemicals Co., Ltd.), or Oncoat (registered trademark) EX-1010, EX-1011, EX-1012, EX-1020, EX-1030, EX-1040, EX-1050, EX-1051, EX-1020M80, or EX-1020M70 (all manufactured by Nagase ChemteX Corporation).

Examples of the (F2) epoxy compound having an indane skeleton and two or more epoxy groups in the molecule include 1,1-bis[4-(2-glycidoxyethoxy)phenyl]indane, 1,1-bis[4-(3-glycidoxypropoxy)phenyl]indane, 1,1-bis[4-(3-glycidoxyhexyloxy)phenyl]indane, 1,1-bis[4-(2-glycidoxyethoxy))-3-methylphenyl]indane, 1,1-bis[4-(2-glycidoxyethoxy)-3,5-dimethylphenyl]indane, 1,1-bis(4-glycidoxyphenyl)indane, 1,1-bis[4-(2-hydroxy-3-glycidoxypropoxy)phenyl]indane, 1,1-bis[4-(2-hydroxy-3-glycidoxypropoxy)-3-methylphenyl]indane, 1,1-bis[4-(2-hydroxy-3-glycidoxypropoxy)-3,5-dimethylphenyl]indane, 1,1-bis[4-(2-glycidoxyethoxy)phenyl]-3-phenylindane, 1,1-bis[3-phenyl-4-(2-glycidoxyethoxy)phenyl]indane, 1,1-bis[4-(2-glycidoxyethoxy)-1-naphthyl]indane, 1,1-bis[3,4-bis(2-glycidoxyethoxy)phenyl]indane, 2,2-bis[4-(2-glycidoxyethoxy)phenyl]indane, 2,2-bis[4-(3-glycidoxypropoxy)phenyl]indane, 2,2-bis[4-[(3-glycidoxy)hexyloxy]phenyl]indane, 2,2-bis[4-(2-glycidoxyethoxy)-3-methylphenyl]indane, 2,2-bis(4-glycidoxyphenyl)indane, 2,2-bis[4-(2-hydroxy-3-glycidoxypropoxy)phenyl]indane, 2,2-bis[3-phenyl-4-(2-glycidoxyethoxy)phenyl]indane, 2,2-bis[4-(2-glycidoxyethoxy)-1-naphthyl]indane, or 2,2-bis[3,4-bis(2-glycidoxyethoxy)phenyl]indane.

The (F1) epoxy compound having a fluorene skeleton and two or more epoxy groups in the molecule, and the (F2) epoxy compound having an indane skeleton and two or more epoxy groups in the molecule can be synthesized by known methods.

The total content of the (F1) epoxy compound having a fluorene skeleton and two or more epoxy groups in the molecule and (F2) epoxy compound having an indane skeleton and two or more epoxy groups in the molecule in the photosensitive resin composition according to the present invention is, in a case where the total of the (A) alkali-soluble resin and (B) radical polymerizable compound is regarded as 100 parts by mass, preferably 0.5 parts by mass or more, more preferably 1 part by mass or more, still more preferably 2 parts by mass or more, even more preferably 3 parts by mass or more, particularly preferably 5 parts by mass or more. When the content is 0.5 parts by mass or more, the sensitivity for exposure can be improved, and a pattern in a low-taper shape can be formed. In addition, the change in pattern opening width between before and after thermal curing can be suppressed. On the other hand, the total content of the (F1) epoxy compound having a fluorene skeleton and two or more epoxy groups in the molecule and (F2) epoxy compound having an indane skeleton and two or more epoxy groups in the molecule is preferably 50 parts by mass or less, more preferably 40 parts by mass or less, still more preferably 30 parts by mass or less, even more preferably 25 parts by mass or less, particularly preferably 20 parts by mass or more. When the content is 50 parts by mass or less, the change in pattern opening width between before and after thermal curing can be suppressed, and the residue generation after development can be inhibited.

<(F3) Epoxy Resin having Structural Unit Including Aromatic Structure, Alicyclic Structure, and Epoxy Group and (F4) Epoxy Resin having Structural Unit Including One or More Selected from the Group Consisting of Biphenyl Structure, Terphenyl Structure, Naphthalene Structure, Anthracene Structure, and Fluorene Structure and Two or More Epoxy Groups>

Containing the (F3) epoxy resin having a structural unit including an aromatic structure, n alicyclic structure, and an epoxy group or the (F4) epoxy resin having a structural unit including one or more selected from the group consisting of a biphenyl structure, a terphenyl structure, a naphthalene structure, an anthracene structure, and a fluorene structure and two or more epoxy groups makes it possible to improve the sensitivity for exposure and control the pattern shape after development, and makes it possible to form a pattern in a low-taper shape after thermal curing. This is presumed to be because in the UV-cured film upon exposure, the above-described epoxy resin is incorporated into the cured film due to the formation of an IPN structure. More specifically, with the introduction of the aromatic structure, alicyclic structure, or polycyclic aromatic structure derived from the epoxy resin described above, the molecular weight of the film is dramatically improved even in UV curing with low exposure energy, thereby making the composition insoluble in an alkaline developer, and the sensitivity for exposure is thus presumed to be improved. In addition, it is believed that, since the aromatic structure, the alicyclic structure, or the polycyclic aromatic structure is hydrophobic, the hydrophobicity of the UV-cured film is improved, thereby suppressing the penetration of the alkaline developer, and making it possible to suppress, in particular, side etching in the deep part of the film, which is likely to be subjected to insufficient UV curing. Thus, the taper inversed after development is inhibited, thereby making it possible to control the pattern shape after development, such as, making it possible to form a pattern in a forward tapered shape after development. In addition to the inhibition of the taper inversed after development, the steric hindrance of the aromatic structure, alicyclic structure, or polycyclic aromatic structure is presumed to inhibit excessive curing during UV curing, thereby making it possible to maintain the reflow property of the tapered part of the pattern during thermal curing, and thus allowing a pattern in a low-taper shape to be formed.

In addition, containing the (F3) epoxy resin having a structural unit including an aromatic structure, n alicyclic structure, and an epoxy group or the (F4) epoxy resin having a structural unit including one or more selected from the group consisting of a biphenyl structure, a terphenyl structure, a naphthalene structure, an anthracene structure, and a fluorene structure and two or more epoxy groups allows a pattern in a forward tapered shape to be formed by controlling the pattern shape after development, thus making it possible to improve the halftone characteristics.

Furthermore, containing the (F3) epoxy resin having a structural unit including an aromatic structure, n alicyclic structure, and an epoxy group or the (F4) epoxy resin having a structural unit including one or more selected from the group consisting of a biphenyl structure, a terphenyl structure, a naphthalene structure, an anthracene structure, and a fluorene structure and two or more epoxy groups allows the change in pattern opening width between before and after thermal curing to be suppressed.

As the (F3) epoxy resin having a structural unit including an aromatic structure, n alicyclic structure, and an epoxy group, an epoxy resin having a structural unit represented by general formula (14) is preferred. As the (F4) epoxy resin having a structural unit including one or more selected from the group consisting of a biphenyl structure, a terphenyl structure, a naphthalene structure, an anthracene structure, and a fluorene structure and two or more epoxy groups, an epoxy resin having a structural unit represented by general formula (15) or a structural unit represented by general formula (16) is preferred.

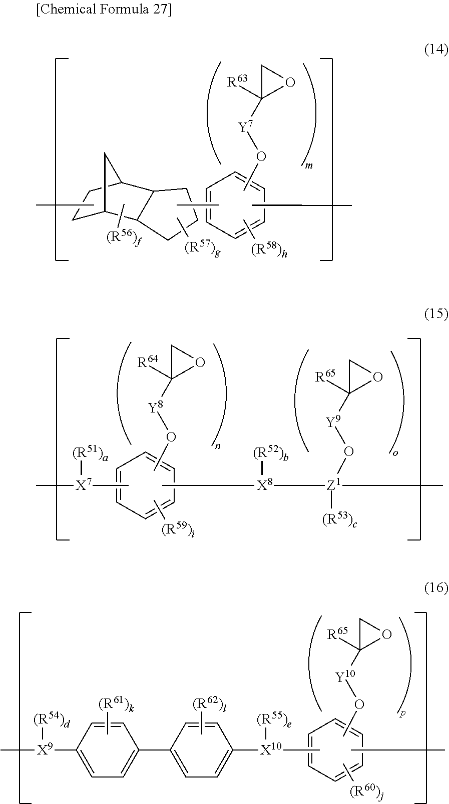

In the general formulas (14), (15), and (16), X⁷ to X¹⁰ each independently represent an aliphatic structure having 1 to 6 carbon atoms. Y⁷ to Y¹⁰ each independently represent a direct bond, an alkylene group having 1 to 10 carbon atoms, a cycloalkylene group having 4 to 10 carbon atoms, or an arylene group having 6 to 15 carbon atoms. Z¹ represents a trivalent to 16-valent aromatic structure having 10 to 25 carbon atoms. R⁵¹ to R⁵⁵ each independently represent an alkyl group having 1 to 10 carbon atoms, a cycloalkyl group having 4 to 10 carbon atoms, or an aryl group having 6 to 15 carbon atoms, and R⁵⁶ and R⁵⁷ each independently represent an alkyl group having 1 to 10 carbon atoms, R⁵⁸ to R⁶² each independently represent halogen, an alkyl group having 1 to 10 carbon atoms, a cycloalkyl group having 4 to 10 carbon atoms, or an aryl group having 6 to 15 carbon atoms, and R⁶³ to R⁶⁶ each independently represent hydrogen, an alkyl group having 1 to 10 carbon atoms, or a hydroxy group. a, b, c, d, and e each independently represent an integer of 0 to 10, f represents an integer of 0 to 8, g represents an integer of 0 to 6, h and i each independently represent an integer of 0 to 3, j represents an integer of 0 to 2, k and 1 each independently represent an integer of 0 to 4, m, n, and o each independently represent an integer of 1 to 4, and p represents an integer of 2 to 4. The aliphatic structure, alkylene group, cycloalkylene group, arylene group, aromatic structure, alkyl group, cycloalkyl group, and aryl group described above may have a hetero atom, and may be either unsubstituted or substituted.

The aromatic structure for Z¹ of the general formula (15) contains one or more selected from the group consisting of a terphenyl structure, a naphthalene structure, an anthracene structure, and a fluorene structure. Other aromatic structures for Z¹ of the general formula (15) include a 1,2,3,4-tetrahydronaphthalene structure, a 2,2-diphenylpropane structure, a diphenyl ether structure, a diphenyl ketone structure, and a diphenyl sulfone structure.

The epoxy equivalent of the (F3) epoxy resin having a structural unit including an aromatic structure, n alicyclic structure, and an epoxy group and (F4) epoxy resin having a structural unit including one or more selected from the group consisting of a biphenyl structure, a terphenyl structure, a naphthalene structure, an anthracene structure, and a fluorene structure and two or more epoxy groups is preferably 150 g/mol or more, more preferably 170 g/mol or more, still more preferably 190 g/mol or more, particularly preferably 210 g/mol or more. When the epoxy equivalent is 150 g/mol or more, a pattern in a low-taper shape can be formed after thermal curing. On the other hand, the epoxy equivalent of the (F3) epoxy resin having a structural unit including an aromatic structure, n alicyclic structure, and an epoxy group and (F4) epoxy resin having a structural unit including one or more selected from the group consisting of a biphenyl structure, a terphenyl structure, a naphthalene structure, an anthracene structure, and a fluorene structure and two or more epoxy groups is preferably 800 g/mol or less, more preferably 600 g/mol or less, still more preferably 500 g/mol or less, particularly preferably 400 g/mol or less. When the epoxy equivalent is 800 g/mol or less, the change in pattern opening width between before and after thermal curing can be suppressed.

Examples of the (F3) epoxy resin having a structural unit including an aromatic structure, n alicyclic structure, and an epoxy group include XD-1000, XD-1000-2L, XD-1000-H, XD-1000-2H, or XD-1000-FH (all manufactured by Nippon Kayaku Co., Ltd.).

Examples of the (F4) epoxy resin having a structural unit including one or more selected from the group consisting of a biphenyl structure, a terphenyl structure, a naphthalene structure, an anthracene structure, and a fluorene structure and two or more epoxy groups include NC-7000L, NC-7000H, NC-7300L, NC-7700, or NC-3500 (all manufactured by Nippon Kayaku Co., Ltd.).

The (F3) epoxy resin having a structural unit including an aromatic structure, n alicyclic structure, and an epoxy group and the (F4) epoxy resin having a structural unit including one or more selected from the group consisting of a biphenyl structure, a terphenyl structure, a naphthalene structure, an anthracene structure, and a fluorene structure and two or more epoxy groups can be synthesized by known methods.

The total content of the (F3) epoxy resin having a structural unit including an aromatic structure, n alicyclic structure, and an epoxy group and (F4) epoxy resin having a structural unit including one or more selected from the group consisting of a biphenyl structure, a terphenyl structure, a naphthalene structure, an anthracene structure, and a fluorene structure and two or more epoxy groups in the photosensitive resin composition according to the present invention is, in a case where the total of the (A) alkali-soluble resin and (B) radical polymerizable compound is regarded as 100 parts by mass, preferably 0.5 parts by mass or more, more preferably 1 part by mass or more, still more preferably 2 parts by mass or more, even more preferably 3 parts by mass or more, particularly preferably 5 parts by mass or more. When the content is 0.5 parts by mass or more, the sensitivity for exposure can be improved, and a pattern in a low-taper shape can be formed. In addition, the change in pattern opening width between before and after thermal curing can be suppressed. On the other hand, the total content of the (F3) epoxy resin having a structural unit including an aromatic structure, an alicyclic structure, and an epoxy group and (F4) epoxy resin having a structural unit including one or more selected from the group consisting of a biphenyl structure, a terphenyl structure, a naphthalene structure, an anthracene structure, and a fluorene structure and two or more epoxy groups in the photosensitive resin composition according to the present invention is preferably 50 parts by mass or less, more preferably 40 parts by mass or less, still more preferably 30 parts by mass or less, even more preferably 25 parts by mass or less, particularly preferably 20 parts by mass or less. When the content is 50 parts by mass or less, a pattern in a low-taper shape can be formed after thermal curing, and the residue generation after development can be inhibited.

<(F5) Epoxy Compound having Two or More Fluorene Skeletons or Two or More Indane Skeletons and Two or More Epoxy Groups in Molecule, (F6) Epoxy Compound having Two or More Condensed Polycyclic Skeletons Linked by Spiro Skeleton and Two or More Epoxy Groups in Molecule, (F7) Epoxy Compound having Indolinone Skeleton or Isoindolinone Skeleton and Two or More Epoxy Groups in Molecule, and (F8) Epoxy Compound having Two or More Naphthalene Skeletons and Two or More Epoxy Groups in Molecule>

Containing the (F5) compound, (F6) compound, (F7) compound, or (F8) compound described above makes it possible to improve the sensitivity for exposure and control the pattern shape after development, and makes it possible to form a pattern in a low-taper shape after thermal curing. This is presumed to be because in the UV-cured film upon exposure, the above-described epoxy resin is incorporated into the cured film due to the formation of an IPN structure. More specifically, with the introduction of the fluorene skeleton, condensed polycyclic skeletons linked by the spiro skeleton, indolinone skeleton, isoindolinone skeleton, or a naphthalene skeleton derived from the epoxy resin described above, the molecular weight of the film is dramatically improved even in UV curing with low exposure energy, thereby making the composition insoluble in an alkaline developer, and the sensitivity for exposure is thus presumed to be improved. In addition, it is believed that, since the skeletons are hydrophobic, the hydrophobicity of the UV-cured film is improved, thereby suppressing the penetration of the alkaline developer, and making it possible to suppress, in particular, side etching in the deep part of the film, which is likely to be subjected to insufficient UV curing. Thus, the taper inversed after development is inhibited, thereby making it possible to control the pattern shape after development, such as, making it possible to form a pattern in a forward tapered shape after development. In addition to the inhibition of the taper inverted after development, the steric hindrance of the skeletons is presumed to inhibit excessive curing during UV curing, thereby making it possible to maintain the reflow property of the tapered part of the pattern during thermal curing, and thus allowing a low-taper pattern to be formed.

In addition, containing the (F5) compound, the (F6) compound, the (F7) compound, or the (F8) compound allows a pattern in a forward tapered shape to be formed by controlling the pattern shape after development, thus making it possible to improve the halftone characteristics. This is believed to be because, due to the hydrophobicity of the skeleton mentioned above, during alkali development, it is possible to suppress side etching of the halftone exposed part cured incompletely, and control the solubility of the halftone exposed part in alkali.

Further, containing the (F5) compound, the (F6) compound, the (F7) compound, or the (F8) compound allows the change in pattern opening width between before and after thermal curing to be suppressed. This is also believed to be due to the fact that the skeletons mentioned above are hydrophobic. More specifically, it is presumed that because side etching during development at the depth part of the film, which is likely to be subjected to insufficient UV curing, is suppressed, thereby allowing a pattern in a forward tapered shape to be formed after development, the suppressed reflow of the pattern skirt during thermal curing allows the change in pattern opening width between before and after thermal curing to be suppressed. In addition, the fact that the molecular weight of the film is drastically improved with the skeleton is introduced into the UV-cured film during exposure, thereby suppressing reflow of the pattern skirt during thermal curing is also considered as a factor.

As the (F5) the epoxy compound having two or more fluorene skeletons or two or more indane skeletons and two or more epoxy groups in the molecule, compounds represented by general formulas (81) to (83) are preferred.

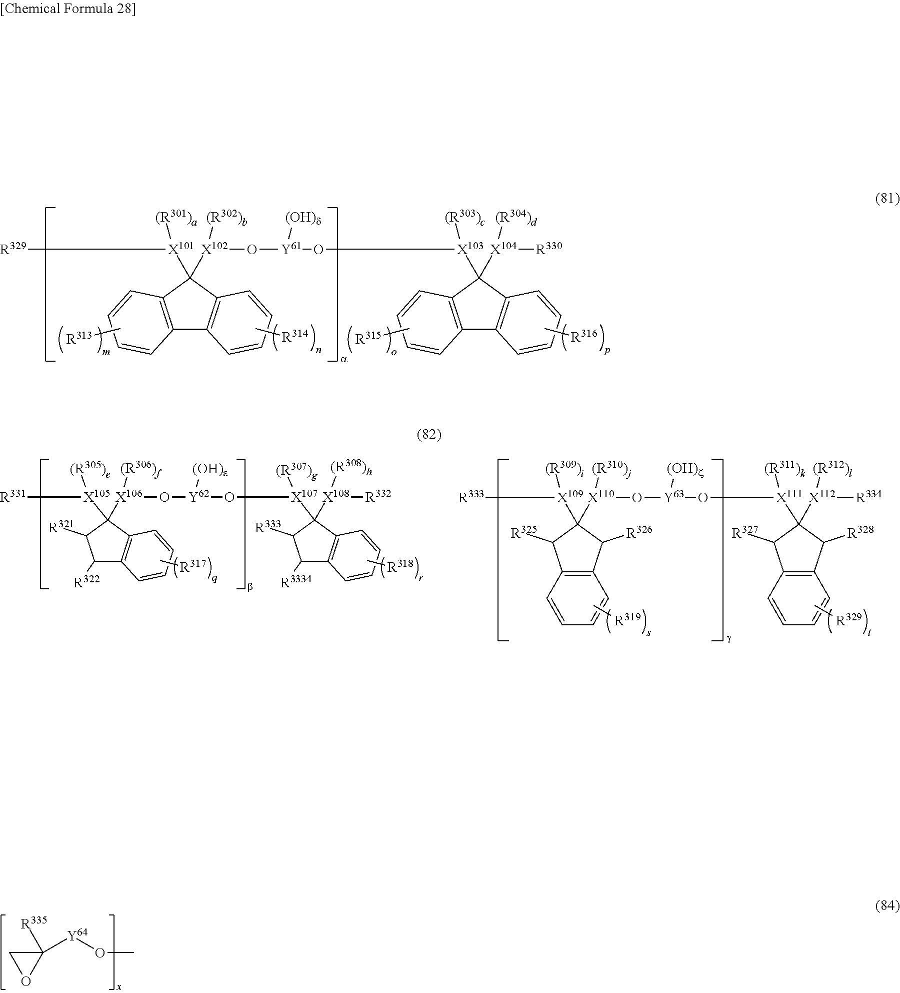

In the general formulas (81) to (83), X¹⁰¹ to X¹¹² each independently represent a divalent to decavalent monocyclic or condensed polycyclic aromatic hydrocarbon ring having 6 to 15 carbon atoms, or a divalent to octavalent monocyclic or condensed polycyclic aliphatic hydrocarbon ring having 4 to 10 carbon atoms. Y⁶¹ to Y⁶³ each independently represent an alkylene group having 1 to 10 carbon atoms, a cycloalkylene group having 4 to 10 carbon atoms, or an arylene group having 6 to 15 carbon atoms. Y⁶⁴ represents a direct bond, an alkylene group having 1 to 10 carbon atoms, a cycloalkylene group having 4 to 10 carbon atoms, or an arylene group having 6 to 15 carbon atoms. R³⁰¹ to R³²⁰ each independently represent halogen, an alkyl group having 1 to 10 carbon atoms, a cycloalkyl group having 4 to 10 carbon atoms, an aryl group having 6 to 15 carbon atoms, a fluoroalkyl group having 1 to 10 carbon atoms, a fluorocycloalkyl group having 4 to 10 carbon atoms, or a fluoroaryl group having 6 to 15 carbon atoms. R³²¹ to R³²⁸ each independently represent hydrogen, an alkyl group having 1 to 10 carbon atoms, a cycloalkyl group having 4 to 10 carbon atoms, or an aryl group having 6 to 15 carbon atoms. R³²⁹ to R³³⁴ represent a group represented by general formula (84). R³³⁵ represents hydrogen, an alkyl group having 1 to 10 carbon atoms, or a hydroxy group. a, b, c, d, e, f, g, h, i, j, k, and 1 each independently represent an integer of 0 to 8. m, n, o, p, q, r, s, and t each independently represent an integer of 0 to 4. x represents an integer of 1 to 4. α, β, and γ and each independently represent an integer of 1 to 10. δ, ε, and ζ each independently represent 0 or 1. In the general formulas (81) to (83), X¹⁰¹ ln to X¹¹² each independently preferably represent a divalent to decavalent monocyclic or condensed polycyclic aromatic hydrocarbon ring having 6 to 10 carbon atoms. The monocyclic or condensed polycyclic aromatic hydrocarbon ring, monocyclic or condensed polycyclic aliphatic hydrocarbon ring, alkylene group, cycloalkylene group, arylene group, alkyl group, cycloalkyl group, and aryl group, fluoroalkyl group, fluorocycloalkyl group, and fluoroaryl group described above may have a hetero atom, and may be either unsubstituted or substituted.

As the (F6) epoxy compound having two or more condensed polycyclic skeletons linked by the spiro skeleton and two or more epoxy groups in Molecule, compounds represented by general formulas (85) to (87) are preferred.

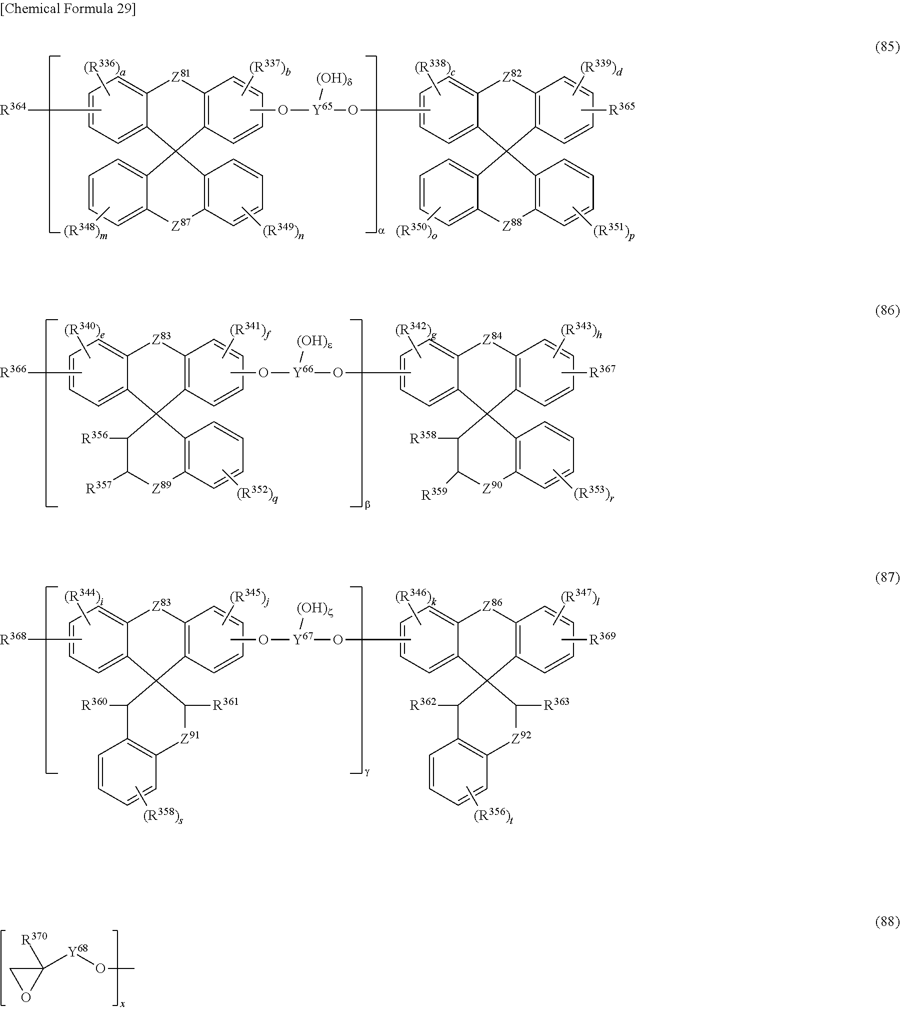

In the general formulas (85) to (87), Y⁶⁵ to Y⁶⁷ each independently represent an alkylene group having 1 to 10 carbon atoms, a cycloalkylene group having 4 to 10 carbon atoms, or an arylene group having 6 to 15 carbon atoms. Y⁶⁸ represents a direct bond, an alkylene group having 1 to 10 carbon atoms, a cycloalkylene group having 4 to 10 carbon atoms, or an arylene group having 6 to 15 carbon atoms. Z⁸¹ to Z⁹² each independently represent a direct bond, an alkylene group having 1 to 5 carbon atoms, oxygen, or sulfur. R³³⁶ to R³⁵⁵ each independently represent halogen, an alkyl group having 1 to 10 carbon atoms, a cycloalkyl group having 4 to 10 carbon atoms, an aryl group having 6 to 15 carbon atoms, a fluoroalkyl group having 1 to 10 carbon atoms, a fluorocycloalkyl group having 4 to 10 carbon atoms, or a fluoroaryl group having 6 to 15 carbon atoms. R³⁵⁶ to R³⁶³ each independently represent hydrogen, an alkyl group having 1 to 10 carbon atoms, a cycloalkyl group having 4 to 10 carbon atoms, or an aryl group having 6 to 15 carbon atoms. R³⁶⁴ to R³⁶⁹ represent a group represented by general formula (88). R³⁷° represents hydrogen, an alkyl group having 1 to 10 carbon atoms, or a hydroxy group. a, b, c, d, e, f, g, h, i, j, k, and 1 each independently represent an integer of 0 to 3. m, n, o, p, q, r, s, and t each independently represent an integer of 0 to 4. x represents an integer of 1 to 4. α, β, and γ each independently represent an integer of 0 to 10. δ, ε, and ζ and each independently represent 0 or 1. In the general formulas (85) to (87), the alkylene group, cycloalkylene group, arylene group, alkyl group, cycloalkyl group, and aryl group, fluoroalkyl group, fluorocycloalkyl group, and fluoroaryl group described above may have a hetero atom, and may be either unsubstituted or substituted.

Examples of the (F6) compound include TBIS (registered trademark) RXG (manufactured by TAOKA CHEMICAL COMPANY, LIMITED).

As the (F7) epoxy compound having an indolinone skeleton or an isoindolinone skeleton and two or more epoxy groups in the molecule, compounds represented by general formulas (89) to (91) are preferred.

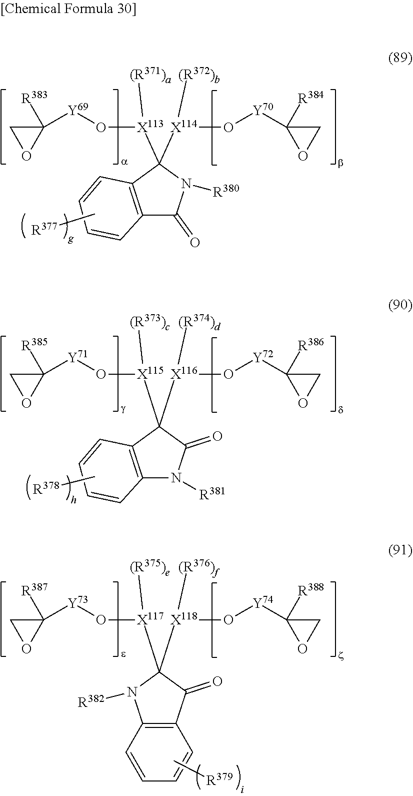

In the general formulas (89) to (91), X¹¹³ to X¹¹⁸ each independently represent a divalent to decavalent monocyclic or condensed polycyclic aromatic hydrocarbon ring having 6 to 15 carbon atoms, or a divalent to octavalent monocyclic or condensed polycyclic aliphatic hydrocarbon ring having 4 to 10 carbon atoms. Y⁶⁹ to Y⁷⁴ each independently represent a direct bond, an alkylene group having 1 to 10 carbon atoms, a cycloalkylene group having 4 to 10 carbon atoms, or an arylene group having 6 to 15 carbon atoms. R³⁷¹ to R³⁷⁹ each independently represent halogen, an alkyl group having 1 to 10 carbon atoms, a cycloalkyl group having 4 to 10 carbon atoms, an aryl group having 6 to 15 carbon atoms, a fluoroalkyl group having 1 to 10 carbon atoms, a fluorocycloalkyl group having 4 to 10 carbon atoms, or a fluoroaryl group having 6 to 15 carbon atoms. R³⁸⁰ to R³⁸² each independently represent hydrogen, an alkyl group having 1 to 10 carbon atoms, a cycloalkyl group having 4 to 10 carbon atoms, an aryl group having 6 to 15 carbon atoms, a fluoroalkyl group having 1 to 10 carbon atoms, a fluorocycloalkyl group having 4 to 10 carbon atoms, or a fluoroaryl group having 6 to 15 carbon atoms. R³⁸³ to R³⁸⁸ each independently represent hydrogen, an alkyl group having 1 to 10 carbon atoms, or a hydroxy group. a, b, c, d, e, and f each independently represent an integer of 0 to 8. g, h, and i each independently represent an integer of 0 to 4. α, β, γ, δ, ε, and ζ each independently represent an integer of 1 to 4. In the general formulas (89) to (91), X¹¹³ to X¹¹⁸ each independently preferably represent a divalent to decavalent monocyclic or condensed polycyclic aromatic hydrocarbon ring having 6 to 10 carbon atoms. The monocyclic or condensed polycyclic aromatic hydrocarbon ring, monocyclic or condensed polycyclic aliphatic hydrocarbon ring, alkylene group, cycloalkylene group, arylene group, alkyl group, cycloalkyl group, and aryl group, fluoroalkyl group, fluorocycloalkyl group, and fluoroaryl group described above may have a hetero atom, and may be either unsubstituted or substituted. Examples of the (F7) compound include WHR-991S (manufactured by Nippon Kayaku Co., Ltd.).

As the (F8) epoxy compound having two or more naphthalene skeletons and two or more epoxy groups in the molecule, a compound represented by general formula (92) is preferred.

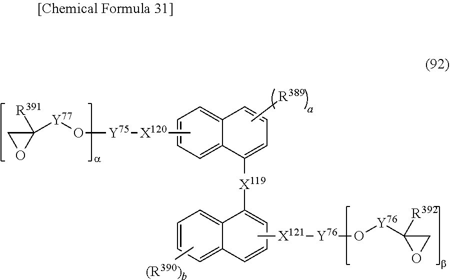

In the general formula (92), X¹¹⁹ represents a direct bond, an alkylene group having 1 to 10 carbon atoms, a cycloalkylene group having 4 to 10 carbon atoms, or an arylene group having 6 to 15 carbon atoms. X¹²⁰ and X¹²¹ each independently represent a direct bond or oxygen. In a case where X¹²⁰ and X¹²¹ represent direct bonds, Y⁷⁵ and Y⁷⁶ represent direct bonds. In a case where X¹²⁰ and X¹²¹ do not represent any direct bond, Y⁷⁵ and Y⁷⁶ represent an alkylene group having 1 to 10 carbon atoms, a cycloalkylene group having 4 to 10 carbon atoms, or an arylene group having 6 to 15 carbon atoms. R³⁸⁹ and R³⁹° each independently represent halogen, an alkyl group having 1 to 10 carbon atoms, a cycloalkyl group having 4 to 10 carbon atoms, an aryl group having 6 to 15 carbon atoms, a fluoroalkyl group having 1 to 10 carbon atoms, a fluorocycloalkyl group having 4 to 10 carbon atoms, or a fluoroaryl group having 6 to 15 carbon atoms. R³⁹¹ and R³⁹² each independently represent hydrogen, an alkyl group having 1 to 10 carbon atoms, or a hydroxy group. a and b each independently represent an integer of 0 to 6. a and 13 each independently represent an integer of 1 to 4. In the general formula (92), the monocyclic or condensed polycyclic aromatic hydrocarbon ring, monocyclic or condensed polycyclic aliphatic hydrocarbon ring, alkylene group, cycloalkylene group, arylene group, alkyl group, cycloalkyl group, and aryl group, fluoroalkyl group, fluorocycloalkyl group, and fluoroaryl group described above may have a hetero atom, and may be either unsubstituted or substituted. Examples of the (F8) compound include IBIS (registered trademark) BNG200 or BNEG (all manufactured by TAOKA CHEMICAL COMPANY, LIMITED).

The epoxy equivalent of the (F5) compound, (F6) compound, (F7) compound, and (F8) compound is preferably 150 g/mol or more, more preferably 170 g/mol or more, still more preferably 190 g/mol or more, particularly preferably 210 g/mol or more. When the epoxy equivalent is 150 g/mol or more, a pattern in a low-taper shape can be formed after thermal curing. On the other hand, the epoxy equivalent of the (F5) compound, (F6) compound, (F7) compound, or (F8) compound is preferably 800 g/mol or less, more preferably 600 g/mol or less, still more preferably 500 g/mol or less, particularly preferably 400 g/mol or less. When the epoxy equivalent is 800 g/mol or less, the change in pattern opening width between before and after thermal curing can be suppressed.

The above-described (F5) compound, (F6) compound, (F7) compound, and (F8) compound can be synthesized by known methods.

The total content of the (F5) compound, (F6) compound, (F7) compound. and (F8) compound in the photosensitive resin composition according to the present invention is, in a case where the total of the (A) alkali-soluble resin and (B) radical polymerizable compound is regarded as 100 parts by mass, preferably 0.5 parts by mass or more, more preferably 1 part by mass or more, still more preferably 2 parts by mass or more, even more preferably 3 parts by mass or more, particularly preferably 5 parts by mass or more. When the content is 0.5 parts by mass or more, the sensitivity for exposure can be improved, and a pattern in a low-taper shape can be formed. In addition, the change in pattern opening width between before and after thermal curing can be suppressed. On the other hand, the total content of the (F5) compound, (F6) compound, (F7) compound, and (F8) compound is preferably 50 parts by mass or less, more preferably 40 parts by mass or less, still more preferably 30 parts by mass or less, even more preferably 25 parts by mass or less, particularly preferably 20 parts by mass or less. When the content is 50 parts by mass or less, the change in pattern opening width between before and after thermal curing can be suppressed, and the residue generation after development can be inhibited.

The photosensitive resin composition according to the present invention more preferably contains two or more of the specific (F) cross-linking agents. More specifically, the composition preferably contains two or more selected from the group consisting of the above-described (F1) compound, (F2) compound, (F3) compound, (F4) compound, (F5) compound, (F6) compound, (F7) compound, and (F8) compound. Containing the two or more compounds makes it possible to form a pattern in a low-taper shape after thermal curing, and allows the change in pattern opening width between before and after thermal curing to be suppressed. In addition, the bendability of the cured film can be improved.

In the photosensitive resin composition according to the present invention, in the case of containing two of the specific (F) cross-linking agents, the content ratio of the two types ((content of first cross-linking agent)/(content of second cross-linking agent)) is preferably 80/20 to 20/80, more preferably 70/30 to 30/70, still more preferably 60/40 to 40/60, where the first type of the specific (F) cross-linking agents and the second type of the specific (F) cross-linking agents are referred to respectively as a first cross-linking agent and a second cross-linking agent. When the content ratio is 80/20 to 20/80, it becomes possible to form a pattern in a low-taper shape after thermal curing, and the change in pattern opening width between before and after thermal curing can be suppressed. In addition, the bendability of the cured film can be improved.

### <(F9) Nitrogen-Containing Ring Skeleton-Containing Epoxy Compound>

The photosensitive resin composition according to the present invention preferably further contains a (F9) nitrogen-containing ring skeleton-containing epoxy compound as the (F) cross-linking agent.

Containing the (F9) nitrogen-containing ring skeleton-containing epoxy compound makes it possible to inhibit the residue generation after development. This is presumed to be because in the UV-cured film upon exposure, the above-described epoxy compound is incorporated into the cured film due to the formation of an IPN structure. More specifically, the polarity/hydrophilicity of the nitrogen-containing ring skeleton derived from the epoxy compound described above is believed to improve the affinity for the alkaline developer for development.

In addition, containing the (F9) nitrogen-containing ring skeleton-containing epoxy compound makes it possible to inhibit the residue generation during thermal curing. This is presumed to be because the above-described epoxy compound functions as a cross-linking agent and also functions as a curing catalyst and a curing accelerator for cross-linking agents such as other epoxy compounds during the thermal curing More specifically, the epoxy compound described above has an epoxy group that serves as a crosslinkable group and a nitrogen-containing ring skeleton. It is believed that the catalytic action of the basic skeleton such as the nitrogen-containing ring skeleton promotes the thermal curing of other epoxy compounds to improve the heat resistance of the cured film, thereby inhibiting the residue generation due to thermal decomposition products and sublimates during thermal curing.

Examples of the nitrogen-containing ring skeleton of the (F9) nitrogen-containing ring skeleton-containing epoxy compound include a pyrrolidine skeleton, a pyrrole skeleton, an imidazole skeleton, a pyrazole skeleton, a triazole skeleton, a tetrazole skeleton, an imidazoline skeleton, an oxazole skeleton, an isoxazole skeleton, an oxazoline skeleton, an isoxazoline skeleton, a thiazole skeleton, an isothiazole skeleton, a thiazoline skeleton, an isothiazoline skeleton, a thiazine skeleton, a piperidine skeleton, a piperazine skeleton, a morpholine skeleton, a pyridine skeleton, a pyridazine skeleton, a pyrimidine skeleton, a pyrazine skeleton, a triazine skeleton, an isocyanuric acid skeleton, an imidazolidinone skeleton, a propylene urea skeleton, a butylene urea skeleton, a hydantoin skeleton, a barbituric acid skeleton, an alloxan skeleton, and a glycoluril skeleton.

From the viewpoint of reducing the residue after development and the residue during thermal curing, an imidazole skeleton, a pyrazole skeleton, a triazole skeleton, a tetrazole skeleton, an oxazole skeleton, an isoxazole skeleton, a thiazole skeleton, an isothiazole skeleton, a thiazine skeleton, a pyridine skeleton, a pyridazine skeleton, a pyrimidine skeleton, a pyrazine skeleton, a triazine skeleton, an isocyanuric acid skeleton, a hydantoin skeleton, a barbituric acid skeleton, an alloxan skeleton, or a glycoluril skeleton is preferred, and an imidazole skeleton, a triazole skeleton, a pyrimidine skeleton, a pyrazine skeleton, a triazine skeleton, an isocyanuric acid skeleton, or a glycoluril skeleton is more preferred.

Further, the (F9) nitrogen-containing ring skeleton-containing epoxy compound preferably has an alkylene chain between the nitrogen-containing ring skeleton and the epoxy group from the viewpoints of improving the bendability of the cured film and reducing the residue after development. The alkylene chain is preferably an alkylene chain having 2 to 30 carbon atoms, more preferably an alkylene chain having 4 to 25 carbon atoms, still more preferably an alkylene chain having 6 to 20 carbon atoms.

The (F9) nitrogen-containing ring skeleton-containing epoxy compound is preferably a compound represented by general formula (17), a compound represented by general formula (18), or a compound represented by general formula (19).

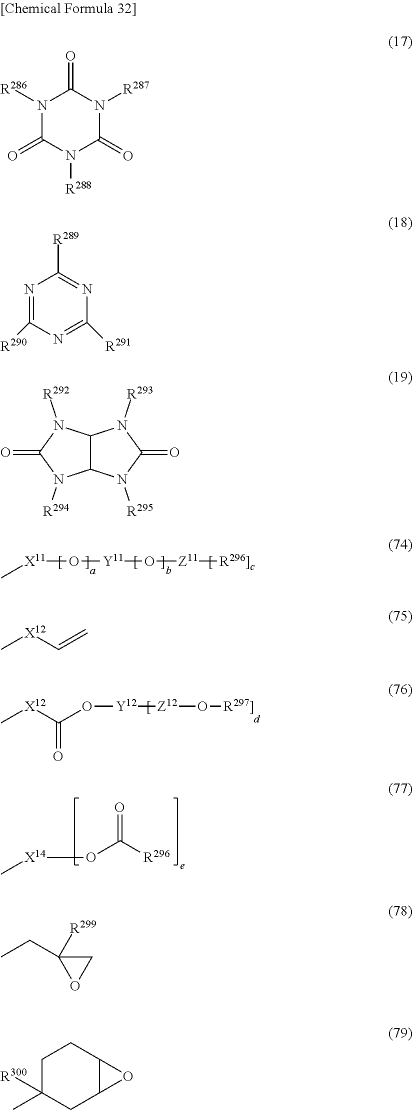

In general formula (17), R²⁸⁶ to R²⁸⁸ each independently represent a group represented by any of the general formulas (74) to (77), hydrogen, an alkyl group having 1 to 10 carbon atoms, and a cycloalkyl group having 4 to 10 carbon atoms, an aryl group having 6 to 15 carbon atoms, or a hydroxy group, and at least one of R²⁸⁶ to R²⁸⁸ represents a group represented by general formula (74) or (76). In general formula (18), R²⁸⁹ to R²⁹¹ each independently represent a group represented by any of the general formulas (74) to (77), hydrogen, an alkyl group having 1 to 10 carbon atoms, and a cycloalkyl group having 4 to 10 carbon atoms, an aryl group having 6 to 15 carbon atoms, or a hydroxy group, and at least one of R²⁸⁹ to R²⁹¹ represents a group represented by general formula (74) or (76). In general formula (19), R²⁹² to R²⁹⁵ each independently represent a group represented by any of the general formulas (74) to (77), hydrogen, an alkyl group having 1 to 10 carbon atoms, and a cycloalkyl group having 4 to 10 carbon atoms, an aryl group having 6 to 15 carbon atoms, or a hydroxy group, and at least one of R²⁹² to R²⁹⁵ represents a group represented by general formula (74) or (76).

In the general formula (74), X¹¹ represents a direct bond or an alkylene chain having 1 to 10 carbon atoms. Yil represents a direct bond or an alkylene chain having 1 to 10 carbon atoms. Z¹¹ represents a direct bond, an alkylene chain having 1 to 10 carbon atoms, a cycloalkylene chain having 4 to 10 carbon atoms, or an arylene chain having 6 to 15 carbon atoms. R²⁹⁶ represents a group represented by general formula (78) or a group represented by general formula (79). a represents 0 or 1, b represents 0 or 1, and c represents an integer of 1 to 4. In a case where b represents 1, a represents 1, and Y¹¹ represents an alkylene chain having 1 to 10 carbon atoms. In the general formula (75), X¹² represents a single bond, an alkylene group having 1 to 6 carbon atoms, or an arylene group having 6 to 15 carbon atoms. In the general formula (76), X¹³ represents a direct bond or an alkylene chain having 1 to 10 carbon atoms. Y¹² represents a direct bond or an alkylene chain having 1 to 10 carbon atoms. Z¹² represents a direct bond, an alkylene chain having 1 to 10 carbon atoms, a cycloalkylene chain having 4 to 10 carbon atoms, or an arylene chain having 6 to 15 carbon atoms. R²⁹⁷ represents a group represented by general formula (78) or a group represented by general formula (79). d represents an integer of 1 to 4. In the general formula (77), X¹⁴ represents a direct bond or an alkylene chain having 1 to 10 carbon atoms. R²⁹⁸ represents hydrogen or an alkyl group having 1 to 10 carbon atoms. e represents an integer of 1 to 6. In the general formula (78), R²⁹⁹ represents hydrogen, an alkyl group having 1 to 10 carbon atoms, or a hydroxy group. In the general formula (79), R³⁰° represents hydrogen, an alkyl group having 1 to 10 carbon atoms, or a hydroxy group. The above-described alkyl group, alkylene chain, cycloalkylene chain, and arylene chain may have a hetero atom, and may be either unsubstituted or substituted.

The number of epoxy groups in the molecule of the (F9) nitrogen-containing ring skeleton-containing epoxy compound is preferably 2 or more, more preferably 3 or more, even more preferably 4 or more. When the number of epoxy groups is 2 or more, the residue generation during thermal curing can be inhibited, and the change in pattern opening width between before and after thermal curing can be suppressed. On the other hand, the number of epoxy groups in the molecule of the (F9) nitrogen-containing ring skeleton-containing epoxy compound is preferably 10 or less, more preferably 8 or less, even more preferably 6 or less. When the number of epoxy groups is 10 or less, a pattern in a low-taper shape can be formed after thermal curing.

The epoxy equivalent of the (F9) nitrogen-containing ring skeleton-containing epoxy compound is preferably 70 g/mol or more, more preferably 80 g/mol or more, still more preferably 90 g/mol or more, particularly preferably 100 g/mol or more. When the epoxy equivalent is 70 g/mol or more, a pattern in a low-taper shape can be formed after thermal curing. On the other hand, the epoxy equivalent of the (F9) nitrogen-containing ring skeleton-containing epoxy compound is preferably 800 g/mol or less, more preferably 600 g/mol or less, still more preferably 500 g/mol or less, particularly preferably 400 g/mol or less. When the epoxy equivalent is 800 g/mol or less, the residue generation during thermal curing can be inhibited, and the change in pattern opening width between before and after thermal curing can be suppressed.

Examples of the (F9) nitrogen-containing ring skeleton-containing epoxy compound include 1,3,5-tris(glycidyl) isocyanurate, 1,3,5-tris(2-glycidylethyl) isocyanurate, 1,3,5-tris(5-glycidylpentyl) isocyanurate, 1,3,5-tris(glycidyldecyl) isocyanurate, 1,3,5-tris(glycidylstearyl) isocyanurate, 1,3,5-tris(glycidyloxy) isocyanurate, 1,3,5-tris(2-glycidyloxyethyl) isocyanurate, 1,3,5-tris(2-glycidylethoxy) isocyanurate, 1,3,5-tris(2-glycidyloxyethoxy) isocyanurate, 1,3,5-tris(3,4-epoxycyclohexyl) isocyanurate, 1,3,5-tris[2-(3,4-epoxycyclohexyl)ethyl]isocyanurate, 1,3,5-tris(4-oxranylbenzyl) isocyanurate, 1,3,5-tris[2-(4-oxiranylbenzyloxy)ethyl]isocyanurate, 1,3,5-tris[2,2-bis(glycidyloxymethyl)butoxycarbonylethyl]isocyanurate, 1,3,5-tris[3-(3,4-epoxycyclohexyl)methoxycarbonylpropyl]isocyanurate, 1,3-bis(glycidyl)-5-[2,3-bis(ethylcarbonyloxy)propyl] isocyanurate, 1-glycidyl-3,5-bis[2,3-bis(ethylcarbonyloxy)propyl] isocyanurate, 1,3-bis(glycidyl)-5-allyl isocyanurate, 1-glycidyl-3,5-diallyl isocyanurate, 2,4,6-tris(glycidyl)triazine, 2,4,6-tris(2-glycidylethyl)triazine, 2,4,6-tris(glycidyloxy)triazine, 2,4,6-tris(2-glycidyloxyethyl)triazine, 2,4,6-tris(2-glycidylethoxy)triazine, 2,4,6-tris(5-glycidylpentyloxy)triazine, 2,4,6-tris(glycidyldecyloxy)triazine, 2,4,6-tris(glycidylstearyloxy)triazine, 2,4,6-tris(2-glycidyloxyethoxy)triazine, 2,4,6-tris(2-glycidyloxyethoxy)triazine, 2,4-bis(glycidyloxy)-6-hydroxytriazine, 1,3,4,6-tetrakis(glycidyl)glycoluril, 1,3,4,6-tetrakis(2-glycidylethyl)glycoluril, 1,3,4,6-tetrakis(5-glycidylpentyl)glycoluril, 1,3,4,6-tetrakis(glycidyldecyl)glycoluril, 1,3,4,6-tetrakis(glycidylstearyl)glycoluril, 1,3,4,6-tetrakis(glycidyloxy)glycoluril, 1,3,4,6-tetrakis(2-glycidyloxyethyl)glycoluril, 1,3,4,6-tetrakis(2-glycidylethoxy)glycoluril, 1,3,4,6-tetrakis(2-glycidyloxyethoxy)glycoluril, or 1,4-bis(glycidyl)glycoluril.

From the viewpoint of improving the bendability of the cured film, 1,3,5-tris(5-glycidylpentyl) isocyanurate, 1,3,5-tris(glycidyldecyl) isocyanurate, 1,3,5-tris(glycidylstearyl) isocyanurate, 1,3,5-tris[2,2-bis(glycidyloxymethyl)butoxycarbonylethyl]isocyanurate, 1,3,5-tris[3-(3,4-epoxycyclohexyl)methoxycarbonylpropyl]isocyanurate, 1,3,5-tris(5-glycidylpentyloxy)triazine, 1,3,5-tris(glycidyldecyloxy)triazine, 1,3,5-tris(glycidylstearyloxy)triazine, 1,3,4,6-tetrakis(5-glycidylpentyl)glycoluril, 1,3,4,6-tetrakis(glycidyldecyl)glycoluril, or 1,3,4,6-tetrakis(glycidylstearyl)glycoluril is preferred.

The content of the (F9) nitrogen-containing ring skeleton-containing epoxy compound in the photosensitive resin composition according to the present invention is, in a case where the total of the (A) alkali-soluble resin and (B) radical polymerizable compound is regarded as 100 parts by mass, preferably 0.3 parts by mass or more, more preferably 0.5 parts by mass or more, still more preferably 1 part by mass or more, even more preferably 2 parts by mass or more, particularly preferably 3 parts by mass or more. When the content is 0.3 parts by mass or more, the residue generation after development can be inhibited, and the residue generation during thermal curing can be inhibited. In addition, the change in pattern opening width between before and after thermal curing can be suppressed. On the other hand, the content of the (F9) nitrogen-containing ring skeleton-containing epoxy compound is preferably 25 parts by mass or less, more preferably 20 parts by mass or less, still more preferably 15 parts by mass or less, even more preferably 12 parts by mass or less, particularly preferably 10 part by mass or less.

When the content is 25 parts by mass or less, a pattern in a low-taper shape can be formed after thermal curing, and the change in pattern opening width between before and after thermal curing can be suppressed.

The photosensitive resin composition according to the present invention preferably contains the above-described specific (F) cross-linking agent (one or more selected from the group consisting of the (F1) compound, (F2) compound, (F3) compound, (F4) compound, (F5) compound, (F6) compound, (F7) compound, and (F8) compounds), and the (F9) nitrogen-containing ring skeleton-containing epoxy compound. The use of the specific (F) cross-linking agent described above and the (F9) nitrogen-containing ring skeleton-containing epoxy compound in combination in combination makes it possible to suppress the change in pattern opening width between before and after thermal curing and inhibit the residue generation during thermal curing. In the photosensitive resin composition according to the present invention, the content ratio of the (F9) nitrogen-containing ring skeleton-containing epoxy compound to 100% by mass in total of the specific (F) cross-linking agent and (F9) nitrogen-containing ring skeleton-containing epoxy compound is preferably 10% by mass or higher, more preferably 15% by mass or higher, still more preferably 20% by mass or higher, particularly preferably 25% by mass or higher. When the content ratio is 10% by mass or higher, the residue generation after development can be inhibited, and the residue generation during thermal curing can be inhibited. In addition, the change in pattern opening width between before and after thermal curing can be suppressed. On the other hand, the content ratio of the (F9) nitrogen-containing ring skeleton-containing epoxy compound is preferably 49% by mass or lower, more preferably 48% by mass or lower, still more preferably 45% by mass or lower, even more preferably 42% by mass or lower, particularly preferably 40% by mass or lower. When the content ratio is 49% by mass or less, a pattern in a low-taper shape can be formed after thermal curing, and the change in pattern opening width between before and after thermal curing can be suppressed.

### <Sensitizer>

The photosensitive resin composition according to the present invention preferably further contains a sensitizer. The sensitizer refers to a compound capable of absorbing exposure energy, generating excited triplet electrons by internal conversion and intersystem crossing, and mediating energy transfer to the above-described (C1) photo initiator or the like.

Containing the sensitizer allows the sensitivity for exposure to be improved. This is presumed to be because the sensitizer absorbs long-wavelength light which is not absorbed by the (C1) photo initiator or the like, then allowing the photoreaction efficiency to be improved by energy transfer of the light from the sensitizer to the (C1) photo initiator or the like.

As the sensitizer, a thioxanthone-based sensitizer is preferred. Examples of the thioxanthone-based sensitizer include thioxanthone, 2-methylthioxanthone, 2-chlorothioxanthone, 2-isopropylthioxanthone, 2,4-dimethylthioxanthone, 2,4-diethylthioxanthone, and 2,4-dichlorothioxanthone.

The content of the sensitizer in the photosensitive resin composition according to the present invention is, in a case where the (A) alkali-soluble resin and the (B) radical polymerizable compound are regarded as 100 parts by mass in total, preferably 0.01 parts by mass or more, more preferably 0.1 parts by mass or more, still more preferably 0.5 parts by mass or more, particularly preferably 1 part by mass or more. When the content is 0.01 parts by mass or more, the sensitivity for exposure can be improved. On the other hand, the content of the sensitizer is preferably 15 parts by mass or less, more preferably 13 parts by mass or less, still more preferably 10 parts by mass or less, particularly preferably 8 parts by mass or less. When the content is 15 parts by mass or less, the resolution after development can be improved, and a cured film in a low-taper pattern shape can be obtained.

### <Chain Transfer Agent>

The photosensitive resin composition according to the present invention preferably further contains a chain transfer agent. The chain transfer agent refers to a compound capable of receiving a radical from a polymer growth terminal of the polymer chain obtained by radical polymerization during exposure and mediating radical transfer to another polymer chain.

Containing the chain transfer agent allows the sensitivity for exposure to be improved. This is presumed to be because the radicals generated by exposure are transferred to other polymer chains by the chain transfer agent, thereby causing radical crosslinking even to the deep part of the film. In particular, for example, in a case where the resin composition contains the (Da) black colorant as the (D) colorant described above, the light from exposure is absorbed by the (Da) black colorant, and thus, no light may reach the deep part of the film. On the other hand, in the case of containing the chain transfer agent, the radical transfer by the chain transfer agent causes radical crosslinking even to the deep part of the film, thus allowing the sensitivity for exposure to be improved.

In addition, containing the chain transfer agent allows a cured film in a low-taper pattern shape to be obtained. This is presumed to be because the radical transfer by the chain transfer agent is capable of controlling the molecular weight of the polymer chain obtained by radical polymerization during exposure. More specifically, containing the chain transfer agent inhibits the production of a remarkably high-molecular-weight polymer chain due to excessive radical polymerization during exposure, thereby keeping the softening point of the obtained film from being increased. Thus, it is believed that the reflow property of the pattern during the thermal curing is improved, thereby providing a low-taper pattern shape.

### <(G) Polyfunctional Thiol Compound>

The photosensitive resin composition according to the present invention preferably contains a (G) polyfunctional thiol compound as a chain transfer agent. Containing the (G) polyfunctional thiol compound as a chain transfer agent allows, in addition to the above-described improvement in sensitivity for exposure and pattern formation in a low-taper shape, the change in pattern opening width between before and after thermal curing to be suppressed. This is presumed to be because the (G) polyfunctional thiol compound suppresses oxygen inhibition to promote UV curing during exposure, and then suppress the reflow of the pattern skirt during thermal curing, thereby allowing the change in pattern opening width between before and after thermal curing to be suppressed.

The (G) polyfunctional thiol compound preferably contains a compound represented by general formula (94) and/or a compound represented by general formula (95).

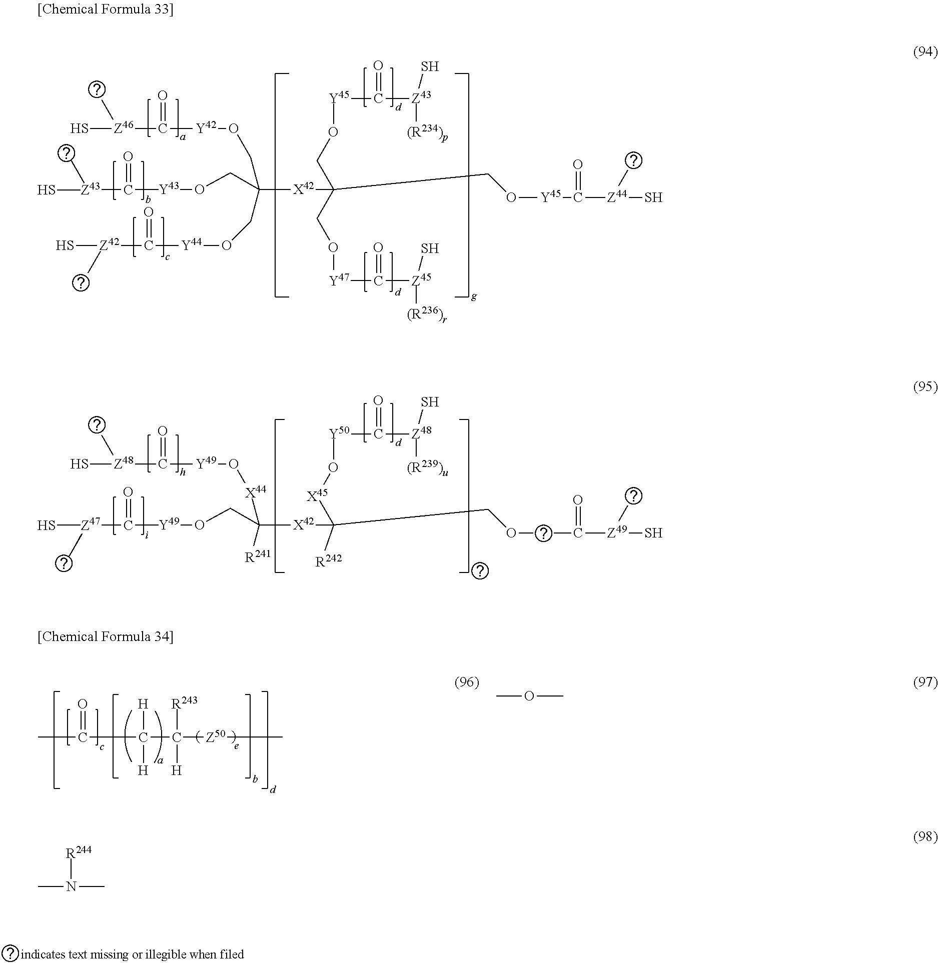

In the general formula (94), X⁴² represents a divalent organic group. Y⁴² to Y⁴⁷ each independently represent a direct bond, an alkylene chain having 1 to 10 carbon atoms, or a group represented by general formula (96). Z⁴⁰ to Z⁴⁵ each independently represent a direct bond or an alkylene chain having 1 to 10 carbon atoms. R²³¹ to R²³⁶ each independently represent an alkylene chain having 1 to 10 carbon atoms. a, b, c, d, e, and f each independently represent 0 or 1, and g represents an integer of 0 to 10. m, n, o, p, q, and r each independently represent an integer of 0 to 10. In the general formula (94), X⁴² preferably represents a divalent organic group having one or more selected from an aliphatic structure having 1 to 10 carbon atoms, an alicyclic structure having 4 to 20 carbon atoms, and an aromatic structure having 6 to 30 carbon atoms. a, b, c, d, e, and f each independently preferably represent 1, and g preferably represents 0 to 5. m, n, o, p, q, and r each independently preferably represent 0. The above-described alkylene chain, aliphatic structure, alicyclic structure, and aromatic structure may have a hetero atom, and may be either unsubstituted or substituted.

In the general formula (95), X⁴³ represents a divalent organic group. X⁴⁴ and X⁴⁵ each independently represent a direct bond or an alkylene chain having 1 to 10 carbon atoms. Y⁴⁸ to Y⁵¹ each independently represent a direct bond, an alkylene chain having 1 to 10 carbon atoms, or a group represented by general formula (96). Z⁴⁶ to Z⁴⁹ each independently represent a direct bond or an alkylene chain having 1 to 10 carbon atoms. R²³⁷ to R²⁴° each independently represent an alkylene chain having 1 to 10 carbon atoms. R²⁴¹ and R²⁴² each independently represent hydrogen or an alkyl group having 1 to 10 carbon atoms. h, i, j, and k each independently represent 0 or 1, and 1 represents an integer of 0 to 10. s, t, u, and v each independently represent an integer of 0 to 10. In the general formula (95), X⁴³ preferably represents a divalent organic group having one or more selected from an aliphatic structure having 1 to 10 carbon atoms, an alicyclic structure having 4 to 20 carbon atoms, and an aromatic structure having 6 to 30 carbon atoms. h, i, j, and k each independently preferably represent 1, and 1 preferably represents 0 to 5. s, t, u, and v each independently preferably represent 0. The above-described alkyl group, alkylene chain, aliphatic structure, alicyclic structure, and aromatic structure may have a hetero atom, and may be either unsubstituted or substituted.

In the general formula (96), R²⁴³ represents hydrogen or an alkyl group having 1 to 10 carbon atoms. Z⁵⁰ represents a group represented by general formula (97) or a group represented by general formula (98). a represents an integer of 1 to 10, b represents an integer of 1 to 4, c represents 0 or 1, d represents an integer of 1 to 4, and e represents 0 or 1. In a case where c is 0, d represents 1. In the general formula (98), R²⁴⁴ represents hydrogen or an alkyl group having 1 to 10 carbon atoms. In the general formula (96), c preferably represents 1, and e preferably represents 1. In the general formula (98), R²⁴⁴ preferably represents hydrogen or an alkyl group having 1 to 4 carbon atoms, more preferably hydrogen or a methyl group.

Examples of the (G) polyfunctional thiol compound include β-mercaptopropionic acid, methyl β-mercaptopropionate, 2-ethylhexyl β-mercaptopropionate, stearyl β-mercaptopropionate, methoxybutyl β-mercaptopropionate, β-mercaptobutanoic acid, methyl β-mercaptobutanoate, methyl thioglycolate, n-octyl thioglycolate, methoxybutyl thioglycolate, 1,4-bis(3-mercaptobutanoyloxy)butane, 1,4-bis(3-mercaptopropionyloxy)butane, 1,4-bis(thioglycoloyloxy)butane, ethylene glycol bis(thioglycolate), trimethylolethane tris(3-mercaptopropionate), trimethylolethane tris(3-mercaptobutyrate), trimethylolpropane tris(3-mercaptopropionate), trimethylolpropane tris(3-mercaptobutyrate), trimethylolpropane tris(thioglycolate), 1,3,5-tris[(3-mercaptopropionyloxy)ethyl]isocyanuric acid, 1,3,5-tris[(3-mercaptobutanoyloxy)ethyl]isocyanuric acid, pentaerythritol tetrakis(3-mercaptopropionate), pentaerythritol tetrakis(3-mercaptobutyrate), pentaerythritol tetrakis(thioglycolate), dipentaerythritol hexakis(3-mercaptopropionate), or dipentaerythritol hexakis(3-mercaptobutyrate).

Trimethylolethane tris(3-mercaptopropionate), trimethylolethane tris(3-mercaptobutyrate), trimethylolpropane tris(3-mercaptopropionate), trimethylolpropane tris(3-mercaptobutyrate), trimethylolpropane tris(thioglycolate), 1,3,5-tris[(3-mercaptopropionyloxy)ethyl]isocyanurate, 1,3,5-tris[(3-mercaptobutanoyloxy)ethyl]isocyanurate, pentaerythritol tetrakis(3-mercaptopropionate), pentaerythritol tetrakis(3-mercaptobutyrate), pentaerythritol tetrakis(thioglycolate), dipentaerythritol hexakis(3-mercaptopropionate), or dipentaerythritol hexakis(3-mercaptobutyrate) is preferred from the viewpoints of improving the sensitivity for exposure, forming a pattern in a low-taper shape, and suppressing the change in pattern opening width between before and after thermal curing.

The content of the (G) polyfunctional thiol compound in the photosensitive resin composition according to the present invention is, in a case where the total of the (A) alkali-soluble resin and (B) radical polymerizable compound is regarded as 100 parts by mass, preferably 0.01 parts by mass or more, more preferably 0.1 parts by mass or more, still more preferably 0.3 parts by mass or more, even more preferably 0.5 parts by mass or more, particularly preferably 1 part by mass or more. When the content is 0.01 parts by mass or more, the sensitivity for exposure can be improved, and a cured film in a low-taper pattern shape can be obtained. In addition, the change in pattern opening width between before and after thermal curing can be suppressed. On the other hand, the content of the (G) polyfunctional thiol compound is preferably 15 parts by mass or less, more preferably 13 parts by mass or less, still more preferably 10 parts by mass or less, even more preferably 8 parts by mass or less, particularly preferably 5 parts by mass or less. When the content is 15 parts by mass or less, a pattern in a low-taper shape can be formed, the residue generation after development can be inhibited, and the heat resistance of the cured film can be improved.

The photosensitive resin composition according to the present invention preferably contains the specific (F) cross-linking agent and (G) polyfunctional thiol compound described above. The use of the specific (F) cross-linking agent and (G) polyfunctional thiol compound described above in combination makes it possible to inhibit the residue generation during thermal curing and improve the bendability of the cured film. This is believed to be because the epoxy group of the specific (F) cross-linking agent and the mercapto group of the (G) polyfunctional thiol compound react during thermal curing to improve the degree of cross-linking, thereby improving the heat resistance of the cured film. More specifically, it is presumed to be because of the inhibition of the residue generation due to thermal decomposition products and sublimates during thermal curing, and the mechanical properties improved by the increased molecular weight of the cured film. In addition, it is believed to be because the specific aromatic structure and/or alicyclic structure of the specific (F) cross-linking agent are introduced into the cured film, and because the (G) polyfunctional thiol compound causes the structure to form a cross-linked structure to improve the crosslink density, thereby dramatically improving the heat resistance of the cured film has been.

Furthermore, the photosensitive resin composition according to the present invention preferably contains the above-described (F9) nitrogen-containing ring skeleton-containing epoxy compound and the (G) polyfunctional thiol compound. The use of the (F9) nitrogen-containing ring skeleton-containing epoxy compound and (G) polyfunctional thiol compound described above in combination makes it possible to inhibit the residue generation during thermal curing and improve the bendability of the cured film. This is believed to be because during thermal curing, the respective compounds increase the degree of cross-linking for the cured film to function for improved heat resistance, and remarkably improve the degree of cross-linking and heat resistance for the cured film due to the synergistic effect, thereby inhibiting the residue generation due to thermal decomposition products and sublimates during thermal curing, and increasing molecular weight of the cured film.

Furthermore, the photosensitive resin composition according to the present invention preferably contains the above-described specific (F) cross-linking agent, (F9) nitrogen-containing ring skeleton-containing epoxy compound, and the (G) polyfunctional thiol compound. The use of the above-described specific (F) cross-linking agent, (F9) nitrogen-containing ring skeleton-containing epoxy compound and (G) polyfunctional thiol compound described above in combination also makes it possible to inhibit the residue generation during thermal curing and improve the bendability of the cured film.

### <Polymerization Terminator>

The photosensitive resin composition according to the present invention preferably further contains a polymerization terminator.

The polymerization terminator refers to a compound capable of terminating radical polymerization by capturing a radical generated at the time of exposure, or a radical at the polymer growth terminal of the polymer chain obtained by radical polymerization at the time of exposure, and holding the radical as a stable radical.

Containing the polymerization terminator in an appropriate amount makes it possible to inhibit the generation of residues after development and improve the resolution after the development. This is presumed to be because the polymerization terminator captures an excessive amount of radical generated at the time of exposure or a radical at the growth terminal of the high-molecular-weight polymer chain, thereby keeping the radical polymerization from proceeding excessively.

As the polymerization terminator, a phenolic polymerization terminator is preferred. Examples of the phenolic polymerization terminator include 4-methoxyphenol, 1,4-hydroquinone, 1,4-benzoquinone, 2-t-butyl-4-methoxyphenol, 3-t-butyl-4-methoxyphenol, 4-t-butylcatechol, 2,6-di-t-butyl-4-methylphenol, 2,5-di-t-butyl-1,4-hydroquinone, or 2,5-di-t-amyl-1,4-hydroquinone, or IRGANOX (registered trademark) 245, 259, 565, 1010, 1035, 1076, 1098, 1135, 1330, 1425, 1520, 1726, 3114 (all manufactured by BASF).

The content of the polymerization terminator in the photosensitive resin composition according to the present invention is, in a case where the (A) alkali-soluble resin and the (B) radical polymerizable compound are regarded as 100 parts by mass in total, preferably 0.01 parts by mass or more, more preferably 0.03 parts by mass or more, still more preferably 0.05 parts by mass or more, particularly preferably 0.1 parts by mass or more. When the content is 0.01 parts by mass or more, the resolution after development and the heat resistance of the cured film can be improved. On the other hand, the content of the polymerization terminator is preferably 10 parts by mass or less, more preferably 8 parts by mass or less, still more preferably 5 parts by mass or less, particularly preferably 3 parts by mass or less. When the content is 10 parts by mass or less, the sensitivity for exposure can be improved.

### <Silane Coupling Agent>

The photosensitive resin composition according to the present invention preferably further contains a silane coupling agent. The silane coupling agent refers to a compound having a hydrolyzable silyl group or silanol group. Containing the silane coupling agent makes it possible to increase the interaction between the cured film of the resin composition and the underlying substrate interface, thereby allowing the adhesion property to the underlying substrate and the chemical resistance of the cured film to be improved. As the silane coupling agent, a trifunctional organosilane, a tetrafunctional organosilane, or a silicate compound is preferred.

Examples of the trifunctional organosilane include methyltrimethoxysilane, cyclohexyltrimethoxysilane, vinyltrimethoxysilane, 3-acryloxypropyltrimethoxysilane, phenyltrimethoxysilane, 4-hydroxyphenyltrimethoxysilane, 1-naphthyltrimethoxysilane, 4-styryltrimethoxysilane, 3-glycidoxypropyltrimethoxysilane, 3-trimethoxysilylpropyl succinic acid, 3-trimethoxysilylpropyl succinic anhydride, 3,3,3-trifluoropropyltrimethoxysilane, 3-[(3-ethyl-3-oxetanyl)methoxy]propyltrimethoxysilane, 3-aminopropyltrimethoxysilane, 3-(4-aminophenyl)propyltrimethoxysilane, 1-(3-trimethoxysilylpropyl) urea, 3-triethoxysilyl-N-(1,3-dimethylbutylidene)propylamine, 3-mercaptopropyltrimethoxysilane, 3-isocyanatopropyltriethoxysilane, 1,3,5-tris(3-trimethoxysilylpropyl) isocyanurate, or N-t-butyl-2-(3-trimethoxysilylpropyl)succinimide.

Examples of the tetrafunctional organosilane or silicate compound include an organosilane represented by general formula (73).

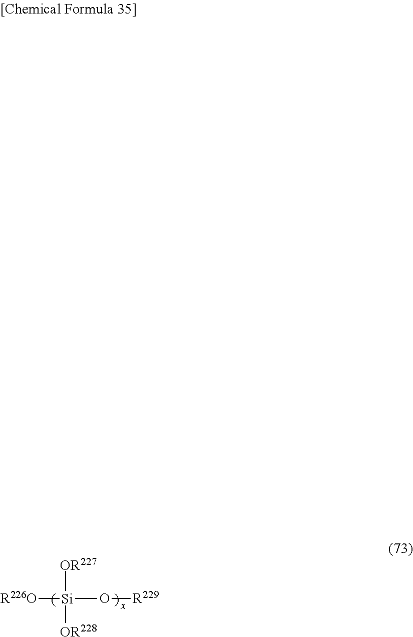

In the general formula (73), R²²⁶ to R²²⁹ each independently represents hydrogen, an alkyl group, an acyl group, or an aryl group, and x represents an integer of 1 to 15. In the general formula (73), R²²⁶ to R²²⁹ each independently preferably hydrogen, an alkyl group having 1 to 6 carbon atoms, an acyl group having 2 to 6 carbon atoms, or an aryl group having 6 to 15 carbon atoms, more p, an alkyl group having 1 to 4 carbon atoms, an acyl group having 2 to 4 carbon atoms, or an aryl group having 6 to 10 carbon atoms. The above-described alkyl group, acyl group, and aryl group may be either unsubstituted or substituted.

Examples of the organosilane represented by general formula (73) include a tetrafunctional organosilane such as tetramethoxysilane, tetraethoxysilane, tetra-n-propoxysilane, tetraisopropoxysilane, tetra-n-butoxysilane, or tetraacetoxysilane, or a silicate compound such as methyl silicate 51 (manufactured by FUSO CHEMICAL CO., LTD.), M silicate 51, silicate 40, or silicate 45 (all manufactured by TAMA CHEMICALS CO., LTD.), or methyl silicate 51, methyl silicate 53A, ethyl silicate 40, or ethyl silicate 48 (all manufactured by COLCOAT CO.,LTD.).

The content of the silane coupling agent in the photosensitive resin composition according to the present invention is, in a case where the (A) alkali-soluble resin and the (B) radical polymerizable compound are regarded as 100 parts by mass in total, preferably 0.01 parts by mass or more, more preferably 0.1 parts by mass or more, still more preferably 0.5 parts by mass or more, particularly preferably 1 part by mass or more. When the content is 0.01 parts by mass or more, the adhesion property to the underlying substrate and the chemical resistance of the cured film can be improved. On the other hand, the content of the silane coupling agent is preferably 15 parts by mass or less, more preferably 13 parts by mass or less, still more preferably 10 parts by mass or less, particularly preferably 8 parts by mass or less. When the content is 15 parts by mass or less, the resolution after development can be improved.

### <Surfactant>

The photosensitive resin composition according to the present invention may further contain a surfactant. The surfactant refers to a compound that has a hydrophilic structure and a hydrophobic structure. Containing the surfactant in an appropriate amount allows the surface tension of the resin composition to be adjusted arbitrarily, thereby improving the leveling property for coating, and then allowing the film thickness uniformity of the coating film to be improved. As the surfactant, a fluororesin-based surfactant, a silicone-based surfactant, a polyoxyalkylene ether-based surfactant, or an acrylic resin-based surfactant is preferable.

The content ratio of the surfactant in the photosensitive resin composition according to the present invention is preferably 0.001% by mass or higher, more preferably 0.005% by mass or higher, still more preferably 0.01% by mass or higher, based on the whole photosensitive resin composition. When the content ratio is 0.001% by mass or higher, the leveling property for coating can be improved. On the other hand, the content ratio of the surfactant is preferably 1% by mass or lower, more preferably 0.5% by mass or lower, still more preferably 0.03% by mass or lower. When the content ratio is 1% by mass or lower, the leveling property for coating can be improved.

### <Solvent>

The photosensitive resin composition according to the present invention preferably further contains a solvent. The solvent refers to a compound capable of dissolving various resins and various additives to be contained in the resin composition. Containing the solvent makes it possible to uniformly dissolve various resins and various additives to be contained in the resin composition, thereby improving the transmittance of the cured film. Furthermore, the viscosity of the resin composition can be adjusted arbitrarily, and a film with a desired film thickness can be formed on the substrate. In addition, the surface tension of the resin composition or the drying speed thereof for coating can be adjusted arbitrarily, and the leveling property for coating and the film thickness uniformity of the coating film can be improved.

As the solvent, a compound having an alcoholic hydroxyl group, a compound having a carbonyl group, or a compound having three or more ether bonds is preferred from the viewpoint of the solubility of various resins and various additives. In addition, a compound having a boiling point of 110 to 250° C. under atmospheric pressure is more preferred. The boiling point is adjusted to 110° C. or higher, thereby causing the solvent to evaporate appropriately for coating, and then causing drying of the coating film to proceed, and thus, coating unevenness can be suppressed, and the film thickness uniformity can be improved. On the other hand, the boiling point is adjusted to 250° C. or lower, thereby allowing the amount of the solvent remaining in the coating film to be reduced. Accordingly, the amount of film shrinkage during thermal curing can be reduced, the flatness of the cured film can be improved, and the film thickness uniformity can be improved.

Examples of the compound having an alcoholic hydroxyl group and a boiling point of 110 to 250° C. under atmospheric pressure include diacetone alcohol, ethyl lactate, ethylene glycol monomethyl ether, propylene glycol monomethyl ether, diethylene glycol monomethyl ether, dipropylene glycol monomethyl ether, 3-methoxy-1-butanol, 3-methoxy-3-methyl-1-butanol, and tetrahydrofurfuryl alcohol.

Examples of the compound having a carbonyl group and a boiling point of 110 to 250° C. under atmospheric pressure include 3-methoxy-n-butyl acetate, 3-methyl-3-n-butyl acetate, propylene glycol monomethyl ether acetate, dipropylene glycol monomethyl ether acetate, and γ-butyrolactone.

Examples of the compound having three or more ether bonds and a boiling point of 110 to 250° C. under atmospheric pressure include diethylene glycol dimethyl ether, diethylene glycol ethyl methyl ether, and dipropylene glycol dimethyl ether.

The content ratio of the solvent in the photosensitive resin composition according to the present invention can be adjusted appropriately depending on the coating method and the like. For example, in the case of forming a coating film by spin coating, it is common to adjust the ratio to 50 to 95% by mass of the whole photosensitive resin composition.

In the case of containing, as the (D) colorant, a dispersive dye as the (D1) pigment and/or (D2) dye, the solvent is preferably a solvent having a carbonyl group or an ester bond. Containing the solvent having a carbonyl group or an ester bond allows the dispersion stability of the dispersive dye to be improved as the (D1) pigment and/or (D2) dye. Furthermore, from the viewpoint of dispersion stability, the solvent is more preferably a solvent having an acetate bond. Containing the solvent having an acetate bond allows the dispersion stability of the dispersive dye to be improved as the (D1) pigment and/or (D2) dye.

Examples of the solvent having an acetate bond include 3-methoxy-n-butyl acetate, 3-methyl-3-methoxy-n-butyl acetate, ethylene glycol monomethyl ether acetate, propylene glycol monomethyl ether acetate, diethylene glycol monomethyl ether acetate, diethylene glycol monoethyl ether acetate, diethylene glycol mono-n-butyl ether acetate, dipropylene glycol monomethyl ether acetate, cyclohexanol acetate, propylene glycol diacetate, and 1,4-butanediol diacetate.

In the photosensitive resin composition according to the present invention, the content ratio of the solvent having a carbonyl group or an ester bond in the solvent is preferably 30 to 100% by mass, more preferably 50 to 100% by mass, still more preferably 70 to 100% by mass. When the content ratio is 30 to 100% by mass, the dispersion stability of the (D1) pigment can be improved.

### <Other Additives>

The photosensitive resin composition according to the present invention may further contain other resins or precursors thereof. Examples of the other resins or precursors thereof include polyamide, polyamideimide, epoxy resins, novolac resins, urea resins, and polyurethane, and precursors thereof.

### <Method for Producing Photosensitive Resin Composition According to Present Invention>

A typical method for producing the photosensitive resin composition according to the present invention will be described. In the case of containing the (D1) pigment including the (Da) black colorant as the (D) colorant, the (E) dispersant is added to a solution of the (A1) first resin and (A2) second resin, and with the use of a disperser, the pigment (D1) is dispersed in this mixed solution to prepare a pigment dispersion. Next, this pigment dispersion with the (B) radical polymerizable compound, the (C1) photo initiator, the other additives, and an optional solvent added thereto, is stirred for 20 minutes to 3 hours to provide a uniform solution. After the stirring, the obtained solution is filtered, thereby providing the photosensitive resin composition according to the present invention.

Examples of the disperser include a ball mill, a bead mill, a sand grinder, a triple roll mill, and a high-speed impact mill. From the viewpoints of more efficient dispersion and finer dispersion, a bead mill is preferred. Examples of the bead mill include a co-ball mill, a basket mill, a pin mill, or a DYNO mill. Examples of the beads of the bead mill include titania beads, zirconia beads, or zircon beads. The bead diameter of the bead mill is preferably 0.01 to 6 mm, more preferably 0.015 to 5 mm, still more preferably 0.03 to 3 mm. In a case where the primary particle size of the (D1) pigment and the particle size of the secondary particle formed by aggregation of the primary particles are equal to or smaller than several hundred nanometers (nm), fine beads of 0.015 to 0.1 mm are preferred. In this case, a bead mill is preferred which is provided with a separator capable of separating minute beads and the pigment dispersion by a centrifugal separation method. On the other hand, in a case where the (D1) pigment contains coarse particles equal to or larger than several hundred nanometers (nm), beads of 0.1 to 6 mm are preferred from the viewpoint of more efficient dispersion.

### <Cured Pattern in Low Taper Pattern Shape>

The photosensitive resin composition according to the present invention is capable of providing a cured film including a cured pattern in a low-taper pattern shape. The taper angle of the inclined side in a cross section of the cured pattern included in the cured film, obtained from the photosensitive resin composition according to the present invention is preferably 1° or more, more preferably 5° or more, still more preferably 10° or more, even more preferably 12° or more, particularly preferably 15° or more. When the taper angle is 1° or more, light-emitting elements can be integrated and arranged at high density, and the resolution of the display device can be thus improved. On the other hand, the taper angle of the inclined side in the cross section of the cured pattern included in the cured film is preferably 60° or less, more preferably 55° or less, still more preferably 50° or less, even more preferably 45° or less, particularly preferably 40 ° or less. When the taper angle is 60° or less, disconnection can be prevented in forming an electrode such as a transparent electrode or a reflective electrode. Furthermore, the electric field concentration at the edge of the electrode can be suppressed, and degradation of the light emitting elements can be thus suppressed.

<Curing Pattern with Step Shape>

The photosensitive resin composition according to the present invention is capable of forming a cured pattern that has a step shape with a sufficient difference in film thickness between a thick film part and a thin film part, and has a low-taper pattern shape, while maintaining a high sensitivity.

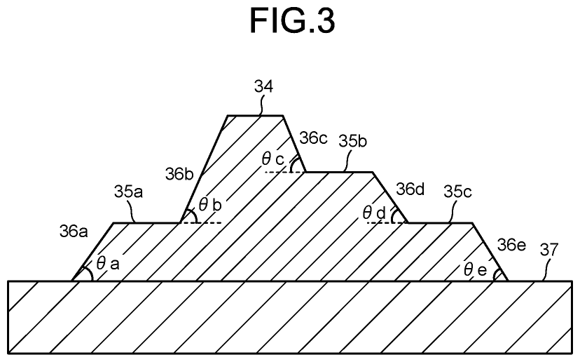

FIG. 3 shows therein a cross section example of a cured pattern which has a step shape, obtained from the photosensitive resin composition according to the present invention. As shown in FIG. 3, a thick film part 34 in the step shape corresponds to a cured part during exposure, and has the maximum film thickness of the cured pattern. Thin film parts 35a, 35b, and 35c in the step shape correspond to halftone exposed parts during exposure, and have film thicknesses smaller than the thickness of the thick film part 34. The taper angles θₐ, θ_{b}, θ_{c}, θ_{d}, and θₑ of inclined sides 36a, 36b, 36c, 36d, and 36e in the cross section of the cured pattern with the step shape preferably have low tapers.

The taper angles 8ₐ, e_{b}, e_{c}, e_{d}, and 19, herein refer to, in FIG. 3, angles inside the cross section of the cured pattern with the step shape, which are made by a horizontal side 37 of the underlying substrate with the cured pattern formed, or the horizontal sides of the thinner film parts 35a, 35b, and 35c, and the inclined sides 36a, 36b, 36c, 36d, and 36e in the cross section of the cured pattern with the step shape, which intersect the horizontal sides. The forward tapered shape means that the taper angle falls within the range of 1° to less than 90°, the inverse tapered shape means that the taper angle falls within the range of less than 91° to less than 180°, the rectangular shape means that the taper angle is 90°, and the low-taper shape means that the taper angle falls within the range of 1° to 60°.

### <Manufacturing Process for Organic EL Display >

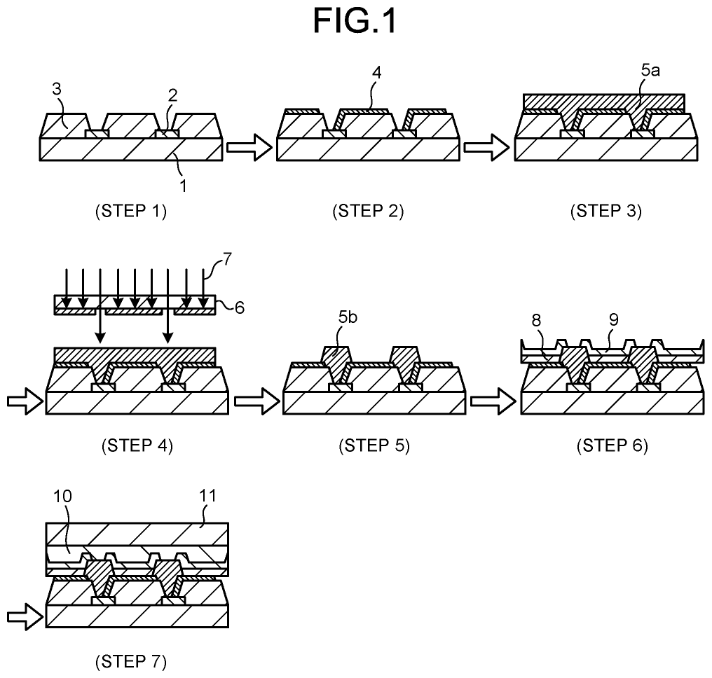

As a process with the photosensitive resin composition according to the present invention, a process using the cured film of the composition as a light-shielding pixel dividing layer of an organic EL display will be described as an example with the schematic cross-sectional shown in FIG. 1.

First, (Step 1) a thin-film-transistor (hereinafter, referred to as a “TFT”) 2 is formed on a glass substrate 1, a photosensitive material for a TFT planarization film is formed, subjected to pattern processing by photolithography, and then thermally cured to a cured film 3 for TFT planarization. Next, (Step 2) a silver-palladium-copper alloy (hereinafter, referred to as “APC”) is deposited by sputtering, and subjected to pattern processing by etching with the use of a photoresist to form an APC layer, and furthermore, as an upper layer on the APC layer, an indium tin oxide (hereinafter, referred to as an “ITO”) is formed by sputtering, and subjected to pattern processing by etching with the use of a photoresist to form the reflective electrode 4 as the first electrode. Thereafter, (Step 3) the photosensitive resin composition according to the present invention is applied and prebaked to form a prebaked film 5a. Then, (Step 4) irradiation with active actinic rays 7 is performed through a mask 6 that has a desired pattern. Next, (step 5) after development and pattern processing, bleaching exposure and middle baking are performed, if necessary, and thermal curing is performed, thereby forming, as a light-blocking pixel defining layer, a cured pattern 5b that has a desired pattern. Thereafter, (Step 6) an EL light-emitting material is deposited by vapor deposition through the mask 6 to form an EL light-emitting layer 8, and a magnesium-silver alloy (hereinafter, referred to as “MgAg”) is deposited by vapor deposition, and subjected to pattern processing by etching with the use of a photoresist to form a transparent electrode 9 as the second electrode. Next, (Step 7) a photosensitive material for a planarization film is deposited, subjected to patter processing by photolithography, and hen thermally cured to form a cured film 10 for planarization, and thereafter, cover glass 11 is joined, thereby providing an organic EL display including the photosensitive resin composition according to the present invention as a light-blocking pixel defining layer.

### <Manufacturing Process for Liquid Crystal Display >

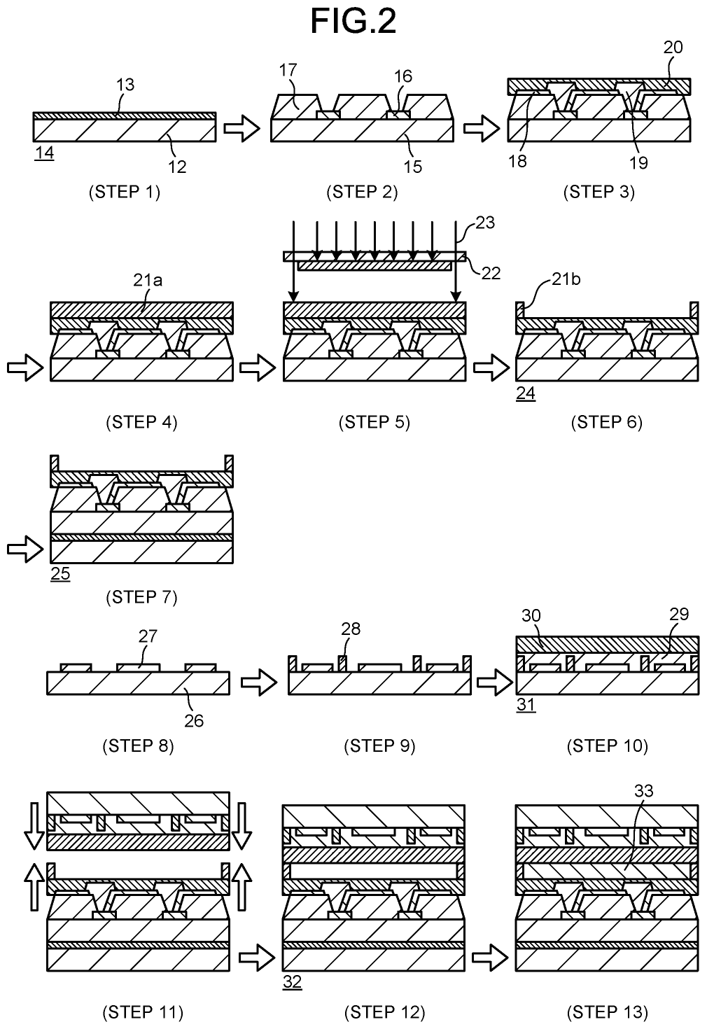

As another process with the photosensitive resin composition according to the present invention, a process with the cured film of the composition as a black column spacer (hereinafter, a “BCS”) for a liquid crystal display and a black matrix (hereinafter, a “BM”) for a color filter will be described as an example with the schematic cross-sectional view shown in FIG. 2.

First, (Step 1) a backlight unit (hereinafter, referred to as a “BLU”) 13 is formed on a glass substrate 12 to obtain a glass substrate 14 with the BLU. Furthermore, (Step 2) a TFT 16 is formed on another glass substrate 15, and a photosensitive material for a TFT planarization film is formed, subjected to pattern processing by photolithography, and then thermally cured to form a cured film 17 for TFT planarization. Next, (Step 3) an ITO is deposited by sputtering, and subjected to pattern processing by etching with the use of a photoresist to form a transparent electrode 18, and a planarization film 19 and an alignment layer 20 are formed thereon. Thereafter, (Step 4) the photosensitive resin composition according to the present invention is applied and prebaked to form a prebaked film 21a. Then, (step 5) irradiation with active actinic rays 23 is performed through a mask 22 that has a desired pattern. Next, (step 6) after development and pattern processing, bleaching exposure and middle baking are performed, if necessary, and thermal curing is performed, thereby forming, as a light-blocking BCS, a cured pattern 21b that has a desired pattern, and then providing a glass substrate 24 with the BCS. Then, (Step 7) the above-described glass substrate 14 and the glass substrate 24 are joined, thereby providing the glass substrate 25 with the BLU and the BCS.

Furthermore, (Step 8) On another glass substrate 26, color filters 27 of three colors of red, green and blue are formed. Next, (Step 9) a cured pattern 28 that has a desired pattern is formed as a light-blocking BM by the same method as mentioned above from the photosensitive resin composition according to the present invention. Thereafter, (Step 10) a photosensitive material for planarization is deposited, subjected to pattern processing by photolithography, and then thermally cured to form a cured film 29 for planarization, and an alignment layer 30 is formed thereon, thereby providing a color filter substrate 31. Next, (Step 11) the above-described glass substrate 25 with the BLU and the BCS and the color filter substrate 31 are joined (Step 12) to obtain a glass substrate 32 with the BLU, the BCS, and the BM. Next, (Step 13) a liquid crystal is injected to form a liquid crystal layer 33, thereby providing a liquid crystal display including the photosensitive resin composition according to the present invention as the BCS and the BM.

As described above, the methods for manufacturing an organic EL display and a liquid crystal display with the use of the photosensitive resin composition according to the present invention are capable of achieving high heat-resistance and light-blocking cured films containing polyimide and/or polybenzoxazole, subjected to pattern processing, thus leading to improvements in yield, performance, and reliability in the manufacture of organic EL displays and liquid crystal displays.

According to the process with the photosensitive resin composition according to the present invention, it is possible for the resin composition to be directly subjected to pattern processing by photolithography, because the composition is photosensitive. Accordingly, the number of steps can be reduced as compared with processes with photoresists, thus making it possible to improv the productivity of organic EL displays and liquid crystal displays, and reduce the process time and the takt time.

<Display Device with Cured Film Obtained from Photosensitive Resin Composition According to Present Invention>

The cured film obtained from the photosensitive resin composition according to the present invention can suitably constitute an organic EL display or a liquid crystal display.

Moreover, the photosensitive resin composition according to the present invention is capable of achieving a low-taper pattern shape, thereby making it possible to obtain a cured film which is excellent in high heat resistance. Thus, the composition is suitable for applications which require high heat resistance and low-taper pattern shapes, such as an insulation layer such as a pixel defining layer of an organic EL display, a TFT planarization layer, or a TFT protective layer. In particular, in applications in which problems due to heat resistance and pattern shapes are expected, such as element failures or characteristic degradation due to degassing by thermal decomposition, or electrode wiring disconnection due to high-taper pattern shapes, the use of a cured film of the photosensitive resin composition according to the present invention makes it possible to manufacture a highly reliable element where the above-described problems are kept from being caused. Furthermore, the cured film is excellent in light-blocking property, thus allowing electrode wiring to be prevented from becoming visible or allowing external light reflection to be reduced, and the contrast in image display can be thus improved.

Accordingly, the use of the cured film obtained from the photosensitive resin composition according to the present invention as a pixel defining layer of an organic EL display device, a TFT planarization layer, or a TFT protective layer can improve the contrast, without forming any polarizing plate and a quarter wavelength plate on the light extraction side of the light-emitting element.

Moreover, the photosensitive resin composition according to the present invention is capable of achieving a cured film which is excellent in bendability with flexibility. Thus, the cured film can be provided as a laminated structure on a flexible substrate, and the cured film is suitable for applications which require flexibility and low-taper pattern shape, such as an insulation layer such as a pixel defining layer of a flexible organic EL display, a TFT planarization layer, or a TFT protective layer Furthermore, the cured film has high heat resistance, and thus, in applications in which problems due to heat resistance and pattern shapes are expected, such as element failures or characteristic degradation due to degassing by thermal decomposition, or electrode wiring disconnection due to high-taper pattern shapes, the use of a cured film of the photosensitive resin composition according to the present invention makes it possible to manufacture a highly reliable element where the above-mentioned problems are not caused.

The display device according to the present invention preferably has a curved display unit. The curvature radius of the curved surface is preferably 0.1 mm or more, more preferably 0.3 mm or more, from the viewpoint of suppressing the defective display caused by disconnection or the like in the curved display unit. In addition, the curvature radius of the curved surface is preferably 10 mm or less, more preferably 7 mm or less, still more preferably 5 mm or less, from the viewpoint of reduction in size and increase in resolution for the display device.

The method for manufacturing a display device with the use of the photosensitive resin composition according to the present invention includes the following steps (1) to (4):

(1) a step of forming, on a substrate, a coating film of the photosensitive resin composition according to the present invention;

(2) a step of irradiating the coating film of the photosensitive resin composition with an active actinic ray through a photomask;

(3) a step of performing development with the use of an alkaline solution to form a pattern of the photosensitive resin composition; and (4) a step of heating the pattern to obtain a cured pattern of the photosensitive resin composition.

### <Step of Forming Coating Film>

The method for manufacturing a display device with the use of the photosensitive resin composition according to the present invention includes the (1) step of forming, on a substrate, a coating film of the photosensitive resin composition. Examples of the method for depositing the photosensitive resin composition according to the present invention include a method of applying the above-described resin composition on a substrate, or a method of applying the above-mentioned resin composition in a pattern on a substrate.

As the substrate, for example, a substrate is used which has an oxide including one or more selected from indium, tin, zinc, aluminum, and gallium, a metal (e.g., molybdenum, silver, copper, aluminum, chromium, or titanium), or a CNT (Carbon Nano Tube) formed as an electrode or a wiring on a glass.

Examples of the oxide including one or more selected from indium, tin, zinc, aluminum, and gallium include an indium tin oxide (ITO), an indium zinc oxide (IZO), an aluminum zinc oxide (AZO), an indium gallium zinc oxide (IGZO), and a zinc oxide (ZnO).

### <Method of Applying Photosensitive Resin Composition According to Present Invention on Substrate>

Examples of the method for applying the photosensitive resin composition according to the present invention on a substrate include microgravure coating, spin coating, dip coating, curtain flow coating, roll coating, spray coating, and slit coating. The coating film thickness varies depending on the coating method, the solid content concentration and viscosity of the resin composition, and the like, and the composition is typically applied such that the film thickness after coating and prebaking is 0.1 to 30 μm.

The photosensitive resin composition according to the present invention is preferably applied on a substrate, and then prebaked to form a film. The prebaking can use an oven, a hot plate, infrared rays, a flash annealing device, a laser annealing device, or the like. The prebaking temperature is preferably 50 to 150° C. The prebaking time is preferably 30 seconds to several hours. Prebaking in two or more stages may be performed, such as prebaking at 80° C. for 2 minutes, and then prebaking at 120° C. for 2 minutes.

### <Method of Applying Photosensitive Resin Composition According to Present Invention in Pattern on Substrate>

Examples of the method of applying the photosensitive resin composition according to the present invention in a pattern on a substrate include letterpress printing, intaglio printing, stencil printing, planographic printing, screen printing, ink-jet printing, offset printing, and laser printing. The coating film thickness varies depending on the coating method, the solid content concentration and viscosity of the photosensitive resin composition according to the present invention, and the like, and the composition is typically applied such that the film thickness after coating and prebaking is 0.1 to 30 μm.

The photosensitive resin composition according to the present invention is preferably applied in a pattern on a substrate, and then prebaked to form a film. The prebaking can use an oven, a hot plate, infrared rays, a flash annealing device, a laser annealing device, or the like. The prebaking temperature is preferably 50 to 150° C. The prebaking time is preferably 30 seconds to several hours. Prebaking in two or more stages may be performed, such as prebaking at 80° C. for 2 minutes, and then prebaking at 120° C. for 2 minutes.

### <Method for Pattern Processing of Coating Film Formed on Substrate>

Examples of the method for pattern processing of the coating film of the photosensitive resin composition according to the present invention formed on the substrate include a method of direct pattern processing by photolithography and a method of pattern processing by etching. From the viewpoint of improving productivity by reducing the number of steps and reducing the process time, a method of direct pattern processing by photolithography is preferred.

<Step of Irradiation with Active Actinic Ray through Photomask>

The method for manufacturing a display device with the use of the photosensitive resin composition according to the present invention includes the (2) step of irradiating the above-described coating film of the photosensitive resin composition with active actinic rays through a photomask.

Onto the substrate, the photosensitive resin composition according to the present invention is applied and prebaked to form a film, and then exposed with the use of an exposure machine such as a stepper, a mirror projection mask aligner (MPA), or a parallel light mask aligner (PLA). Examples of the active actinic rays in irradiation for the exposure include ultraviolet light, visible light, electron beams, X-rays, KrF (wavelength: 248 nm) lasers, and ArF (wavelength: 193 nm) lasers. It is preferable to use j-rays (wavelength: 313 nm), i-rays (wavelength: 365 nm), h-rays (wavelength: 405 nm), or g-rays (wavelength: 436 nm) from a mercury lamp. In addition, the exposure energy is typically approximately 100 to 40,000 J/m² (10 to 4,000 mJ/cm²) (i-line illuminance meter value), and exposure can be performed through a photomask that has a desired pattern, if necessary.

After the exposure, post-exposure baking may be performed. By performing the post-exposure baking, effects can be expected, such as an improved resolution after development or increased tolerance for development conditions. The post-exposure baking can use an oven, a hot plate, infrared rays, a flash annealing device, a laser annealing device, or the like. The post-exposure baking temperature is preferably 50 to 180° C., more preferably 60 to 150° C. The post-exposure baking time is preferably 10 seconds to several hours. When the post-exposure baking time is 10 seconds to several hours, the reaction may proceed favorably, thereby shortening the development time.

<Step of Performing Development with Alkaline Solution to Form Pattern>

The method for manufacturing a display device with the use of the photosensitive resin composition according to the present invention includes the (3) step of performing development with the use of an alkaline solution to form a pattern of the photosensitive resin composition described above. After the exposure, development is performed with the use of an automatic development device or the like. The photosensitive resin composition according to the present invention has photosensitivity, and thus, after the development, the exposed part or the unexposed part is removed with a developer, thereby allowing a relief pattern to be obtained.

As the developer, an alkaline developer is typically used. As the alkaline developer, for example, an organic alkaline solution or an aqueous solution of an alkaline compound is preferred, and an aqueous solution of an alkaline compound, that is, an alkaline aqueous solution is more preferred from the viewpoint of the environment aspect.

Examples of the organic alkaline solution or alkaline compound include 2-aminoethanol, 2-(dimethylamino)ethanol, 2-(diethylamino)ethanol, diethanolamine, methylamine, ethylamine, dimethylamine, diethylamine, triethylamine, acetic acid (2-dimethylamino)ethyl, (meth)acrylic acid (2-dimethylamino) ethyl, cyclohexylamine, ethylenediamine, hexamethylenediamine, ammonia, tetramethylammonium hydroxide, tetraethylammonium hydroxide, sodium hydroxide, potassium hydroxide, magnesium hydroxide, calcium hydroxide, barium hydroxide, sodium carbonate, and potassium carbonate, and from the viewpoint of reducing metal impurities in the cured film and suppressing defective display in the display device, tetramethylammonium hydroxide or tetraethylammonium hydroxide is preferred.

As the developer, an organic solvent may be used. As the developer, a mixed solution may be used which contains both the organic solvent and a poor solvent with respect to the photosensitive resin composition according to the present invention.

Examples of the development method include paddle development, spray development, and dip development. Examples of the paddle development include a method of applying the above-described developer directly to the exposed film, and then leaving the film for an arbitrary period of time, and a method of applying the above-described developer by spraying in the form of a mist to the exposed film for an arbitrary period of time, and then leaving the film for an arbitrary period of time. Examples of the spray development include a method of keeping on spraying the above-described developer in the form of a mist to the exposed film for an arbitrary period of time. Examples of the dip development include a method of immersing the exposed film in the developer described above for an arbitrary period of time, and a method of immersing the exposed film in the developer described above, and then keeping on irradiation with ultrasonic waves for an arbitrary period of time. From the viewpoint of suppressing device contamination during the development and reducing the process cost by reducing the usage of the developer, the paddle development is preferred as the development method. Device contamination during the development is suppressed, thereby allowing substrate contamination during the development to be suppressed, and then allowing defective display in the display device to be suppressed. On the other hand, from the viewpoint of inhibiting the residue generation after development, the spray development is preferred as the development method. In addition, from the viewpoint of reducing the usage of the developer by reuse of the developer and reducing the process cost, the dip development is preferred as the development method.

The development time is preferably 5 seconds or longer, more preferably 10 seconds or longer, still more preferably 30 seconds or longer, particularly preferably 1 minute or longer. When the development time falls within the range mentioned above, the residue generation during the alkali development can be inhibited. On the other hand, from the viewpoint of reducing the takt time, the development time is preferably 30 minutes or shorter, more preferably 15 minutes or shorter, still more preferably 10 minutes or shorter, particularly preferably 5 minutes or shorter.

After the development, the obtained relief pattern is preferably washed with a rinse solution. As the rinse solution, water is preferred in a case where an alkaline aqueous solution is used as the developer. As the rinsing solution, for example, an aqueous solution of an alcohol such as ethanol or isopropyl alcohol, an aqueous solution of an ester such as propylene glycol monomethyl ether acetate, or an aqueous solution of an acidic compound such as carbon dioxide, hydrochloric acid, or acetic acid may be used. As the rinse solution, an organic solvent may be used.

After obtaining the pattern of the photosensitive resin composition according to the present invention by photolithography, bleaching exposure may be performed. Performing bleaching exposure allows the pattern shape after thermal curing to be arbitrarily controlled. Moreover, the transparency of the cured film can be improved.

For the bleaching exposure, an exposure machine such as a stepper, a mirror projection mask aligner (MPA), or a parallel light mask aligner (PLA) can be used. Examples of the active actinic rays in irradiation for the bleaching exposure include ultraviolet light, visible light, electron beams, X-rays, KrF (wavelength: 248 nm) lasers, and ArF (wavelength: 193 nm) lasers. It is preferable to use f-rays (wavelength: 313 nm), i-rays (wavelength: 365 nm), b-rays (wavelength: 405 nm), or g-rays (wavelength: 436 nm) from a mercury lamp. In addition, the exposure energy is typically approximately 500 to 500,000 J/m² (50 to 50,000 mJ/cm²) (i-line illuminance meter value), and exposure can be performed through a mask that has a desired pattern, if necessary.

After obtaining the pattern of the photosensitive resin composition according to the present invention, middle baking may be performed. Performing middle baking improves the resolution after thermal curing, and allows the pattern shape after thermal curing to be arbitrarily controlled. The middle baking can use an oven, a hot plate, infrared rays, a flash annealing device, a laser annealing device, or the like. The middle baking temperature is preferably 50 to 250° C., more preferably 70 to 220° C. The middle baking time is preferably 10 seconds to several hours. Middle baking in two or more stages may be performed, such as middle baking at 100° C. for 5 minutes, and then middle baking at 150° C. for 5 minutes.

### <Step of Heating Pattern to Obtain Cured Pattern>

The method for manufacturing a display device with the use of the photosensitive resin composition according to the present invention includes the (4) step of heating the pattern of the photosensitive resin composition described above to obtain a cured pattern of the photosensitive resin composition described above.

For heating the pattern of the photosensitive resin composition according to the present invention, formed on the substrate, an oven, a hot plate, infrared rays, a flash annealing device, a laser annealing device, or the like can be used. The pattern of the photosensitive resin composition according to the present invention is cured and then thermally cured, thereby allowing the heat resistance of the cured film to be improved, and allowing a low-taper pattern shape to be obtained.

The temperature for thermosetting is preferably 150° C. or higher, more preferably 200° C. or higher, and further preferably 250° C. or higher. When the thermal curing temperature is 150° C. or higher, the heat resistance of the cured film can be improved, and the pattern shape after the thermal curing can be further reduced in taper. On the other hand, from the viewpoint of shortening the tact time, the thermosetting temperature is preferably 500° C. or lower, more preferably 450° C. or lower, and further preferably 400° C. or lower.

The time for the thermal curing is preferably 1 minute or longer, more preferably 5 minutes or longer, still more preferably 10 minutes or longer, particularly preferably 30 minutes or longer. When the thermal curing time is 1 minute or longer, the pattern shape after the thermal curing can be further reduced in taper. On the other hand, from the viewpoint of reducing the takt time, the time for the thermal curing is preferably 300 minutes or shorter, more preferably 250 minutes or shorter, still more preferably 200 minutes or shorter, particularly preferably 150 minutes or shorter. Thermal curing in two or more stages may be performed, such as thermal curing at 150° C. for 30 minutes, and then thermal curing at 250° C. for 30 minutes.

Further, the photosensitive resin composition a to the present invention makes it possible to obtain cured films which are suitably used for applications such as a pixel defining layer, an electrode insulation layer, a wiring insulation layer, an interlayer insulation layer, a TFT planarization layer, an electrode planarization layer, a wiring planarization layer, a TFT protective layer, an electrode protective layer, a wiring protective layer, a gate insulation layer, a color filter, a black matrix, or a black column spacer. Moreover, it becomes possible to obtain an elements and display devices including the cured films. The organic EL display according to the present invention includes the above-mentioned cured film as one or more selected from the group consisting of a pixel defining layer, an electrode insulation layer, a wiring insulation layer, an interlayer insulation layer, a TFT planarization layer, an electrode planarization layer, a wiring planarization layer, a TFT protective layer, an electrode protective layer, a wiring protective layer, a gate insulation layer, a color filter, a black matrix, and a black column spacer. In particular, the negative photosensitive resin composition according to the present invention is excellent in light-blocking property, and thus more preferred as a light-blocking pixel defining layer, electrode insulation layer, wiring insulation layer, interlayer insulation layer, TFT planarization layer, electrode planarization layer, wiring planarization layer, TFT protective layer, electrode protective layer, wiring protective layer, or gate insulating layer of an organic EL display protective layer, and suitable for applications which require contrast increased by suppression of external light reflection, such as a light-blocking pixel defining layer, interlayer insulation layer, TFT planarization layer, or TFT protective layer.

Furthermore, the methods for manufacturing a display device with the use of the photosensitive resin composition according to the present invention are capable of achieving high heat-resistance and light-blocking cured films containing polyimide and/or polybenzoxazole, subjected to pattern processing, thus leading to improvements in yield, performance, and reliability in the manufacture of organic EL displays and liquid crystal displays. In addition, since the photosensitive resin composition according to the present invention is capable of being directly subjected to pattern processing by photolithography, the number of steps can be reduced as compared with processes with photoresists, thus making it possible to improv the productivity, and reduce the process time and the takt time.

### EXAMPLE 1

The present invention will be described more specifically with reference to examples and comparative examples, but the present invention is not limited to the scope thereof. It is to be noted that here are names for the abbreviation used for some of the compounds used.

6FDA: 2,2-(3,4-dicarboxyphenyl)hexafluoropropane dianhydride; 4,4′-hexafluoropropane-2,2-diyl-bis(1,2-phthalic anhydride)

AcrTMS: 3-acryloxypropyltrimethoxysilane

A-DPH-6E: “NK ESTER” (registered trademark) A-DPH-6E (manufactured by Shin Nakamura Chemical Co., Ltd.; ethoxylated dipentaerythritol hexaacrylate having 6 oxyethylene structures in the molecule)

APC: Argentum-Palladium-Cupper (silver-palladium-copper alloy)

BAHF: 2,2-bis(3-amino-4-hydroxyphenyl) hexafluoropropane

BAPF: 9,9-bis(3-amino-4-hydroxyphenyl)fluorene

BFE: 1,2-bis(4-formylphenyl)ethane

BHPF: 9,9-bis(4-hydroxyphenyl)fluorene

Bis-A-AF: 2,2-bis(4-aminophenyl)hexafluoropropane

Bk-A1103: “CHROMOFINE” (registered trademark) BLACK A1103 (manufactured by Dainichiseika Color & Chemicals Mfg. Co., Ltd.; azo-based black pigment of 50 to 100 nm in primary particle size)

Bk-50084: “PALIOGEN” (registered trademark) BLACK S0084 (manufactured by BASF; perylene-based black pigment of 50 to 100 nm in primary particle size)

BLACK S0100CF; “IRGAPHOR” (registered trademark) BLACK S0100CF (manufactured by BASF; benzofuranone-based black pigment of 40 to 80 nm in primary particle size)

D.BYK-167: “DISPERBYK” (registered trademark) -167 (manufactured by BYK-Chemie Japan; polyurethane-based dispersant having a tertiary amino group with an amine value of 13 mgKOH/g (solid content concentration: 52% by mass))

DFA: N, N-dimethylformamide dimethyl acetal

DPCA-30; “KAYARAD” (registered trademark) DPCA-30 (manufactured by Nippon Kayaku Co., Ltd.; ε-caprolactone-modified dipentaerythritol hexaacrylate having 3 oxypentylene carbonyl structures in the molecule)

DPCA-60; “KAYARAD” (registered trademark) DPCA-60 (manufactured by Nippon Kayaku Co., Ltd.; ε-caprolactone-modified dipentaerythritol hexaacrylate having 6 oxypentylene carbonyl structures in the molecule)

DPHA: “KAYARAD” (registered trademark) DPHA (manufactured by Nippon Kayaku Co., Ltd.; dipentaerythritol hexaacrylate)

DPMP: Dipentaerythritol hexakis(3-mercaptopropionate) EOCN-1020: Epoxy resin having a benzene skeleton and a structural unit including an epoxy group (manufactured by Nippon Kayaku Co., Ltd.)

FLE-1: 9,9-bis[4-(2-glycidoxyethoxy)phenyl]fluorene

FLE-2: 9,9-bis(4-glycidoxy-1-naphthyl)fluorene

FLE-3: Epoxy compound having two fluorene skeletons and two epoxy groups

FR-201: 9,9-bis(4-glycidoxyphenyl)fluorene (manufactured by Tronly)

GMA: Glycidyl methacrylate

HA: N,NY-bis[5,5′-hexafluoropropane-2,2-diyl-bis(2-hydroxyphenyl)]bis(3-aminobenzoic acid amide)

HX-220: “KAYARAD” (registered trademark) HX-220 (manufactured by Nippon Kayaku Co., Ltd.; ε-caprolactone-modified hydroxypivalate neopentyl glycol diacrylate having two oxypentylene carbonyl structures in the molecule)

IDE-1: 1,1-bis(4-glycidoxyphenyl)-3-phenylindane IDE-2: 1,1-bis[4-(2-glycidoxyethoxy)phenyl]-3-phenylindane

IGZO: Indium gallium zinc oxide

ITO: Indium tin oxide

jer-834: 2,2-bis(4-glycidoxyphenyl)propane (manufactured by Mitsubishi Chemical Corporation)

MAA: Methacrylic acid

MAP: 3-aminophenol; meta amino phenol

MBA: 3-methoxy-n-butyl acetate

MeTMS: Methyltrimethoxysilane

MgAg: Magnesium-Argentum (magnesium-silver alloy)

NA: 5-norbornene-2,3-dicarboxylic anhydride; nadic anhydride

NC-3500: Epoxy resin having a structural unit including a biphenyl skeleton, a benzene skeleton, and two epoxy groups (manufactured by Nippon Kayaku Co., Ltd.)

NC-7000L: Epoxy resin having a structural unit including a naphthalene skeleton, a benzene skeleton, and two epoxy groups (manufactured by Nippon Kayaku Co., Ltd.)

NC-7300L: Epoxy resin having a structural unit including a naphthalene skeleton, a benzene skeleton, and two epoxy groups (manufactured by Nippon Kayaku Co., Ltd.)

NCI-831: “ADEKA ARKLS” (registered trademark) NCI-831 (manufactured by ADEKA Corporation; oxime ester-based photo initiator).

NMP: N-methyl-2-pyrrolidone

ODPA: bis(3,4-dicarboxyphenyl)ether dianhydride; oxydiphthalic dianhydride

P. B. 15: 6; C. I. Pigment Blue 15: 6

P. R. 254: C. I. Pigment Red 254

P. V. 23: C. I. Pigment Violet 23

P. Y. 139: C. I. Pigment Yellow 139

PGMEA: Propylene glycol monomethyl ether acetate

PHA: phthalic anhydride

PhTMS: Phenyltrimethoxysilane

S-20000: “SOLSPERSE” (registered trademark) 20000 (manufactured by Lubrizol; polyoxyalkylene ether-based dispersant having a tertiary amino group with an amine value of 32 mg KOH/g (solid content concentration: 100% by mass))

SiDA: 1,3-bis(3-aminopropyl)tetramethyldisiloxane

STR: Styrene

TAZ-G: 2,4,6-tris(glycidyloxy)triazine

TCDM: tricyclo[5.2.1.0^{2,6}]decan-8-yl methacrylate; dimethylol-tricyclodecane dimethacrylate

ICA-GST: 1,3,5-tris(glycidylstearyl) isocyanurate

TBIS-BNG200: 2,2′-bis(glycidoxy)-1,1′-binaphthalene (TAOKA CHEMICAL COMPANY, LIMITED)

TBIS-RXG: 3′,6′-bis(glycidoxy)-spiro[9H-fluorene-9,9-[9H]xanthene] (TAOKA CHEMICAL COMPANY, LIMITED)

TEPIC-FL: “TEPIC” (registered trademark) -FL (manufactured by Nissan Chemical Corporation; 1,3,5-tris(5-glycidylpentyl) isocyanurate)

TEPIC-L: “TEPIC” (registered trademark) -L (manufactured by Nissan Chemical Corporation; 1,3,5-tris(glycidyl) isocyanurate)

TG-G: 1,3,4,6-tetrakis(glycidyl)glycoluril (manufactured by SHIKOKU CHEMICALS CORPORATION)

THPHA: 1,2,3,6-tetrahydrophthalic anhydride

TMAH: Tetramethylammonium hydroxide

TMOS: Tetramethoxysilane

TMMP: Trimethylolpropane tris(3-mercaptopropionate)

TMSSucA: 3-trimethoxysilylpropyl succinic anhydride

TPK-1227; carbon black (manufactured by CABOT) surface-treated for introducing a sulfonic acid group.

WHR-9915: 3,3-bis(4-glycidoxyphenyl)-1-isoindolinone (manufactured by Nippon Kayaku Co., Ltd.)

WR-301: “ADEKA ARKLS” (registered trademark) WR-301 (polycyclic side chain-containing resin obtained by reacting a carboxylic anhydride with the resin obtained by the ring-opening addition reaction of an aromatic compound having an epoxy group and an unsaturated carboxylic acid, acid equivalent: 560, double bond equivalent: 450)

XD-1000-H: Epoxy resin having a benzene skeleton, a tricyclodecane skeleton, and a structural unit including an epoxy group (manufactured by Nippon Kayaku Co., Ltd.)

### SYNTHESIS EXAMPLE (A)

In a three-neck flask, 18.31 g (0.05 mol) of BAHF and 17.42 g (0.3 mol) of propylene oxide were dissolved in 100 mL of acetone weighed. Into this solution, a solution of 20.41 g (0.11 mol) of 3-nitrobenzoyl chloride dissolved in 10 mL of acetone was delivered by drops. After the completion of dropping, the solution was allowed to undergo a reaction for 4 hours at −15° C., and then, the temperature thereof was returned to room temperature. The precipitated white solid matter was filtered off, and subjected to vacuum dry at 50° C. In a 300 mL stainless-steel autoclave, 30 g of the obtained solid was placed, dispersed in 250 mL of 2-methoxyethanol, and 2 g of 5% palladium-carbon was added to the dispersion. Into the dispersion, hydrogen was introduced with a balloon, thereby allowing for a reaction at room temperature for 2 hours. After 2 hours, it was confirmed that the balloon is not squeezed any more. After completion of the reaction, the palladium compound as a catalyst was removed by filtration, and the filtrate was concentrated by distillation under reduced pressure to obtain a hydroxy group-containing diamine compound (HA) having the structure shown below.

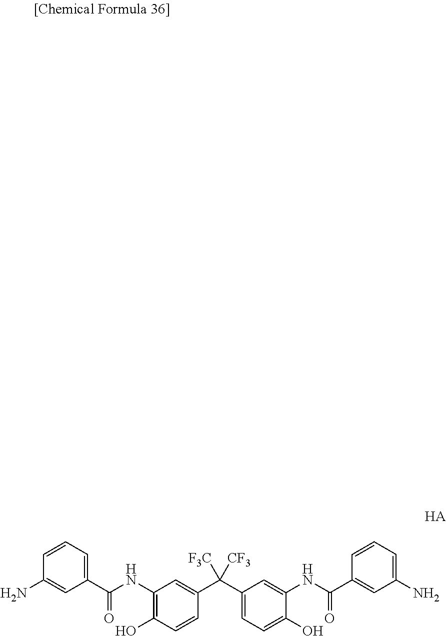 [SMILES: Nc1cccc(C(=O)Nc2cc(C(c3ccc(O)c(NC(=O)c4cccc(N)c4)c3)(C(F)(F)F)C(F)(F)F)ccc2O)c1]

Next, synthesis examples will be described. The compositions according to Synthesis Examples 1 to 14 are shown in Table 1-1 to Table 1-3.

TABLE 1-1

| | | | | | | | | | | Structural Unit | |
|---|---|---|---|---|---|---|---|---|---|---|---|
| | | | | | | | | | Structural Unit | derived from | |
| | | | | | | | | Structural Unit | derived from | Monomer having | |
| | | | | | | | | derived from | Monomer having | Fluorine Atom to | |
| | | | | | | | | Monomer having | Fluorine Atom to | Structural Units | |
| | | Monomer [mol ratio] | | | | | | Fluorine Atom | Structural Units | derived from | |
| | | Tetracarboxylic | | | | | | to All of | derived from All | structural units | Acid |
| | | Acid and | | | | | End- | Structural | of Carboxylic | derived from All of | Equiva- |
| | | Derivatives | | Diamine and Derivatives | | | capping | Units | Acid Derivatives | Amine Derivatives | lent |
| | Polymer | thereof | | thereof | | | Agent | [mol %] | [mol %] | [mol %] | [g/mol] |
| Synthesis | Polyimide | ODPA | — | BAHF | — | SiDA | MAP | 40.5 | 0.0 | 77.3 | 350 |
| Example 1 | (PI-1) | (100) | | (85) | | (5) | (20) | | | | |
| Synthesis | Polyimide | ODPA | — | BAHF | Bis-A-AF | SiDA | MAP | 16.7 | 0.0 | 31.8 | 720 |
| Example 2 | (PI-2) | (100) | | (35) | (50) | (5) | (20) | | | | |
| Synthesis | Polyimide | ODPA | 6FDA | BAHF | — | SiDA | MAP | 59.5 | 40.0 | 77.3 | 380 |
| Example 3 | (PI-3) | (60) | (40) | (85) | | (5) | (20) | | | | |
| Synthesis | Polyimide | — | 6FDA | BAHF | — | SiDA | MAP | 88.1 | 100.0 | 77.3 | 420 |
| Example 4 | (PI-4) | | (100) | (85) | | (5) | (20) | | | | |
| Synthesis | Polyimide | ODPA | — | — | BAPF | SiDA | MAP | 0.0 | 0.0 | 0.0 | 360 |
| Example 5 | (PI-5) | (100) | | | (85) | (5) | (20) | | | | |
| Synthesis | Polyimide | — | 6FDA | BAHF | HA | SiDA | MAP | 75.6 | 100.0 | 56.0 | 450 |
| Example 6 | Precursor | | (100) | (40) | (30) | (5) | (50) | | | | |
| | (PIP-1) | | | | | | | | | | |
| Synthesis | Polyimide | ODPA | 6FDA | BAHF | HA | SiDA | MAP | 57.8 | 60.0 | 56.0 | 420 |
| Example 7 | Precursor | (40) | (60 | (40) | (30) | (5) | (50) | | | | |
| | (PIP-2) | | | | | | | | | | |

TABLE 1-2

| | | | | | | | | Structural Unit | | |
|---|---|---|---|---|---|---|---|---|---|---|
| | | | | | | | | derived from | | |
| | | | | | | | | Monomer | | |
| | | | | | | | | having | | |
| | | Monomer [mol ratio] | | | | | Structural Unit | Fluorine | | |
| | | Dicarboxylic | | | | Structural Unit | derived from | Atom to | | |
| | | Acid and | | | | derived from | Monomer having | Structural Units | | |
| | | Derivatives | Bisaminophenol | | | Monomer | Fluorine Atom | dervived from | | |
| | | thereof | Compound and | | | having | to Structural | structural units | | |
| | | Diformyl | Derivatives | | | Fluorine Atom | Units derived | dervived from | | Double |
| | | Compound | thereof | | | to All of | from All of | All | Acid | Bond |
| | | and | Dihydroxydiamine | | End- | Structural | Carboxylic Acid | of Amine | Equiva- | Equiva- |
| | | Derivatives | and Derivatives | | capping | Units | Derivatives | Derivatives | lent | lent |
| | Polymer | thereof | thereof | | Agent | [mol %] | [mol %] | [mol %] | [g/mol] | [g/mol] |
| Synthesis | Polybenzoxazole | BFE | BAHF | SiDA | NA | 43.2 | 0.0 | 95.0 | 330 | — |
| Example 8 | (PBO-1) | (80) | (95) | (5) | (40) | | | | | |
| Synthesis | Polybenzoxazole | BFE | BAHF | SiDA | NA | 43.2 | 0.0 | 95.0 | 330 | — |
| Example 9 | Precursor | (80) | (95) | (5) | (40) | | | | | |
| | (PBOP-1) | | | | | | | | | |
| | | | | | | | | Structural Unit | | |
| | | | | | | | | derived from | | |
| | | Monomer [mol %] | | | | | | Organosilane | | |
| | | | | | | Tetrafunctional | | having | | Double |
| | | | | | | Organosilane | Bifunctional | Aromatic | Acid | Bond |
| | | | | | | Tetrafunctional | Organosilane | Group to | Equiva- | Equiva- |
| | | | | | | Organosilane | Monofunctional | Polysiloxane | lent | lent |
| | Polymer | Trifunctional Organosilane | | | | Oligomer | Organosilane | [mol %] | [g/mol] | [g/mol] |
| Synthesis | Polysiloxane | MeTMS | PhTMS | TMSSucA | — | TMOS | — | 50.0 | 700 | — |
| Example 10 | Solution | (35) | (50) | (10) | | (5) | | | | |
| | (PS-1) | | | | | | | | | |
| Synthesis | Polysiloxane | MeTMS | PhTMS | TMSSucA | AcrTMS | — | — | 50.0 | 800 | 800 |
| Example 11 | Solution | (20) | (50) | (10) | (20) | | | | | |
| | (PS-2) | | | | | | | | | |

TABLE 1-3

| | | | | | | Structural Unit | | |
|---|---|---|---|---|---|---|---|---|
| | | | | | | derived from | | |
| | | | | | | Monomer having | | |
| | | | | | | Aromatic Group to | | |
| | | Monomer [mol ratio] | | | | Structural Units | | |
| | | Compound | | | Unsaturated | derived from | | |
| | | having | | | Compound having | structural units | | Double |
| | | Two or More | Tetracarboxylic | | Ethylenically | derived from All | Acid | Bond |
| | | Aromatic | Dianhydride | End- | Unsaturated | of Carboxylic | Equiva- | Equiva- |
| | | Groups and | Tetracarboxylic | capping | Double Bond Group | Acid Derivatives | lent | lent |
| | Polymer | Hydroxy Group | Acid | Agent | and Epoxy Group | [mol %] | [g/mol] | [g/mol] |
| Synthesis | Polycyclic Side | BHPF | ODPA | PHA | GMA | 100.0 | 810 | 810 |
| Example 12 | Chain-containing | (100) | (90) | (20) | (100) | | | |
| | Resin Solution | | | | | | | |
| | (CR-1) | | | | | | | |
| | | | | | | Structural Unit | | |
| | | | | | | derived from | | |
| | | | | | | Monomer having | | |
| | | Monomer [mass, mol, and mol ratio] | | | | Aromatic Group to | | |
| | | | | | Unsaturated | Structural Units | | |
| | | | | | Carboxylic Acid | derived from | | |
| | | | | | having | structural units | | Double |
| | | | | Dicarboxylic | Ethylenically | derived from All | Acid | Bond |
| | | | | Anhydride | Unsaturated | of Carboxylic | Equiva- | Equiva- |
| | | Compound having Aromatic Group | | Dicarboxylic | Double Bond | Acid Derivatives | lent | lent |
| | Polymer | and Epoxy Group | | Acid | Group | [mol %] | [g/mol] | [g/mol] |
| Synthesis | Acid-modified | NC-7300L | | THPHA | MAA | 0.0 | 510 | 410 |
| Example 13 | Epoxy Resin | (Epoxy Equivalent: 210 g/mol) | | 24.34 g | 17.22 g | | | |
| | Solution | 42.00 g | | (0.16 mol) | (0.20 mol) | | | |
| | (AE-1) | (Epoxy Group Standard: 0.2 mol) | | (mol ratio: 80) | (mol ratio: 100) | | | |
| | | (Epoxy Group Standard | | | | | | |
| | | mol ratio: 100) | | | | | | |
| | | | | | | Structural Unit | | |
| | | | | | | derived from | | |
| | | | | | | Monomer having | | |
| | | | | | | Aromatic Group | | |
| | | | | | | to Structural | | |
| | | Monomer [mol ratio] | | | | Units derived | | |
| | | Copolymer- | Copolymer- | Copolymer- | Unsaturated | from structural | | |
| | | ization | ization | ization | Compound having | units derived | | Double |
| | | Component | Component | Component | Ethylenically | from All of | Acid | Bond |
| | | having | having | having | Unsaturated | Copolymerization | Equiva- | Equiva- |
| | | Acidic | Aromatic | Alicyclic | Double Bond Group | Components | lent | lent |
| | Polymer | Group | Group | Group | and Epoxy Group | [mol %] | [g/mol] | [g/mol] |
| Synthesis | Acrylic Resin | MAA | STR | TCDM | GMA | 30.0 | 490 | 740 |
| Example 14 | Solution | (50) | (30) | (20) | (20) | | | |
| | (AC-1) | | | | | | | |

### SYNTHESIS EXAMPLE 1

### Synthesis of Polyimide (PI-1)

Under a dry nitrogen stream, 31.13 g (0.085 mol; 77.3 mol % based on the structural units derived from all of amines and derivatives thereof) of BAHF and 1.24 g (0.0050 mol; 4.5 mol % based on the structural units derived from all of amines and derivatives thereof) of SiDA, 2.18 g (0.020 mol; 18.2 mol % based on the structural units derived from all of amines and derivatives thereof) of MAP as an end-capping agent, and 150.00 g of NMP were weight, and then dissolved in a three-neck flask. To this solution, a solution of 31.02 g (0.10 mol; 100 mol % based on the structural units derived from all of carboxylic acids and derivatives thereof) of ODPA dissolved in 50.00 g of NMP was added, stirred at 20° C. for 1 hour, and then 50° C. for 4 hours. Thereafter, 15 g of xylene was added thereto, and the solution was stirred for 5 hours at 150° C. while azeotroping the water with the xylene. After completion of the reaction, the reaction solution was poured into 3 L of water, and the deposited solid precipitate was obtained by filtration. The obtained solid was washed with water three times, and then dried for 24 hours with a vacuum dryer at 80° C. to obtain a polyimide (PI-1). The Mw of the obtained polyimide was 27,000, and the acid equivalent thereof was 350.

### SYNTHESIS EXAMPLES 2-5

### Synthesis of Polyimide (PI-2) to Polyimide (PI-5)

With the monomer types and ratios thereof shown in Table 1-1, polymerization was performed in the same manner as in Synthesis Example 1 to obtain a polyimide (PI-2) to a polyimide (PI-5).

### SYNTHESIS EXAMPLE 6

### Synthesis of Polyimide Precursor (PIP-1)

Under a nitrogen stream, 44.42 g (0.10 mol; 100 mol % based on the structural units derived from all of carboxylic acids and derivatives thereof) of 6FDA and 150 g of NMP were weighed, and then dissolved in a three-necked flask. To this solution, a solution of: 14.65 g (0.040mol; 32.0 mol % based on the structural units derived from all of amines and derivatives thereof) of BAHF; 18.14 g (0.030 mol; 24.0 mol % based on the structural units derived from all of the amines and derivatives thereof) of HA; and 1.24 g (0.0050 mol; 4.0 mol % based on the structural units derived from all of the amines and derivatives thereof) of SiDA dissolved in 50 g of NMP was added, and the solution was stirred at 20° C. for 1 hour, and then 50° C. for 2 hours. Next, a solution of 5.46 g (0.050 mol; 40.0 mol % based on the structural units derived from all of amines and derivatives thereof) of MAP dissolved in 15 g of NMP was added as an end-capping agent, and the solution was stirred at 50° C. for 2 hours. Thereafter, a solution of 23.83 g (0.20 mol) of DFA dissolved in 15 g of NMP was delivered by drops over 10 minutes. After completion of dropping, the solution was stirred at 50° C. for 3 hours. After completion of the reaction, the reaction solution was cooled to room temperature, then, the reaction solution was poured into 3 L of water, and the deposited solid precipitate was obtained by filtration. The obtained solid was washed with water three times, and then dried for 24 hours with a vacuum dryer at 80° C. to obtain a polyimide precursor (PIP-1). The Mw of the obtained polyimide precursor was 20,000, and the acid equivalent thereof was 450.

### SYNTHESIS EXAMPLE 7

### Synthesis of Polyimide Precursor (PIP-2)

With the monomer types and ratios thereof listed in Table 1-1, polymerization was performed in the same manner as in Synthesis Example 6 to obtain a polyimide precursor (PIP-2).

### SYNTHESIS EXAMPLE 8

### Synthesis of Polybenzoxazole (PBO-1)

In a 500 mL round-bottom flask equipped with a Dean-Stark water separator filled with toluene and a cooling tube, 34.79 g (0.095 mol; 95.0 mol % based on the structural units derived from all of amines and derivatives thereof) of BAHF, and 1.24 g (0.0050 mol; 5.0 mol % based on the structural units derived from all of the amines and derivatives thereof) of SiDA, and 75.00 g of NMP were weighed, and then dissolved. To this solution, a solution of 19.06 g (0.080 mol; 66.7 mol % based on the structural units derived from all of carboxylic acids and derivatives thereof) of BFE and 6.57 g (0.040 mol; 33.3 mol % based on the structural units derived from all of the carboxylic acids and derivatives thereof) of NA as an end-capping agent) dissolved in 25.00 g of NMP was added, and the solution was stirred at 20° C. for 1 hour, and then stirred at 50° C. for 1 hour. Thereafter, under a nitrogen atmosphere, the solution was heated and stirred at 200° C. or higher for 10 hours to develop a dehydration reaction. After completion of the reaction, the reaction solution was poured into 3 L of water, and the deposited solid precipitate was obtained by filtration. The obtained solid was washed with water three times, and then dried for 24 hours with a vacuum dryer at 80° C. to obtain a polybenzoxazole (PBO-1). The Mw of the obtained polybenzoxazole was 25,000, and the acid equivalent thereof was 330.

### SYNTHESIS EXAMPLE 9

### Synthesis of Polybenzoxazole Precursor (PBOP-1)

In a 500 mL round-bottom flask equipped with a Dean-Stark water separator filled with toluene and a cooling tube, 34.79 g (0.095 mol; 95.0 mol % based on the structural units derived from all of amines and derivatives thereof) of BAHF, and 1.24 g (0.0050 mol; 5.0 mol % based on the structural units derived from all of the amines and derivatives thereof) of SiDA, and 70.00 g of NMP were weighed, and then dissolved. To this solution, a solution of 19.06 g (0.080 mol; 66.7 mol % based on the structural units derived from all of carboxylic acids and derivatives thereof) of BFE dissolved in 20.00 g of NMP was added, and the solution was stirred at 20° C. for 1 hour, and then stirred at 50° C. for 2 hours. Next, a solution of 6.57 g (0.040 mol; 33.3 mol % based on the structural units derived from all of carboxylic acids and derivatives thereof) of NA dissolved in 10 g of NMP was added as an end-capping agent, and the solution was stirred at 50° C. for 2 hours. Thereafter, the solution was stirred at 100° C. for 2 hours under a nitrogen atmosphere. After completion of the reaction, the reaction solution was poured into 3 L of water, and the deposited solid precipitate was obtained by filtration. The obtained solid was washed with water three times, and then dried for 24 hours with a vacuum dryer at 80° C. to obtain a polybenzoxazole precursor (PBOP-1). The Mw of the obtained polybenzoxazole precursor was 20,000, and the acid equivalent thereof was 330.

### SYNTHESIS EXAMPLE 10

### Synthesis of Polysiloxane Solution (PS-1)

In a three-neck flask, 23.84 g (35 mol %) of MeTMS, 49.57 g (50 mol %) of PhTMS, 3.81 g (5 mol %) of TMOS, and 76.36 g of PGMEA were put. Air was allowed to flow through the flask at 0.05 L/min, and the mixed solution was heated to 40° C. in an oil bath while stirring. While further stirring the mixed solution, a phosphoric acid aqueous solution of 0.271 g of phosphoric acid dissolved in 28.38 g of water was delivered by drops over 10 minutes. After completion of the delivery by drops, the solution was stirred at 40° C. for 30 minutes to hydrolyze the silane compound. After completion of the hydrolysis, a solution of 13.12 g (10 mol %) of TMSSucA dissolved in 8.48 g of PGMEA was added. Thereafter, after stirring for 1 hour at the bath temperature adjusted to 70° C., the bath temperature was then raised to 115° C. After the start of the temperature raise, the internal temperature of the solution reached 100° C. after about 1 hour, and the solution was then heated and stirred for 2 hours (internal temperature from 100 to 110° C.). The resin solution obtained by heating and stirring for 2 hours was cooled in an ice bath to obtain a polysiloxane solution (PS-1). The Mw of the obtained polysiloxane was 4,200, and the carboxylic acid equivalent thereof was 700 g/mol.

### SYNTHESIS EXAMPLE 11

### Synthesis of Polysiloxane Solution (PS-2)

In a three-neck flask, 13.62 g (20 mol %) of MeTMS, 49.57 g (50 mol %) of PhTMS, 23.43 g (20 mol %) of AcrTMS, and 89.84 g of PGMEA were put. Nitrogen was allowed to flow through the flask at 0.05 L/min, and the mixed solution was heated to 40° C. in an oil bath while stirring. While further stirring the mixed solution, a phosphoric acid aqueous solution of 0.499 g of phosphoric acid dissolved in 27.93 g of water was added over 10 minutes. After completion of the addition, the solution was stirred at 40° C. for 30 minutes to hydrolyze the silane compound. After completion of the hydrolysis, a solution of 13.12 g (10 mol %) of TMSSucA dissolved in 9.98 g of PGMEA was added. Thereafter, after stirring for 1 hour at the bath temperature adjusted to 70° C., the bath temperature was then raised to 115° C. After the start of the temperature raise, the internal temperature of the solution reached 100° C. after about 1 hour, and the solution was then heated and stirred for 2 hours (internal temperature from 100 to 110° C.). The resin solution obtained by heating and stirring for 2 hours was cooled in an ice bath to obtain a polysiloxane solution (PS-2). The Mw of the obtained polysiloxane was 5,200, the carboxylic acid equivalent thereof was 800 g/mol, and the double bond equivalent was 800 g/mol.

### SYNTHESIS EXAMPLE 12

### Synthesis of Polycyclic Side Chain-containing Resin Solution (CR-1)

In a three-neck flask, 35.04 g (0.10 mol) of BHPF was dissolved in 40.31 g of MBA weighed. To this solution, a solution of 27.92 g (0.090 mol) of ODPA and 2.96 g (0.020 mol) of PHA as an end-capping agent dissolved in 30.00 g of MBA was added, and the solution was stirred at 20° C. for 1 hour. Thereafter, the solution was stirred at 150° C. for 5 hours under a nitrogen atmosphere. After completion of the reaction, to the obtained solution, a solution of 14.22 g (0.10 mol) of GMA, 0.135 g (0.0010 mol) of dibenzylamine, and 0.037 g (0.0003 mol) of 4-methoxyphenol dissolved in 10.00 g of MBA was added, and the solution was stirred at 90° C. for 4 hours to obtain a polycyclic side chain-containing resin solution (CR-1). The Mw of the obtained polycyclic side chain-containing resin was 4,000, the carboxylic acid equivalent thereof was 810 g/mol, and the double bond equivalent was 810 g/mol.

### SYNTHESIS EXAMPLE 13

### Synthesis of Acid-Modified Epoxy Resin Solution (AE-1)

In a three-neck flask, 42.00 g of NC-7300L (epoxy equivalent: 210 g/mol) was dissolved in 47.91 g of MBA weighed. To this solution, a solution of 17.22 g (0.20 mol) of MAA, 0.270 g (0.0020 mol) of dibenzylamine, and 0.074 g (0.0006 mol) of 4-methoxyphenol dissolved in 10.00 g of MBA was added, and the solution was stirred at 90° C. for 4 hours. Thereafter, a solution of 24.34 g (0.160 mol) of THPHA dissolved in 30.00 g of MBA was added, and the solution was stirred at 20° C. for 1 hour. Thereafter, under a nitrogen atmosphere, the solution was stirred at 150° C. for 5 hours to obtain an acid-modified epoxy resin solution (AE-1). The Mw of the obtained acid-modified epoxy resin was 5,000, the acid equivalent thereof was 510 g/mol, and the double bond equivalent was 410 g/mol.

### SYNTHESIS EXAMPLE 14

### Synthesis of Acrylic Resin Solution (AC-1)

In a three-neck flask, 0.821 g (1 mol %) of 2,2′-azobis(isobutyronitrile) and 29.29 g of PGMEA were put. Next, 21.52 g (50 mol %) of MAA, 22.03 g (20 mol %) of TCDM, 15.62 g (30 mol %) of STR were put, the mixture was stirred at room temperature for a while, and after sufficiently purging the inside of the flask with nitrogen by bubbling, stirred at 70° C. for 5 hours. Next, to the obtained solution, a solution of 59.47 g of PGMEA, 14.22 g (20 mol %) of GMA, 0.676 g (1 mol %) of dibenzylamine, and 0.186 g (0.3 mol %) of 4-methoxyphenol dissolved was added, and the solution was stirred at 90° C. for 4 hours to obtain an acrylic resin solution (AC-1). The Mw of the obtained acrylic resin was 15,000, the carboxylic acid equivalent thereof was 490 g/mol, and the double bond equivalent was 740 g/mol.

### COVERING EXAMPLE 1

### Synthesis of Surface-Coated Benzofuranone-Based Black Pigment (Bk-CBF1)

As a black pigment, 150 g of benzofuranone-based black pigment Bk-S0100CF (surface-untreated product; pH 4.5 at the pigment surface) was put into a glass container containing 2,850 g of deionized water, and stirred with a dissolver, thereby providing an aqueous pigment suspension. This suspension was sacked up with a tube pump, fed into a horizontal bead mill filled with 0.4 mmcp zirconia beads (“TORAYCERAM” (registered trademark); manufactured by Toray Industries, Inc.) and subjected to a 2-pass dispersion treatment therein, then entirely discharged into the original glass container, and stirred again with a dissolver. With a pH meter such that the electrode tip was immersed at a depth of 3 to 5 cm from the liquid surface of the aqueous pigment suspension being stirred in the glass container, the pH of the obtained aqueous pigment suspension was measured, and then, the pH meter read pH 4.5 (liquid temperature: 25° C.). Thereafter, the temperature of the aqueous pigment suspension was raised to 60° C. while stirring, and the stirring was temporarily stopped after 30 minutes, then after 2 minutes, it was confirmed that there was no sediment deposited on the bottom of the glass container, and stirring was restarted.

To the aqueous pigment suspension, a sodium silicate aqueous solution (Na₂O-nSiO₂-mH₂O; 30% by mass as sodium oxide, 10% by mass as silicon dioxide) diluted 1/100 with deionized water and a 0.001 mol/L sulfuric acid were added in parallel while adjusting the respective addition rates so as to maintain the pH in the range of 2 to less than 7, such that the covering amount of silica was 10.0 parts by mass in terms of SiO₂ with respect to 100 parts by mass of the black pigment, thereby depositing silica on the particle surface of the black pigment to cover the surface. Then, to the aqueous pigment suspension, a sodium aluminate aqueous solution (Na₂O-nA1₂0₃-mH₂O; 40% by mass as sodium oxide, 50% by mass as alumina) diluted 1/100 with deionized water and a 0.001 mol/L sulfuric acid were added in parallel while adjusting the respective addition rates so as to maintain the pH in the range of 2 to less than 7, such that the covering amount of alumina was 2.0 parts by mass in terms of Al₂O₃with respect to 100 parts by mass of the black pigment, thereby depositing alumina on the surface of the silica covering layer to cover the surface. Subsequently, filtration and water washing operations were repeated three times to remove some of water-soluble impurities in the aqueous pigment suspension, and the suspension was fed into a horizontal bead mill filled with 0.4 mmp zirconia beads, and subjected to a 1-pass dispersion treatment therein. Furthermore, in order to remove ionic impurities, 10 g of a cation exchange resin and 10 g of an anion exchange resin (Amberlite; manufactured by ORGANO CORPORATION) were put in the aqueous pigment suspension, then stirred for 12 hours, and filtered to obtain a black filter cake. This filter cake was dried in a drying oven at 90° C. for 6 hours and in a drying oven at 200° C. for 30 minutes, and then subjected to granulation by dry grinding with the use of a jet mill, thereby providing a surface-coated benzofuranone-based black pigment (Bk-CBF1).

As a result of time-of-flight secondary ion mass spectrometry and X-ray diffraction analysis, the silica and alumina covering amounts of the surface-coated benzofuranone-based black pigment (Bk-CBF1) obtained were respectively 10.0 parts by mass in terms of SiO₂ and 2.0 parts by mass in terms of Al₂O₃with respect to 100 parts by mass of the black pigment, and the average coverage of the covering layer with respect to the pigment was 97.5%.

Next, adjustment examples will be described. The compositions according to Preparation Examples 1 to 8 are shown in Table 2-1.

TABLE 2-1

| | | | | | | | Number Average |
|---|---|---|---|---|---|---|---|
| | | | | | | | Particle Size |
| | | | | | | | of Pigment in |
| | | Composition (% by mass) | | | | | Pigment |
| | | | | | (A1) First | <(E) | Dispersion |
| | Dispersion | Colorant | | | Resin | Dispersant> | [nm] |
| Preparation | Pigment | Bk-S0100CF | — | — | — | S-20000 | 100 |
| Example 1 | Dispersion | (75) | | | | (25) | |
| | (Bk-1) | | | | | | |
| Preparation | Pigment | Bk-S0100CF | — | — | Polyimide | S-20000 | 100 |
| Example 2 | Dispersion | (60) | | | (PI-1) | (20) | |
| | (Bk-2) | | | | (20) | | |
| Preparation | Pigment | Bk-S0100CF | — | — | Polyimide | S-20000 | 120 |
| Example 3 | Dispersion | (65) | | | (PI-1) | (10) | |
| | (Bk-3) | | | | (25) | | |
| Preparation | Pigment | Bk-S0084 | — | — | Polyimide | D.BYK-167 | 120 |
| Example 4 | Dispersion | (60) | | | (PI-1) | (20) | |
| | (Bk-4) | | | | (20) | | |
| Preparation | Pigment | Bk-A1103 | — | — | Polyimide | D.BYK-167 | 120 |
| Example 5 | Dispersion | (60) | | | (PI-1) | (20) | |
| | (Bk-5) | | | | (20) | | |
| Preparation | Pigment | TPK-1227 | — | — | Polyimide | D.BYK-167 | 120 |
| Example 6 | Dispersion | (60) | | | (PI-1) | (20) | |
| | (Bk-6) | | | | (20) | | |
| Preparation | Pigment | P.R.254 | P.Y.139 | P.B.15:6 | Polyimide | D.BYK-167 | 110 |
| Example 7 | Dispersion | (21) | (9) | (30) | (PI-1) | (20) | |
| | (Bk-7) | | | | (20) | | |
| Preparation | Pigment | P.V.23 | P.Y.139 | — | Polyimide | D.BYK-167 | 110 |
| Example 8 | Dispersion | (30) | (30) | | (PI-1) | (20) | |
| | (Bk-8) | | | | (20) | | |
| Preparation | Pigment | Bk-CBF | — | — | Polyimide | S-20000 | 100 |
| Example 9 | Dispersion | (60) | | | (PI-1) | (20) | |
| | (Bk-9) | | | | (20) | | |

### PREPARATION EXAMPLE 1

### Preparation of Pigment Dispersion (Bk-1)

After 34.5 g of S-20000 as a dispersant, 782.0 g of MBA as a solvent were weighed, and mixed, and diffused by stirring for 10 minutes, 103.5 g of Bk-S0100CF as a colorant was weighed, and then mixed with the dispersant and the solvent, and stirred for 30 minutes, and subjected to a wet media dispersion treatment with the use of a horizontal bead mill filled with 0.40 mmcp zirconia beads such that the number average particle size was 100 nm, thereby providing a pigment dispersion (Bk-1) with a solid content concentration 15% by mass, and colorant/dispersant =75/25 (mass ratio). The number average particle size of the pigment in the obtained pigment dispersion was 100 nm.

### PREPARATION EXAMPLE 2

### Preparation of Pigment Dispersion (Bk-2)

After 92.0 g of a 30% by mass MBA solution of the polyimide (PI-1) obtained in accordance with Synthesis Example 1 as a resin, 27.6 g of S-20000 as a dispersant, 717.6 g of MBA as a solvent were weighed, and mixed, and diffused by stirring for 10 minutes, 82.8 g of Bk-S0100CF as a colorant was weighed, and then mixed with the dispersant and the solvent, and stirred for 30 minutes, and subjected to a wet media dispersion treatment with the use of a horizontal bead mill filled with 0.40 mmcp zirconia beads such that the number average particle size was 100 nm, thereby providing a pigment dispersion (Bk-2) with a solid content concentration 15% by mass, and colorant/resin/dispersant =60/20/20 (mass ratio). The number average particle size of the pigment in the obtained pigment dispersion was 100 nm.

### PREPARATION EXAMPLES 3 to 8

### Preparation of Pigment Dispersion (Bk-3) to Pigment Dispersion (Bk-8)

With the types and ratios of the colorant, (A1) first resin, and (E) dispersant, listed in Table 2-1, pigments were dispersed in the same manner as in Preparation Example 2, thereby providing a pigment dispersion (Bk-3) to a pigment dispersion (Bk-8).

Table 2-2 shows therein a list of the (F) cross-linking agents and specific (F) cross-linking agents ((F1) to (F9) compounds) used for the respective examples and comparative examples, and the physical property values of the agents.

TABLE 2-2

| | | (F) Physical Property Value of Cross-linking Agent | | | | | | |
|---|---|---|---|---|---|---|---|---|
| | | | | | | Number | | |
| | | | Aromatic | Alicyclic | | of Epoxy | | |
| | | | Structure | Structure | | Groups in | | |
| | (F) Cross- | | in Molecule | in Molecule | Nitrogen- | Molecule | | |
| | linking | Fluorene | Aromatic | Alicyclic | containing | Number | | |
| | Agent | Skeleton or | Structure in | Structure in | Ring | of Epoxy | | Epoxy |
| | (F1) to (F9) | Indane | Structural | Structural | Skeleton in | Groups in | Molecular | Equivalent |
| | Compounds | Skeleton | Unit | Unit | Molecule | Structural Unit | Weight | [g/mol] |
| 1 | (F1) | One Fluorene | Two Benzene | — | — | 2 | 462.54 | 231 |
| | FR-201 | Skeleton | Skeletons | | | | | |
| 2 | (F1) | One Fluorene | Two Benzene | — | — | 2 | 550.64 | 275 |
| | FLE-1 | Skeleton | Skeletons | | | | | |
| 3 | (F1) | One Fluorene | Two Benzene | — | — | 2 | 562.65 | 281 |
| | FLE-2 | Skeleton | Skeletons | | | | | |
| 4 | (F2) | One Indane | Two Benzene | — | — | 2 | 488.57 | 244 |
| | IDE-1 | Skeleton | Skeletons | | | | | |
| 5 | (F2) | One Indane | Two Benzene | — | — | 2 | 576.68 | 288 |
| | IDE-2 | Skeleton | Skeletons | | | | | |
| 6 | (F3) | — | One Benzene | One | — | 1 | — | 250 |
| | XD-1000-H | | Skeleton | Tricyclodecane | | | | |
| | | | | Skeleton | | | | |
| 7 | (F4) | — | One Naphthalene | — | — | 2 | — | 230 |
| | NC-7000L | | Skeleton | | | | | |
| | | | One Benzene | | | | | |
| | | | Skeleton | | | | | |
| 8 | (F4) | — | One Biphenyl | — | — | 2 | — | 210 |
| | NC-3500 | | Skeleton | | | | | |
| | | | One Benzene | | | | | |
| | | | Skeleton | | | | | |
| | | (F) Physical Property Value of Cross-linking Agent | | | | | | |
| | | | | | | Number | | |
| | | | | | | of Epoxy | | |
| | | | | | | Groups in | | |
| | (F) Cross- | | Condensed | | Nitrogen- | Molecule | | |
| | linking | | Polycyclic | | containing | Number | | |
| | Agent | | Skeletons | Aromatic | Ring | of Epoxy | | Epoxy |
| | (F1) to (F9) | Fluorene | linked by | Structure | Skeleton in | Groups in | Molecular | Equivalent |
| | Compounds | Skeleton | Spiro Skeleton | in Molecule | Molecule | Structural Unit | Weight | [g/mol] |
| 9 | (F5) | Two Fluorene | — | — | — | 2 | 869.00 | 435 |
| | FLE-3 | Skeleton | | | | | | |
| 10 | (F6) | — | One Fluorene | — | — | 2 | 476.52 | 238 |
| | TBIS-RXG | | Skeleton | | | | | |
| | | | One Xanthene | | | | | |
| | | | Skeleton | | | | | |
| 11 | (F7) | — | — | One | — | 2 | 505.56 | 253 |
| | WHR-991S | | | Isoindolinone | | | | |
| | | | | Skeleton | | | | |
| 12 | (F8) | — | — | Two Naphthalene | — | 2 | 398.45 | 199 |
| | TBIS-BNG200 | | | Skeletons | | | | |
| 13 | (F9) | — | — | — | One | 3 | 297.26 | 99 |
| | TEPIC-L | | | | Isocyanuric | | | |
| | | | | | Acid Skeleton | | | |
| 14 | (F9) | — | — | — | One Isocyanuric | 3 | 507.66 | 169 |
| | TEPIC-FL | | | | Acid Skeleton | | | |
| 15 | (F9) | — | — | — | One Isocyanuric | 3 | 1054.70 | 352 |
| | ICA-GST | | | | Acid Skeleton | | | |
| 16 | (F9) | — | — | — | One Triazine | 3 | 297.26 | 99 |
| | TAZ-G | | | | Skeleton | | | |
| 17 | (F9) | — | — | — | One Glycoluril | 4 | 366.37 | 92 |
| | TG-G | | | | Skeleton | | | |
| | | (F) Physical Property Value of Cross-linking Agent | | | | | | |
| | | | | | | Number | | |
| | (F) | | | | | of Epoxy | | |
| | Compounds | | Aromatic | Alicyclic | | Groups in | | |
| | not included | | Structure | Structure | Nitrogen- | Molecule | | |
| | in Cross- | Fluorene | in Molecule | in Molecule | containing | Number | | |
| | linking | Skeleton or | Aromatic | Alicyclic | Ring | of Epoxy | | Epoxy |
| | Agent | Indane | Structure | Structure | Skeleton in | Groups in | Molecular | Equivalent |
| | (F1) to (F9) | Skeleton | in Structural Unit | in Structural Unit | Molecule | Structural Unit | Weight | [g/mol] |
| 18 | jer-834 | — | One Bisphenol | — | — | 1 | 340.41 | 340 |
| | | | Skeleton | | | | | |
| 19 | EOCN-1020 | — | One Benzene | — | — | 1 | — | 200 |
| | | | Skeleton | | | | | |

Here are the structural units of XD-1000-H, NC-7000L, NC-3500, and FLE-3, and the acid-modified epoxy resin (AE-1) obtained in accordance with Synthesis Example 13. XD-1000-H has a structural unit represented by general formula (14a). NC-7000L has a structural unit represented by general formula (15a). NC-3500 has a structural unit represented by general formula (16a). FLE-3 (epoxy compound having two fluorene skeletons and two epoxy groups) has a structure represented by general formula (81). The acid-modified epoxy resin (AE-1) has a structural unit represented by general formula (38a).

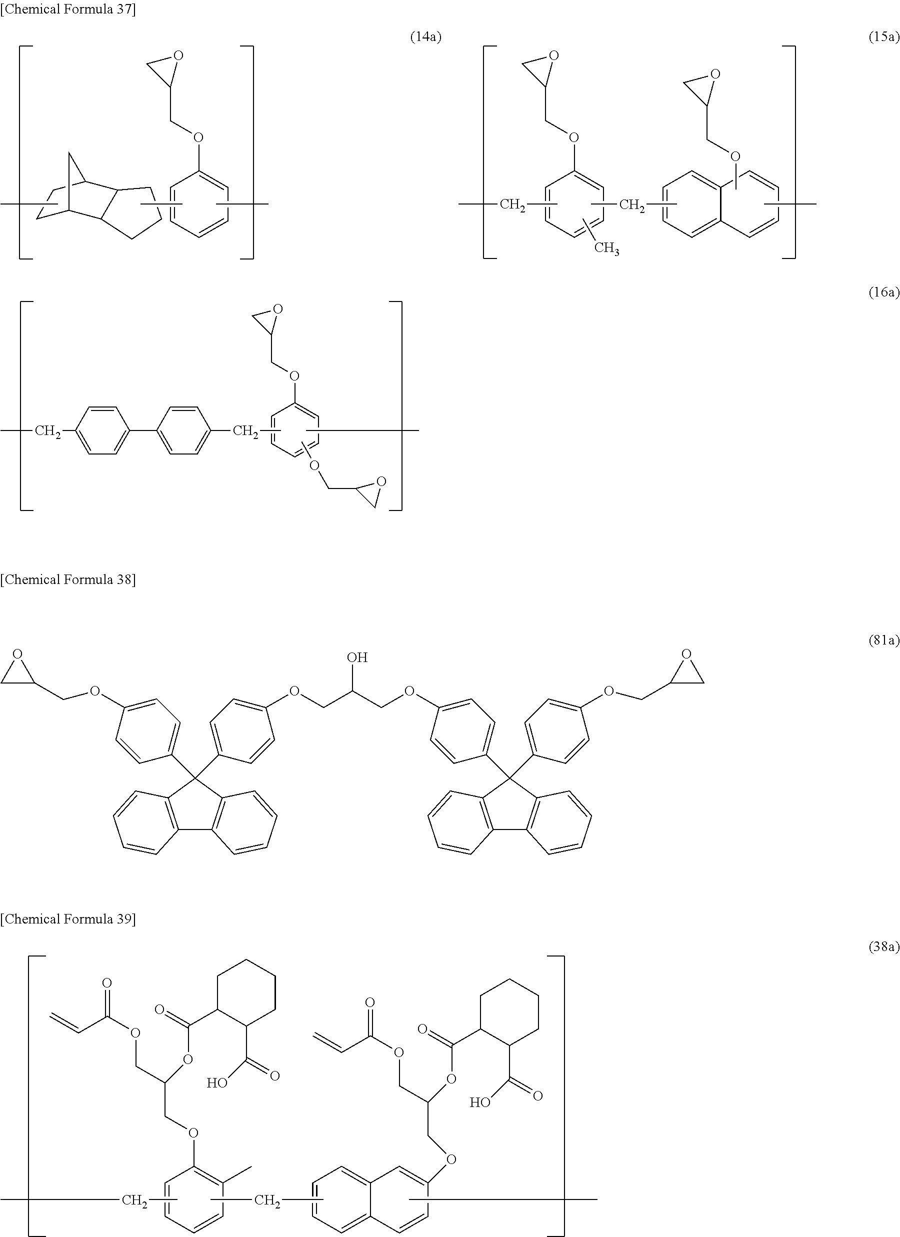

Next, evaluation methods in the respective examples and comparative examples will be described.
(1) Weight Average Molecular Weight of Resin

With the use of a GPC analyzer (HLC-8220; manufactured by Tosoh Corporation), and with the use of tetrahydrofuran or NMP as a fluidized bed, the weight average molecular weight in terms of polystyrene was measured and then determined by a method at around normal temperature, based on “JIS K7252-3 (2008)”.
(2) Acid Value, Acid Equivalent

With the use of an automatic potentiometric titrator (AT-510; manufactured by KYOTO ELECTRONICS MANUFACTURING CO.,LTD.), and with the use of a 0.1 mol/L sodium hydroxide/ethanol solution as a titration reagent, xylene/N,N-dimethylformamide=1/1 (mass ratio) as a titration solvent, the acid value (unit: mgKOH/g) was measured, and then determined by a potentiometric titration method, based on “JIS K2501 (2003)”. The acid equivalent (unit: g/mol) was calculated from the measured acid value.
(3) Double Bond Equivalent

With the use of an automatic potentiometric titrator (AT-510; manufactured by KYOTO ELECTRONICS MANUFACTURING CO.,LTD.), and with the use of an iodine monochloride solution (mixed solution of iodine trichloride=7.9 g, iodine=8.9 g, acetic acid =1,000 mL) as an iodine source, a 100 g/L potassium iodide aqueous solution as an aqueous solution for trapping unreacted iodine, and a 0.1 mol/L sodium thiosulfate aqueous solution as a titration reagent, the iodine value of the resin was measured by the Wiis method, based on the method described in the “Section 6: Iodine Value” of JIS K0070: 1992 “Method for Testing Acid Value, Saponification Value, Ester Value, Iodine Value, Hydroxyl Value, and Unsaponifiable Matter of Chemical Product”. The double bond equivalent (unit: g/mol) was calculated from the measured iodine value (unit: g1/100 g).
(4) Content Ratio of Each Organosilane Unit in Polysiloxane

The measurement of ²⁹Si-NMR was performed for calculating the ratio of the integration value of Si derived from a specific organosilane unit to the integration value of the entire Si derived from organosilane, and the content ratios thereof were calculated. The sample (liquid) was injected into an NMR sample tube made of “Teflon (registered trademark)” of 10 mm in diameter, and used for the measurement. Here are the ²⁹Si-NMR measurement conditions.

Apparatus: nuclear magnetic resonance apparatus (JNM-GX270; manufactured by JEOL Ltd.)

Measurement method: gated decoupling method

Measurement nucleus frequency: 53.6693 MHz (²⁹Si nucleus)

Spectrum width: 20000 Hz

Pulse width: 12 ps (45° pulse)

Pulse repetition time: 30.0 seconds

Solvent: acetone -d6

Reference material: Tetramethylsilane

Measurement temperature: 23° C.

Sample rotation speed: 0.0Hz.
(5) Number Average Particle Size of Pigment

With the use of a zeta potential/particle size/molecular weight measuring device (Zetasizer Nano ZS; manufactured by SYSMEX CORPORATION), and with the use of PGMEA as a diluent solvent, the pigment dispersion was diluted to a concentration of 1.0×10⁻⁵ to 40% by volume, the refractive index of the solvent was set to the refractive index of PGMEA, whereas the refractive index of an object to be measured was set to 1.6, and the object was irradiated with laser light with a wavelength of 633 nm to measure the number average particle size of the pigment in the pigment dispersion.
(6) Pretreatment for Substrate

The glass substrate with an ITO of 100 nm formed by sputtering on glass (GEOMATEC Co., Ltd.; hereinafter, referred to as an “ITO substrate”) was subjected to a UV-O₃ cleaning treatment for 100 seconds with the use of a tabletop optical surface treatment device (PL16-110; manufactured by SEN LIGHTS Corporation), and then used. The Si wafer (manufactured by ELECTRONICS AND MATERIALS CORPORATION LIMITED) was dehydrated and baked by heating at 130° C. for 2 minutes with the use of a hot plate (HP-1SA; manufactured by AS ONE Corporation), and used. The polyimide film Kapton (registered trademark) -150EN-C (manufactured by DU PONT-TORAY CO., LTD.; hereinafter, referred to as a “PI film substrate”) was used without any pretreatment.
(7) Film Thickness Measurement

With the use of a surface texture and contour measuring instrument (SURFCOM 1400D; manufactured by TOKYO SEIMITSU CO., LTD.), at the measurement magnification of 10,000 times, the measurement length of 1.0 mm, the measurement speed of 0.30 mm/s, the film thickness was measured after prebaking, after development, and after curing.
(8) Sensitivity

In accordance with the method described in Example 1 below, after exposure for patterning with the i-ray (wavelength: 365 nm), h-ray (wavelength: 405 nm), and g-ray (wavelength 436 nm) of an ultra-high pressure mercury lamp through a gray scale mask (MDRM MODEL 4000-5-FS; Opto-Line International, Inc.) for sensitivity measurement with the use of a double-sided alignment single-sided exposure apparatus (Mask Aligner PEM-6M; manufactured by Union Optical Co., Ltd.), development was performed with the use of a small-size development device (AD-2000; TAKIZAWA SANGYO K.K.) for photolithography, thereby preparing a developed film of the photosensitive resin composition.

With the use of a FPD/LSI inspection microscope (OPTIPHOT-300; manufactured by NIKON CORPORATION), the resolution pattern of the developed film prepared was observed, and the exposure energy (i-line illuminance meter value) for the formation of the 20 μm line-and-space pattern with a one-to-one width was regarded as the sensitivity. It has been determined as follows that the A+, A, B, and C with the sensitivity of 90 mJ/cm² or less are regarded as pass, the A+, A, and B with the sensitivity of 60 mJ/cm² or less are regarded as favorable sensitivities, and the A+and A with the sensitivity of 45 mJ/cm² or less are regarded as excellent sensitivities.

A+: The sensitivity is 1 to 30 mJ/cm²

A: The sensitivity is 31 to 45 mJ/cm²

B: The sensitivity is 46 to 60 mJ/cm²

C: The sensitivity is 61 to 90 mJ/cm²

D: The sensitivity is 91 to 150 mJ/cm²

E: The sensitivity is 151 to 500 mJ/cm².
(9) Development Residue

In accordance with the method described in Example 1 below, after exposure for patterning with the i-ray (wavelength: 365 nm), h-ray (wavelength: 405 nm), and g-ray (wavelength 436 nm) of an ultra-high pressure mercury lamp through a gray scale mask (MDRM MODEL 4000-5-FS; Opto-Line International, Inc.) for sensitivity measurement with the use of a double-sided alignment single-sided exposure apparatus (Mask Aligner PEM-6M; manufactured by Union Optical Co., Ltd.), development was performed with the use of a small-size development device (AD-2000; TAKIZAWA SANGYO K.K.) for photolithography, thereby preparing a developed film of the photosensitive resin composition.

With the use of a FPD/LSI inspection microscope (OPTIPHOT-300; manufactured by NIKON CORPORATION), the resolution pattern of the cured film prepared was observed to observe the presence or presence of any residue derived from the pigment in the opening of the 20 μm line-and-space pattern. It has been determined as follows that the A+, A, and B where the presence area of the residue in the opening is 10% or lower are regarded as pass, the A+and A where the presence area of the residue in the opening is 5% or lower are regarded as favorable development residues, and the A+without the presence area of the residue in the opening is regarded as an excellent development residue.

A+: No residue in the opening

A: The presence area of the residue in the opening is 1 to 5%

B: The presence area of the residue in the opening is 6 to 10%

C: The presence area of the residue in the opening is 11 to 30%

D: The presence area of the residue in the opening is 31 to 50%

E: The presence area of the residue in the opening is 51 to 100%.
(10) Pattern Cross-Section Shape after Development

In accordance with the method described in Example 1 below, after exposure for patterning with the i-ray (wavelength: 365 nm), h-ray (wavelength: 405 nm), and g-ray (wavelength 436 nm) of an ultra-high pressure mercury lamp through a gray scale mask (MDRM MODEL 4000-5-FS; Opto-Line International, Inc.) for sensitivity measurement with the use of a double-sided alignment single-sided exposure apparatus (Mask Aligner PEM-6M; manufactured by Union Optical Co., Ltd.), development was performed with the use of a small-size development device (AD-2000; TAKIZAWA SANGYO K.K.) for photolithography, thereby preparing a developed film of the photosensitive resin composition.

With the use of a field-emission scanning electron microscope (S-4800; manufactured by Hitachi High-Technologies Corporation), of the resolution pattern of the developed film prepared, the cross section of the line-and-space pattern with a space width of 20 μm was observed, and the taper angle of the cross section was measured. It has been determined as follows that the A+, A, and B where the taper angle of the cross section is 60° or less are regarded as pass, the A+and A where the taper angle of the cross section is 45° or less are regarded as favorable pattern shapes, and the A+where the taper angle of the cross section is 30° or less is regarded as an excellent pattern shape.

A+: The taper angle of the cross section is 1° to 30°.

A: The taper angle of the cross section is 31° to 45°.

B: The taper angle of the cross section is 46° to 60°.

C: The taper angle of the cross section is 61° to 70°.

D: The taper angle of the cross section is 71° to 80°.

E: The taper angle of the cross section is 81° to 179°.
(11) Pattern Cross-Section Shape after Thermal Curing

In accordance with the method described in Example 1 below, after exposure for patterning with the i-ray (wavelength: 365 nm), h-ray (wavelength: 405 nm), and g-ray (wavelength 436 nm) of an ultra-high pressure mercury lamp through a gray scale mask (MDRM MODEL 4000-5-FS; Opto-Line International, Inc.) for sensitivity measurement with the use of a double-sided alignment single-sided exposure apparatus (Mask Aligner PEM-6M; manufactured by Union Optical Co., Ltd.), development was performed with the use of a small-size development device (AD-2000; TAKIZAWA SANGYO K.K.) for photolithography, and a cured film of the photosensitive resin composition was then prepared with the use of a high-temperature inert gas oven (INH-9CD-S; manufactured by Koyo Thermo Systems Co., Ltd.). [0605]

With the use of a field-emission scanning electron microscope (S-4800; manufactured by Hitachi High-Technologies Corporation), of the resolution pattern of the cured film prepared, the cross section of the line-and-space pattern with a space width of 20 μm was observed, and the taper angle of the cross section was measured. It has been determined as follows that the A+, A, and B where the taper angle of the cross section is 60° or less are regarded as pass, the A+and A where the taper angle of the cross section is 45° or less are regarded as favorable pattern shapes, and the A+where the taper angle of the cross section is 30° or less is regarded as an excellent pattern shape.

A+: The taper angle of the cross section is 1° to 30°.

A: The taper angle of the cross section is 31° to 45°.

B: The taper angle of the cross section is 46° to 60°.

C: The taper angle of the cross section is 61° to 70°.

D: The taper angle of the cross section is 71° to 80°.

E: The taper angle of the cross section is 81° to 179°.
(12) Change in Pattern Opening width between Before and After Thermal Curing

In accordance with the method described in Example 1 below, after exposure for patterning with the i-ray (wavelength: 365 nm), h-ray (wavelength: 405 nm), and g-ray (wavelength 436 nm) of an ultra-high pressure mercury lamp through a gray scale mask (MDRM MODEL 4000-5-FS; Opto-Line International, Inc.) for sensitivity measurement with the use of a double-sided alignment single-sided exposure apparatus (Mask Aligner PEM-6M; manufactured by Union Optical Co., Ltd.), development was performed with the use of a small-size development device (AD-2000; TAKIZAWA SANGYO K.K.) for photolithography, thereby preparing a developed film of the photosensitive resin composition.

With the use of a FPD/LSI inspection microscope (OPTIPHOT-300; manufactured by NIKON CORPORATION), the resolution pattern of the developed film prepared was observed, and the opening width of the 20 μm line-and-space pattern was measured, and regarded as a developed pattern opening width (CD_{DEV}).

Thereafter, the developed film described above was thermally cured with the use of a high-temperature inert gas oven (INH-9CD-S; manufactured by Koyo Thermo Systems Co., Ltd.) in accordance with the method described in Example 1 below, thereby preparing a cured film of the photosensitive resin composition.

With the use of a FPD/LSI inspection microscope (OPTIPHOT-300; manufactured by NIKON CORPORATION), the resolution pattern of the cured film prepared was observed, and the opening width of the 20 μm line-and-space pattern was measured at the same site as observed after the development, and regarded as a thermally cured pattern opening width (CD_{CURE}).

From the developed pattern opening width and the thermal cured pattern opening width, the change in pattern opening width between before and after thermal curing ((CD_{DEV})−(CD_{CRE})) was calculated. It has been determined as follows that the A+, A, and B where the change in pattern opening width between before and after thermal curing is 0.60 μm or less are regarded as pass, the A+and A where the change in pattern opening width between before and after thermal curing is 0.40 μm or less are regarded as favorable changes in pattern width, and the A+where the change in pattern opening width between before and after thermal curing is 0.20 μm or less is regarded as an excellent change in pattern width.

A+: The change in pattern opening width between before and after thermal curing is 0 to 0.20 μm.

A: The change in pattern opening width between before and after thermal curing is 0.21 to 0.40μm.

B: The change in pattern opening width between before and after thermal curing is 0.41 to 0.60 μm.

C: The change in pattern opening width between before and after thermal curing is 0.61 to 1.00 μm.

D: The change in pattern opening width between before and after thermal curing is 1.01 to 2.00 μm.

E: The change in pattern opening width between before and after thermal curing is 2.01 μm or more.
(13) Heat Resistance (Difference in High-Temperature Weight Residual Ratio)

In accordance with the method described in Example 1 below, after exposure for patterning with the i-ray (wavelength: 365 nm), h-ray (wavelength: 405 nm), and g-ray (wavelength 436 nm) of an ultra-high pressure mercury lamp through a gray scale mask (MDRM MODEL 4000-5-FS; Opto-Line International, Inc.) for sensitivity measurement with the use of a double-sided alignment single-sided exposure apparatus (Mask Aligner PEM-6M; manufactured by Union Optical Co., Ltd.), development was performed with the use of a small-size development device (AD-2000; TAKIZAWA SANGYO K.K.) for photolithography, and a cured film of the photosensitive resin composition was then prepared with the use of a high-temperature inert gas oven (INH-9CD-S; manufactured by Koyo Thermo Systems Co., Ltd.).

After the thermal curing, the cured film prepared was scraped from the substrate, and about 10 mg of the film was put in an aluminum cell. This aluminum cell was, with the use of a thermogravimetric measurement device (TGA-50; manufactured by Shimadzu Corporation), held at 30° C. for 10 minutes in a nitrogen atmosphere, then heated to 150° C. at a temperature increase rate of 10° C./min, and thereafter, held at 150° C. for 30 minutes, and furthermore, a thermogravimetric analysis was carried out while increasing the temperature up to 500° C. at a temperature increase rate of 10° C./min. With respect to 100% by mass of the weight after heating at 150° C. for 30 minutes, the weight residual ratio at 350° C. in the case of further heating is denoted by (Mₐ) % by mass, and the weight residual ratio at 400° C. is denoted by (M_{b}) % by mass, and the difference ((Mₐ)−(M_{b})) in high-temperature weight residual ratio was calculated as a heat resistance index. It has been determined as follows that the A+, A, and B where the difference in high-temperature weight residual ratio is 25.0% by mass or lower are regarded as pass, A+ and A where the difference in high-temperature weight residual ratio is 15.0% or lower are regarded as favorable heat resistance, and A+ where the difference in high-temperature weight residual ratio is 5.0% or lower is regarded as excellent heat resistance.

A+: The difference in high-temperature weight residual ratio is 0 to 5.0%.

A: The difference in high-temperature weight residual ratio is 5.1 to 15.0%.

B: The difference in high-temperature weight residual ratio is 15.1 to 25.0%.

C: The difference in high-temperature weight residual ratio is 25.1 to 35.0%.

D: The difference in high-temperature weight residual ratio is 35.1 to 45.0%.

E: The difference in high-temperature weight residual ratio is 45.1 to 100%.
(14) Light-Blocking (Optical Density (Hereinafter, Referred to as an “OD”) Value)

In accordance with the method described in Example 1 below, after exposure for patterning with the i-ray (wavelength: 365 nm), h-ray (wavelength: 405 nm), and g-ray (wavelength 436 nm) of an ultra-high pressure mercury lamp through a gray scale mask (MDRM MODEL 4000-5-FS; Opto-Line International, Inc.) for sensitivity measurement with the use of a double-sided alignment single-sided exposure apparatus (Mask Aligner PEM-6M; manufactured by Union Optical Co., Ltd.), development was performed with the use of a small-size development device (AD-2000; TAKIZAWA SANGYO K.K.) for photolithography, and a cured film of the photosensitive resin composition was then prepared with the use of a high-temperature inert gas oven (INH-9CD-S; manufactured by Koyo Thermo Systems Co., Ltd.).

With the use of a transmission densitometer (X-Rite 361T (V); manufactured by X-Rite), the incident light intensity (Iₛ) and transmitted light intensity (I) of the cured film prepared were measured. The OD value was calculated by the following formula as a light-blocking index.

OD Value=log₁₀(I₀/I).
(15) Insulation Properties (Surface Resistivity)

In accordance with the method described in Example 1 below, after exposure for patterning with the i-ray (wavelength: 365 nm), h-ray (wavelength: 405 nm), and g-ray (wavelength 436 nm) of an ultra-high pressure mercury lamp through a gray scale mask (MDRM MODEL 4000-5-FS; Opto-Line International, Inc.) for sensitivity measurement with the use of a double-sided alignment single-sided exposure apparatus (Mask Aligner PEM-6M; manufactured by Union Optical Co., Ltd.), development was performed with the use of a small-size development device (AD-2000; TAKIZAWA SANGYO K.K.) for photolithography, and a cured film of the photosensitive resin composition was then prepared with the use of a high-temperature inert gas oven (INH-9CD-S; manufactured by Koyo Thermo Systems Co., Ltd.).

The surface resistivity (Ω/□) of the cured film prepared was measured with the use of a high resistivity meter (“HIRESTA” UP; manufactured by Mitsubishi Chemical Corporation).
(16) Light-Emitting Characteristics of Organic EL Display (Method for Manufacturing Organic EL Display)

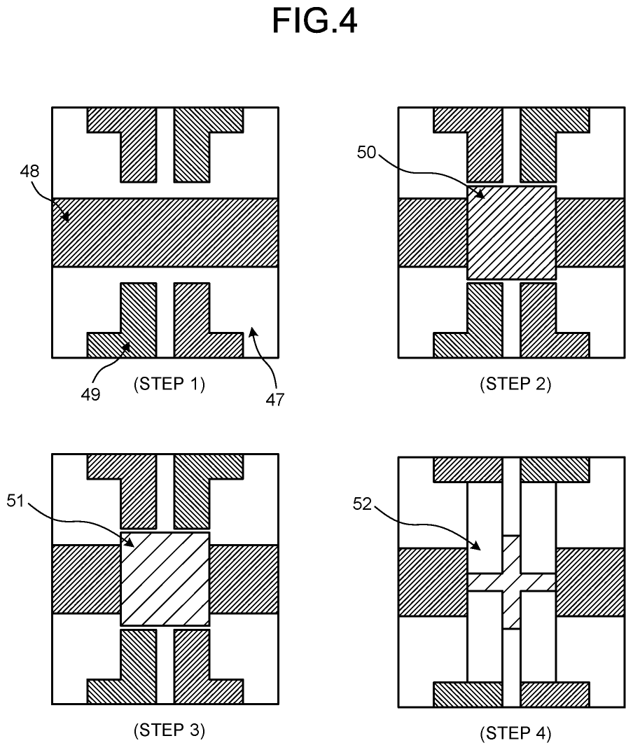

FIG. 4 shows a schematic diagram of the substrate used. First, ITO transparent conductive coatings of 10 nm were formed on the entire surface of a 38×46 mm non-alkali glass substrate 47 by sputtering, and etched as a first electrode 48 to form a transparent electrode. In addition, an auxiliary electrode 49 was formed at the same time to take out a second electrode (FIG. 4 (Step 1)). The obtained substrate was subjected to ultrasonic cleaning for 10 minutes with “Semico Clean” (registered trademark) 56 (manufactured by Furuuchi Chemical Corporation), and washed with ultrapure water. Next, the photosensitive resin composition was applied and prebaked on the substrate by the method described in Example 1 below, subjected to patterning exposure through a photomask with a predetermined pattern, and development and rinsing, and then thermally cured by heating. In accordance with the method mentioned above, openings of 70 μm in width and 260 pm in length were arranged at a pitch of 155 μm in the width direction and a pitch of 465 μm in the length direction, and an insulation layer 50 in a shape for exposing the first electrode through the respective openings was formed only on a substrate effective area in a limited fashion (FIG. 4 (Step 2)). It is to be noted that the openings will finally serve for light-emitting pixels of an organic EL display. Further, the substrate effective area was a square of 16 mm on a side, and the insulation layer 50 was formed to have a thickness of about 1.0 μm.

Next, an organic EL display was manufactured with the use of the substrate with the first electrode 48, auxiliary electrode 49, and insulation layer 50 formed. After the substrate was subjected to a nitrogen plasma treatment as a pretreatment, an organic EL layer 51 including a light-emitting layer was formed by vacuum deposition (FIG. 4 (Step 3)). It is to be noted that the degree of vacuum for the deposition was 1×10⁻³ Pa or less, and during the deposition, the substrate was rotated with respect to a deposition source. First, a compound (HT-1) of 10 nm and a compound (HT-2) of 50 nm were deposited respectively as a hole injection layer and a hole transport layer. Next, for the light-emitting layer, a compound (GH-1) as a host material and a compound (GD-1) as a dopant material were deposited to have a thickness of 40 nm, in such a way that the dope concentration reached 10%. Thereafter, as an electron transport material, a compound (ET-1) and a compound (LiQ) were laminated at a volume ratio of 1:1 to have a thickness of 40 nm. Here are the structures of the compounds used for the organic EL layer.

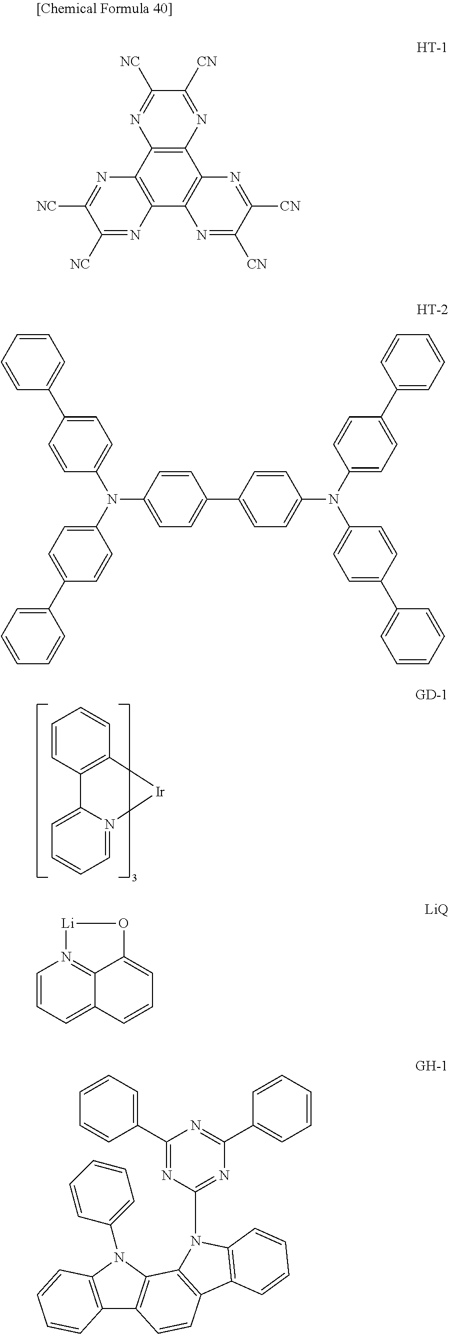

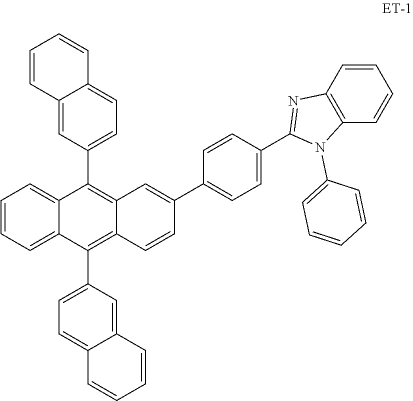 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

Next, after the vapor deposition of the compound (LiQ) of 2 nm, 100 nm MgAg (magnesium/silver =10/1 (volume ratio)) was deposited as a second electrode 52 to form a reflective electrode (step 4 in FIG. 4). Thereafter, under a low-humidity nitrogen atmosphere, sealing was performed by bonding a cap-shaped glass plate with the use of an epoxy resin-based adhesive, and four bottom-emission organic EL displays each in a square shape of 5 mm on a side were prepared on one substrate.
(Light-Emitting Characteristic Evaluation)

The organic EL displays prepared by the method described above was driven with a direct current at 10 mA/cm² to emit light, and it was confirmed whether there were defective light emissions such as non-light-emitting areas and uneven luminance. The prepared organic EL displays were held at 80° C. for 500 hours as a durability test. After the durability test, the organic EL displays prepared by the method described above was driven with a direct current at 10 mA/cm² to emit light, and it was confirmed whether there was any change in light-emitting characteristics such as light-emitting areas and uneven luminance. It has been determined as follows that, in a case where the light-emitting area before the durability test is regarded as 100%, the A+, A, and B where the light-emitting area after the durability test is 80% or higher are regarded as pass, A+and A where the light-emitting area is 90% or higher are regarded as favorable light-emitting characteristics, and A+where the light-emitting area is 95% or higher is regarded as an excellent light-emitting characteristic.

A+: The light-emitting area after the durability test is 95 to 100%.

A: The light-emitting area after the durability test is 90 to 94%.

B: The light-emitting area after the durability test is 80 to 89%.

C: The light-emitting area after the durability test is 70 to 79%.

D: The light-emitting area after the durability test is 50 to 69%

E: The light emitting area after the durability test is 0 to 49%.

### EXAMPLE 1

Under a yellow light, 0.313 g of NCI-831 and 0.261 g of FR-201 were weighed, 8.060 g of MBA and 5.100 g of PGMEA were added thereto, and dissolved by stirring. Next, 5.650 g of a 30% by mass MBA solution of the polyimide (PI-1) obtained in Synthesis Example 1 and 1.825 g of a 50% by mass MBA solution of DPHA were added to the solution, and then stirred to obtain a prepared liquid as a homogeneous solution. Next, 7.326 g of the pigment dispersion (Bk-1) obtained in Preparation Example 1 was weighed, and with 17.674 g of the obtained prepared liquid added thereto, and then stirred to obtain a homogeneous solution. Thereafter, the obtained solution was filtered through a 0.45 μmcp filter to prepare Composition 1.

The prepared composition 1 was applied onto an ITO substrate by spin coating at an arbitrary rotation speed with the use of a spin coater (MS-A100; manufactured by Mikasa Co., Ltd.), and then prebaked at 110° C. for 120 seconds with the use of a buzzer hot plate (HPD-3000BZN; manufactured by AS ONE Corporation) to prepare a prebaked film of about 1.8 μm in film thickness.

The prebaked film prepared was subjected to spray development with a 2.38% by mass TMAH aqueous solution with the use of a small-size development device (AD-2000; manufactured by TAKIZAWA SANGYO K.K.) for photolithography, and the time at which the prebaked film (unexposed part) was completely dissolved (Breaking Point; hereinafter, a “B.P.”) was measured.

In the same manner as mentioned above, a prebaked film was prepared, and the prepared prebaked film was subjected to exposure for patterning with the i-ray (wavelength: 365 nm), h-ray (wavelength: 405 nm), and g-ray (wavelength 436 nm) of an ultra-high pressure mercury lamp through a gray scale mask (MDRM MODEL 4000-5-FS; Opto-Line International, Inc.) for sensitivity measurement with the use of a double-sided alignment single-sided exposure apparatus (Mask Aligner PEM-6M; manufactured by Union Optical Co., Ltd.), development was performed with the use of a small-size development device (AD-2000; TAKIZAWA SANGYO K.K.) for photolithography, thereby preparing a developed film of the photosensitive resin composition. After the exposure, a 2.38% by mass TMAH aqueous solution was applied for 10 seconds with the use of a small-size development device (AD-2000; manufactured by TAKIZAWA SANGYO K.K.) for photolithography, then subjected to paddle development, and rinsed with water for 30 seconds. The development time was 1.5 times as long as B.P. It is to be noted that the development time refers to the total of 10 seconds for applying the 2.38% by mass TMAH aqueous solution described above and the time for the paddle development.

After the development, with the use of a high-temperature inert gas oven (INH-9CD-S; manufactured by Koyo Thermo Systems Co., Ltd.), thermal curing was performed at 250° C. to produce a cured film of about 1.2 μm in film thickness. The thermal curing condition was thermal curing at 250° C. for 60 minutes in a nitrogen atmosphere.

### EXAMPLES 2 to 88 AND COMPARATIVE EXAMPLES 1 to 9

In the same manner as in Example 1, compositions 2 to 98 were prepared in accordance with the compositions described in Table 3-1 to Table 15-1. With the use of the respective compositions obtained, compositions were deposited on substrates in the same manner as in Example 1, and the photosensitive characteristics and the characteristics of the cured film were evaluated. The evaluation results are shown in Table 3-2 to Table 15-2. It is to be noted that for ease of comparison, the composition and evaluation results according to Example 7 are listed in Table 4-1, Table 5-1, Table 7-1, Table 8-1, Table 10-1, Table 11-1, Table 12-1, Table 13-1, Table 14-1, Table 4-2, Table 5-2, Table 7-2, Table 8-2, Table 10-2, Table 11-2, Table 12-2, Table 13-2, and Table 14-2. Similarly, the composition and evaluation results according to Example 15 are listed in Table 6-1, Table 9-1, Table 10-1, Table 6-2, Table 9-2, and Table 10-2.

TABLE 3-1

| | | | | | | | | | | | (D) |
|---|---|---|---|---|---|---|---|---|---|---|---|
| | | Composition (parts by mass) | | | | | | | | | Content |
| | | | | | | | | | (F) Cross- | | Ratio of |
| | | | | | (B) Radical | | | | linking | | Colorant to |
| | | | | | Polymerizable | | | | Agent | | Total Solid |
| | | | (A1) | (A2) | Compound | (C1) | | | (F1) to | | Content |
| | Com- | Pigment | First | Second | (B1) to (B4) | Photo | (D) | <(E) | (F9) | | (% by |
| | position | Dispersion | Resin | Resin | compounds | Initiator | Colorant | Dispersant> | Compounds | Solvent | mass) |
| Example 1 | 1 | Bk-1 | PI-1 | — | DPHA | NCI-831 | Bk-S0100CF | S-20000 | FR-201 | MBA | 22.0 |
| | | | (65) | | (35) | (12) | (37.9) | (12.6) | (10) | PGMEA | |
| Example 2 | 2 | Bk-1 | PIP-1 | — | DPHA | NCI-831 | Bk-S0100CF | S-20000 | FR-201 | MBA | 22.0 |
| | | | (65) | | (35) | (12) | (37.9) | (12.6) | (10) | PGMEA | |
| Example 3 | 3 | Bk-1 | PBO-1 | — | DPHA | NCI-831 | Bk-S0100CF | S-20000 | FR-201 | MBA | 22.0 |
| | | | (65) | | (35) | (12) | (37.9) | (12.6) | (10) | PGMEA | |
| Example 4 | 4 | Bk-1 | PBOP-1 | — | DPHA | NCI-831 | Bk-S0100CF | S-20000 | FR-201 | MBA | 22.0 |
| | | | (65) | | (35) | (12) | (37.9) | (12.6) | (10) | PGMEA | |
| Example 5 | 5 | Bk-1 | PI-1 | PS-1 | DPHA | NCI-831 | Bk-S0100CF | S-20000 | FR-201 | MBA | 22.0 |
| | | | (50) | (15) | (35) | (12) | (37.9) | (12.6) | (10) | PGMEA | |
| Example 6 | 6 | Bk-2 | PI-1 | — | DPHA | NCI-831 | Bk-S0100CF | S-20000 | FR-201 | MBA | 22.5 |
| | | | (65) | | (35) | (12) | (37.9) | (12.6) | (10) | PGMEA | |
| Example 7 | 7 | Bk-2 | PI-1 | — | DPHA | NCI-831 | Bk-S0100CF | S-20000 | FR-201 | MBA | 22.0 |
| | | | (65) | | (35) | (12) | (37.9) | (12.6) | (10) | PGMEA | |
| Example 8 | 8 | Bk-2 | PI-1 | — | DPHA | NCI-831 | Bk-S0100CF | S-20000 | FR-201 | MBA | 21.0 |
| | | | (65) | | (35) | (20) | (37.9) | (12.6) | (10) | PGMEA | |
| Example 9 | 9 | Bk-2 | PI-1 | — | DPHA | NCI-831 | Bk-S0100CF | S-20000 | FR-201 | MBA | 20.4 |
| | | | (65) | | (35) | (25) | (37.9) | (12.6) | (10) | PGMEA | |
| Example 10 | 10 | Bk-2 | PI-1 | — | DPHA | NCI-831 | Bk-S0100CF | S-20000 | FR-201 | MBA | 19.7 |
| | | | (65) | | (35) | (32) | (37.9) | (12.6) | (10) | PGMEA | |

TABLE 3-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | Light-emitting | |
| | | | | | | Opening | Heat | | | Characteristics of | |
| | | | | | | Width | Resistance | | | Organic EL | |
| | | | | | Pattern | Dimension | Difference | | | Display Device | |
| | | | Devel- | Pattern | Cross- | between | in High- | | | | Charac- |
| | | | opment | Cross- | section | Before and | temperature | | Insulation | | teristics |
| | | | Residue | section | Shape after | After | Weight | Light- | Properties | | after |
| | | Sen- | Presence | Shape after | Thermal | Thermal | Residual | blocking | Surface | Initial | Durability |
| | Com- | sitivity | Area | Development | Curing | Curing | Ratio | OD | Resistivity | Charac- | Test |
| | position | [mJ/cm²] | [%] | [°] | [°] | [μm] | [% by mass] | Value | [Ω/□] | teristics | [%] |
| Example 1 | 1 | 50 | 10 | 37 | 22 | 0.55 | 7.5 | 1.0 | >1.0 × 10\hat{ }15 | Favorable | 100 |
| | | B | B | A | A+ | B | A | | | | A+ |
| Example 2 | 2 | 40 | 10 | 32 | 20 | 0.55 | 17.3 | 1.0 | >1.0 × 10\hat{ }15 | Favorable | 100 |
| | | A | B | A | A+ | B | B | | | | A+ |
| Example 3 | 3 | 50 | 10 | 37 | 22 | 0.55 | 7.7 | 1.0 | >1.0 × 10\hat{ }15 | Favorable | 100 |
| | | B | B | A | A+ | B | A | | | | A+ |
| Example 4 | 4 | 40 | 10 | 33 | 20 | 0.55 | 17.5 | 1.0 | >1.0 × 10\hat{ }15 | Favorable | 100 |
| | | A | B | A | A+ | B | B | | | | A+ |
| Example 5 | 5 | 40 | 10 | 30 | 20 | 0.55 | 10.1 | 1.0 | >1.0 × 10\hat{ }15 | Favorable | 100 |
| | | A | B | A+ | A+ | B | A | | | | A+ |
| Example 6 | 6 | 65 | 7 | 33 | 20 | 0.90 | 7.6 | 1.0 | >1.0 × 10\hat{ }15 | Favorable | 100 |
| | | C | B | A | A+ | C | A | | | | A+ |
| Example 7 | 7 | 50 | 7 | 37 | 22 | 0.55 | 7.3 | 1.0 | >1.0 × 10\hat{ }15 | Favorable | 100 |
| | | B | B | A | A+ | B | A | | | | A+ |
| Example 8 | 8 | 35 | 7 | 43 | 31 | 0.45 | 7.1 | 1.0 | >1.0 × 10\hat{ }15 | Favorable | 100 |
| | | A | B | A | A | B | A | | | | A+ |
| Example 9 | 9 | 20 | 7 | 56 | 41 | 0.50 | 7.1 | 1.0 | >1.0 × 10\hat{ }15 | Favorable | 100 |
| | | A+ | B | B | A | B | A | | | | A+ |
| Example 10 | 10 | 20 | 7 | 67 | 50 | 0.70 | 7.0 | 1.0 | >1.0 × 10\hat{ }15 | Favorable | 100 |
| | | A+ | B | C | B | C | A | | | | A+ |

TABLE 4-1

| | | | | | | | | | | | (D) |
|---|---|---|---|---|---|---|---|---|---|---|---|
| | | Composition (parts by mass) | | | | | | | | | Content |
| | | | | | | | | | (F) Cross- | | Ratio of |
| | | | | | (B) Radical | | | | linking | | Colorant to |
| | | | | | Polymerizable | | | | Agent | | Total Solid |
| | | | (A1) | (A2) | Compound | (C1) | | | (F1) to | | Content |
| | Com- | Pigment | First | Second | (B1) to (B4) | Photo | (D) | <(E) | (F9) | | (% by |
| | position | Dispersion | Resin | Resin | compounds | Initiator | Colorant | Dispersant> | Compounds | Solvent | mass) |
| Example 7 | 7 | Bk-2 | PI-1 | — | DPHA | NCI-831 | Bk-S0100CF | S-20000 | FR-201 | MBA | 22.0 |
| | | | (65) | | (35) | (12) | (37.9) | (12.6) | (10) | PGMEA | |
| Example 11 | 11 | Bk-2 | PI-1 | — | DPHA | NCI-831 | Bk-S0100CF | S-20000 | FR-201 | MBA | 10.0 |
| | | | (65) | | (35) | (12) | (14.0) | (4.7) | (10) | PGMEA | |
| Example 12 | 12 | Bk-2 | PI-1 | — | DPHA | NCI-831 | Bk-S0100CF | S-20000 | FR-201 | MBA | 32.0 |
| | | | (65) | | (35) | (12) | (68.1) | (22.7) | (10) | PGMEA | |
| Example 13 | 13 | Bk-3 | PI-1 | — | DPHA | NCI-831 | Bk-S0100CF | S-20000 | FR-201 | MBA | 45.0 |
| | | | (65) | | (35) | (12) | (114.1) | (17.6) | (10) | PGMEA | |
| Example 14 | 14 | Bk-2 | PI-1 | — | DPHA (10) | NCI-831 | Bk-S0100CF | S-20000 | FR-201 | MBA | 22.0 |
| | | | (65) | | DPCA-30 (25) | (12) | (37.9) | (12.6) | (10) | PGMEA | |
| Example 15 | 15 | Bk-2 | PI-1 | — | DPHA (10) | NCI-831 | Bk-S0100CF | S-20000 | FR-201 | MBA | 22.0 |
| | | | (65) | | DPCA-60 (25) | (12) | (37.9) | (12.6) | (10) | PGMEA | |
| Example 16 | 16 | Bk-2 | PI-1 | — | DPHA (10) | NCI-831 | Bk-S0100CF | S-20000 | FR-201 | MBA | 22.0 |
| | | | (65) | | A-DPH-6E (25) | (12) | (37.9) | (12.6) | (10) | PGMEA | |

TABLE 4-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | Light-emitting | |
| | | | | | | Opening | Heat | | | Characteristics of | |
| | | | | | | Width | Resistance | | | Organic EL | |
| | | | | | Pattern | Dimension | Difference | | | Display Device | |
| | | | Devel- | Pattern | Cross- | between | in High- | | | | Charac- |
| | | | opment | Cross- | section | Before and | temperature | | Insulation | | teristics |
| | | | Residue | section | Shape after | After | Weight | Light- | Properties | | after |
| | | Sen- | Presence | Shape after | Thermal | Thermal | Residual | blocking | Surface | Initial | Durability |
| | Com- | sitivity | Area | Development | Curing | Curing | Ratio | OD | Resistivity | Charac- | Test |
| | position | [mJ/cm²] | [%] | [°] | [°] | [μm] | [% by mass] | Value | [Ω/□] | teristics | [%] |
| Example 7 | 7 | 50 | 7 | 37 | 22 | 0.55 | 7.3 | 1.0 | >1.0 × 10\hat{ }15 | Favorable | 100 |
| | | B | B | A | A+ | B | A | | | | A+ |
| Example 11 | 11 | 40 | 5 | 34 | 20 | 0.55 | 6.4 | 0.5 | >1.0 × 10\hat{ }15 | Favorable | 100 |
| | | A | A | A | A+ | B | A | | | | A+ |
| Example 12 | 12 | 60 | 9 | 41 | 26 | 0.55 | 9.3 | 1.5 | >1.0 × 10\hat{ }15 | Favorable | 100 |
| | | B | B | A | A+ | B | A | | | | A+ |
| Example 13 | 13 | 80 | 10 | 47 | 32 | 0.60 | 11.5 | 2.0 | >1.0 × 10\hat{ }15 | Favorable | 100 |
| | | C | B | B | A | B | A | | | | A+ |
| Example 14 | 14 | 35 | 2 | 37 | 26 | 0.30 | 7.1 | 1.0 | >1.0 × 10\hat{ }15 | Favorable | 100 |
| | | A | A | A | A+ | A | A | | | | A+ |
| Example 15 | 15 | 30 | 0 | 37 | 29 | 0.20 | 7.0 | 1.0 | >1.0 × 10\hat{ }15 | Favorable | 100 |
| | | A+ | A+ | A | A+ | A+ | A | | | | A+ |
| Example 16 | 16 | 40 | 5 | 43 | 30 | 0.40 | 8.0 | 1.0 | >1.0 × 10\hat{ }15 | Favorable | 100 |
| | | A | A | A | A+ | A | A | | | | A+ |

TABLE 5-1

| | | | | | | | | | | | (D) |
|---|---|---|---|---|---|---|---|---|---|---|---|
| | | Composition (parts by mass) | | | | | | | | | Content |
| | | | | | | | | | (F) Cross- | | Ratio of |
| | | | | | (B) Radical | | | | linking | | Colorant to |
| | | | | | Polymerizable | | | | Agent | | Total Solid |
| | | | (A1) | (A2) | Compound | (C1) | | | (F1) to | | Content |
| | Com- | Pigment | First | Second | (B1) to (B4) | Photo | (D) | <(E) | (F9) | | (% by |
| | position | Dispersion | Resin | Resin | compounds | Initiator | Colorant | Dispersant> | Compounds | Solvent | mass) |
| Example 7 | 7 | Bk-2 | PI-1 | — | DPHA | NCI-831 | Bk-S0100CF | S-20000 | FR-201 | MBA | 22.0 |
| | | | (65) | | (35) | (12) | (37.9) | (12.6) | (10) | PGMEA | |
| Example 17 | 17 | Bk-2 | PI-1 | — | DPHA | NCI-831 | Bk-S0100CF | S-20000 | FLE-1 | MBA | 22.0 |
| | | | (65) | | (35) | (12) | (37.9) | (12.6) | (10) | PGMEA | |
| Example 18 | 18 | Bk-2 | PI-1 | — | DPHA | NCI-831 | Bk-S0100CF | S-20000 | FLE-2 | MBA | 22.0 |
| | | | (65) | | (35) | (12) | (37.9) | (12.6) | (10) | PGMEA | |
| Example 19 | 19 | Bk-3 | PI-1 | — | DPHA | NCI-831 | Bk-S0100CF | S-20000 | IDE-1 | MBA | 22.0 |
| | | | (65) | | (35) | (12) | (37.9) | (12.6) | (10) | PGMEA | |
| Example 20 | 20 | Bk-2 | PI-1 | — | DPHA | NCI-831 | Bk-S0100CF | S-20000 | IDE-2 | MBA | 22.0 |
| | | | (65) | | (35) | (12) | (37.9) | (12.6) | (10) | PGMEA | |
| Example 21 | 21 | Bk-2 | PI-1 | — | DPHA | NCI-831 | Bk-S0100CF | S-20000 | XD-1000-H | MBA | 22.0 |
| | | | (65) | | (35) | (12) | (37.9) | (12.6) | (10) | PGMEA | |
| Example 22 | 22 | Bk-2 | PI-1 | — | DPHA | NCI-831 | Bk-S0100CF | S-20000 | NC-7000L | MBA | 22.0 |
| | | | (65) | | (35) | (12) | (37.9) | (12.6) | (10) | PGMEA | |
| Example 23 | 23 | Bk-2 | PI-1 | — | DPHA | NCI-831 | Bk-S0100CF | S-20000 | NC-3500 | MBA | 22.0 |
| | | | (65) | | (35) | (12) | (37.9) | (12.6) | (10) | PGMEA | |

TABLE 5-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | Light-emitting | |
| | | | | | | Opening | Heat | | | Characteristics of | |
| | | | | | | Width | Resistance | | | Organic EL | |
| | | | | | Pattern | Dimension | Difference | | | Display Device | |
| | | | Devel- | Pattern | Cross- | between | in High- | | | | Charac- |
| | | | opment | Cross- | section | Before and | temperature | | Insulation | | teristics |
| | | | Residue | section | Shape after | After | Weight | Light- | Properties | | after |
| | | Sen- | Presence | Shape after | Thermal | Thermal | Residual | blocking | Surface | Initial | Durability |
| | Com- | sitivity | Area | Development | Curing | Curing | Ratio | OD | Resistivity | Charac- | Test |
| | position | [mJ/cm²] | [%] | [°] | [°] | [μm] | [% by mass] | Value | [Ω/□] | teristics | [%] |
| Example 7 | 7 | 50 | 7 | 37 | 22 | 0.55 | 7.3 | 1.0 | >1.0 × 10\hat{ }15 | Favorable | 100 |
| | | B | B | A | A+ | B | A | | | | A+ |
| Example 17 | 17 | 50 | 7 | 37 | 22 | 0.55 | 7.3 | 1.0 | >1.0 × 10\hat{ }15 | Favorable | 100 |
| | | A | B | A | A+ | B | A | | | | A+ |
| Example 18 | 18 | 45 | 6 | 33 | 20 | 0.55 | 7.0 | 1.0 | >1.0 × 10\hat{ }15 | Favorable | 100 |
| | | A | B | A | A+ | B | A | | | | A+ |
| Example 19 | 19 | 50 | 7 | 40 | 25 | 0.60 | 8.3 | 1.0 | >1.0 × 10\hat{ }15 | Favorable | 100 |
| | | B | B | A | A+ | B | A | | | | A+ |
| Example 20 | 20 | 50 | 7 | 40 | 25 | 0.60 | 8.3 | 1.0 | >1.0 × 10\hat{ }15 | Favorable | 100 |
| | | B | B | A | A+ | B | A | | | | A+ |
| Example 21 | 21 | 50 | 7 | 37 | 25 | 0.60 | 7.7 | 1.0 | >1.0 × 10\hat{ }15 | Favorable | 100 |
| | | B | B | A | A+ | B | A | | | | A+ |
| Example 22 | 22 | 50 | 7 | 37 | 25 | 0.60 | 7.7 | 1.0 | >1.0 × 10\hat{ }15 | Favorable | 100 |
| | | B | B | A | A+ | B | A | | | | A+ |
| Example 23 | 23 | 55 | 7 | 40 | 25 | 0.55 | 8.0 | 1.0 | >1.0 × 10\hat{ }15 | Favorable | 100 |
| | | A | B | A | A+ | B | A | | | | A+ |

TABLE 6-1

| | | | | | | | | | | | (D) |
|---|---|---|---|---|---|---|---|---|---|---|---|
| | | Composition (parts by mass) | | | | | | | | | Content |
| | | | | | | | | | (F) Cross- | | Ratio of |
| | | | | | (B) Radical | | | | linking | | Colorant to |
| | | | | | Polymerizable | | | | Agent | | Total Solid |
| | | | (A1) | (A2) | Compound | (C1) | | | (F1) to | | Content |
| | Com- | Pigment | First | Second | (B1) to (B4) | Photo | (D) | <(E) | (F9) | | (% by |
| | position | Dispersion | Resin | Resin | compounds | Initiator | Colorant | Dispersant> | Compounds | Solvent | mass) |
| Example 15 | 15 | Bk-2 | PI-1 | — | DPHA (10) | NCI-831 | Bk-S0100CF | S-20000 | FR-201 | MBA | 22.0 |
| | | | (65) | | DPCA-60 (25) | (12) | (37.9) | (12.6) | (10) | PGMEA | |
| Example 24 | 24 | Bk-2 | PI-1 | — | DPHA (10) | NCI-831 | Bk-S0100CF | S-20000 | FR-201 | MBA | 23.0 |
| | | | (65) | | DPCA-60 (25) | (12) | (37.9) | (12.6) | (2) | PGMEA | |
| Example 25 | 25 | Bk-2 | PI-1 | — | DPHA (10) | NCI-831 | Bk-S0100CF | S-20000 | FR-201 | MBA | 22.6 |
| | | | (65) | | DPCA-60 (25) | (12) | (37.9) | (12.6) | (5) | PGMEA | |
| Example 26 | 26 | Bk-2 | PI-1 | — | DPHA (10) | NCI-831 | Bk-S0100CF | S-20000 | FR-201 | MBA | 20.8 |
| | | | (65) | | DPCA-60 (25) | (12) | (37.9) | (12.6) | (20) | PGMEA | |
| Example 27 | 27 | Bk-2 | PI-1 | — | DPHA (10) | NCI-831 | Bk-S0100CF | S-20000 | FR-201 | MBA | 20.2 |
| | | | (65) | | DPCA-60 (25) | (12) | (37.9) | (12.6) | (25) | PGMEA | |
| Example 28 | 28 | Bk-2 | PI-1 | — | DPHA (10) | NCI-831 | Bk-S0100CF | S-20000 | XD-1000-H | MBA | 19.7 |
| | | | (65) | | DPCA-60 (25) | (12) | (37.9) | (12.6) | (30) | PGMEA | |
| Example 29 | 29 | Bk-2 | PI-1 | — | DPHA (10) | NCI-831 | Bk-S0100CF | S-20000 | XD-1000-H | MBA | 22.6 |
| | | | (65) | | DPCA-60 (25) | (12) | (37.9) | (12.6) | (5) | PGMEA | |
| Example 30 | 30 | Bk-2 | PI-1 | — | DPHA (10) | NCI-831 | Bk-S0100CF | S-20000 | XD-1000-H | MBA | 22.0 |
| | | | (65) | | DPCA-60 (25) | (12) | (37.9) | (12.6) | (10) | PGMEA | |
| Example 31 | 31 | Bk-2 | PI-1 | — | DPHA (10) | NCI-831 | Bk-S0100CF | S-20000 | XD-1000-H | MBA | 20.8 |
| | | | (65) | | DPCA-60 (25) | (12) | (37.9) | (12.6) | (20) | PGMEA | |

TABLE 6-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | Light-emitting | |
| | | | | | | Opening | Heat | | | Characteristics of | |
| | | | | | | Width | Resistance | | | Organic EL | |
| | | | | | Pattern | Dimension | Difference | | | Display Device | |
| | | | Devel- | Pattern | Cross- | between | in High- | | | | Charac- |
| | | | opment | Cross- | section | Before and | temperature | | Insulation | | teristics |
| | | | Residue | section | Shape after | After | Weight | Light- | Properties | | after |
| | | Sen- | Presence | Shape after | Thermal | Thermal | Residual | blocking | Surface | Initial | Durability |
| | Com- | sitivity | Area | Development | Curing | Curing | Ratio | OD | Resistivity | Charac- | Test |
| | position | [mJ/cm²] | [%] | [°] | [°] | [μm] | [% by mass] | Value | [Ω/□] | teristics | [%] |
| Example 15 | 15 | 30 | 0 | 37 | 29 | 0.20 | 7.0 | 1.0 | >1.0 × 10\hat{ }15 | Favorable | 100 |
| | | A+ | A+ | A | A+ | A+ | A | | | | A+ |
| Example 24 | 24 | 30 | 0 | 41 | 31 | 0.30 | 7.6 | 1.0 | >1.0 × 10\hat{ }15 | Favorable | 100 |
| | | A+ | A+ | A | A | A | A | | | | A+ |
| Example 25 | 25 | 30 | 0 | 37 | 29 | 0.20 | 7.2 | 1.0 | >1.0 × 10\hat{ }15 | Favorable | 100 |
| | | A+ | A+ | A | A+ | A+ | A | | | | A+ |
| Example 26 | 26 | 30 | 0 | 37 | 29 | 0.25 | 6.9 | 1.0 | >1.0 × 10\hat{ }15 | Favorable | 100 |
| | | A+ | A+ | A | A+ | A | A | | | | A+ |
| Example 27 | 27 | 30 | 0 | 37 | 27 | 0.30 | 6.9 | 1.0 | >1.0 × 10\hat{ }15 | Favorable | 100 |
| | | A+ | A+ | A | A+ | A | A | | | | A+ |
| Example 28 | 28 | 30 | 3 | 37 | 24 | 0.45 | 6.8 | 1.0 | >1.0 × 10\hat{ }15 | Favorable | 100 |
| | | A+ | A+ | A | A+ | B | A | | | | A+ |
| Example 29 | 29 | 30 | 0 | 37 | 31 | 0.25 | 7.5 | 1.0 | >1.0 × 10\hat{ }15 | Favorable | 100 |
| | | A+ | A+ | A | A | A | A | | | | A+ |
| Example 30 | 30 | 30 | 0 | 37 | 31 | 0.25 | 7.3 | 1.0 | >1.0 × 10\hat{ }15 | Favorable | 100 |
| | | A+ | A+ | A | A | A | A | | | | A+ |
| Example 31 | 31 | 30 | 0 | 37 | 31 | 0.30 | 7.1 | 1.0 | >1.0 × 10\hat{ }15 | Favorable | 100 |
| | | A+ | A+ | A | A | A | A | | | | A+ |

TABLE 7-1

| | | | | | | | | | | | (D) |
|---|---|---|---|---|---|---|---|---|---|---|---|
| | | Composition (parts by mass) | | | | | | | | | Content |
| | | | | | | | | | (F) Cross- | | Ratio of |
| | | | | | (B) Radical | | | | linking | | Colorant to |
| | | | | | Polymerizable | | | | Agent | | Total Solid |
| | | | (A1) | (A2) | Compound | (C1) | | | (F1) to | | Content |
| | Com- | Pigment | First | Second | (B1) to (B4) | Photo | (D) | <(E) | (F9) | | (% by |
| | position | Dispersion | Resin | Resin | compounds | Initiator | Colorant | Dispersant> | Compounds | Solvent | mass) |
| Example 7 | 7 | Bk-2 | PI-1 | — | DPHA (35) | NCI-831 | Bk-S0100CF | S-20000 | FR-201 | MBA | 22.0 |
| | | | (65) | | | (12) | (37.9) | (12.6) | (10) | PGMEA | |
| Example 32 | 32 | Bk-2 | PI-2 | — | DPHA (35) | NCI-831 | Bk-S0100CF | S-20000 | FR-201 | MBA | 22.0 |
| | | | (65) | | | (12) | (37.9) | (12.6) | (10) | PGMEA | |
| Example 33 | 33 | Bk-2 | PI-3 | — | DPHA (35) | NCI-831 | Bk-S0100CF | S-20000 | FR-201 | MBA | 22.0 |
| | | | (65) | | | (12) | (37.9) | (12.6) | (10) | PGMEA | |
| Example 34 | 34 | Bk-2 | PI-4 | — | DPHA (35) | NCI-831 | Bk-S0100CF | S-20000 | FR-201 | MBA | 22.0 |
| | | | (65) | | | (12) | (37.9) | (12.6) | (10) | PGMEA | |
| Example 35 | 35 | Bk-2 | PI-1 (50) | — | DPHA (35) | NCI-831 | Bk-S0100CF | S-20000 | FR-201 | MBA | 22.0 |
| | | | PIP-1 (15) | | | (12) | (37.9) | (12.6) | (10) | PGMEA | |
| Example 36 | 36 | Bk-2 | PI-1 (50) | — | DPHA (35) | NCI-831 | Bk-S0100CF | S-20000 | FR-201 | MBA | 22.0 |
| | | | PIP-2 (15) | | | (12) | (37.9) | (12.6) | (10) | PGMEA | |
| Example 37 | 37 | Bk-2 | PI-1 (50) | — | DPHA (35) | NCI-831 | Bk-S0100CF | S-20000 | FR-201 | MBA | 22.0 |
| | | | PBO-1 (15) | | | (12) | (37.9) | (12.6) | (10) | PGMEA | |
| Example 38 | 38 | Bk-2 | PI-1 (50) | — | DPHA (35) | NCI-831 | Bk-S0100CF | S-20000 | FR-201 | MBA | 22.0 |
| | | | PBOP-1 (15) | | | (12) | (37.9) | (12.6) | (10) | PGMEA | |

TABLE 7-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | Light-emitting | |
| | | | | | | Opening | Heat | | | Characteristics of | |
| | | | | | | Width | Resistance | | | Organic EL | |
| | | | | | Pattern | Dimension | Difference | | | Display Device | |
| | | | Devel- | Pattern | Cross- | between | in High- | | | | Charac- |
| | | | opment | Cross- | section | Before and | temperature | | Insulation | | teristics |
| | | | Residue | section | Shape after | After | Weight | Light- | Properties | | after |
| | | Sen- | Presence | Shape after | Thermal | Thermal | Residual | blocking | Surface | Initial | Durability |
| | Com- | sitivity | Area | Development | Curing | Curing | Ratio | OD | Resistivity | Charac- | Test |
| | position | [mJ/cm²] | [%] | [°] | [°] | [μm] | [% by mass] | Value | [Ω/□] | teristics | [%] |
| Example 7 | 7 | 50 | 7 | 37 | 22 | 0.55 | 7.3 | 1.0 | >1.0 × 10\hat{ }15 | Favorable | 100 |
| | | B | B | A | A+ | B | A | | | | A+ |
| Example 32 | 32 | 55 | 7 | 37 | 22 | 0.55 | 7.4 | 1.0 | >1.0 × 10\hat{ }15 | Favorable | 100 |
| | | B | B | A | A+ | B | A | | | | A+ |
| Example 33 | 33 | 45 | 7 | 37 | 22 | 0.55 | 7.3 | 1.0 | >1.0 × 10\hat{ }15 | Favorable | 100 |
| | | A | B | A | A+ | B | A | | | | A+ |
| Example 34 | 34 | 45 | 7 | 37 | 22 | 0.55 | 7.4 | 1.0 | >1.0 × 10\hat{ }15 | Favorable | 100 |
| | | A | B | A | A+ | B | A | | | | A+ |
| Example 35 | 35 | 45 | 7 | 34 | 20 | 0.55 | 8.4 | 1.0 | >1.0 × 10\hat{ }15 | Favorable | 100 |
| | | A | B | A | A+ | B | A | | | | A+ |
| Example 36 | 36 | 45 | 7 | 34 | 20 | 0.55 | 8.3 | 1.0 | >1.0 × 10\hat{ }15 | Favorable | 100 |
| | | A | B | A | A+ | B | A | | | | A+ |
| Example 37 | 37 | 50 | 7 | 37 | 22 | 0.55 | 7.3 | 1.0 | >1.0 × 10\hat{ }15 | Favorable | 100 |
| | | B | B | A | A+ | B | A | | | | A+ |
| Example 38 | 38 | 45 | 7 | 35 | 20 | 0.55 | 8.4 | 1.0 | >1.0 × 10\hat{ }15 | Favorable | 100 |
| | | A | B | A | A+ | B | A | | | | A+ |

TABLE 8-1

| | | | | | | | | | | | (D) |
|---|---|---|---|---|---|---|---|---|---|---|---|
| | | Composition (parts by mass) | | | | | | | | | Content |
| | | | | | | | | | (F) Cross- | | Ratio of |
| | | | | | (B) Radical | | | | linking | | Colorant to |
| | | | | | Polymerizable | | | | Agent | | Total Solid |
| | | | (A1) | (A2) | Compound | (C1) | | | (F1) to | | Content |
| | Com- | Pigment | First | Second | (B1) to (B4) | Photo | (D) | <(E) | (F9) | | (% by |
| | position | Dispersion | Resin | Resin | compounds | Initiator | Colorant | Dispersant> | Compounds | Solvent | mass) |
| Example 7 | 7 | Bk-2 | PI-1 | — | DPHA (35) | NCI-831 | Bk-S0100CF | S-20000 | FR-201 | MBA | 22.0 |
| | | | (65) | | | (12) | (37.9) | (12.6) | (10) | PGMEA | |
| Example 39 | 39 | Bk-2 | PI-1 | PS-1 | DPHA (35) | NCI-831 | Bk-S0100CF | S-20000 | FR-201 | MBA | 22.0 |
| | | | (50) | (15) | | (12) | (37.9) | (12.6) | (10) | PGMEA | |
| Example 40 | 40 | Bk-2 | PI-1 | PS-2 | DPHA (35) | NCI-831 | Bk-S0100CF | S-20000 | FR-201 | MBA | 22.0 |
| | | | (50) | (15) | | (12) | (37.9) | (12.6) | (10) | PGMEA | |
| Example 41 | 41 | Bk-3 | PI-1 | CR-1 | DPHA (35) | NCI-831 | Bk-S0100CF | S-20000 | FR-201 | MBA | 22.0 |
| | | | (50) | (15) | | (12) | (37.9) | (12.6) | (10) | PGMEA | |
| Example 42 | 42 | Bk-2 | PI-1 | WR-301 | DPHA (35) | NCI-831 | Bk-S0100CF | S-20000 | FR-201 | MBA | 22.0 |
| | | | (50) | (15) | | (12) | (37.9) | (12.6) | (10) | PGMEA | |
| Example 43 | 43 | Bk-2 | PI-1 | AE-1 | DPHA (35) | NCI-831 | Bk-S0100CF | S-20000 | FR-201 | MBA | 22.0 |
| | | | (50) | (15) | | (12) | (37.9) | (12.6) | (10) | PGMEA | |
| Example 44 | 44 | Bk-2 | PI-1 | AC-1 | DPHA (35) | NCI-831 | Bk-S0100CF | S-20000 | FR-201 | MBA | 22.0 |
| | | | (50) | (15) | | (12) | (37.9) | (12.6) | (10) | PGMEA | |
| Example 45 | 45 | Bk-2 | PI-1 | CR-1 | DPHA (35) | NCI-831 | Bk-S0100CF | S-20000 | FR-201 | MBA | 22.0 |
| | | | (35) | (30) | | (12) | (37.9) | (12.6) | (10) | PGMEA | |
| Example 46 | 46 | Bk-2 | PI-1 | CR-1 | DPHA (35) | NCI-831 | Bk-S0100CF | S-20000 | FR-201 | MBA | 22.0 |
| | | | (60) | (5) | DPHA (35) | (12) | (37.9) | (12.6) | (10) | PGMEA | |

TABLE 8-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | Light-emitting | |
| | | | | | | Opening | Heat | | | Characteristics of | |
| | | | | | | Width | Resistance | | | Organic EL | |
| | | | | | Pattern | Dimension | Difference | | | Display Device | |
| | | | Devel- | Pattern | Cross- | between | in High- | | | | Charac- |
| | | | opment | Cross- | section | Before and | temperature | | Insulation | | teristics |
| | | | Residue | section | Shape after | After | Weight | Light- | Properties | | after |
| | | Sen- | Presence | Shape after | Thermal | Thermal | Residual | blocking | Surface | Initial | Durability |
| | Com- | sitivity | Area | Development | Curing | Curing | Ratio | OD | Resistivity | Charac- | Test |
| | position | [mJ/cm²] | [%] | [°] | [°] | [μm] | [% by mass] | Value | [Ω/□] | teristics | [%] |
| Example 7 | 7 | 50 | 7 | 37 | 22 | 0.55 | 7.3 | 1.0 | >1.0 × 10\hat{ }15 | Favorable | 100 |
| | | B | B | A | A+ | B | A | | | | A+ |
| Example 39 | 39 | 40 | 7 | 31 | 20 | 0.55 | 10.4 | 1.0 | >1.0 × 10\hat{ }15 | Favorable | 100 |
| | | A | B | A | A+ | B | A | | | | A+ |
| Example 40 | 40 | 35 | 7 | 41 | 26 | 0.55 | 11.1 | 1.0 | >1.0 × 10\hat{ }15 | Favorable | 100 |
| | | A | B | A | A+ | B | A | | | | A+ |
| Example 41 | 41 | 35 | 7 | 32 | 20 | 0.55 | 14.4 | 1.0 | >1.0 × 10\hat{ }15 | Favorable | 95 |
| | | A | B | A | A+ | B | A | | | | A |
| Example 42 | 42 | 35 | 7 | 32 | 20 | 0.55 | 14.2 | 1.0 | >1.0 × 10\hat{ }15 | Favorable | 95 |
| | | A | B | A | A+ | B | A | | | | A |
| Example 43 | 43 | 35 | 7 | 32 | 20 | 0.55 | 16.2 | 1.0 | >1.0 × 10\hat{ }15 | Favorable | 90 |
| | | A | B | A | A+ | B | B | | | | A |
| Example 44 | 44 | 35 | 7 | 31 | 20 | 0.55 | 20.2 | 1.0 | >1.0 × 10\hat{ }15 | Favorable | 85 |
| | | A | B | A | A+ | B | B | | | | B |
| Example 45 | 45 | 25 | 7 | 46 | 31 | 0.55 | 18.4 | 1.0 | >1.0 × 10\hat{ }15 | Favorable | 85 |
| | | A+ | B | B | A+ | B | B | | | | B |
| Example 46 | 46 | 45 | 7 | 34 | 21 | 0.55 | 10.1 | 1.0 | >1.0 × 10\hat{ }15 | Favorable | 100 |
| | | A | B | A | A+ | B | A | | | | A+ |

TABLE 9-1

| | | | | | | | | | | | (D) |
|---|---|---|---|---|---|---|---|---|---|---|---|
| | | Composition (parts by mass) | | | | | | | | | Content |
| | | | | | | | | | (F) Cross- | | Ratio of |
| | | | | | (B) Radical | | | | linking | | Colorant to |
| | | | | | Polymerizable | | | | Agent | | Total Solid |
| | | | (A1) | (A2) | Compound | (C1) | | | (F1) to | | Content |
| | Com- | Pigment | First | Second | (B1) to (B4) | Photo | (D) | <(E) | (F9) | | (% by |
| | position | Dispersion | Resin | Resin | compounds | Initiator | Colorant | Dispersant> | Compounds | Solvent | mass) |
| Example 15 | 15 | Bk-2 | PI-1 | — | DPHA (10) | NCI-831 | Bk-S0100CF | S-20000 | FR-201 | MBA | 22.0 |
| | | | (65) | | DPCA-60 (25) | (12) | (37.9) | (12.6) | (10) | PGMEA | |
| Example 47 | 47 | Bk-4 | PI-1 | — | DPHA (10) | NCI-831 | Bk-S0084 | D.BYK-167 | FR-201 | MBA | 22.0 |
| | | | (65) | | DPCA-60 (25) | (12) | (37.9) | (12.6) | (10) | PGMEA | |
| Example 48 | 48 | Bk-5 | PI-1 | — | DPHA (10) | NCI-831 | Bk-A1103 | D.BYK-167 | FR-201 | MBA | 22.0 |
| | | | (65) | | DPCA-60 (25) | (12) | (37.9) | (12.6) | (10) | PGMEA | |
| Example 49 | 49 | Bk-6 | PI-1 | — | DPHA (10) | NCI-831 | TPK-1227 | D.BYK-167 | FR-201 | MBA | 15.0 |
| | | | (65) | | DPCA-60 (25) | (12) | (22.9) | (7.6) | (10) | PGMEA | |
| Example 50 | 50 | Bk-7 | PI-1 | — | DPHA (10) | NCI-831 | P.R.254 | D.BYK-167 | FR-201 | MBA | 32.0 |
| | | | (65) | | DPCA-60 (25) | (12) | (23.8) | (22.7) | (10) | PGMEA | |
| | | | | | | | P.Y.139 | | | | |
| | | | | | | | (10.2) | | | | |
| | | | | | | | P.B.15:6 | | | | |
| | | | | | | | (34.1) | | | | |
| Example 51 | 51 | Bk-8 | PI-1 | — | DPHA (10) | NCI-831 | P.V.23 | D.BYK-167 | FR-201 | MBA | 32.0 |
| | | | (65) | | DPCA-60 (25) | (12) | (34.1) | (22.7) | (10) | PGMEA | |
| | | | | | | | P.Y.139 | | | | |
| | | | | | | | (34.1) | | | | |

TABLE 9-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | | |
| | | | | | | Opening | Heat | | | | |
| | | | | | Pattern | Width | Resistance | | | | |
| | | | | | Cross- | Dimension | Difference | | | Light-emitting | |
| | | | | Pattern | section | between | in High- | | | Characteristics of Organic | |
| | | | Development | Cross- | Shape | Before and | temperature | | Insulation | EL Display Device | |
| | | | Residue | section | after | After | Weight | Light- | Properties | | Characteristics |
| | | | Presence | Shape after | Thermal | Thermal | Residual | blocking | Surface | Initial | after Durability |
| | Compo- | Sensitivity | Area | Development | Curing | Curing | Ratio | OD | Resistivity | Character- | Test |
| | sition | [mJ/cm²] | [%] | [°] | [°] | [μm] | [% by mass] | Value | [Ω/□] | istics | [%] |
| Example | 15 | 30 | 0 | 37 | 29 | 0.20 | 7.0 | 1.0 | >1.0 × 10\hat{ }15 | Favorable | 100 |
| 15 | | A+ | A+ | A | A+ | A+ | A | | | | A+ |
| Example | 47 | 40 | 0 | 37 | 29 | 0.20 | 8.3 | 1.0 | >1.0 × 10\hat{ }15 | Favorable | 100 |
| 47 | | A | A+ | A | A+ | A+ | A | | | | A+ |
| Example | 48 | 40 | 0 | 38 | 30 | 0.20 | 8.6 | 1.0 | >1.0 × 10\hat{ }15 | Favorable | 100 |
| 48 | | A | A+ | A | A+ | A+ | A | | | | A+ |
| Example | 49 | 55 | 0 | 39 | 29 | 0.25 | 9.4 | 1.0 | 1.0 × 10\hat{ }13 | Favorable | 80 |
| 49 | | B | A+ | A | A+ | A | A | | | | B |
| Example | 50 | 50 | 0 | 37 | 29 | 0.20 | 9.6 | 1.0 | 1.0 × 10\hat{ }14 | Favorable | 95 |
| 50 | | B | A+ | A | A+ | A+ | A | | | | A |
| Example | 51 | 50 | 0 | 37 | 29 | 0.20 | 9.5 | 1.0 | 1.0 × 10\hat{ }14 | Favorable | 95 |
| 51 | | B | A+ | A | A+ | A+ | A | | | | A |

TABLE 10-1

| | Composition (parts by mass) | | | | | | | | | | | Content |
|---|---|---|---|---|---|---|---|---|---|---|---|---|
| | | | | | | | | | (F) Cross- | | (D) Content | Ratio of |
| | | | | | (B) Radical | | | | linking | | Ratio of | (B4) to |
| | | | | | Polymerizable | | | | Agent | | Colorant to | (B3) + |
| | | | (A1) | (A2) | Compound | (C1) | | | (F1) to | | Total Solid | (B4) |
| | Compo- | Pigment | First | Second | (B1) to (B4) | Photo | (D) | <(E) | (F9) | | Content | [% by |
| | sition | Dispersion | Resin | Resin | compounds | Initiator | Colorant | Dispersant> | Compounds | Solvent | [% by mass] | mass] |
| Example | 7 | Bk-2 | PI-1 | — | DPHA (35) | NCI-831 | Bk-S0100CF | S-20000 | FR-201 | MBA | 22.0 | — |
| 7 | | | (65) | | | (12) | (37.9) | (12.6) | (10) | PGMEA | | |
| Example | 15 | Bk-2 | PI-1 | — | DPHA (10) | NCI-831 | Bk-S0100CF | S-20000 | FR-201 | MBA | 22.0 | — |
| 15 | | | (65) | | DPCA-60 (25) | (12) | (37.9) | (12.6) | (10) | PGMEA | | |
| Example | 52 | Bk-2 | PI-1 | — | DPCA-60 (28) | NCI-831 | Bk-S0100CF | S-20000 | FR-201 | MBA | 22.0 | 20 |
| 52 | | | (65) | | HX-220 (7) | (12) | (37.9) | (12.6) | (10) | PGMEA | | |
| Example | 53 | Bk-2 | PI-1 | — | DPCA-60 (21) | NCI-831 | Bk-S0100CF | S-20000 | FR-201 | MBA | 22.0 | 40 |
| 53 | | | (65) | | HX-220 (14) | (12) | (37.9) | (12.6) | (10) | PGMEA | | |
| Example | 54 | Bk-2 | PI-1 | — | DPCA-60 (14) | NCI-831 | Bk-S0100CF | S-20000 | FR-201 | MBA | 22.0 | 60 |
| 54 | | | (65) | | HX-220 (21) | (12) | (37.9) | (12.6) | (10) | PGMEA | | |
| Example | 55 | Bk-2 | PI-1 | — | DPCA-60 (7) | NCI-831 | Bk-S0100CF | S-20000 | FR-201 | MBA | 22.0 | 80 |
| 55 | | | (65) | | HX-220 (28) | (12) | (37.9) | (12.6) | (10) | PGMEA | | |
| Example | 56 | Bk-2 | PI-1 | — | DPHA (10) | NCI-831 | Bk-S0100CF | S-20000 | FR-201 | MBA | 22.0 | — |
| 56 | | | (65) | | HX-220 (25) | (12) | (37.9) | (12.6) | (10) | PGMEA | | |
| Example | 57 | Bk-9 | PI-1 | — | DPHA (10) | NCI-831 | Bk-CBF | S-20000 | FR-201 | MBA | 22.0 | — |
| 57 | | | (65) | | DPCA-60 (25) | (12) | (37.9) | (12.6) | (10) | PGMEA | | |

TABLE 10-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | | |
| | | | | | | Opening | Heat | | | Light-emitting | |
| | | | | | Pattern | Width | Resistance | | | Characterististics | |
| | | | | | Cross- | Dimension | Difference | | | of Organic EL | |
| | | | Develop- | Pattern | section | between | in High- | | | Display Device | |
| | | | ment | Cross- | Shape | Before and | temperature | | Insulation | | Characteristics |
| | | | Residue | section | after | After | Weight | Light- | Properties | | after |
| | | | Presence | Shape after | Thermal | Thermal | Residual | blocking | Surface | | Durability |
| | Compo- | Sensitivity | Area | Development | Curing | Curing | Ratio | OD | Resistivity | Initial | Test |
| | sition | [mJ/cm²] | [%] | [°] | [°] | [μm] | [% by mass] | Value | [Ω/□] | Characteristics | [%] |
| Example | 7 | 50 | 7 | 37 | 22 | 0.55 | 7.3 | 1.0 | >1.0 × 10\hat{ }15 | Favorable | 100 |
| 7 | | B | B | A | A+ | B | A | | | | A+ |
| Example | 15 | 30 | 0 | 37 | 29 | 0.20 | 7.0 | 1.0 | >1.0 × 10\hat{ }15 | Favorable | 100 |
| 15 | | A+ | A+ | A | A+ | A+ | A | | | | A+ |
| Example | 52 | 30 | 0 | 35 | 29 | 0.20 | 6.9 | 1.0 | >1.0 × 10\hat{ }15 | Favorable | 100 |
| 52 | | A+ | A+ | A | A+ | A+ | A | | | | A+ |
| Example | 53 | 32 | 0 | 32 | 27 | 0.10 | 6.8 | 1.0 | >1.0 × 10\hat{ }15 | Favorable | 100 |
| 53 | | A | A+ | A | A+ | A+ | A | | | | A+ |
| Example | 54 | 32 | 0 | 32 | 27 | 0.15 | 6.8 | 1.0 | >1.0 × 10\hat{ }15 | Favorable | 100 |
| 54 | | A | A+ | A | A+ | A+ | A | | | | A+ |
| Example | 55 | 37 | 3 | 35 | 25 | 0 .30 | 7.0 | 1.0 | >1.0 × 10\hat{ }15 | Favorable | 100 |
| 55 | | A | A | A | A+ | A | A | | | | A+ |
| Example | 56 | 40 | 3 | 35 | 24 | 0.30 | 7.1 | 1.0 | >1.0 × 10\hat{ }15 | Favorable | 100 |
| 56 | | A | A | A | A+ | A | A | | | | A+ |
| Example | 57 | 30 | 0 | 30 | 25 | 0.15 | 5.0 | 1.0 | >1.0 × 10\hat{ }15 | Favorable | 100 |
| 57 | | A+ | A+ | A+ | A+ | A+ | A+ | | | | A+ |

TABLE 11-1

| | | Composition (parts by mass) | | | | | | | | | (D) Content | |
|---|---|---|---|---|---|---|---|---|---|---|---|---|
| | | | | | | | | | (F) Cross- | | Ratio of | Content |
| | | | | | (B) Radical | | | | linking | | Colorant to | Ratio |
| | | | | | Polymerizable | | | | Agent | | Total Solid | of |
| | | | (A1) | (A2) | Compound | (C1) | | | (F1) to | | Content | Two |
| | Compo- | Pigment | First | Second | (B1) to (B4) | Photo | (D) | <(E) | (F9) | | [% by | of (F1) |
| | sition | Dispersion | Resin | Resin | compounds | Initiator | Colorant | Dispersant> | Compounds | Solvent | mass] | to (F8) |
| Example | 7 | Bk-2 | PI-1 | — | DPHA (35) | NCI-831 | Bk-S0100CF | S-20000 | FR-201 | MBA | 22.0 | — |
| 7 | | | (65) | | | (12) | (37.9) | (12.6) | (10) | PGMEA | | |
| Example | 58 | Bk-2 | PI-1 | — | DPHA (35) | NCI-831 | Bk-S0100CF | S-20000 | FR-201 (8) | MBA | 22.0 | 80/20 |
| 58 | | | (65) | | | (12) | (37.9) | (12.6) | XD-1000-H | PGMEA | | |
| | | | | | | | | | (2) | | | |
| Example | 59 | Bk-2 | PI-1 | — | DPHA (35) | NCI-831 | Bk-S0100CF | S-20000 | FR-201 (6) | MBA | 22.0 | 60/40 |
| 59 | | | (65) | | | (12) | (37.9) | (12.6) | XD-1000-H | PGMEA | | |
| | | | | | | | | | (4) | | | |
| Example | 60 | Bk-2 | PI-1 | — | DPHA (35) | NCI-831 | Bk-S0100CF | S-20000 | FR-201 (4) | MBA | 22.0 | 40/60 |
| 60 | | | (65) | | | (12) | (37.9) | (12.6) | XD-1000-H | PGMEA | | |
| | | | | | | | | | (6) | | | |
| Example | 61 | Bk-2 | PI-1 | — | DPHA (35) | NCI-831 | Bk-S0100CF | S-20000 | FR-201 (2) | MBA | 22.0 | 20/80 |
| 61 | | | (65) | | | (12) | (37.9) | (12.6) | XD-1000-H | PGMEA | | |
| | | | | | | | | | (8) | | | |
| Example | 62 | Bk-2 | PI-1 | — | DPHA (35) | NCI-831 | Bk-S0100CF | S-20000 | FR-201 (6) | MBA | 22.0 | 60/40 |
| 62 | | | (65) | | | (12) | (37.9) | (12.6) | IDE-1 (4) | PGMEA | | |
| Example | 63 | Bk-2 | PI-1 | — | DPHA (35) | NCI-831 | Bk-S0100CF | S-20000 | FR-201 (6) | MBA | 22.0 | 60/40 |
| 63 | | | (65) | | | (12) | (37.9) | (12.6) | NC-7000L | PGMEA | | |
| | | | | | | | | | (4) | | | |

TABLE 11-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | | |
| | | | | | | Opening | Heat | | | Light-emitting | |
| | | | | | Pattern | Width | Resistance | | | Characteristics | |
| | | | | | Cross- | Dimension | Difference | | | of Organic EL | |
| | | | Develop- | Pattern | section | between | in High- | | | Display Device | |
| | | | ment | Cross- | Shape | Before and | temperature | | Insulation | | Characteristics |
| | | | Residue | section | after | After | Weight | Light- | Properties | | after |
| | | | Presence | Shape after | Thermal | Thermal | Residual | blocking | Surface | | Durability |
| | Compo- | Sensitivity | Area | Development | Curing | Curing | Ratio [% | OD | Resistivity | Initial | Test |
| | sition | [mJ/cm²] | [%] | [°] | [°] | [μm] | by mass] | Value | [Ω/□] | Caracteristics | [%] |
| Example | 7 | 50 | 7 | 37 | 22 | 0.55 | 7.3 | 1.0 | >1.0 × 10\hat{ }15 | Favorable | 100 |
| 7 | | B | B | A | A+ | B | A | | | | A+ |
| Example | 58 | 50 | 7 | 35 | 20 | 0.50 | 7.1 | 1.0 | >1.0 × 10\hat{ }15 | Favorable | 100 |
| 58 | | B | B | A | A+ | B | A | | | | A+ |
| Example | 59 | 50 | 7 | 33 | 20 | 0.30 | 6.8 | 1.0 | >1.0 × 10\hat{ }15 | Favorable | 100 |
| 59 | | B | B | A | A+ | A | A | | | | A+ |
| Example | 60 | 50 | 7 | 33 | 20 | 0.30 | 6.8 | 1.0 | >1.0 × 10\hat{ }15 | Favorable | 100 |
| 60 | | B | B | A | A+ | A | A | | | | A+ |
| Example | 61 | 50 | 7 | 35 | 20 | 0.50 | 7.1 | 1.0 | >1.0 × 10\hat{ }15 | Favorable | 100 |
| 61 | | B | B | A | A+ | B | A | | | | A+ |
| Example | 62 | 50 | 7 | 33 | 20 | 0 .35 | 7.3 | 1.0 | >1.0 × 10\hat{ }15 | Favorable | 100 |
| 62 | | B | B | A | A+ | A | A | | | | A+ |
| Example | 63 | 50 | 7 | 33 | 20 | 0.30 | 7.3 | 1.0 | >1.0 × 10\hat{ }15 | Favorable | 100 |
| 63 | | B | B | A | A+ | A | A | | | | A+ |

TABLE 12-1

| | | Composition (parts by mass) | | | | | | | | | | Content |
|---|---|---|---|---|---|---|---|---|---|---|---|---|
| | | | | | | | | | (F) Cross- | | (D) Content | Ratio of |
| | | | | | (B) Radical | | | | linking | | Ratio of | (F9) to |
| | | | | | Polymerizable | | | | Agent | | Colorant to | (F1) to |
| | | | (A1) | (A2) | Compound | (C1) | | | (F1) to | | Total Solid | (F9) |
| | Compo- | Pigment | First | Second | (B1) to (B4) | Photo | (D) | <(E) | (F9) | | Content | [% by |
| | sition | Dispersion | Resin | Resin | compounds | Initiator | Colorant | Dispersant> | Compounds | Solvent | [% by mass] | mass] |
| Example | 7 | Bk-2 | PI-1 | — | DPHA (35) | NCI-831 | Bk-S0100CF | S-20000 | FR-201 | MBA | 22.0 | — |
| 7 | | | (65) | | | (12) | (37.9) | (12.6) | (10) | PGMEA | | |
| Example | 64 | Bk-2 | PI-1 | — | DPHA (35) | NCI-831 | Bk-S0100CF | S-20000 | FR-201 (10) | MBA | 21.7 | 16.7 |
| 64 | | | (65) | | | (12) | (37.9) | (12.6) | TEPIC-L (2) | PGMEA | | |
| Example | 65 | Bk-2 | PI-1 | — | DPHA (35) | NCI-831 | Bk-S0100CF | S-20000 | FR-201 (10) | MBA | 21.5 | 28.6 |
| 65 | | | (65) | | | (12) | (37.9) | (12.6) | TEPIC-L (4) | PGMEA | | |
| Example | 66 | Bk-2 | PI-1 | — | DPHA (35) | NCI-831 | Bk-S0100CF | S-20000 | FR-201 (10) | MBA | 21.2 | 37.5 |
| 66 | | | (65) | | | (12) | (37.9) | (12.6) | TEPIC-L (6) | PGMEA | | |
| Example | 67 | Bk-2 | PI-1 | — | DPHA (35) | NCI-831 | Bk-S0100CF | S-20000 | FR-201 (10) | MBA | 20.9 | 47.4 |
| 67 | | | (65) | | | (12) | (37.9) | (12.6) | TEPIC-L (9) | PGMEA | | |
| Example | 68 | Bk-2 | PI-1 | — | DPHA (35) | NCI-831 | Bk-S0100CF | S-20000 | FR-201 (10) | MBA | 21.6 | 28.6 |
| 68 | | | (65) | | | (12) | (37.9) | (12.6) | TAZ-G (4) | PGMEA | | |
| Example | 69 | Bk-2 | PI-1 | — | DPHA (35) | NCI-831 | Bk-S0100CF | S-20000 | FR-201 (10) | MBA | 21.6 | 28.6 |
| 69 | | | (65) | | | (12) | (37.9) | (12.6) | TG-G (4) | PGMEA | | |
| Example | 70 | Bk-2 | PI-1 | — | DPHA (35) | NCI-831 | Bk-S0100CF | S-20000 | FR-201 (10) | MBA | 21.5 | 28.6 |
| 70 | | | (65) | | | (12) | (37.9) | (12.6) | TEPIC-FL | PGMEA | | |
| | | | | | | | | | (4) | | | |
| Example | 71 | Bk-2 | PI-1 | — | DPHA (35) | NCI-831 | Bk-S0100CF | S-20000 | FR-201 (10) | MBA | 21.5 | 28.6 |
| 71 | | | (65) | | | (12) | (37.9) | (12.6) | ICA-GST (4) | PGMEA | | |

TABLE 12-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | | |
| | | | | | | Opening | Heat | | | Light-emitting | |
| | | | | | Pattern | Width | Resistance | | | Characteristics | |
| | | | | | Cross- | Dimension | Difference | | | of Organic EL | |
| | | | Develop- | Pattern | section | between | in High- | | | Display Device | |
| | | | ment | Cross- | Shape | Before and | temperature | | Insulation | | Characteristics |
| | | | Residue | section | after | After | Weight | Light- | Properties | | after |
| | | | Presence | Shape after | Thermal | Thermal | Residual | blocking | Surface | | Durability |
| | Compo- | Sensitivity | Area | Development | Curing | Curing | Ratio [% | OD | Resistivity | Initial | Test |
| | sition | [mJ/cm²] | [%] | [°] | [°] | [μm] | by mass] | Value | [Ω/□] | Characteristics | [%] |
| Example | 7 | 50 | 7 | 37 | 22 | 0.55 | 7.3 | 1.0 | >1.0 × 10\hat{ }15 | Favorable | 100 |
| 7 | | B | B | A | A+ | B | A | | | | A+ |
| Example | 64 | 50 | 6 | 36 | 20 | 0.50 | 7.1 | 1.0 | >1.0 × 10\hat{ }15 | Favorable | 100 |
| 64 | | B | B | A | A+ | B | A | | | | A+ |
| Example | 65 | 50 | 3 | 32 | 20 | 0.30 | 6.8 | 1.0 | >1.0 × 10\hat{ }15 | Favorable | 100 |
| 65 | | B | A | A | A+ | A | A | | | | A+ |
| Example | 66 | 50 | 3 | 32 | 20 | 0.30 | 6.8 | 1.0 | >1.0 × 10\hat{ }15 | Favorable | 100 |
| 66 | | B | A | A | A+ | A | A | | | | A+ |
| Example | 67 | 50 | 3 | 36 | 20 | 0.55 | 7.1 | 1.0 | >1.0 × 10\hat{ }15 | Favorable | 100 |
| 67 | | B | A | A | A+ | B | A | | | | A+ |
| Example | 68 | 50 | 3 | 32 | 20 | 0.35 | 6.8 | 1.0 | >1.0 × 10\hat{ }15 | Favorable | 100 |
| 68 | | B | A | A | A+ | A | A | | | | A+ |
| Example | 69 | 50 | 3 | 32 | 20 | 0.30 | 6.8 | 1.0 | >1.0 × 10\hat{ }15 | Favorable | 100 |
| 69 | | B | A | A | A+ | A | A | | | | A+ |
| Example | 70 | 50 | 3 | 33 | 20 | 0.30 | 7.0 | 1.0 | >1.0 × 10\hat{ }15 | Favorable | 100 |
| 70 | | B | A | A | A+ | A | A | | | | A+ |
| Example | 71 | 50 | 3 | 34 | 20 | 0.30 | 7.2 | 1.0 | >1.0 × 10\hat{ }15 | Favorable | 100 |
| 71 | | B | A | A | A+ | A | A | | | | A+ |

TABLE 13-1

| | | Composition (parts by mass) | | | | | | | | | (D) | | |
|---|---|---|---|---|---|---|---|---|---|---|---|---|---|
| | | | | (B) Radical | | | | (F) Cross- | | | Content | | Content |
| | | | | Poly- | | | | linking | | | Rate of | Content | Rate of |
| | | | | merizable | | | | Agent | (G) | | Colorant to | Rate of | (F9) to |
| | | Pigment | (A1) | Compound | (C1) | | <(E) | (F1) to | Chain | | Total Solid | Two | (F1) to |
| | Compo- | Dis- | First | (B1) to (B4) | Photo | (D) | Dis- | (F9) | Transfer | | Content [% | of (F1) | (F9) [% |
| | sition | persion | Resin | compounds | Initiator | Colorant | persant> | Compounds | Agent | Solvent | by mass] | to (F8) | by mass] |
| Example | 7 | Bk-2 | PI-1 | DPHA (35) | NCI-831 | Bk-S0100CF | S-20000 | FR-201 | — | MBA | 22.0 | — | — |
| 7 | | | (65) | | (12) | (37.9) | (12.6) | (10) | | PGMEA | | | |
| Example | 72 | Bk-2 | PI-1 | DPHA (35) | NCI-831 | Bk-S0100CF | S-20000 | FR-201 | TMMP | MBA | 21.9 | — | — |
| 72 | | | (65) | | (12) | (37.9) | (12.6) | (10) | (0.3) | PGMEA | | | |
| Example | 73 | Bk-2 | PI-1 | DPHA (35) | NCI-831 | Bk-S0100CF | S-20000 | FR-201 | TMMP | MBA | 21.9 | — | — |
| 73 | | | (65) | | (12) | (37.9) | (12.6) | (10) | (1) | PGMEA | | | |
| Example | 74 | Bk-2 | PI-1 | DPHA (35) | NCI-831 | Bk-S0100CF | S-20000 | FR-201 | TMMP | MBA | 21.2 | — | — |
| 74 | | | (65) | | (12) | (37.9) | (12.6) | (10) | (6) | PGMEA | | | |
| Example | 75 | Bk-2 | PI-1 | DPHA (35) | NCI-831 | Bk-S0100CF | S-20000 | FR-201 | DPMP | MBA | 21.9 | — | — |
| 75 | | | (65) | | (12) | (37.9) | (12.6) | (10) | (1) | PGMEA | | | |
| Example | 76 | Bk-2 | PI-1 | DPHA (35) | NCI-831 | Bk-S0100CF | S-20000 | IDE-1 | TMMP | MBA | 21.9 | — | — |
| 76 | | | (65) | | (12) | (37.9) | (12.6) | (10) | (1) | PGMEA | | | |
| Example | 77 | Bk-2 | PI-1 | DPHA (35) | NCI-831 | Bk-S0100CF | S-20000 | XD-1000-H | TMMP | MBA | 21.9 | — | — |
| 77 | | | (65) | | (12) | (37.9) | (12.6) | (10) | (1) | PGMEA | | | |
| Example | 78 | Bk-2 | PI-1 | DPHA (35) | NCI-831 | Bk-S0100CF | S-20000 | NC-7000L | TMMP | MBA | 21.9 | — | — |
| 78 | | | (65) | | (12) | (37.9) | (12.6) | (10) | (1) | PGMEA | | | |
| Example | 79 | Bk-2 | PI-1 | DPHA (35) | NCI-831 | Bk-S0100CF | S-20000 | FR-201 (6) | TMMP | MBA | 21.9 | 60/40 | — |
| 79 | | | (65) | | (12) | (37.9) | (12.6) | XD-1000-H | (1) | PGMEA | | | |
| | | | | | | | | (4) | | | | | |
| Example | 80 | Bk-2 | PI-1 | DPHA (35) | NCI-831 | Bk-S0100CF | S-20000 | FR-201 (10) | TMMP | MBA | 21.4 | — | 28.6 |
| 80 | | | (65) | | (12) | (37.9) | (12.6) | TEPIC-L | (1) | PGMEA | | | |
| | | | | | | | | (4) | | | | | |

TABLE 13-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | | |
| | | | | | | Opening | Heat | | | Light-emitting | |
| | | | | | Pattern | Width | Resistance | | | Characteristics | |
| | | | | | Cross- | Dimension | Difference | | | of Organic EL | |
| | | | Develop- | Pattern | section | between | in High- | | | Display Device | |
| | | | ment | Cross- | Shape | Before and | temperature | | Insulation | | Characteristics |
| | | | Residue | section | after | After | Weight | Light- | Properties | | after |
| | | | Presence | Shape after | Thermal | Thermal | Residual | blocking | Surface | | Durability |
| | Compo- | Sensitivity | Area | Development | Curing | Curing | Ratio | OD | Resistivity | Initial | Test |
| | sition | [mJ/cm²] | [%] | [°] | [°] | [μm] | [% by mass] | Value | [Ω/□] | Characteristics | [%] |
| Example | 7 | 50 | 7 | 37 | 22 | 0.55 | 7.3 | 1.0 | >1.0 × 10\hat{ }15 | Favorable | 100 |
| 7 | | B | B | A | A+ | B | A | | | | A+ |
| Example | 72 | 40 | 7 | 33 | 20 | 0.40 | 7.5 | 1.0 | >1.0 × 10\hat{ }15 | Favorable | 100 |
| 72 | | A | B | A | A+ | A | A | | | | A+ |
| Example | 73 | 30 | 7 | 30 | 20 | 0.30 | 7.6 | 1.0 | >1.0 × 10\hat{ }15 | Favorable | 100 |
| 73 | | A+ | B | A+ | A+ | A | A | | | | A+ |
| Example | 74 | 25 | 10 | 40 | 30 | 0.40 | 9.1 | 1.0 | >1.0 × 10\hat{ }15 | Favorable | 100 |
| 74 | | A+ | B | A | A+ | A | A | | | | A+ |
| Example | 75 | 35 | 7 | 33 | 25 | 0.35 | 8.0 | 1.0 | >1.0 × 10\hat{ }15 | Favorable | 100 |
| 75 | | A | B | A | A+ | A | A | | | | A+ |
| Example | 76 | 30 | 7 | 32 | 22 | 0.35 | 8.3 | 1.0 | >1.0 × 10\hat{ }15 | Favorable | 100 |
| 76 | | A+ | B | A | A+ | A | A | | | | A+ |
| Example | 77 | 30 | 7 | 30 | 20 | 0.35 | 7.7 | 1.0 | >1.0 × 10\hat{ }15 | Favorable | 100 |
| 77 | | A+ | B | A+ | A+ | A | A | | | | A+ |
| Example | 78 | 30 | 7 | 30 | 20 | 0.35 | 7.7 | 1.0 | >1.0 × 10\hat{ }15 | Favorable | 100 |
| 78 | | A+ | B | A+ | A+ | A | A | | | | A+ |
| Example | 79 | 30 | 7 | 27 | 20 | 0.20 | 6.1 | 1.0 | >1.0 × 10\hat{ }15 | Favorable | 100 |
| 79 | | A+ | B | A+ | A+ | A+ | | | | | A+ |
| Example | 80 | 30 | 3 | 27 | 20 | 0.20 | 6.1 | 1.0 | >1.0 × 10\hat{ }15 | Favorable | 100 |
| 80 | | A+ | A | A+ | A+ | A+ | | | | | A+ |

TABLE 14-1

| | | | | | | | | | | | (D) | | |
|---|---|---|---|---|---|---|---|---|---|---|---|---|---|
| | | | | | | | | | | | Content | | |
| | | | | | | | | | | | Rate of | | |
| | | Composition (parts by mass) | | | | | | | | | Colorant | | Content |
| | | | | | (B) Radical | | | | (F) Cross- | | to Total | Content | Rate of |
| | | Pig- | | | Polymerizable | | | | linking | | Solid | Rate of | (F9) to |
| | | ment | (A1) | (A2) | Compound | (C) | | <(E) | Agent | | Constant | Two of | (F1) to |
| | Compo- | Disper- | First | Second | (B1) to (B4) | Photo | (D) | Disper- | (F1) to (F9) | | [% by | (F1) | (F9) [% |
| | sition | sion | Resin | Resin | compounds | Initiator | Colorant | sant> | Compounds | Solvant | mass] | to (F8) | by mass] |
| Example | 7 | Bk-2 | PI-1 | — | DPHA (35) | NCI-831 | Bk-S0100CF | S-20000 | FR-201 | MBA | 22.0 | — | — |
| 7 | | | (65) | | | (12) | (37.9) | (12.6) | (10) | PGMEA | | | |
| Example | 81 | Bk-2 | PI-1 | — | DPHA (35) | NCI-831 | Bk-S0100CF | S-20000 | FLE-3 | MBA | 22.0 | — | — |
| 81 | | | (65) | | | (12) | (37.9) | (12.6) | (10) | PGMEA | | | |
| Example | 82 | Bk-2 | PI-1 | — | DPHA (35) | NCI-831 | Bk-S0100CF | S-20000 | TBIS-RXG | MBA | 22.0 | — | — |
| 82 | | | (65) | | | (12) | (37.9) | (12.6) | (10) | PGMEA | | | |
| Example | 83 | Bk-2 | PI-1 | — | DPHA (35) | NCI-831 | Bk-S0100CF | S-20000 | WHR-991S | MBA | 22.0 | — | — |
| 83 | | | (65) | | | (12) | (37.9) | (12.6) | (10) | PGMEA | | | |
| Example | 84 | Bk-2 | PI-1 | — | DPHA (35) | NCI-831 | Bk-S0100CF | S-20000 | TBIS- | MBA | 22.0 | — | — |
| 84 | | | (65) | | | (12) | (37.9) | (12.6) | BNG200 | PGMEA | | | |
| | | | | | | | | | (10) | | | | |
| Example | 85 | Bk-2 | PI-1 | — | DPHA (35) | NCI-831 | Bk-S0100CF | S-20000 | TBIS-RXG | MBA | | 60/90 | — |
| 85 | | | (65) | | | (12) | (37.9) | (12.6) | (6) | PGMEA | | | |
| | | | | | | | | | FR-201 (4) | | | | |
| Example | 86 | Bk-2 | PI-1 | — | DPHA (35) | NCI-831 | Bk-S0100CF | S-20000 | WHR-991S | MBA | | 60/90 | — |
| 86 | | | (65) | | | (12) | (37.9) | (12.6) | (6) | PGMEA | | | |
| | | | | | | | | | FR-201 (4) | | | | |
| Example | 87 | Bk-2 | PI-1 | — | DPHA (35) | NCI-831 | Bk-S0100CF | S-20000 | TBIS-RXG | MBA | 22.0 | — | 28.6 |
| 87 | | | (65) | | | (12) | (37.9) | (12.6) | (10) | PGMEA | | | |
| | | | | | | | | | TEPIC-L | | | | |
| | | | | | | | | | (4) | | | | |
| Example | 88 | Bk-2 | PI-1 | — | DPHA (35) | NCI-831 | Bk-S0100CF | S-20000 | WHR-991S | MBA | 22.0 | — | 28.6 |
| 88 | | | (65) | | | (12) | (37.9) | (12.6) | (10) | PGMEA | | | |
| | | | | | | | | | TEPIC-L | | | | |
| | | | | | | | | | (4) | | | | |

TABLE 14-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | | |
| | | | | | | Opening | Heat | | | Light-emitting | |
| | | | | | Pattern | Width | Resistance | | | Characterististics | |
| | | | | | Cross- | Dimension | Difference | | | of Organic EL | |
| | | | | Pattern | section | between | in High- | | | Display Device | |
| | | | Development | Cross- | Shape | Before | temperature | | Insulation | | Characteristics |
| | | | Residue | section | after | and After | Weight | Light- | Properties | | after |
| | | | Presence | Shape after | Thermal | Thermal | Residual | blocking | Surface | | Durability |
| | | Sensitivity | Area | Development | Curing | Curing | Ratio | OD | Resistivity | Initial | Test |
| | | [mJ/cm²] | [%] | [°] | [°] | [μm] | [% by mass] | Value | [Ω/□] | Characteristics | [%] |
| Example | 7 | 50 | 7 | 37 | 22 | 0.55 | 7.3 | 1.0 | >1.0 × 10\hat{ }15 | Favorable | 100 |
| 7 | | B | B | A | A+ | B | A | | | | A+ |
| Example | 81 | 50 | 7 | 37 | 25 | 0.60 | 7.3 | 1.0 | >1.0 × 10\hat{ }15 | Favorable | 100 |
| 81 | | B | B | A | A+ | B | A | | | | A+ |
| Example | 82 | 50 | 7 | 37 | 22 | 0.55 | 7.3 | 1.0 | >1.0 × 10\hat{ }15 | Favorable | 100 |
| 82 | | B | B | A | A+ | B | A | | | | A+ |
| Example | 83 | 50 | 7 | 37 | 22 | 0.55 | 7.3 | 1.0 | >1.0 × 10\hat{ }15 | Favorable | 100 |
| 83 | | B | B | A | A+ | B | A | | | | A+ |
| Example | 84 | 50 | 7 | 37 | 25 | 0.60 | 7.3 | 1.0 | >1.0 × 10\hat{ }15 | Favorable | 100 |
| 84 | | B | B | A | A+ | B | A | | | | A+ |
| Example | 85 | 50 | 7 | 33 | 20 | 0.25 | 6.5 | 1.0 | >1.0 × 10\hat{ }15 | Favorable | 100 |
| 85 | | B | B | A | A+ | A | A | | | | A+ |
| Example | 86 | 50 | 7 | 33 | 20 | 0.25 | 6.5 | 1.0 | >1.0 × 10\hat{ }15 | Favorable | 100 |
| 86 | | B | B | A | A+ | A | A | | | | A+ |
| Example | 87 | 50 | 3 | 32 | 20 | 0.25 | 6.5 | 1.0 | >1.0 × 10\hat{ }15 | Favorable | 100 |
| 87 | | B | A | A | A+ | A | A | | | | A+ |
| Example | 88 | 50 | 3 | 32 | 20 | 0.25 | 6.5 | 1.0 | >1.0 × 10\hat{ }15 | Favorable | 100 |
| 88 | | B | A | A | A+ | A | A | | | | A+ |

TABLE 15-1

| | | | | | | | | | | | | | (D) |
|---|---|---|---|---|---|---|---|---|---|---|---|---|---|
| | | | | | | | | | | | | | Content |
| | | Composition (parts by mass) | | | | | | | | | | Content | Rate of |
| | | | | | (B) Radical | | | | (F) Cross- | | | Rate of | Colorant |
| | | | | | Poly- | | | | linking | | | (A1) to | to Total |
| | | Pig- | | | merizable | | | | Agent | (G) | | (A1) + | Solid |
| | | ment | (A1) | (A2) | Compound | (C1) | | <(E) | (F1) to | Chain | | (A2) | Content |
| | Compo- | Dis- | First | Second | (B1) to (B4) | Photo | (D) | Disper- | (F9) Com- | Transfer | | [% by | [% by |
| | sition | persion | Resin | Resin | compounds | Initiator | Colorant | sant> | pounds | Agent | Solvent | mass] | mass] |
| Comparative | 89 | Bk-1 | — | AC-1 | DPHA (35) | NCI-831 | Bk-S0100CF | S-20000 | FR-201 | — | MBA | 0 | 22.0 |
| Example 1 | | | | (65) | | (12) | (37.9) | (12.6) | (10) | | PGMEA | | |
| Comparative | 90 | Bk-2 | PI-1 | — | DPHA (35) | NCI-831 | Bk-S0100CF | S-20000 | jer-834 | — | MBA | 100 | 2.5 |
| Example 2 | | | (65) | | | (12) | (3.1) | (1) | (10) | | PGMEA | | |
| Comparative | 91 | Bk-2 | PI-1 | — | DPHA (35) | NCI-831 | Bk-S0100CF | S-20000 | jer-834 | — | MBA | 100 | 10.0 |
| Example 3 | | | (65) | | | (12) | (14) | (4.7) | (10) | | PGMEA | | |
| Comparative | 92 | Bk-2 | PI-1 | — | DPHA (35) | NCI-831 | Bk-S0100CF | S-20000 | jer-834 | — | MBA | 100 | 22.0 |
| Example 4 | | | (65) | | | (12) | (37.9) | (12.6) | (10) | | PGMEA | | |
| Comparative | 93 | Bk-2 | PI-1 | — | DPHA (35) | NCI-831 | Bk-S0100CF | S-20000 | jer-834 | TMMP | MBA | 100 | 22.0 |
| Example 5 | | | (65) | | | (12) | (37.9) | (12.6) | (10) | (0.3) | PGMEA | | |
| Comparative | 94 | Bk-2 | PI-1 | — | DPHA (35) | NCI-831 | Bk-S0100CF | S-20000 | EOCN- | — | MBA | 100 | 32.0 |
| Example 6 | | | (65) | | | (12) | (37.9) | (12.6) | 1020 | | PGMEA | | |
| | | | | | | | | | (10) | | | | |
| Comparative | 95 | Bk-6 | PI-1 | — | DPHA (35) | NCI-831 | P.R.254 | D.BYK- | jer-834 | — | MBA | 100 | 22.0 |
| Example 7 | | | (65) | | | (12) | (23.8) | 167 | (10) | | PGMEA | | |
| | | | | | | | P.Y.139 | (22.7) | | | | | |
| | | | | | | | (10.2) | | | | | | |
| | | | | | | | P.B.15:6 | | | | | | |
| | | | | | | | (34.1) | | | | | | |
| Comparative | 96 | Bk-2 | PI-5 | — | DPHA (35) | NCI-831 | Bk-S0100CF | S-20000 | FR-201 | — | MBA | 100 | 2.5 |
| Example 8 | | | (65) | | | (12) | (37.9) | (12.6) | (10) | | PGMEA | | |
| Comparative | 97 | Bk-2 | PI-1 | — | DPHA (35) | NCI-831 | Bk-S0100CF | S-20000 | FR-201 | — | MBA | 100 | 0.0 |
| Example 9 | | | (65) | | | (12) | (3.1) | (1) | (10) | | PGMEA | | |
| Comparative | 98 | — | PI-1 | — | DPHA (35) | NCI-831 | — | — | FR-201 | — | MBA | 100 | 0.0 |
| Example 10 | | | (65) | | | (12) | | | (10) | | PGMEA | | |

TABLE 15-2

| | | Photosensitive Characteristics/Cured Film Characteristics | | | | | | | | | |
|---|---|---|---|---|---|---|---|---|---|---|---|
| | | | | | | Change in | | | | | |
| | | | | | | Pattern | | | | | |
| | | | | | | Opening | Heat | | | Light-emitting | |
| | | | | | Pattern | Width | Resistance | | | Characteristics | |
| | | | | | Cross- | Dimension | Difference | | | of Organic EL | |
| | | | Develop- | Pattern | section | between | in High- | | | Display Device | |
| | | | ment | Cross- | Shape | Before and | temperature | | Insulation | | Characteristics |
| | | | Residue | section | after | After | Weight | Light- | Properties | | after |
| | | | Presence | Shape after | Thermal | Thermal | Residual | blocking | Surface | Initial | Durability |
| | Compo- | Sensitivity | Area | Development | Curing | Curing | Ratio [% | OD | Resistivity | Charac- | Test |
| | sition | [mJ/cm²] | [%] | [°] | [°] | [μm] | by mass] | Value | [Ω/□] | teristics | [%] |
| Comparative | 89 | 35 | 40 | 32 | 20 | 0.55 | 36.8 | 1.0 | >1.0 × 10\hat{ }15 | Favorable | 30 |
| Example 1 | | A | D | A | A+ | B | D | | | | E |
| Comparative | 90 | 55 | 20 | 53 | 33 | 1.20 | 8.5 | 0.15 | >1.0 × 10\hat{ }15 | Favorable | 100 |
| Example 2 | | B | C | B | A | D | A | | | | A+ |
| Comparative | 91 | 65 | 40 | 55 | 37 | 1.10 | 10.1 | 0.5 | >1.0 × 10\hat{ }15 | Favorable | 100 |
| Example 3 | | C | D | B | A | D | A | | | | A+ |
| Comparative | 92 | 90 | 80 | 60 | 40 | 1.20 | 12.2 | 1.0 | >1.0 × 10\hat{ }15 | Favorable | 100 |
| Example 4 | | C | E | B | A | D | A | | | | A+ |
| Comparative | 93 | 80 | 80 | 60 | 40 | 1.20 | 12.5 | 1.0 | >1. 0 × 10\hat{ }15 | Favorable | 100 |
| Example 5 | | C | E | B | A | D | A | | | | A+ |
| Comparative | 94 | 85 | 80 | 60 | 40 | 1.15 | 12.0 | 1.0 | >1.0 × 10\hat{ }15 | Favorable | 100 |
| Example 6 | | C | E | B | A | D | A | | | | A+ |
| Comparative | 95 | 110 | 50 | 60 | 40 | 1.20 | 15.1 | 1.0 | 1.0 × 10\hat{ }15 | Favorable | 95 |
| Example 7 | | D | E | B | A | D | B | | | | A |
| Comparative | 96 | 70 | 7 | 42 | 25 | 0.70 | 7.7 | 1.0 | >1.0 × 10\hat{ }15 | Favorable | 100 |
| Example 8 | | C | B | A | A+ | C | A | | | | A+ |
| Comparative | 97 | 30 | 2 | 31 | 20 | 0.70 | 4.1 | 0.15 | >1.0 × 10\hat{ }15 | Favorable | 100 |
| Example 9 | | A | A | A | A+ | C | A+ | | | | A+ |
| Comparative | 98 | 25 | 0 | 30 | 20 | 0.70 | 4.0 | — | >1.0 × 10\hat{ }15 | Favorable | 100 |
| Example 10 | | A+ | A+ | A+ | A+ | C | A+ | | | | A+ |

### EXAMPLE 89

(Method for Manufacturing Organic EL Display without Polarizing Layer)

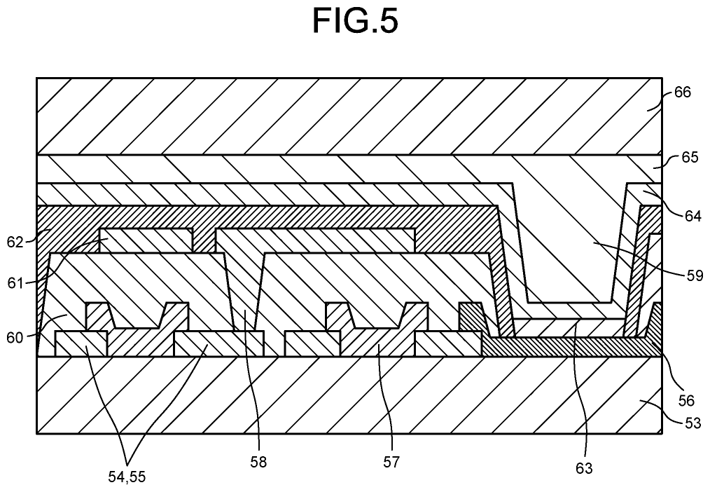

FIG. 5 shows therein an outline of an organic EL display to be prepared. First, a laminated film of chromium and gold was formed by an electron beam evaporation method on a 38×46 mm non-alkali glass substrate 53, and a source electrode 54 and a drain electrode 55 were formed by etching. Next, APC (silver/palladium/copper=98.07/0.87/1.06 (mass ratio)) of 100 nm was deposited by sputtering, and subjected to pattern processing by etching to form an APC layer, and an ITO of 10 nm was further deposited by sputtering for an upper layer on the APC layer, and etched to form a reflective electrode 56 as a first electrode. After cleaning the electrode surface with oxygen plasma, an amorphous IGZO was deposited by sputtering, and etched to form an oxide semiconductor layer 57 between the source and drain electrodes. Next, a positive photosensitive polysiloxane-based material (SP-P2301; manufactured by Toray Industries, Inc.) was deposited by a spin coating method, and after making a via hole 58 and a pixel region 59 as openings by photolithography, thermally cured to form a gate insulation layer 60. Thereafter, gold was deposited by an electron beam evaporation method, and etched to form a gate electrode 61, thereby providing an oxide TFT array.

In accordance with the above-mentioned method described in Example 1, the composition 7 was applied and prebaked on the oxide TFT array to form a film, and the film was subjected to exposure for patterning through a photomask with a predetermined pattern, and development and rinsing to make a pixel region as an opening, and then thermally cured to form a TFT protective layer/pixel defining layer 62 with light-blocking property. In accordance with the method described above, openings of 70 μm in width and 260 μm in length were arranged at a pitch of 155 μm in the width direction and a pitch of 465 μm in the length direction, and the pixel defining layer in a shape for exposing the reflective electrode 56 through the respective openings was formed only on a substrate effective area in a limited fashion. It is to be noted that the openings will finally serve for light-emitting pixels of an organic EL display. Further, the substrate effective area was a square of 16 mm on a side, and the pixel defining layer was formed to have a thickness of about 1.0 μm.

Next, an organic EL light-emitting layer 63 was formed by the method described in the section (16) mentioned above, with the use of the compound (HT-1) as a hole injection layer, the compound (HT-2) as a hole transport layer, the compound (GH-1) as a host material, the compound (GD-1) as a dopant material, and the compound (ET-1) and the compound (LiQ) as electron transport materials.

Thereafter, MgAg (magnesium/silver=10/1 (volume ratio)) of 10 nm was deposited by a vapor deposition method, and etched to form a transparent electrode 64 as a second electrode. Then, a sealing film 65 was formed with the use of an organic EL sealing material (Structbond (registered trademark) XMF-T; manufactured by Mitsui Chemicals, Inc.) under a low-humidity nitrogen atmosphere. Furthermore, an non-alkali glass substrate 66 was bonded onto the sealing film 65, thereby preparing, on one substrate, four top-emission organic EL displays each of 5 mm on a side without any polarizing layer.

### (Light-Emitting Characteristic Evaluation)

The organic EL display prepared by the method described above was allowed to emit light by direct-current drive at 10 mA/cm², and the luminance (Y′) in the case of irradiating the pixel defining layer part with external light, and the luminance (Y₀) in the case of irradiating the part with no external light were measured. As an index for reduction in external light reflection, the contrast was calculated by the following equation:

Contrast=Y₀/Y′

It has been determined as follows that A+, A, and B where the contrast is 0.80 or more are regarded as pass, A+ and A where the contrast is 0.90 or more are regarded as favorable effects of reduction in external light reflection, and A+ where the contrast is 0.95 or more is regarded as an excellent effect of reduction in external light reflection. It has been confirmed that the organic EL display prepared by the above-described method has contrast of 0.90, and has ability to reduce external light reflection.

A+: The contrast is 0.95 to 1.00.

A: The contrast is 0.90 to 0.94.

B: The contrast is 0.80 to 0.89.

C: The contrast is 0.70 to 0.79.

D: The contrast is 0.50 to 0.69.

E: The contrast is 0.01 to 0.49.

### EXAMPLE 90

### Evaluation of Halftone Characteristics

In accordance with the method described in Example 1 as mentioned above, a prebaked film of the composition 7 was formed to have a film thickness of 5 μm on an ITO substrate, subjected to exposure for patterning with the f-ray (wavelength: 365 nm), h-ray (wavelength: 405 nm), and g-ray (wavelength 436 nm) of an ultra-high pressure mercury lamp through a gray scale mask (MDRM MODEL 4000-5-FS; Opto-Line International, Inc.) for sensitivity measurement with the use of a double-sided alignment single-sided exposure apparatus (Mask Aligner PEM-6M; manufactured by Union Optical Co., Ltd.), and developed with the use of a small-size developing device (AD-2000; TAKIZAWA SANGYO K.K.) for photolithography, and a cured film of the composition 7 was then prepared with the use of a high-temperature inert gas oven (INH-9CD-S; manufactured by Koyo Thermo Systems Co., Ltd.). [0661]

With the use of a surface texture and contour measuring instrument (SURFCOM 1400D; TOKYO SEIMITSU CO., LTD.), at the measurement magnification of 10,000 times, the measurement length of 1.0 mm, the measurement speed of 0.30 mm/s, the film thickness after the development was measured, and the film thickness (T_{FT}) μm after the thermal curing with the exposure energy at the sensitivity according to Example 7 was measured. In a case where the exposure energy at the sensitivity according to Example 7 was denoted by (E_{FT}) mJ/cm², the film thickness (T_{HT25}) pm after thermal curing with exposure energy of 0.25×(E_{FT}) mJ/cm² was measured. As an index of halftone characteristics, the step film thickness was calculated by the following formula:

Step Film Thickness=(T_{FT})−(T_{HT25})

It has been determined as follows that A+, A, and B, and C where the step film thickness is 0.5 μm or more are regarded as pass, A+, A, and B where the step film thickness is 1.0 μm or more are regarded as favorable halftone characteristics, and A+ and A where the step film thickness is 1.5 μm or more are regarded as excellent half-tone characteristics. It has been confirmed that the cured film of the composition 7 prepared by the method described above has a step film thickness of 1.7 μm, and have excellent halftone characteristics.

A+: The step film thickness is 2.0 μm or more.

A: The step film thickness is 1.5 μm or more and less than 2.0 μm.

B: The step film thickness is 1.0 μm or more and less than 1.5 μm.

C: The step film thickness is 0.5 μm or more and less than 1.0 μm.

D: The step film thickness is 0.1 μm or more and less than 0.5μm.

E: The step film thickness is less than 0.1 μm or not measurable without any residual film after the development.

### EXAMPLE 91

### (Evaluation of Bendability)

In accordance with the method described in Example 1 as mentioned above, a prebaked film of the composition 7 was formed to have a film thickness of 1.8 μm on a PI film substrate, and with the use of a double-sided alignment-single-sided exposure system (Mask Aligner PEM-6M; manufactured by Union Optical Co., Ltd.), subjected to exposure for patterning with i-ray (wavelength: 365 nm), b-ray (wavelength: 405 nm), and g-ray (wavelength: 436 nm) of an ultra-high pressure mercury lamp. The exposure for patterning was performed through a photomask including a pattern where openings of 30 μm in width and of 50 μm in length were arranged at a pitch of 60 μm in the width direction and a pitch of 100 μm in the length direction. After the exposure for patterning, development was performed with the use of a small-size developing device (AD-2000; TAKIZAWA SANGYO K.K.) for photolithography, and a cured film of the composition 7 was then prepared with the use of a high-temperature inert gas oven (INH-9CD-S; manufactured by Koyo Thermo Systems Co., Ltd.). The PI film substrate with the cured film formed was cut into a length of 2 cm×5 cm.

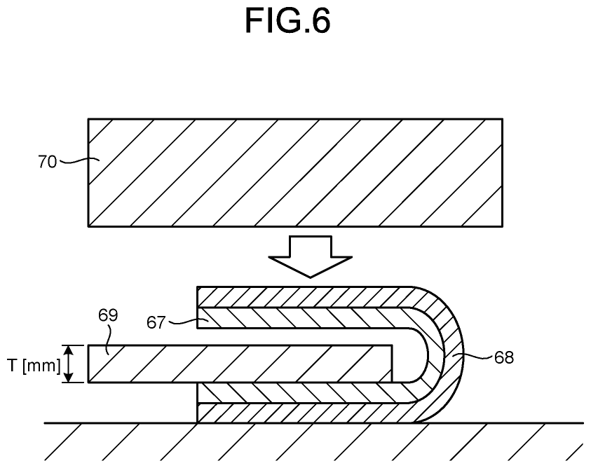

FIG. 6 shows therein a schematic diagram of a method for evaluating the bendability of the cured film. The cured film 68 formed on a PI film substrate 67 by the above-mentioned method was bent with the surface of the cured film 68 facing outward as shown in FIG. 6, and with a Si wafer 69 of (T) mm in thickness sandwiched, temporarily fixed with CELLOTAPE (registered trademark) (No. 405 (industrial); manufactured by Nichiban Co., Ltd.; width=18 mm, thickness=0.050 mm, adhesive strength=3.93 N/10 mm, tensile strength=41.6 N/10 mm). Thereafter, with a weight 70 of 1 kg in mass and 10 cm in length×10 cm in width (bottom area: 100 cm²) placed on the cured film 68, and left bent to the curvature radius (R=T/2) mm for 1 minute. The weight 70 and the Si wafer 69 were removed, and the presence or absence of any crack in the bent part of the cured film 68 was observed with the use of an FPD/LSI inspection microscope (OPTIPHOT-300; manufactured by NIKON CORPORATION). With the use of Si wafers different in thickness (T) mm, the above-mentioned bendability evaluation was repeated, and the minimum curvature radius R with which no crack was generated at the bent part was determined as an index of bendability.

It has been determined as follows that A+, A, B, and C where the minimum curvature radius R is 0.50 mm or less are regarded as pass, A+, A, and B where the minimum curvature radius R is 0.25mm or less are regarded as favorable bendability, and A+ and A where the minimum curvature radius R is 0.10 mm or less are regarded as excellent bendability. It has been confirmed that the cured film of the composition 7 prepared by the method above had a minimum curvature radius R of 0.40 mm with which no crack is generated at the bent part, and has bendability regarded as pass.

A+: The minimum curvature radius R is 0 mm. A: The minimum curvature radius R is 0.01 mm or more and 0.10 mm or less.

B: The minimum curvature radius R is 0.11 mm or more and 0.20 mm or less.

C: The minimum curvature radius R is 0.21 mm or more and 0.40 mm or less.

D: The minimum curvature radius R is 0.41 mm or more and 1.00 mm or less.

E: The minimum curvature radius R is 1.00 mm or more, or not measurable.

In accordance with similar methods, as Examples 92 to 104, with the use of the compositions 15, 56, 52, 53, 58, 59, 65, 70, 71, 72, 73, 79, and 80, a cured film of each of the compositions was prepared on a PI film substrate each, and the bendability of each film was evaluated to determine the minimum curvature radius R. The evaluation results of Examples 91 to 104 are shown in Table 16.

TABLE 16

| | | | | | | | | | | | | | Character- |
|---|---|---|---|---|---|---|---|---|---|---|---|---|---|
| | | | | | | | | | | | | | istics |
| | | | | | | | | | | | | | of Cured |
| | | Composition (parts by mass) | | | | | | | | Content | | Content | Film |
| | | | | (B) Radical | | | | | | Rate of | | Rate of | Bend- |
| | | | | Poly- | | | | (F) Cross- | | (B4) to | Content | (F9) to | ability |
| | | Pig- | | merizable | | | | linking | (G) | (B3) + | Rate of | (F1) | Minimum |
| | | ment | (A1) | Compound | (C) | | <(E) | Agent | Chain | (B4) | Two of | to (F9) | Curvature |
| | Compo- | Disper- | First | (B1) to (B4) | Photo | (D) | Disper- | (F1) to (F9) | Transer | [% by | (F1) to | [% by | Radius R |
| | sition | sion | Resin | compounds | Initiator | Colorant | sant> | Compounds | Agent | mass] | (F8) | mass] | [nm] |
| Example | 7 | Bk-2 | PI-1 | DPHA (35) | NCI-831 | Bk-S0100CF | S-20000 | FR-201 | — | — | — | — | 0.40 |
| 91 | | | (65) | | (12) | (37.9) | (12.6) | (10) | | | | | C |
| Example | 15 | Bk-2 | PI-1 | DPHA (10) | NCI-831 | Bk-S0100CF | S-20000 | FR-201 | — | — | — | — | 0.20 |
| 92 | | | (65) | DPCA-60 | (12) | (37.9) | (12.6) | (10) | | | | | B |
| | | | | (25) | | | | | | | | | |
| Example | 56 | Bk-2 | PI-1 | DPHA (10) | NCI-831 | Bk-S0100CF | S-20000 | FR-201 | — | — | — | — | 0.15 |
| 93 | | | (65) | HX-220 (25) | (12) | (37.9) | (12.6) | (10) | | | | | B |
| Example | 52 | Bk-2 | PI-1 | DPCA-60 | NCI-831 | Bk-S0100CF | S-20000 | FR-201 | — | 20 | — | — | 0.10 |
| 94 | | | (65) | (28) | (12) | (37.9) | (12.6) | (10) | | | | | A |
| | | | | HX-220 (7) | | | | | | | | | |
| Example | 53 | Bk-2 | PI-1 | DPCA-60 | NCI-831 | Bk-S0100CF | S-20000 | FR-201 | — | 40 | — | — | 0.05 |
| 95 | | | (65) | (21) | (12) | (37.9) | (12.6) | (10) | | | | | A |
| | | | | HX-220 (14) | | | | | | | | | |
| Example | 58 | Bk-2 | PI-1 | DPHA (35) | NCI-831 | Bk-S0100CF | S-20000 | FR-201 (8) | — | — | 80/20 | — | 0.35 |
| 96 | | | (65) | | (12) | (37.9) | (12.6) | XD-1000-H | | | | | C |
| | | | | | | | | (2) | | | | | |
| Example | 59 | Bk-2 | PI-1 | DPHA (35) | NCI-831 | Bk-S0100CF | S-20000 | FR-201 (6) | — | — | 60/40 | — | 0.25 |
| 97 | | | (65) | | (12) | (37.9) | (12.6) | XD-1000-H | | | | | C |
| | | | | | | | | (4) | | | | | |
| Example | 65 | Bk-2 | PI-1 | DPHA (35) | NCI-831 | Bk-S0100CF | S-20000 | FR-201 (10) | — | — | — | 28.6 | 0.35 |
| 98 | | | (65) | | (12) | (37.9) | (12.6) | TEPIC-L (4) | | | | | C |
| Example | 70 | Bk-2 | PI-1 | DPHA (35) | NCI-831 | Bk-S0100CF | S-20000 | FR-201 (10) | — | — | — | 28.6 | 0.20 |
| 99 | | | (65) | | (12) | (37.9) | (12.6) | TEPIC-FL | | | | | B |
| | | | | | | | | (4) | | | | | |
| Example | 71 | Bk-2 | PI-1 | DPHA (35) | NCI-831 | Bk-S0100CF | S-20000 | FR-201 (10) | — | — | — | 28.6 | 0.10 |
| 100 | | | (65) | | (12) | (37.9) | (12.6) | ICA-GST | | | | | A |
| | | | | | | | | (4) | | | | | |
| Example | 72 | Bk-2 | PI-1 | DPHA (35) | NCI-831 | Bk-S0100CF | S-20000 | FR-201 | TMMP | — | — | — | 0.35 |
| 101 | | | (65) | | (12) | (37.9) | (12.6) | (10) | (0.3) | | | | C |
| Example | 73 | Bk-2 | PI-1 | DPHA (35) | NCI-831 | Bk-S0100CF | S-20000 | FR-201 | TMMP | — | — | — | 0.25 |
| 102 | | | (65) | | (12) | (37.9) | (12.6) | (10) | (1) | | | | C |
| Example | 79 | Bk-2 | PI-1 | DPHA (35) | NCI-831 | Bk-S0100CF | S-20000 | FR-201 (6) | TMMP | — | 60/40 | — | 0.15 |
| 103 | | | (65) | | (12) | (37.9) | (12.6) | XD-1000-H | (1) | | | | B |
| Example | 80 | Bk-2 | PI-1 | DPHA (35) | NCI-831 | Bk-S0100CF | S-20000 | FR-201 (10) | TMMP | — | — | 28.6 | 0.20 |
| 104 | | | (65) | | (12) | (37.9) | (12.6) | TEPIC-L (4) | (1) | | | | B |

### EXAMPLE 105

### (Evaluation of Residue During Thermal Curing)

In accordance with the method described in Example 1 as mentioned above, a prebaked film of the composition 7 was formed to have a film thickness of 1.8 μm on an ITO substrate, subjected to exposure for patterning with the f-ray (wavelength: 365 nm), h-ray (wavelength: 405 nm), and g-ray (wavelength 436 nm) of an ultra-high pressure mercury lamp through a gray scale mask (MDRM MODEL 4000-5-FS; Opto-Line International, Inc.) for sensitivity measurement with the use of a double-sided alignment single-sided exposure apparatus (Mask Aligner PEM-6M; manufactured by Union Optical Co., Ltd.), and developed with the use of a small-size developing device (AD-2000; TAKIZAWA SANGYO K.K.) for photolithography, thereby preparing a developed film of the composition 7. In accordance with a similar method, a developed film of the composition 7 was separately prepared, and the ITO substrate with the developed film formed was cut in half.

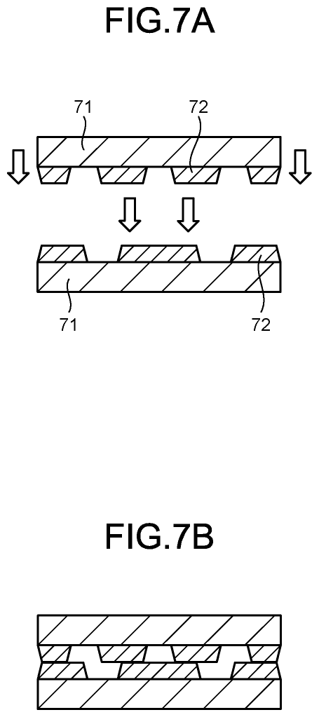

FIGS. 7A and 7B show therein schematic diagrams of a residue evaluation method during thermal curing. The ITO substrate 71 with a developed film 72 formed was cut in half by the above-mentioned method, and then stacked so as to bring the surfaces of the developed films 72 in contact with each other as shown in FIG. 7A, and brought into the state shown in FIG. 7B. With this state maintained, thermal curing was performed with the use of a high-temperature inert gas oven (INH-9CD-S; manufactured by Koyo Thermo Systems Co., Ltd.), thereby preparing a cured film of the composition 7 in a state where residues due to thermal decomposition products and sublimates during thermal curing are likely to be generated.

With the use of a field-emission scanning electron microscope (S-4800; manufactured by Hitachi High-Technologies Corporation), the resolution pattern of the developed film prepared was observed to observe the presence or absence of any residue in the openings of the line-and-space pattern with a space width of 20 μm, and the presence area (R_{DEV}) of residues in the openings after the development was calculated. In accordance with a similar method, the resolution pattern of the cured film of the upper ITO substrate in FIG. 7B was observed, and the presence area (R_{CURE}) of residues in the openings after the thermal curing was calculated. As an index of the residue during the thermal curing, the residue increase rate during the thermal curing was calculated by the following formula:

Residue Increase Rate during Thermal Curing=(R_{CRE})−(R_{DEV})

It has been determined as follows that A+, A, and B where the residue increase rate during the thermal curing is 10% or less are regarded as pass, A+ and A where the residue increase rate during the thermal curing is 5% or less are regarded as favorable residues during thermal curing, and A+ without any residue increase during the thermal curing is regarded as an excellent residue during thermal curing. It has been confirmed that the developed film and cured film of the composition 7 prepared by the above-mentioned method has a residue increase rate of 10% during the thermal curing, which is regarded as pass in terms of the residue during thermal curing.

A+: There is no residue increase during the thermal curing.

A: The residual increase rate during the thermal curing is 1 to 5%.

B: The residual increase rate during the thermal curing is 6 to 10%.

C: The residue increase rate during the thermal curing is 11 to 30%

D: The residue increase rate during the thermal curing is 31 to 50%

E: The residue increase rate during the thermal curing is 51 to 100%.

In accordance with similar methods, as Examples 106 to 112, with the use of the compositions 15, 64, 65, 72, 73, 79, and 80, and as Comparative Example 11, with the use of the composition 85, a cured film of each of the compositions was prepared on a PI film substrate each, and the bendability of each film was evaluated to determine the minimum curvature radius R. The evaluation results of Examples 105 to 112 and Comparative Example 11 are shown in Table 17.

TABLE 17

| | | | | | | | | | | | | Photosensitive |
|---|---|---|---|---|---|---|---|---|---|---|---|---|
| | | | | | | | | | | | | Characteristics/ |
| | | | | | | | | | | | Content | Cured Film |
| | | Composition (parts by mass) | | | | | | | | | Ratio of | Characteristics |
| | | | | (B) Radical | | | | | | Content | (F9) to | Residue during |
| | | | | Polymerizable | | | | (F) Cross- | (G) | Ratio of | (F1) | Thermal Curing |
| | | | (A1) | Compound | (C1) | | <(E) | linking Agent | Chain | Two of | to (F9) | Residue |
| | Compo- | Pigment | First | (B1) to (B4) | Photo | (D) | Disper- | (F1) to (F9) | Transfer | (F1) to | [% by | Increase Rate |
| | sition | Dispersion | Resin | compounds | Initiator | Colorant | sant> | Compounds | Agent | (F8) | mass] | [%] |
| Example | 7 | Bk-2 | PI-1 | DPHA (35) | NCI-831 | Bk-S0100CF | S-20000 | FR-201 | — | — | — | 10 |
| 105 | | | (65) | | (12) | (37.9) | (12.6) | (10) | | | | B |
| Example | 15 | Bk-2 | PI-1 | DPHA (10) | NCI-831 | Bk-S0100CF | S-20000 | FR-201 | — | — | — | 10 |
| 106 | | | (65) | DPCA-60 | (12) | (37.9) | (12.6) | (10) | | | | B |
| | | | | (25) | | | | | | | | |
| Example | 64 | Bk-2 | PI-1 | DPHA (35) | NCI-831 | Bk-S0100CF | S-20000 | FR-201 (10) | — | — | 167 | 3 |
| 107 | | | (65) | | (12) | (37.9) | (12.6) | TEPIC-L (2) | | | | A |
| Example | 65 | Bk-2 | PI-1 | DPHA (35) | NCI-831 | Bk-S0100CF | S-20000 | FR-201 (10) | — | — | 28 .6 | 0 |
| 108 | | | (65) | | (12) | (37.9) | (12.6) | TEPIC-L (9) | | | | A+ |
| Example | 72 | Bk-2 | PI-1 | DPHA (35) | NCI-831 | Bk-S0100CF | S-20000 | FR-201 | TMMP | — | — | 7 |
| 109 | | | (65) | | (12) | (37.9) | (12.6) | (10) | (0.3) | | | B |
| Example | 73 | Bk-2 | PI-1 | DPHA (35) | NCI-831 | Bk-S0100CF | S-20000 | FR-201 | TMMP | — | — | 7 |
| 110 | | | (65) | | (12) | (37.9) | (12.6) | (10) | (1) | | | B |
| Example | 79 | Bk-2 | PI-1 | DPHA (35) | NCI-831 | Bk-S0100CF | S-20000 | FR-201 (6) | TMMP | 60/90 | — | 3 |
| 111 | | | (65) | | (12) | (37.9) | (12.6) | XD-1000-H | (1) | | | A |
| | | | | | | | | (4) | | | | |
| Example | 80 | Bk-2 | PI-1 | DPHA (35) | NCI-831 | Bk-S0100CF | S-20000 | FR.-201 (10) | TMMP | — | 28.6 | 0 |
| 112 | | | (65) | | (12) | (37.9) | (12.6) | TEPIC-L (9) | (1) | | | A+ |
| Compar- | 85 | Bk-2 | PI-1 | DPHA (35) | NCI-831 | Bk-S0100CF | S-20000 | jer-839 | TMMP | — | — | 35 |
| ative | | | (65) | | (12) | (37.9) | (12.6) | (10) | (0.3) | | | B |
| Example | | | | | | | | | | | | |
| 11 | | | | | | | | | | | | |

### EXAMPLE 113

(Method for Manufacturing Flexible Organic EL Display without Polarizing Layer)

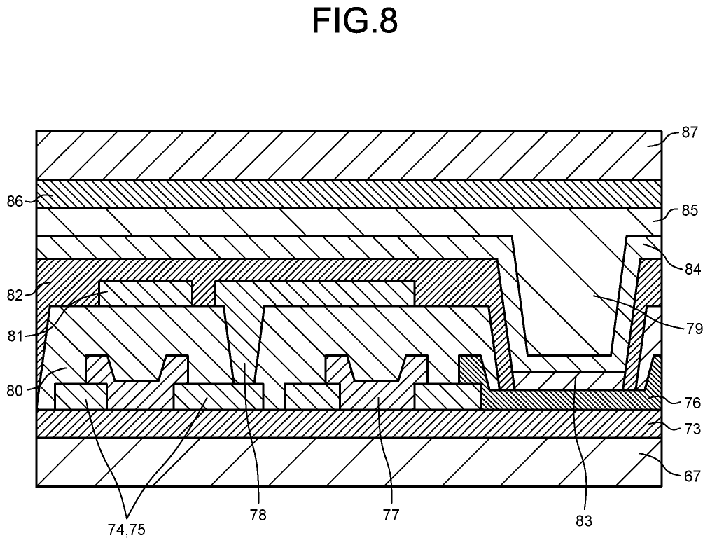

FIG. 8 shows therein an outline of an organic EL display to be prepared. First, a PI film substrate is temporarily fixed on a 38×46 mm non-alkali glass substrate with an adhesive layer, and dehydrated and baked at 130° C. for 120 seconds with the use of a hot plate (SCW-636; manufactured by Dainippon Screen Mfg. Co., Ltd.). Next, on the PI film substrate, an SiO₂ film 73 was formed as a gas barrier layer by a CVD method. On the gas barrier layer, a laminated film of chromium and gold was formed by an electron beam evaporation method, and etched to form a source electrode 74 and a drain electrode 75. Next, APC (silver/palladium/copper=98.07/0.87/1.06 (mass ratio)) of 100 nm was deposited by sputtering, and subjected to pattern processing by etching to form an APC layer, and an ITO was further deposited by sputtering for an upper layer on the APC layer, and etched to form a reflective electrode 76 as a first electrode. After cleaning the electrode surface with oxygen plasma, an amorphous IGZO was deposited by sputtering, and etched to form an oxide semiconductor layer 77 between the source and drain electrodes. Next, a positive photosensitive polysiloxane-based material (SP-P2301; manufactured by Toray Industries, Inc.) was deposited by a spin coating method, and after making a via hole 78 and a pixel region 79 as openings by photolithography, thermally cured to form a gate insulation layer 80. Thereafter, gold was deposited by an electron beam evaporation method, and etched to form a gate electrode 81, thereby providing an oxide TFT array.

In accordance with the above-mentioned method described in Example 1, the composition 52 was applied and prebaked on the oxide TFT array to form a film, and the film was subjected to exposure for patterning through a photomask with a predetermined pattern, and development and rinsing to make a pixel region as an opening, and then thermally cured to form a TFT protective layer/pixel defining layer 82 with light-blocking property. In accordance with the method described above, openings of 70 μm in width and 260 μm in length were arranged at a pitch of 155 μm in the width direction and a pitch of 465 μm in the length direction, and the pixel defining layer in a shape for exposing the reflective electrode through the respective openings was formed only on a substrate effective area in a limited fashion. It is to be noted that the openings will finally serve for light-emitting pixels of an organic EL display. Further, the substrate effective area was a square of 16 mm on a side, and the pixel defining layer was formed to have a thickness of about 1.0 μm.

Next, an organic EL light-emitting layer 83 was formed by the method described in the section (16) mentioned above, with the use of the compound (HT-1) as a hole injection layer, the compound (HT-2) as a hole transport layer, the compound (GH-1) as a host material, the compound (GD-1) as a dopant material, and the compound (ET-1) and the compound (LiQ) as electron transport materials.

Thereafter, MgAg (magnesium/silver=10/1 (volume ratio)) of 10 nm was deposited by a vapor deposition method, and etched to form a transparent electrode 84 as a second electrode. Then, a sealing film 85 was formed with the use of an organic EL sealing material (Structbond (registered trademark) XMF-T; manufactured by Mitsui Chemicals, Inc.) under a low-humidity nitrogen atmosphere. Furthermore, after a PET film substrate 87 with an SiO₂ film 86 formed was bonded as a gas barrier layer onto the sealing film, the non-alkali glass substrate is peeled from the PI film substrate, thereby preparing, on one substrate, four top-emission flexible organic EL displays each of 5 mm on a side without any polarizing layer.

### (Light-Emitting Characteristic Evaluation)

The organic EL display prepared by the method mentioned above was allowed to emit light by direct-current drive at 10 mA/cm², and the luminance (Y′) in the case of irradiating the pixel defining layer part with external light, and the luminance (Y₀) in the case of irradiating the part with no external light were measured. As an index for reduction in external light reflection, the contrast was calculated by the following equation:

Contrast=Y₀/Y′

It has been determined as follows that A+, A, and B where the contrast is 0.80 or more are regarded as pass, A+ and A where the contrast is 0.90 or more are regarded as favorable effects of reduction in external light reflection, and A+where the contrast is 0.95 or more is regarded as an excellent effect of reduction in external light reflection. It has been confirmed that the organic EL display prepared by the above-mentioned method has contrast of 0.90, and has ability to reduce external light reflection.

A+: The contrast is 0.95 to 1.00.

A: The contrast is 0.90 to 0.94.

B: The contrast is 0.80 to 0.89.

C: The contrast is 0.70 to 0.79.

D: The contrast is 0.50 to 0.69.

E: The contrast is 0.01 to 0.49.

### (Flexibility Evaluation)

The organic EL display prepared by the method mentioned above was allowed to emit light by direct-current drive at 10 mA/cm². With the light emitted, the organic EL display was curved in a U shape, with the PET film surface to serve as a display surface outward, thereby making the display part curved, and the curved surface with a curvature radius of 1 mm was held for 1 minute. After keeping the display part curved, the organic EL display caused no abnormal light emission, and it was thus confirmed that the display was a flexible organic EL display.

### INDUSTRIAL APPLICABILITY

The photosensitive resin composition, the cured film, and the element including the cured film according to the present invention are high in sensitivity, capable of forming a pattern in a low-taper shape after thermal curing, and capable of suppressing the change in pattern opening width between before and after thermal curing, thus making it possible to obtain a cured film with excellent light-blocking property, and thus, can be suitably used for organic EL displays.

### DESCRIPTION OF REFERENCE SIGNS

1, 12, 15, 26: Glass substrate

2, 16: TFT

3, 17: Cured film for TFT planarization

4, 56, 76: Reflective electrode

5a, 21a: Prebaked film

5b, 21b, 28: Cured pattern

6, 22: Mask

7, 23: Active actinic rays

8: EL light-emitting layer

9, 18, 64, 84: Transparent electrode

10, 29: Cured film for planarization

11: Cover glass

13: BLU

14: Glass substrate with BLU

19: Planarization film

20, 30: Alignment layer

24: Glass substrate with BCS

25: Glass substrate with BLU and BCS

27: Color filter

31: Color filter substrate

32: Glass substrate with BLU, BCS, and BM

33: Liquid crystal layer

34: Thick film part

35a, 35b, 35c: Thin film part

36a, 36b, 36c, 36d, 36e: Inclined side of cross section of cured pattern

37: Horizontal side of underlying substrate

47, 53, 66: Non-alkali glass substrate

48: First electrode

49: Auxiliary electrode

50: Insulation layer

51: Organic EL layer

52: Second electrode

54, 74: Source electrode

55, 75: Drain electrode

57, 77: Oxide semiconductor layer

58, 78: Via hole

59, 79: Pixel region

60, 80: Gate insulation layer

61, 81: Gate electrode

62, 82: TFT protective layer/pixel defining layer

63, 83: Organic EL light-emitting layer

65, 85: Sealing film

67: PI film substrate

68: Cured film

69: Si wafer

70: Weight

71: ITO substrate

72: Developed film

73, 86: SiO₂ film

87: PET film substrate

1. A photosensitive resin composition comprising an (A) alkali-soluble resin, a (C) photosensitive agent, a (Da) black colorant, and a (F) cross-linking agent,
wherein the (A) alkali-soluble resin contains a (A1) first resin including one or more selected from the group consisting of a (A1-1) polyimide, a (A1-2) polyimide precursor, a (A1-3) polybenzoxazole, and a (A1-4) polybenzoxazole precursor,
the one or more selected from the group consisting of the (A1-1) polyimide, the (A1-2) polyimide precursor, the (A1-3) polybenzoxazole, and the (A1-4) polybenzoxazole precursor contains a structural unit having a fluorine atom at 10 to 100 mol % to all of structural units,
a content ratio of the (Da) black colorant is 5 to 70% by mass to a total solid content, and
the (F) cross-linking agent contains one or more selected from the group consisting of:
an (F1) epoxy compound having a fluorene skeleton and two or more epoxy groups in a molecule;
an (F2) epoxy compound having an indane skeleton and two or more epoxy groups in a molecule;
an (F3) epoxy resin having a structural unit including an aromatic structure, an alicyclic structure, and an epoxy group;
an (F4) epoxy resin having a structural unit including one or more selected from the group consisting of a biphenyl structure, a terphenyl structure, a naphthalene structure, an anthracene structure, and a fluorene structure, and including two or more epoxy groups;
an (F5) epoxy compound having two or more fluorene skeletons or two or more indane skeletons, and two or more epoxy groups in a molecule;
an (F6) epoxy compound having two or more condensed polycyclic skeletons linked by a spiro skeleton, and two or more epoxy groups in a molecule;
an (F7) epoxy compound having an indolinone skeleton or an isoindolinone skeleton, and two or more epoxy groups in a molecule; and
an (F8) epoxy compound having two or more naphthalene skeletons and two or more epoxy groups in a molecule.

2. The photosensitive resin composition according to claim 1,
wherein the (F) cross-linking agent contains one or more selected from the group consisting of:
an (F1) epoxy compound having a fluorene skeleton and two or more epoxy groups in a molecule;
an (F2) epoxy compound having an indane skeleton and two or more epoxy groups in a molecule;
an (F3) epoxy resin having a structural unit including an aromatic structure, an alicyclic structure, and an epoxy group; and
an (F4) epoxy resin having a structural unit including one or more selected from the group consisting of a biphenyl structure, a terphenyl structure, a naphthalene structure, an anthracene structure, and a fluorene structure, and two or more epoxy groups.

3. The photosensitive resin composition according to claim 1,
wherein the (Da) black colorant contains a (D1a) black pigment, and
the (D 1 a) black pigment contains a (D 1 a-1 a) benzofuranone-based black pigment as a (D1a-1) black organic pigment.

4. The photosensitive resin composition according to claim 3,
wherein the (D1a-1) black organic pigment further contains a (DC) covering layer, and
the (DC) covering layer includes one or more selected from the group consisting of a (DC-1) silica covering layer, a (DC-2) metal oxide covering layer, and a (DC-3) metal hydroxide covering layer.

5. The photosensitive resin composition according to claim 1, the photosensitive resin composition containing one or more selected from the group consisting of:
as the (F1) epoxy compound having a fluorene skeleton and two or more epoxy groups in the molecule, a compound represented by general formula (11);
as the (F2) epoxy compound having an indane skeleton and two or more epoxy groups in the molecule, a compound represented by general formula (12) and/or a compound represented by general formula (13);
as the (F3) epoxy resin having a structural unit including an aromatic structure, an alicyclic structure, and an epoxy group, an epoxy resin having a structural unit represented by general formula (14); and
as the (F4) epoxy resin having a structural unit including one or more selected from the group consisting of a biphenyl structure, a terphenyl structure, a naphthalene structure, an anthracene structure, and a fluorene structure, and two or more epoxy groups, an epoxy resin having a structural unit represented by general formula (15) or a structural unit represented by general formula (16). 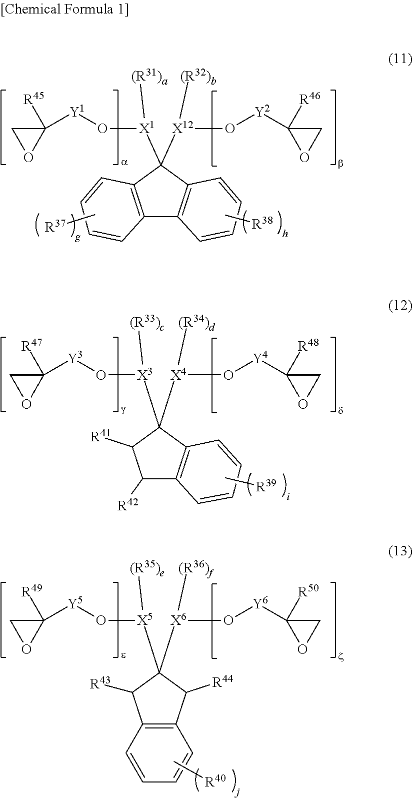
(In the general formulas (11), (12), and (13), X¹ to X⁶ each independently represent a divalent to decavalent monocyclic or condensed polycyclic aromatic hydrocarbon ring having 6 to 15 carbon atoms, or a divalent to octavalent monocyclic or condensed polycyclic aliphatic hydrocarbon ring having 4 to 10 carbon atoms. Y¹ to Y⁶ each independently represent a direct bond, an alkylene group having 1 to 10 carbon atoms, a cycloalkylene group having 4 to 10 carbon atoms, or an arylene group having 6 to 15 carbon atoms. R³¹ to R⁴⁰ each independently represent halogen, an alkyl group having 1 to 10 carbon atoms, a cycloalkyl group having 4 to 10 carbon atoms, an aryl group having 6 to 15 carbon atoms, a fluoroalkyl group having 1 to 10 carbon atoms, a fluorocycloalkyl group having 4 to 10 carbon atoms, or a fluoroaryl group having 6 to 15 carbon atoms, R⁴¹ to R⁴⁴ each independently represent hydrogen, an alkyl group having 1 to 10 carbon atoms, or a cycloalkyl group having 4 to 10 carbon atoms, or an aryl group having 6 to 15 carbon atoms, and R⁴⁵ to R⁵⁰ each independently represent hydrogen, an alkyl group having 1 to 10 carbon atoms, or a hydroxy group. a, b, c, d, e, and f each independently represent an integer of 0 to 8, and g, h, i, and j each independently represent an integer of 0 to 4. α, β, γ, δ, ε, and ζ each independently represent an integer of 1 to 4.) 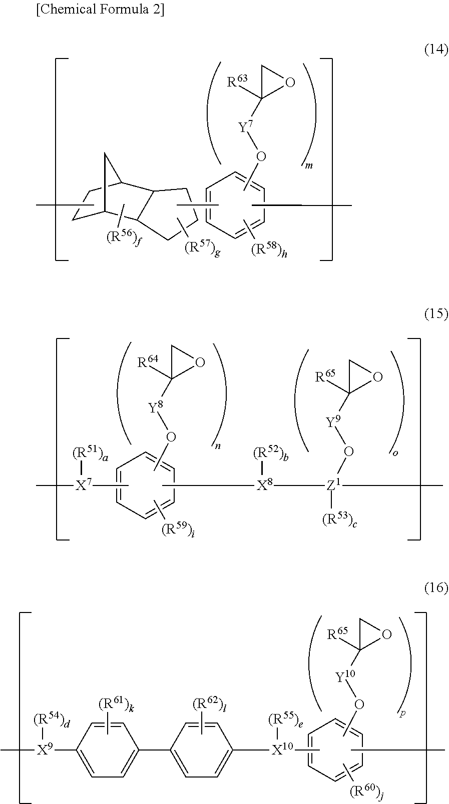
(In the general formulas (14), (15), and (16), X⁷ to X¹⁰ each independently represent an aliphatic structure having 1 to 6 carbon atoms. Y⁷ to Y¹⁰ each independently represent a direct bond, an alkylene group having 1 to 10 carbon atoms, a cycloalkylene group having 4 to 10 carbon atoms, or an arylene group having 6 to 15 carbon atoms. Z¹ represents a trivalent to 16-valent aromatic structure having 10 to 25 carbon atoms. R⁵¹ to R⁵⁵ each independently represent an alkyl group having 1 to 10 carbon atoms, a cycloalkyl group having 4 to 10 carbon atoms, or an aryl group having 6 to 15 carbon atoms, and R⁵⁶ and R⁵⁷ each independently represent an alkyl group having 1 to 10 carbon atoms, R⁵⁸ to R⁶² each independently represent halogen, an alkyl group having 1 to 10 carbon atoms, a cycloalkyl group having 4 to 10 carbon atoms, or an aryl group having 6 to 15 carbon atoms, and R⁶³ to R⁶⁶ each independently represent hydrogen, an alkyl group having 1 to 10 carbon atoms, or a hydroxy group. a, b, c, d, and e each independently represent an integer of 0 to 10, f represents an integer of 0 to 8, g represents an integer of 0 to 6, h and i each independently represent an integer of 0 to 3, j represents an integer of 0 to 2, k and 1 each independently represent an integer of 0 to 4, m, n, and o each independently represent an integer of 1 to 4, and p represents an integer of 2 to 4.)

6. The photosensitive resin composition according to claim 1,
further comprising a (B) radical polymerizable compound, wherein
the (B) radical polymerizable compound includes a (B3) flexible chain-containing aliphatic radical polymerizable compound and/or a (B4) flexible chain-containing bifunctional radical polymerizable compound, and
the (B3) flexible chain-containing aliphatic radical polymerizable compound and the (B4) flexible chain-containing bifunctional radical polymerizable compound have at least one lactone-modified chain and/or at least one lactam-modified chain.

7. The photosensitive resin composition according to claim 6,
wherein the (B) radical polymerizable compound includes a (B3) flexible chain-containing aliphatic radical polymerizable compound and a (B4) flexible chain-containing bifunctional radical polymerizable compound,
wherein the (B3) flexible chain-containing aliphatic radical polymerizable compound has, as a lactone-modified chain and/or a lactam-modified chain, a group represented by general formula (24) and three or more groups represented by general formulas (25) in a molecule, and
wherein the (B4) flexible chain-containing bifunctional radical polymerizable compound has, as a lactone-modified chain and/or a lactam-modified chain, a group represented by general formula (21) and two groups represented by general formula (25) in a molecule. 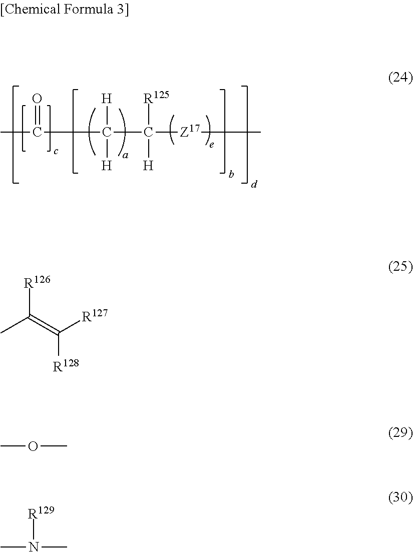
(In the general formula (24), R¹²⁵ represents hydrogen or an alkyl group having 1 to 10 carbon atoms. Z¹⁷ represents a group represented by general formula (29) or a group represented by general formula (30). a represents an integer of 1 to 10, b represents an integer of 1 to 4, c represents 0 or 1, d represents an integer of 1 to 4, and e represents 0 or 1. In a case where c is 0, d is 1. In the general formula (25), R¹²⁶ to R¹²⁸ each independently represent hydrogen, an alkyl group having 1 to 10 carbon atoms, or an aryl group having 6 to 15 carbon atoms. In the general formula (30), R¹²⁹ represents hydrogen or an alkyl group having 1 to 10 carbon atoms.) 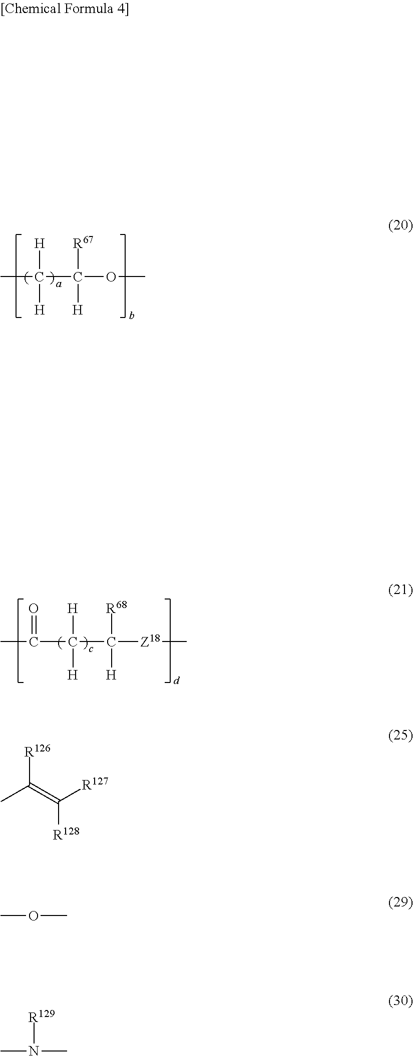
(In the general formula (20), R⁶⁷ represents hydrogen or an alkyl group having 1 to 10 carbon atoms. a represents an integer of 1 to 10, and b represents an integer of 1 to 4. In the general formula (21), R⁶⁸ represents hydrogen or an alkyl group having 1 to 10 carbon atoms. Z¹⁸ represents a group represented by general formula (29) or a group represented by general formula (30). c represents an integer of 1 to 10, and d represents an integer of 1 to 4. In the general formula (25), 10²⁶ to R¹²⁸ each independently represents hydrogen, an alkyl group having 1 to 10 carbon atoms, or an aryl group having 6 to 15 carbon atoms. In the general formula (30), R129 represents hydrogen or an alkyl group having 1 to 10 carbon atoms.)

8. The photosensitive resin composition according to claim 7,
wherein a content ratio of the (B4) flexible chain-containing bifunctional radical polymerizable compound to 100% by mass of the (B3) flexible chain-containing aliphatic radical polymerizable compound and the (B4) flexible chain-containing bifunctional radical polymerizable compound in total is 20 to 80% by mass.

9. The photosensitive resin composition according to claim 1, further containing, as the (F) cross-linking agent, a (F9) nitrogen-containing ring skeleton-containing epoxy compound.

10. The photosensitive resin composition according to claim 1, further containing a (G) polyfunctional thiol compound.

11. The photosensitive resin composition according to claim 1,
further comprising a (B) radical polymerizable compound,
wherein the (C) photosensitive agent contains a (C1) photo initiator, and
a content of the (C1) photo initiator is 10 to 30 parts by mass in a case where the (A) alkali-soluble resin and the (B) radical polymerizable compound are regarded as 100 parts by mass in total.

12. The photosensitive resin composition according to claim 1,
wherein the (Da) black colorant contains a (D1a) black pigment,
the (D1 a) black pigment contains a (D1 a-3) coloring pigment mixture of two or more colors, and the (D1 a-3) coloring pigment mixture of two or more colors contains two or more pigments selected from red, orange, yellow, green, blue or purple pigments.

13. The photosensitive resin composition according to claim 1,
wherein the (A) alkali-soluble resin further contains a (A2) second resin including one or more selected from the group consisting of a (A2-1) polysiloxane, a (A2-2) polycyclic side chain-containing resin, an (A2-3) acid-modified epoxy resin, and an (A2-4) acrylic resin, and
a content ratio of the (A1) first resin in 100% by mass in total of the (A1) first resin and the (A2) second resin is 70 to 99% by mass.

14. The photosensitive resin composition according to claim 1,
further comprising a (B) radical polymerizable compound, wherein
the (B) radical polymerizable compound includes one or more selected from the group consisting of a (B1) fluorene skeleton-containing radical polymerizable compound and/or an (B2) indane skeleton-containing radical polymerizable compound.

15. A cured film obtained by curing the photosensitive resin composition according to claim 1.

16. The cured film according to claim 15,
wherein an optical density per 1μm film thickness of the cured film is 0.3 to 5.0, and the cured film has a cured pattern with a step shape.

17. The cured film according to claim 15, wherein the cured film has a cured pattern, and an inclined side in a cross section of the cured pattern has a taper angle of 1° to 60°.

18. An element comprising the cured film according to claim 15.

19. An organic EL display comprising the cured film according to claim 15,
wherein the cured film is included as one or more selected from a pixel defining layer, an electrode insulation layer, a wiring insulation layer, an interlayer insulation layer, a TFT planarization layer, an electrode planarization layer, a wiring planarization layer, a TFT protective layer, an electrode protective layer, a wiring protective layer, and a gate insulation layer.

20. The organic EL display according to claim 19, wherein the organic EL display includes a curved display unit, and the curved surface has a curvature radius of 0.1 to 10 mm.

21. A method for manufacturing an organic EL display, the method comprising:
(1) a step of forming, on a substrate, a coating film of the photosensitive resin composition according to claim 1;
(2) a step of irradiating the coating film of the photosensitive resin composition with an active actinic ray through a photomask;
(3) developing with an alkaline solution to form a pattern of the photosensitive resin composition; and
(4) heating the pattern to obtain a cured pattern of the photosensitive resin composition.
